(19) United States
(12) Patent Application Publication
(10) Pub. No.: US 2026/0198177 A1
(43) Pub. Date: Jul. 9, 2026

(54) SEMICONDUCTOR DEVICE, DISPLAY APPARATUS, AND ELECTRONIC DEVICE

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Hajime KIMURA, Atsugi, Kanagawa (JP); Tatsunori INOUE, Yamato, Kanagawa (JP)

(21) Appl. No.: 19/131,576

(22) PCT Filed: Nov. 20, 2023
(86) PCT No.: PCT/IB2023/061666

§ 371 Date: May 21, 2025

(30) Foreign Application Priority Data
Nov. 25, 2022 (JP) 2022-188163
Dec. 16, 2022 (JP) 2022-201083

(51) Int. Cl. H10K 59/121; H10K 59/124

(52) U.S. Cl. CPC H10K 59/1213; H10K 59/124

(57) ABSTRACT

A semiconductor device that operates stably is provided. The semiconductor device includes first to fourth transistors. The first to fourth transistors each include a first insulator. The first and second transistors each include a first gate insulating film, and the third and fourth transistors each include a second gate insulating film. The first and second transistors each include a first channel formation region along a side surface of a first opening formed in the first insulator, and the third and fourth transistors each include a second channel formation region along a side surface of a second opening formed in the first insulator. The first gate insulating film is positioned above the first channel formation region, and the second gate insulating film is positioned above the second channel formation region. A thickness of the first gate insulating film is larger than a thickness of the second gate insulating film. The first and second transistors are electrically connected to each other in series, and the third and fourth transistors are electrically connected to each other in series.

### TECHNICAL FIELD

One embodiment of the present invention relates to a semiconductor device, a display apparatus, and an electronic device.

Note that one embodiment of the present invention is not limited to the above technical field. The technical field of the invention disclosed in this specification and the like relates to an object, an operation method, or a manufacturing method. Alternatively, one embodiment of the present invention relates to a process, a machine, manufacture, or a composition of matter. Therefore, specific examples of the technical field of one embodiment of the present invention disclosed in this specification include a semiconductor device, a display apparatus, a liquid crystal display apparatus, a light-emitting apparatus, a power storage device, an imaging device, a memory device, a signal processing device, a sensor, a processor, an electronic device, a system, a driving method thereof, a manufacturing method thereof, and a testing method thereof.

### BACKGROUND ART

Display apparatuses included in, for example, electronic devices for XR (Extended Reality or Cross Reality) such as VR (virtual reality) or AR (augmented reality), mobile phones (e.g., smartphones), tablet information terminals, and laptop PCs (personal computers) have been improved in various aspects in recent years. For example, display apparatuses have been developed aiming for a higher screen resolution, higher color reproducibility (NTSC ratio), a smaller driver circuit, lower power consumption, and the like.

For example, a circuit for reducing variations in the characteristics of a driving transistor included in a pixel has also been under development in order to improve the display quality of a display apparatus. In particular, Patent Document 1 discloses the invention of a pixel circuit that includes a circuit for correcting the threshold voltage of a driving transistor.

Another example is a technique of using a transistor including an oxide semiconductor in a semiconductor thin film, as a switching element included in a pixel circuit of a display apparatus.

A silicon-based semiconductor material is widely known as a material for a semiconductor thin film applicable to a transistor. Other than the silicon-based semiconductor material, an oxide semiconductor has attracted attention. Examples of oxide semiconductors include not only single-component metal oxides, such as indium oxide and zinc oxide, but also multi-component metal oxides. Among the multi-component metal oxides, in particular, an In—Ga—Zn oxide (hereinafter also referred to as IGZO) has been actively researched.

A transistor including IGZO in an active layer has an extremely low off-state current (see Non-Patent Document 1), and LSI (Large Scale Integration) and a display apparatus that utilize the characteristics have been reported (see Non-Patent Document 2 and Non-Patent Document 3). Patent Document 2 discloses the invention in which a transistor including IGZO in an active layer is used in a pixel circuit of a display apparatus.

### REFERENCES

### Patent Documents

[Patent Document 1] Japanese Published Patent Application No. 2017-10000
[Patent Document 2] Japanese Published Patent Application No. 2010-156963

### Non-Patent Documents

[Non-Patent Document 1] K. Kato et al., “Japanese Journal of Applied Physics”, 2012, volume 51, p. 021201-1-021201-7
[Non-Patent Document 2] S. Matsuda et al., “2015 Symposium on VLSI Technology Digest of Technical Papers”, 2015, p. T216-T217
[Non-Patent Document 3] S. Amano et al., “SID Symposium Digest of Technical Papers”, 2010, volume 41, issue 1, p. 626-629

### SUMMARY OF THE INVENTION

### Problems to be Solved by the Invention

In general, a display apparatus is provided with a driver circuit, and the driver circuit is provided with a variety of circuits. For example, a driver circuit having a function of a source driver is provided with a shift register circuit, a latch circuit, a source follower circuit, and the like.

In the case where the display apparatus is desired to have a high frame frequency, the shift register circuit is preferably provided with a transistor having a high driving frequency. The transistor having a high driving frequency can be manufactured by reducing the thickness of a gate insulating film between a gate and a semiconductor layer including a channel formation region. Meanwhile, a transistor used in the source follower circuit is preferably a transistor having high resistance to voltage. The transistor having high resistance to voltage can be manufactured by increasing the thickness of a gate insulating film.

In manufacturing the driver circuit, it is preferable to manufacture the shift register circuit and the source follower circuit concurrently in terms of cost, the number of processes, and the like. Note that as described above, the optimal thickness of the gate insulating film is different between the transistor used for the shift register circuit and the transistor used for the source follower circuit; thus, in the case of manufacturing the shift register circuit and the source follower circuit concurrently, it is necessary to consider a process for separate formation of transistors whose gate insulating films have thicknesses different from each other. In addition, such separate formation of transistors may be employed for not only the transistors in the driver circuit but also transistors included in a pixel circuit.

One object of one embodiment of the present invention is to provide a semiconductor device that operates stably. Another object of one embodiment of the present invention is to provide a semiconductor device having a high driving frequency. Another object of one embodiment of the present invention is to provide a highly reliable semiconductor device. Another object of one embodiment of the present invention is to provide a display apparatus including the semiconductor device. Another object of one embodiment of the present invention is to provide an electronic device including the display apparatus. Another object of one embodiment of the present invention is to provide a novel semiconductor device, a novel display apparatus, or a novel electronic device.

Note that the objects of one embodiment of the present invention are not limited to the above-listed objects. The above-listed objects do not preclude the existence of other objects. Note that the other objects are objects that are not described in this section and will be described below. The objects that are not described in this section can be derived from the description of the specification, the drawings, and the like and can be extracted as appropriate from the description by those skilled in the art. Note that one embodiment of the present invention achieves at least one of the above-listed objects and the other objects. Accordingly, one embodiment of the present invention does not necessarily achieve all of the above-listed objects and the other objects.

### Means for Solving the Problems

One embodiment of the present invention has been made in view of the above objects, and is a semiconductor device including a transistor in which a gate electrode and a channel formation region are provided along the height direction. The channel formation region is along the height direction, so that a source electrode and a drain electrode are positioned at different levels.

Moreover, the thickness of a gate insulating film can be made different between a plurality of the transistors. For example, the plurality of transistors are each provided with a stack of a first insulating film and a second insulating film, which are to be part of the gate insulating film. In the transistor including a thin gate insulating film, etching treatment is performed so that the second insulating film can be removed from a region to be the gate insulating film. Meanwhile, in the transistor including a thick gate insulating film, the second insulating film is left after the etching treatment in a region to be the gate insulating film. Accordingly, the transistors whose gate insulating films have thicknesses different from each other can be separately formed.

Typical structure examples of a processing device of one embodiment of the present invention are described below.

(1)

One embodiment of the present invention is a semiconductor device including a shift register and a source follower circuit. The shift register includes a first transistor. The source follower circuit includes a second transistor. The first transistor and the second transistor each include a first insulator. The first transistor includes a first gate insulating film. The second transistor includes a second gate insulating film. The first transistor includes a first channel formation region along a side surface of a first opening formed in the first insulator. The second transistor includes a second channel formation region along a side surface of a second opening formed in the first insulator. The first gate insulating film is positioned above the first channel formation region in a plan view. The second gate insulating film is positioned above the second channel formation region in the plan view. A thickness of the second gate insulating film is larger than a thickness of the first gate insulating film.

(2)

Alternatively, in (1) above, one embodiment of the present invention may have a structure in which the first gate insulating film includes a second insulator and the second gate insulating film includes the second insulator and a third insulator. The third insulator is preferably positioned over the second insulator.

(3)

Alternatively, in (2) above, one embodiment of the present invention may have a structure including a latch circuit. In particular, the latch circuit preferably includes a third transistor, and the third transistor preferably includes a third gate insulating film. The third transistor preferably includes a third channel formation region along a side surface of a third opening formed in the first insulator. The third gate insulating film is preferably positioned above the third channel formation region in the plan view. The third gate insulating film preferably includes the second insulator.

(4)

Alternatively, in (3) above, one embodiment of the present invention may have a structure including a level shifter circuit. In particular, the level shifter circuit preferably includes a fourth transistor, and the fourth transistor preferably includes a fourth gate insulating film. The fourth transistor preferably includes a fourth channel formation region along a side surface of a fourth opening formed in the first insulator. The fourth gate insulating film is preferably positioned above the fourth channel formation region in the plan view. The fourth gate insulating film preferably includes the second insulator and the third insulator.

(5)

Alternatively, in (4) above, one embodiment of the present invention may have a structure in which the first channel formation region to the fourth channel formation region each contain one or more selected from indium, zinc, and an element M.

Note that the element Mis one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony.

(6)

Alternatively, in (5) above, one embodiment of the present invention may have a structure in which the side surfaces of the first opening to the fourth opening each have a taper angle greater than or equal to 70° and less than or equal to 110°.

(7)

Alternatively, one embodiment of the present invention is a display apparatus including the semiconductor device described in (6) above and a pixel circuit. The pixel circuit includes a driving transistor, and the driving transistor includes a fifth gate insulating film. The driving transistor includes a fifth channel formation region above the first insulator. The fifth gate insulating film is positioned above the fifth channel formation region in the plan view. The fifth gate insulating film includes the second insulator and the third insulator.

(8)

Alternatively, in (7) above, one embodiment of the present invention may have a structure in which the fifth channel formation region contains one or more selected from indium, zinc, and the element M.

(9)

Alternatively, in (8) above, one embodiment of the present invention may have a structure in which the pixel circuit includes a light-emitting device including an organic EL material.

(10)

Alternatively, one embodiment of the present invention is an electronic device including the display apparatus described in (9) above and a housing.

(11)

Alternatively, one embodiment of the present invention is a semiconductor device including a first transistor, a second transistor, a third transistor, and a fourth transistor.

The first transistor to the fourth transistor each include a first conductor positioned below a first insulator and functioning as one of a source and a drain, a second conductor positioned above the first insulator and functioning as the other of the source and the drain, a semiconductor in contact with a side surface of an opening formed in the first insulator and in contact with the first conductor and the second conductor, a gate insulating film positioned over the semiconductor, and a gate electrode positioned over the gate insulating film. The gate insulating film of each of the first transistor and the second transistor is thicker than the gate insulating film of each of the third transistor and the fourth transistor.

One of the first conductor and the second conductor of the first transistor is electrically connected to one of the first conductor and the second conductor of the second transistor. One of the first conductor and the second conductor of the third transistor is electrically connected to one of the first conductor and the second conductor of the fourth transistor.

(12)

Alternatively, in (11) above, one embodiment of the present invention may have a structure in which the gate insulating film of each of the first transistor and the second transistor includes a second insulator and the gate insulating film of each of the third transistor and the fourth transistor includes the second insulator and a third insulator. In particular, the third insulator is preferably positioned over the second insulator.

(13)

Alternatively, in (12) above, one embodiment of the present invention may have a structure including a first circuit. In particular, the first circuit preferably includes a first terminal, a second terminal, a third terminal, and a fourth terminal, and it is preferable that the first terminal be electrically connected to the gate electrode of the first transistor, the second terminal be electrically connected to the gate electrode of the second transistor, the third terminal be electrically connected to the gate electrode of the third transistor, and the fourth terminal be electrically connected to the gate electrode of the fourth transistor. The first circuit preferably has a function of outputting one of a high-level potential and a low-level potential to each of the first terminal and the third terminal and a function of outputting the other of the high-level potential and the low-level potential to each of the second terminal and the fourth terminal.

(14)

Alternatively, one embodiment of the present invention is a semiconductor device including a first transistor, a second transistor, a third transistor, a fourth transistor, a fifth transistor, a sixth transistor, a first capacitor, and a second capacitor.

The first transistor to the sixth transistor each include a first conductor positioned below a first insulator and functioning as one of a source and a drain, a second conductor positioned above the first insulator and functioning as the other of the source and the drain, a semiconductor in contact with a side surface of an opening formed in the first insulator and in contact with the first conductor and the second conductor, a gate insulating film positioned over the semiconductor, and a gate electrode positioned over the gate insulating film. The gate insulating film of each of the first transistor, the second transistor, and the fifth transistor is thicker than the gate insulating film of each of the third transistor, the fourth transistor, and the sixth transistor.

One of the first conductor and the second conductor of the first transistor is electrically connected to one of the first conductor and the second conductor of the second transistor and one of a pair of terminals of the first capacitor. The gate electrode of the first transistor is electrically connected to one of the first conductor and the second conductor of the fifth transistor and the other of the pair of terminals of the first capacitor. One of the first conductor and the second conductor of the third transistor is electrically connected to one of the first conductor and the second conductor of the fourth transistor and one of a pair of terminals of the second capacitor. The gate electrode of the third transistor is electrically connected to one of the first conductor and the second conductor of the sixth transistor and the other of the pair of terminals of the second capacitor. The other of the first conductor and the second conductor of the fifth transistor is electrically connected to the other of the first conductor and the second conductor of the sixth transistor. The gate electrode of the second transistor is electrically connected to the gate electrode of the fourth transistor.

(15)

Alternatively, in (14) above, one embodiment of the present invention may have a structure in which the gate insulating film of each of the first transistor, the second transistor, and the fifth transistor includes a second insulator and the gate insulating film of each of the third transistor, the fourth transistor, and the sixth transistor includes the second insulator and a third insulator. In particular, the third insulator is preferably positioned over the second insulator.

(16)

Alternatively, in (15) above, one embodiment of the present invention may have a structure including a first circuit. In particular, the first circuit preferably includes a first terminal and a second terminal, and it is preferable that the first terminal be electrically connected to the other of the first conductor and the second conductor of the fifth transistor and the other of the first conductor and the second conductor of the sixth transistor, and the second terminal be electrically connected to the gate electrode of the second transistor and the gate electrode of the fourth transistor. The first circuit preferably has a function of outputting one of a high-level potential and a low-level potential to the first terminal and a function of outputting the other of the high-level potential and the low-level potential to the second terminal.

(17)

Alternatively, one embodiment of the present invention is a semiconductor device including a first transistor, a second transistor, a third transistor, a fourth transistor, a fifth transistor, a sixth transistor, a seventh transistor, an eighth transistor, a first capacitor, and a second capacitor.

The first transistor to the eighth transistor each include a first conductor positioned below a first insulator and functioning as one of a source and a drain, a second conductor positioned above the first insulator and functioning as the other of the source and the drain, a semiconductor in contact with a side surface of an opening formed in the first insulator and in contact with the first conductor and the second conductor, a gate insulating film positioned over the semiconductor, and a gate electrode positioned over the gate insulating film. The gate insulating film of each of the first transistor, the second transistor, the fifth transistor, and the seventh transistor is thicker than the gate insulating film of each of the third transistor, the fourth transistor, the sixth transistor, and the eighth transistor.

One of the first conductor and the second conductor of the first transistor is electrically connected to one of the first conductor and the second conductor of the second transistor and one of a pair of terminals of the first capacitor. The gate electrode of the first transistor is electrically connected to one of the first conductor and the second conductor of the fifth transistor, the other of the pair of terminals of the first capacitor, and one of the first conductor and the second conductor of the seventh transistor. One of the first conductor and the second conductor of the third transistor is electrically connected to one of the first conductor and the second conductor of the fourth transistor and one of a pair of terminals of the second capacitor. The gate electrode of the third transistor is electrically connected to one of the first conductor and the second conductor of the sixth transistor, the other of the pair of terminals of the second capacitor, and one of the first conductor and the second conductor of the eighth transistor. The other of the first conductor and the second conductor of the fifth transistor is electrically connected to the gate electrode of the fifth transistor, the other of the first conductor and the second conductor of the sixth transistor, and the gate electrode of the sixth transistor. The gate electrode of the second transistor is electrically connected to the gate electrode of the fourth transistor.

(18)

Alternatively, in (17) above, one embodiment of the present invention may have a structure in which the gate insulating film of each of the first transistor, the second transistor, the fifth transistor, and the seventh transistor includes a second insulator and the gate insulating film of each of the third transistor, the fourth transistor, the sixth transistor, and the eighth transistor includes the second insulator and a third insulator. In particular, the third insulator is preferably positioned over the second insulator.

(19)

Alternatively, in (18) above, one embodiment of the present invention may have a structure including a first circuit. In particular, the first circuit preferably includes a first terminal and a second terminal, and it is preferable that the first terminal be electrically connected to the other of the first conductor and the second conductor of the fifth transistor and the other of the first conductor and the second conductor of the sixth transistor, and the second terminal be electrically connected to the gate electrode of the second transistor and the gate electrode of the fourth transistor. The first circuit preferably has a function of outputting one of a high-level potential and a low-level potential to the first terminal and a function of outputting the other of the high-level potential and the low-level potential to the second terminal.

(20)

Alternatively, one embodiment of the present invention is a semiconductor device including a first transistor, a second transistor, a third transistor, a fourth transistor, a fifth transistor, a sixth transistor, a ninth transistor, a first capacitor, and a second capacitor.

The first transistor to the sixth transistor and the ninth transistor each include a first conductor positioned below a first insulator and functioning as one of a source and a drain, a second conductor positioned above the first insulator and functioning as the other of the source and the drain, a semiconductor in contact with a side surface of an opening formed in the first insulator and in contact with the first conductor and the second conductor, a gate insulating film positioned over the semiconductor, and a gate electrode positioned over the gate insulating film. The gate insulating film of each of the first transistor, the second transistor, the fifth transistor, and the ninth transistor is thicker than the gate insulating film of each of the third transistor, the fourth transistor, and the sixth transistor.

One of the first conductor and the second conductor of the first transistor is electrically connected to one of the first conductor and the second conductor of the second transistor and one of a pair of terminals of the first capacitor. The gate electrode of the first transistor is electrically connected to one of the first conductor and the second conductor of the fifth transistor, the other of the pair of terminals of the first capacitor, and the gate electrode of the ninth transistor. One of the first conductor and the second conductor of the third transistor is electrically connected to one of the first conductor and the second conductor of the fourth transistor and one of a pair of terminals of the second capacitor. The gate electrode of the third transistor is electrically connected to one of the first conductor and the second conductor of the sixth transistor and the other of the pair of terminals of the second capacitor. The other of the first conductor and the second conductor of the fifth transistor is electrically connected to the other of the first conductor and the second conductor of the sixth transistor and one of the first conductor and the second conductor of the ninth transistor. The gate electrode of the second transistor is electrically connected to the gate electrode of the fourth transistor.

(21)

Alternatively, in (20) above, one embodiment of the present invention may have a structure in which the gate insulating film of each of the first transistor, the second transistor, the fifth transistor, and the ninth transistor includes a second insulator and the gate insulating film of each of the third transistor, the fourth transistor, and the sixth transistor includes the second insulator and a third insulator. In particular, the third insulator is preferably positioned over the second insulator.

(22)

Alternatively, in (21) above, one embodiment of the present invention may have a structure including a first circuit. In particular, the first circuit preferably includes a first terminal and a second terminal, and it is preferable that the first terminal be electrically connected to the other of the first conductor and the second conductor of the fifth transistor and the other of the first conductor and the second conductor of the sixth transistor, and the second terminal be electrically connected to the gate electrode of the second transistor and the gate electrode of the fourth transistor. The first circuit preferably has a function of outputting one of a high-level potential and a low-level potential to the first terminal and a function of outputting the other of the high-level potential and the low-level potential to the second terminal.

(23)

Alternatively, one embodiment of the present invention is a semiconductor device including a first transistor, a second transistor, a third transistor, a fourth transistor, a fifth transistor, a sixth transistor, a seventh transistor, an eighth transistor, a first capacitor, and a second capacitor and having a structure different from that in (7) above.

The first transistor to the eighth transistor each include a first conductor positioned below a first insulator and functioning as one of a source and a drain, a second conductor positioned above the first insulator and functioning as the other of the source and the drain, a semiconductor in contact with a side surface of an opening formed in the first insulator and in contact with the first conductor and the second conductor, a gate insulating film positioned over the semiconductor, and a gate electrode positioned over the gate insulating film. The gate insulating film of each of the first transistor, the second transistor, the fifth transistor, and the seventh transistor is thicker than the gate insulating film of each of the third transistor, the fourth transistor, the sixth transistor, and the eighth transistor.

One of the first conductor and the second conductor of the first transistor is electrically connected to one of the first conductor and the second conductor of the second transistor and one of a pair of terminals of the first capacitor. The gate electrode of the first transistor is electrically connected to one of the first conductor and the second conductor of the fifth transistor, the other of the pair of terminals of the first capacitor, and one of the first conductor and the second conductor of the seventh transistor. One of the first conductor and the second conductor of the third transistor is electrically connected to one of the first conductor and the second conductor of the fourth transistor and one of a pair of terminals of the second capacitor. The gate electrode of the third transistor is electrically connected to one of the first conductor and the second conductor of the sixth transistor, the other of the pair of terminals of the second capacitor, and one of the first conductor and the second conductor of the eighth transistor. The gate electrode of the fifth transistor is electrically connected to the gate electrode of the sixth transistor. The gate electrode of the second transistor is electrically connected to the gate electrode of the fourth transistor.

(24)

Alternatively, in (23) above, one embodiment of the present invention may have a structure in which the gate insulating film of each of the first transistor, the second transistor, the fifth transistor, and the seventh transistor includes a second insulator and the gate insulating film of each of the third transistor, the fourth transistor, the sixth transistor, and the eighth transistor includes the second insulator and a third insulator. In particular, the third insulator is preferably positioned over the second insulator.

(25)

Alternatively, in (24) above, one embodiment of the present invention may have a structure including a first circuit. In particular, the first circuit preferably includes a first terminal and a second terminal, and it is preferable that the first terminal be electrically connected to the gate electrode of the fifth transistor and the gate electrode of the sixth transistor, and the second terminal be electrically connected to the gate electrode of the second transistor and the gate electrode of the fourth transistor. The first circuit preferably has a function of outputting one of a high-level potential and a low-level potential to the first terminal and a function of outputting the other of the high-level potential and the low-level potential to the second terminal.

(26)

Alternatively, in any one of (11) to (25) above, one embodiment of the present invention may have a structure in which the side surfaces of the openings each have a taper angle greater than or equal to 70° and less than or equal to 110°

(27)

Alternatively, in (26) above, one embodiment of the present invention may have a structure in which the channel formation regions in the semiconductors each contain one or more selected from indium, zinc, and an element M.

Note that the element M is one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony.

(28)

Alternatively, one embodiment of the present invention is a display apparatus including the semiconductor device described in (27) above and a display apparatus.

(29)

Alternatively, in (29) above, one embodiment of the present invention may have a structure in which a display portion includes a pixel circuit including any one of a light-emitting device including an organic EL material, a light-emitting device including an inorganic EL material, and a light-emitting diode.

(30)

Alternatively, one embodiment of the present invention is an electronic device including the display apparatus described in (29) above and a housing.

### Effect of the Invention

In the above manner, transistors including different gate insulating films can be provided in the same circuit or the same device. Accordingly, a transistor having a high driving frequency and a transistor having high resistance to voltage can be provided in the same circuit or the same device.

One embodiment of the present invention can provide a semiconductor device that operates stably. Another embodiment of the present invention can provide a semiconductor device having a high driving frequency. Another embodiment of the present invention can provide a highly reliable semiconductor device. Another embodiment of the present invention can provide a display apparatus including the semiconductor device. Another embodiment of the present invention can provide an electronic device including the display apparatus. Another embodiment of the present invention can provide a novel semiconductor device, a novel display apparatus, or a novel electronic device.

Note that the effects of one embodiment of the present invention are not limited to the above-listed effects. The above-listed effects do not preclude the existence of other effects. Note that the other effects are effects that are not described in this section and will be described below. The effects that are not described in this section can be derived from the description of the specification, the drawings, and the like and can be extracted as appropriate from the description by those skilled in the art. Note that one embodiment of the present invention has at least one of the above-listed effects and the other effects. Accordingly, one embodiment of the present invention sometimes does not have the effects depending on the case.

### BRIEF DESCRIPTION OF THE DRAWINGS

FIG. 1 is a block diagram showing an example of a display apparatus.

FIG. 2A is a schematic plan view showing an example of a semiconductor device, and FIG. 2B to FIG. 2D are cross-sectional views showing the example of the semiconductor device.

FIG. 3 is a block diagram showing an example of a semiconductor device.

FIG. 4 is a block diagram showing an example of a semiconductor device.

FIG. 5A and FIG. 5B are block diagrams illustrating examples of a semiconductor device.

FIG. 6A and FIG. 6B are circuit diagrams showing structure examples of semiconductor devices.

FIG. 7 is a layout showing a structure example of a semiconductor device.

FIG. 8A and FIG. 8B are cross-sectional views showing structure examples of a semiconductor device.

FIG. 9A and FIG. 9B are circuit diagrams showing structure examples of semiconductor devices.

FIG. 10 is a circuit diagram showing a structure example of a semiconductor device.

FIG. 11A and FIG. 11B are circuit diagrams showing structure examples of semiconductor devices.

FIG. 12A and FIG. 12B are circuit diagrams showing structure examples of semiconductor devices.

FIG. 13 is a circuit diagram showing a structure example of a semiconductor device.

FIG. 14A and FIG. 14B are circuit diagrams showing structure examples of semiconductor devices.

FIG. 15A and FIG. 15B are circuit diagrams showing structure examples of semiconductor devices.

FIG. 16 is a circuit diagram showing a structure example of a semiconductor device.

FIG. 17A and FIG. 17B are circuit diagrams showing structure examples of semiconductor devices.

FIG. 18A and FIG. 18B are circuit diagrams showing structure examples of semiconductor devices.

FIG. 19A and FIG. 19B are circuit diagrams showing structure examples of semiconductor devices.

FIG. 20A and FIG. 20B are circuit diagrams showing structure examples of semiconductor devices.

FIG. 21A and FIG. 21B are circuit diagrams showing structure examples of semiconductor devices.

FIG. 22A and FIG. 22B are circuit diagrams showing structure examples of semiconductor devices.

FIG. 23 is a circuit diagram showing a structure example of a semiconductor device.

FIG. 24 is a circuit diagram showing a structure example of a semiconductor device.

FIG. 25A to FIG. 25E are circuit diagrams showing structure examples of semiconductor devices.

FIG. 26A to FIG. 26C are circuit diagrams showing structure examples of semiconductor devices.

FIG. 27A is a circuit diagram showing a structure example of a semiconductor device, and FIG. 27B is a timing chart showing an operation example of the semiconductor device.

FIG. 28 is a circuit diagram showing a structure example of a semiconductor device.

FIG. 29A is a circuit diagram showing a structure example of a semiconductor device, and FIG. 29B is a timing chart showing an operation example of the semiconductor device.

FIG. 30A to FIG. 30D are circuit diagrams showing structure examples of pixel circuits.

FIG. 31A and FIG. 31B are circuit diagrams showing structure examples of pixel circuits.

FIG. 32A and FIG. 32B are circuit diagrams showing structure examples of pixel circuits.

FIG. 33 is a circuit diagram showing a structure example of a pixel circuit.

FIG. 34 is a circuit diagram showing a structure example of a pixel circuit.

FIG. 35A is a schematic plan view showing an example of a method for manufacturing a semiconductor device, and FIG. 35B to FIG. 35D are schematic cross-sectional views showing the example of the method for manufacturing a semiconductor device.

FIG. 36A is a schematic plan view showing an example of a method for manufacturing a semiconductor device, and FIG. 36B to FIG. 36D are schematic cross-sectional views showing the example of the method for manufacturing a semiconductor device.

FIG. 37A is a schematic plan view showing an example of a method for manufacturing a semiconductor device, and FIG. 37B to FIG. 37D are schematic cross-sectional views showing the example of the method for manufacturing a semiconductor device.

FIG. 38A is a schematic plan view showing an example of a method for manufacturing a semiconductor device, and FIG. 38B to FIG. 38D are schematic cross-sectional views showing the example of the method for manufacturing a semiconductor device.

FIG. 39A is a schematic plan view showing an example of a method for manufacturing a semiconductor device, and FIG. 39B to FIG. 39D are schematic cross-sectional views showing the example of the method for manufacturing a semiconductor device.

FIG. 40A is a schematic plan view showing an example of a method for manufacturing a semiconductor device, and FIG. 40B to FIG. 40D are schematic cross-sectional views showing the example of the method for manufacturing a semiconductor device.

FIG. 41A is a schematic plan view showing an example of a method for manufacturing a semiconductor device, and FIG. 41B to FIG. 41D are schematic cross-sectional views showing the example of the method for manufacturing a semiconductor device.

FIG. 42A is a schematic plan view showing an example of a method for manufacturing a semiconductor device, and FIG. 42B to FIG. 42D are schematic cross-sectional views showing the example of the method for manufacturing a semiconductor device.

FIG. 43A is a schematic plan view showing an example of a method for manufacturing a semiconductor device, and FIG. 43B to FIG. 43D are schematic cross-sectional views showing the example of the method for manufacturing a semiconductor device.

FIG. 44A is a schematic plan view showing an example of a method for manufacturing a semiconductor device, and FIG. 44B to FIG. 44D are schematic cross-sectional views showing the example of the method for manufacturing a semiconductor device.

FIG. 45A is a schematic plan view showing an example of a method for manufacturing a semiconductor device, and FIG. 45B to FIG. 45D are schematic cross-sectional views showing the example of the method for manufacturing a semiconductor device.

FIG. 46A is a schematic plan view showing an example of a semiconductor device, and FIG. 46B to FIG. 46D are schematic cross-sectional views showing the example of the semiconductor device.

FIG. 47A is a schematic plan view showing an example of a semiconductor device, and FIG. 47B to FIG. 47D are schematic cross-sectional views showing the example of the semiconductor device.

FIG. 48A is a schematic plan view showing an example of a semiconductor device, and FIG. 48B and FIG. 48C are schematic cross-sectional views showing the example of the semiconductor device.

FIG. 49A is a schematic plan view showing an example of a semiconductor device, and FIG. 49B to FIG. 49D are schematic cross-sectional views showing the example of the semiconductor device.

FIG. 50A is a schematic plan view showing an example of a semiconductor device, and FIG. 50B to FIG. 50D are schematic cross-sectional views showing the example of the semiconductor device.

FIG. 51A is a schematic plan view showing an example of a semiconductor device, and FIG. 51B to FIG. 51D are schematic cross-sectional views showing the example of the semiconductor device.

FIG. 52A is a schematic plan view showing an example of a method for manufacturing a semiconductor device, and FIG. 52B to FIG. 52D are schematic cross-sectional views showing the example of the method for manufacturing a semiconductor device.

FIG. 53A is a schematic plan view showing an example of a method for manufacturing a semiconductor device, and FIG. 53B to FIG. 53D are schematic cross-sectional views showing the example of the method for manufacturing a semiconductor device.

FIG. 54A is a schematic plan view showing an example of a method for manufacturing a semiconductor device, and FIG. 54B to FIG. 54D are schematic cross-sectional views showing the example of the method for manufacturing a semiconductor device.

FIG. 55A is a schematic plan view showing an example of a method for manufacturing a semiconductor device, and FIG. 55B to FIG. 55D are schematic cross-sectional views showing the example of the method for manufacturing a semiconductor device.

FIG. 56A is a schematic plan view showing an example of a method for manufacturing a semiconductor device, and FIG. 56B to FIG. 56D are schematic cross-sectional views showing the example of the method for manufacturing a semiconductor device.

FIG. 57A is a schematic plan view showing an example of a semiconductor device, and FIG. 57B to FIG. 57D are schematic cross-sectional views showing the example of the semiconductor device.

FIG. 58A is a schematic plan view showing an example of a semiconductor device, and FIG. 58B to FIG. 58D are schematic cross-sectional views showing the example of the semiconductor device.

FIG. 59A is a schematic plan view showing an example of a semiconductor device, and FIG. 59B to FIG. 59D are schematic cross-sectional views showing the example of the semiconductor device.

FIG. 60A is a schematic plan view showing an example of a semiconductor device, and FIG. 60B to FIG. 60D are schematic cross-sectional views showing the example of the semiconductor device.

FIG. 61A is a schematic plan view showing an example of a semiconductor device, and FIG. 61B to FIG. 61D are schematic cross-sectional views showing the example of the semiconductor device.

FIG. 62A is a schematic plan view showing an example of a semiconductor device, and FIG. 62B to FIG. 62D are schematic cross-sectional views showing the example of the semiconductor device.

FIG. 63A is a schematic plan view showing an example of a semiconductor device, and FIG. 63B to FIG. 63D are schematic cross-sectional views showing the example of the semiconductor device.

FIG. 64A is a schematic plan view showing an example of a semiconductor device, and FIG. 64B to FIG. 64D are schematic cross-sectional views showing the example of the semiconductor device.

FIG. 65A is a schematic plan view showing an example of a method for manufacturing a semiconductor device, and FIG. 65B to FIG. 65D are schematic cross-sectional views showing the example of the method for manufacturing a semiconductor device.

FIG. 66A is a schematic plan view showing an example of a method for manufacturing a semiconductor device, and FIG. 66B to FIG. 66D are schematic cross-sectional views showing the example of the method for manufacturing a semiconductor device.

FIG. 67A is a schematic plan view showing an example of a method for manufacturing a semiconductor device, and FIG. 67B to FIG. 67D are schematic cross-sectional views showing the example of the method for manufacturing a semiconductor device.

FIG. 68A is a schematic plan view showing an example of a method for manufacturing a semiconductor device, and FIG. 68B to FIG. 68D are schematic cross-sectional views showing the example of the method for manufacturing a semiconductor device.

FIG. 69A is a schematic plan view showing an example of a method for manufacturing a semiconductor device, and FIG. 69B to FIG. 69D are schematic cross-sectional views showing the example of the method for manufacturing a semiconductor device.

FIG. 70A is a schematic plan view showing an example of a method for manufacturing a semiconductor device, and FIG. 70B to FIG. 70D are schematic cross-sectional views showing the example of the method for manufacturing a semiconductor device.

FIG. 71A is a schematic plan view showing an example of a method for manufacturing a semiconductor device, and FIG. 71B to FIG. 71D are schematic cross-sectional views showing the example of the method for manufacturing a semiconductor device.

FIG. 72A is a schematic plan view showing an example of a method for manufacturing a semiconductor device, and FIG. 72B to FIG. 72D are schematic cross-sectional views showing the example of the method for manufacturing a semiconductor device.

FIG. 73A is a schematic plan view showing an example of a method for manufacturing a semiconductor device, and FIG. 73B to FIG. 73D are schematic cross-sectional views showing the example of the method for manufacturing a semiconductor device.

FIG. 74A is a schematic plan view showing an example of a semiconductor device, and FIG. 74B to FIG. 74D are schematic cross-sectional views showing the example of the semiconductor device.

FIG. 75A and FIG. 75B are schematic perspective views showing structure examples of display apparatuses.

FIG. 76 is a block diagram showing a structure example of a display apparatus.

FIG. 77 is a schematic cross-sectional view showing a structure example of a display apparatus.

FIG. 78A to FIG. 78C are cross-sectional views showing structure examples of a display apparatus.

FIG. 79 is a schematic cross-sectional view showing a structure example of a display apparatus.

FIG. 80 is a schematic cross-sectional view showing a structure example of a display apparatus.

FIG. 81 is a schematic cross-sectional view showing a structure example of a display apparatus.

FIG. 82 is a schematic cross-sectional view showing a structure example of a display apparatus.

FIG. 83 is a schematic cross-sectional view showing a structure example of a display apparatus.

FIG. 84 is a schematic cross-sectional view showing a structure example of a display apparatus.

FIG. 85 is a schematic cross-sectional view showing a structure example of a display apparatus.

FIG. 86 is a schematic cross-sectional view showing a structure example of a display apparatus.

FIG. 87 is a schematic cross-sectional view showing a structure example of a display apparatus.

FIG. 88A and FIG. 88B are diagrams showing a structure example of a display module.

FIG. 89A to FIG. 89I are perspective views showing examples of electronic devices.

FIG. 90A is a schematic perspective view illustrating a structure example of a memory device, and

FIG. 90B is a block diagram illustrating a structure example of a semiconductor device.

FIG. 91 is a block diagram illustrating a structure example of a memory device.

FIG. 92A and FIG. 92B are diagrams illustrating examples of electronic components.

FIG. 93A and FIG. 93B are diagrams showing examples of electronic devices, and FIG. 93C to FIG. 93E are diagrams showing an example of a large computer.

FIG. 94 is a diagram showing an example of space equipment.

FIG. 95 is a diagram illustrating an example of a storage system that can be used in a data center.

### MODE FOR CARRYING OUT THE INVENTION

In this specification and the like, a semiconductor device refers to a device that utilizes semiconductor characteristics, and means a circuit including a semiconductor element (e.g., a transistor, a diode, and a photodiode), or a device including the circuit. The semiconductor device also means all devices that can function by utilizing semiconductor characteristics. An example of a semiconductor device is an integrated circuit. Another example of a semiconductor device is a chip that includes an integrated circuit. Another example of a semiconductor device is an electronic component in which a chip is stored in a package. Moreover, a memory device, a display apparatus, a light-emitting apparatus, a lighting device, an electronic device, and the like themselves are semiconductor devices in some cases and include semiconductor devices in other cases.

In the case where there is description “X and Y are connected” in this specification and the like, the case where X and Y are electrically connected, the case where X and Y are functionally connected, and the case where X and Y are directly connected are regarded as being disclosed in this specification and the like. Accordingly, without being limited to a predetermined connection relationship, for example, a connection relationship shown in drawings or texts, a connection relationship other than one shown in drawings or texts is regarded as being disclosed in the drawings or the texts. Each of X and Y denotes an object (e.g., a device, an element, a circuit, a wiring, an electrode, a terminal, a conductive film, or a layer).

For example, in the case where X and Y are electrically connected, one or more elements that allow electrical connection between X and Y (e.g., a switch, a transistor, a capacitor, an inductor, a resistor, a diode, a display device, a light-emitting device, and a load) can be connected between X and Y. Note that a switch has a function of being controlled to be turned on or off. That is, the switch has a function of being in a conduction state (on state) or a non-conduction state (off state) to control whether a current flows or not.

In the case where an element and a power supply line (e.g., a wiring for supplying VDD (high power supply potential), VSS (low power supply potential), GND (ground potential), or a desired potential) are both provided between X and Y, X and Y are not defined as being electrically connected. In the case where only a power supply line is provided between X and Y, there is no element between X and Y; therefore, X and Y are directly connected. Accordingly, in the case where only a power supply line is provided between X and Y, X and Y can be expressed as being “electrically connected”. However, in the case where an element and a power supply line are both provided between X and Y, X and Y are not defined as being electrically connected, although X and the power supply line are electrically connected (through the element) and Y and the power supply line are electrically connected. Note that in the case where a gate and a source of a transistor are provided between X and Y, X and Y are not defined as being electrically connected. Note that in the case where a gate and a drain of a transistor are provided between X and Y, X and Y are not defined as being electrically connected. That is, in the case where a drain and a source of a transistor are provided between X and Y, X and Y are defined as being electrically connected. Note that in the case where a capacitor is provided between X and Y, X and Y are defined as being electrically connected in some cases and not defined in other cases. For example, in the case where a capacitor is provided between X and Y in a structure of a digital circuit or a logic circuit, X and Y are not defined as being electrically connected in some cases. On the other hand, for example, in the case where a capacitor is provided between X and Y in a structure of an analog circuit, X and Y are defined as being electrically connected in some cases.

For example, in the case where X and Y are functionally connected, one or more circuits that allow functional connection between X and Y (e.g., a logic circuit (e.g., an inverter, a NAND circuit, or a NOR circuit); a signal converter circuit (e.g., a digital-to-analog converter circuit, an analog-digital converter circuit, or a gamma correction circuit); a potential level converter circuit (e.g., a power supply circuit such as a step-up circuit or a step-down circuit, or a level shifter circuit for changing the potential level of a signal); a voltage source; a current source; a switching circuit; an amplifier circuit (e.g., a circuit that can increase signal amplitude, the amount of current, or the like, an operational amplifier, a differential amplifier circuit, a source follower circuit, or a buffer circuit); a signal generation circuit; a memory circuit; or a control circuit) can be connected between X and Y. For instance, even if another circuit is provided between X and Y, X and Y are regarded as being functionally connected when a signal output from X is transmitted to Y.

For example, an expression “X, Y, a source (sometimes called one of a first terminal and a second terminal) of a transistor, and a drain (sometimes called the other of the first terminal and the second terminal) of the transistor are electrically connected to each other, and X, the source of the transistor, the drain of the transistor, and Y are electrically connected to each other in this order” can be used. Alternatively, an expression “a source of a transistor is electrically connected to X; a drain of the transistor is electrically connected to Y; and X, the source of the transistor, the drain of the transistor, and Y are electrically connected to each other in this order” can be used. Alternatively, an expression “X is electrically connected to Y through a source and a drain of a transistor, and X, the source of the transistor, the drain of the transistor, and Y are provided in this connection order” can be used. When the connection order in a circuit structure is defined by an expression like the above examples, a source and a drain of a transistor can be distinguished from each other to specify the technical scope. Note that these expressions are non-limiting examples. Here, X and Y each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has both a function of a wiring and a function of an electrode. Thus, electrical connection in this specification includes, in its category, such a case where one conductive film has functions of a plurality of components.

In this specification and the like, a “resistor” can be, for example, a circuit element having a resistance value higher than 0Ω or a wiring having a resistance value higher than 0Ω. Therefore, in this specification and the like, a “resistor” includes a wiring having a resistance value, a transistor in which a current flows between a source and a drain, a diode, and a coil. Thus, the term “resistor” can sometimes be replaced with the terms “resistance”, “load”, or “region having a resistance value”. Conversely, the terms “resistance”, “load”, or “region having a resistance value” can sometimes be replaced with the term “resistor”. The resistance value can be, for example, preferably higher than or equal to 1 mΩ and lower than or equal to 10Ω, further preferably higher than or equal to 5 mΩ and lower than or equal to 5Ω, still further preferably higher than or equal to 10 mΩ and lower than or equal to 1Ω. For another example, the resistance value may be higher than or equal to 1Ω and lower than or equal to 1×10⁹Ω.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. The term “capacitor”, “parasitic capacitance”, or “gate capacitance” can be replaced with the term “capacitance” in some cases. Conversely, the term “capacitance” can be replaced with the term “capacitor”, “parasitic capacitance”, or “gate capacitance” in some cases. In addition, a “capacitor” (including a “capacitor” with three or more terminals) includes an insulator and a pair of conductors between which the insulator is interposed. Thus, the term “pair of conductors” of “capacitor” can be replaced with “pair of electrodes”, “pair of conductive regions”, “pair of regions”, or “pair of terminals”. In addition, the terms “one of a pair of terminals” and “the other of the pair of terminals” are referred to as a first terminal and a second terminal, respectively, in some cases. Note that the electrostatic capacitance value can be higher than or equal to 0.05 fF and lower than or equal to 10 pF, for example. For another example, the electrostatic capacitance value may be higher than or equal to 1 pF and lower than or equal to 10 μF.

In this specification and the like, a transistor includes three terminals called a gate, a source, and a drain. The gate is a control terminal for controlling the conduction state of the transistor. Two terminals functioning as the source and the drain are input/output terminals of the transistor. One of the two input/output terminals serves as the source and the other serves as the drain on the basis of the conductivity type (for example, n-channel type or p-channel type) of the transistor and the levels of potentials applied to the three terminals of the transistor. Thus, the terms “source” and “drain” can sometimes be replaced with each other in this specification and the like. In this specification and the like, expressions “one of a source and a drain” (or a first electrode or a first terminal) and “the other of the source and the drain” (or a second electrode or a second terminal) are used in description of the connection relationship of a transistor. Depending on the transistor structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, a third gate, and the like in this specification and the like.

In this specification and the like, for example, a transistor with a multi-gate structure having two or more gate electrodes can be used as the transistor. With the multi-gate structure, channel formation regions are connected to each other in series; accordingly, a plurality of transistors are connected to each other in series. Thus, with the multi-gate structure, the amount of an off-state current can be reduced, and the breakdown voltage of the transistor can be increased (the reliability can be improved). Alternatively, with the multi-gate structure, drain-source current does not change very much even if drain-source voltage changes at the time of an operation in a saturation region, so that a flat slope of voltage-current characteristics can be obtained. By utilizing the flat slope of the voltage-current characteristics, an ideal current source circuit or an active load having an extremely high resistance value can be obtained. Accordingly, a differential circuit, a current mirror circuit, and the like having excellent properties can be obtained.

The case where a single circuit element is illustrated in a circuit diagram may include a case where the circuit element includes a plurality of circuit elements. For example, the case where a single resistor is illustrated in a circuit diagram may include a case where two or more resistors are electrically connected to each other in series. For another example, the case where a single capacitor is illustrated in a circuit diagram may include a case where two or more capacitors are electrically connected to each other in parallel. For another example, the case where a single transistor is illustrated in a circuit diagram may include a case where two or more transistors are electrically connected to each other in series and gates of the transistors are electrically connected to each other. Similarly, for another example, the case where a single switch is illustrated in a circuit diagram may include a case where the switch includes two or more transistors, the two or more transistors are electrically connected to each other in series or in parallel, and gates of the transistors are electrically connected to each other.

In this specification and the like, a node can be referred to as a terminal, a wiring, an electrode, a conductive layer, a conductor, or an impurity region depending on the circuit structure and the device structure. Furthermore, a terminal, a wiring, or the like can be referred to as a node.

In this specification and the like, a “voltage” and a “potential” can be replaced with each other as appropriate. A “voltage” refers to a potential difference from a reference potential, and when the reference potential is a ground potential, for example, a “voltage” can be replaced with a “potential”. Note that the ground potential does not necessarily mean 0 V. Moreover, potentials are relative values, and a potential supplied to a wiring, a potential applied to a circuit or the like, and a potential output from a circuit or the like, for example, change with a change of the reference potential.

In this specification and the like, the terms “high-level potential” and “low-level potential” do not mean a particular potential. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

A “current” means a charge transfer phenomenon (electrical conduction); for example, the description “electrical conduction of positively charged particles occurs” can be rephrased as “electrical conduction of negatively charged particles occurs in the opposite direction”. Therefore, unless otherwise specified, a “current” in this specification and the like refers to a charge transfer phenomenon (electrical conduction) accompanying carrier movement. Examples of a carrier here include an electron, a hole, an anion, a cation, and a complex ion, and the type of carrier differs between current flow systems (e.g., a semiconductor, a metal, an electrolyte solution, and a vacuum). The “direction of a current” in a wiring or the like refers to the direction in which a carrier with positive charge moves, and the amount of the current is expressed as a positive value. In other words, the direction in which a carrier with negative charge moves is opposite to the direction of a current, and the amount of the current is expressed as a negative value. Thus, in the case where the polarity of a current (or the direction of a current) is not specified in this specification and the like, the description “a current flows from element A to element B” can be rephrased as “a current flows from element B to element A”. The description “a current is input to element A” can be rephrased as “a current is output from element A”.

Ordinal numbers such as “first”, “second”, and “third” in this specification and the like are used in order to avoid confusion among components. Thus, the terms do not limit the number of components. The terms do not limit the order of components, either. For example, a “first” component in one embodiment in this specification and the like can be referred to as a “second” component in other embodiments or the scope of claims. For another example, a “first” component in one embodiment in this specification and the like can be omitted in other embodiments or the scope of claims.

In this specification and the like, the terms for describing positioning, such as “over” and “under”, are sometimes used for convenience to describe the positional relationship between components with reference to drawings. The positional relationship between components is changed as appropriate in accordance with the direction in which the components are described. Thus, the positional relationship is not limited to the terms described in the specification and the like, and can be described with another term as appropriate depending on the situation. For example, the expression “an insulator located over (on) a top surface of a conductor” can be replaced with the expression “an insulator located under (on) a bottom surface of a conductor” when the direction of a drawing illustrating these components is rotated by 180°.

Furthermore, the terms “over” and “under” do not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B. Similarly, for example, the expression “electrode B above insulating layer A” does not necessarily mean that the electrode B is formed above and in direct contact with the insulating layer A, and does not exclude the case where another component is provided between the insulating layer A and the electrode B. Similarly, for example, the expression “electrode B under insulating layer A” does not necessarily mean that the electrode B is formed under and in direct contact with the insulating layer A, and does not exclude the case where another component is provided between the insulating layer A and the electrode B.

In this specification and the like, components arranged in a matrix and their positional relationship are sometimes described using terms such as “row” and “column”. The positional relationship between components is changed as appropriate in accordance with the direction in which the components are described. Thus, the positional relationship is not limited to the terms described in the specification and the like, and can be described with another term as appropriate depending on the situation. For example, the term “row direction” can be replaced with the term “column direction” when the direction of the drawing is rotated by 90°.

In this specification and the like, the terms “film” and “layer” can be interchanged with each other depending on the situation. For example, the term “conductive layer” can be replaced with the term “conductive film” in some cases. For another example, the term “insulating film” can be changed into the term “insulating layer” in some cases. Alternatively, the terms “film” and “layer” are not used and can be interchanged with another term depending on the case or the situation. For example, the term “conductive layer” or “conductive film” can be changed into the term “conductor” in some cases. Furthermore, for example, the term “insulating layer” or “insulating film” can be changed into the term “insulator” in some cases.

In this specification and the like, the terms “electrode”, “wiring”, “terminal”, and the like do not limit the functions of such components. For example, an “electrode” is used as part of a “wiring” in some cases, and vice versa. Furthermore, the term “electrode” or “wiring” also refers to, for example, the case where a plurality of “electrodes” or “wirings” are formed in an integrated manner. For example, a “terminal” is used as part of a “wiring” or an “electrode” in some cases, and vice versa. Furthermore, the term “terminal” also refers to the case where one or more selected from “electrodes”, “wirings”, and “terminals” are formed in an integrated manner, for example. Therefore, for example, an “electrode” can be part of a “wiring” or a “terminal”, and a “terminal” can be part of a “wiring” or an “electrode”. Moreover, the term “electrode”, “wiring”, or “terminal” is sometimes replaced with the term “region” depending on the case.

In this specification and the like, the terms “wiring”, “signal line”, and “power supply line” can be interchanged with each other depending on the case or the situation. For example, the term “wiring” can be changed into the term “signal line” in some cases. For another example, the term “wiring” can be changed into the term “power supply line” or the like in some cases. Conversely, the term “signal line” or “power supply line” can be changed into the term “wiring” in some cases. The term “power supply line” can be changed into the term “signal line” in some cases. Conversely, the term “signal line” can be changed into the term “power supply line” in some cases. The term “potential” that is applied to a wiring can be changed into the term “signal” depending on the case or the situation. Conversely, the term “signal” can be changed into the term “potential” in some cases.

In this specification and the like, a timing chart is used in some cases to describe an operation method of a semiconductor device. The timing chart used in this specification and the like shows an ideal operation example and a period, a level of a signal (e.g., a potential or a current), and a timing described in the timing chart are not limited unless otherwise specified. In the timing chart described in this specification and the like, the level of a signal (e.g., a potential or a current) input to a wiring (including a node) and a timing can be changed depending on the situation. For example, even when two periods are shown to have an equal length in the timing chart, the two periods have different lengths in some cases. Furthermore, for example, even when one of two periods is shown long and the other is shown short, the two periods can have the equal length in some cases, or the one period can have a short length and the other can have a long length in other cases.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is included in a channel formation region of a transistor, the metal oxide is referred to as an oxide semiconductor in some cases. That is, when a metal oxide can form a channel formation region of a transistor that has at least one of an amplifying function, a rectifying function, and a switching function, the metal oxide can be referred to as a metal oxide semiconductor. In the case where an OS transistor is mentioned, the OS transistor can also be referred to as a transistor including a metal oxide or an oxide semiconductor.

In this specification and the like, a metal oxide containing nitrogen is also referred to as a metal oxide in some cases. Alternatively, a metal oxide containing nitrogen may be called a metal oxynitride.

In this specification and the like, an impurity in a semiconductor refers to, for example, an element other than a main component of a semiconductor layer. For example, an element with a concentration of lower than 0.1 atomic % is an impurity. When an impurity is contained, for example, one or more of an increase in the density of defect states in a semiconductor, a decrease in carrier mobility, and a decrease in crystallinity occur in some cases. In the case where the semiconductor is an oxide semiconductor, examples of an impurity that changes characteristics of the semiconductor include Group 1 elements, Group 2 elements, Group 13 elements, Group 14 elements, Group 15 elements, and transition metals other than the main components; specific examples are hydrogen (contained also in water), lithium, sodium, silicon, boron, phosphorus, carbon, and nitrogen.

In this specification and the like, a switch refers to an element having a function of being in a conduction state (on state) or a non-conduction state (off state) to control whether a current flows or not. Alternatively, a switch refers to an element having a function of selecting and changing a current path. Thus, a switch may have two terminals or three or more terminals through which a current flows, in addition to a control terminal. For example, an electrical switch or a mechanical switch can be used. That is, a switch can be any element capable of controlling a current, and is not limited to a particular element.

Examples of an electrical switch include a transistor (e.g., a bipolar transistor and a MOS transistor), a diode (e.g., a PN diode, a PIN diode, a Schottky diode, a MIM (Metal Insulator Metal) diode, a MIS (Metal Insulator Semiconductor) diode, and a diode-connected transistor), and a logic circuit in which such elements are combined. Note that in the case of using a transistor as a switch, a “conduction state” of the transistor refers to a state where a source electrode and a drain electrode of the transistor can be regarded as being electrically short-circuited or a state where a current can be made to flow between the source electrode and the drain electrode. Furthermore, a “non-conduction state” of the transistor refers to a state where the source electrode and the drain electrode of the transistor can be regarded as being electrically disconnected. Note that in the case where a transistor operates just as a switch, there is no particular limitation on the polarity (conductivity type) of the transistor.

An example of a mechanical switch is a switch formed using a MEMS (micro electro mechanical systems) technology. Such a switch includes an electrode that can be moved mechanically, and operates by controlling conduction and non-conduction with movement of the electrode.

In this specification and the like, a device fabricated using a metal mask or an FMM (fine metal mask, high-resolution metal mask) may be referred to as a device having an MM (metal mask) structure. In this specification and the like, a device fabricated without using a metal mask or an FMM may be referred to as a device having an MML (metal maskless) structure.

In this specification and the like, a structure in which light-emitting layers in light-emitting devices of different colors (here, blue (B), green (G), and red (R)) are separately formed or separately patterned may be referred to as an SBS (Side By Side) structure. In this specification and the like, a light-emitting device capable of emitting white light may be referred to as a white-light-emitting device. Note that a combination of white-light-emitting devices with coloring layers (e.g., color filters) enables a full-color display apparatus.

Light-emitting devices can be classified roughly into a single structure and a tandem structure. A device having a single structure includes one light-emitting unit between a pair of electrodes, and the light-emitting unit preferably includes one or more light-emitting layers. When white light emission is obtained using two light-emitting layers, the two light-emitting layers are selected such that emission colors of the light-emitting layers are complementary colors. For example, when the emission color of a first light-emitting layer and the emission color of a second light-emitting layer have a relationship of complementary colors, a structure in which the light-emitting device emits white light as a whole can be obtained. When white light emission is obtained using three or more light-emitting layers, a light-emitting device is configured to emit white light as a whole by combining emission colors of the three or more light-emitting layers.

A device having a tandem structure includes two or more light-emitting units between a pair of electrodes, and each light-emitting unit preferably includes one or more light-emitting layers. To obtain white light emission, the light-emitting device is configured to obtain white light emission by combining light from light-emitting layers of the plurality of light-emitting units. Note that a structure for obtaining white light emission is similar to the structure of the case of a single structure. In the device having a tandem structure, an intermediate layer such as a charge-generation layer is suitably provided between the plurality of light-emitting units.

When the above white-light-emitting device (having a single structure or a tandem structure) and the above light-emitting device having an SBS structure are compared to each other, the light-emitting device having an SBS structure can have lower power consumption than the white-light-emitting device. To reduce power consumption, the light-emitting device having an SBS structure is suitably used. Meanwhile, the white-light-emitting device is suitable in terms of lower manufacturing cost or higher manufacturing yield because the manufacturing process of the white-light-emitting device is simpler than that of the light-emitting device having an SBS structure.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −20° and less than or equal to 20°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 70° and less than or equal to 110°.

In this specification and the like, one embodiment of the present invention can be constituted by appropriately combining a structure described in an embodiment with any of the structures described in the other embodiments. In addition, in the case where a plurality of structure examples are described in one embodiment, the structure examples can be combined as appropriate.

Note that a content (or part of the content) described in one embodiment can be applied to, combined with, or replaced with at least one of another content (or part of the content) in the embodiment and a content (or part of the content) described in one or a plurality of different embodiments.

Note that in each embodiment, a content described in the embodiment is a content described using a variety of diagrams or a content described with text disclosed in the specification.

Note that by combining a diagram (or part thereof) described in one embodiment with at least one of another part of the diagram, a different diagram (or part thereof) described in the embodiment, and a diagram (or part thereof) described in one or a plurality of different embodiments, much more diagrams can be provided.

Embodiments described in this specification are described with reference to the drawings. Note that the embodiments can be implemented in many different modes, and it will be readily appreciated by those skilled in the art that modes and details can be changed in various ways without departing from the spirit and scope thereof. Thus, the present invention should not be interpreted as being limited to the description in the embodiments. Note that in the structures of the invention in the embodiments, the same portions or portions having similar functions are denoted by the same reference numerals in different drawings, and repeated description thereof is omitted in some cases. In perspective views and the like, illustration of some components may be omitted for clarity of the drawings.

In this specification and the like, when a plurality of components are denoted with the same reference numerals, and in particular need to be distinguished from each other, an identification sign such as “_1”, “[n]”, or “[m,n]” is sometimes added to the reference numerals. Components denoted with identification signs such as “_1”, “[n]”, and “[m,n]” in the drawings and the like are sometimes described without such identification signs in this specification and the like when the components do not need to be distinguished from each other.

In the drawings in this specification, the size, the layer thickness, or the region is exaggerated for clarity in some cases. Thus, the size, the layer thickness, or the region is not limited to the illustrated scale. The drawings are schematic views showing ideal examples, and embodiments of the present invention are not limited to shapes, values, or the like shown in the drawings. For example, variations in a signal, a voltage, or a current due to noise, variations in a signal, a voltage, or a current due to difference in timing, or the like can be included.

### Embodiment 1

In this embodiment, a display apparatus of one embodiment of the present invention will be described.

### <Structure Example of Display Apparatus>

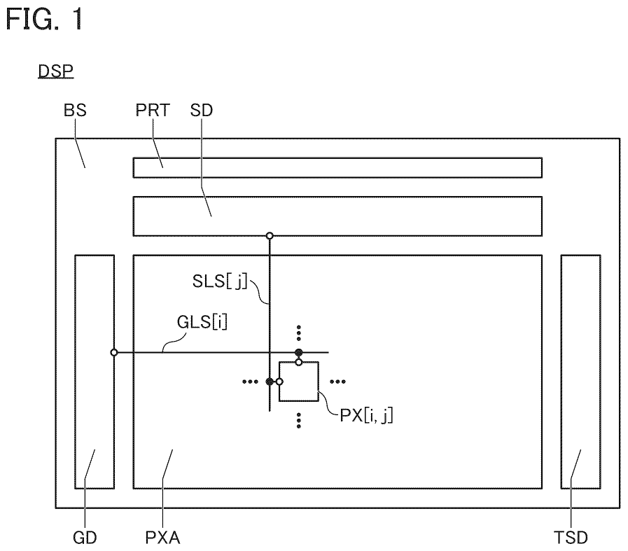

FIG. 1 is a schematic view showing an example of a display apparatus DSP of one embodiment of the present invention. The display apparatus DSP has a structure in which a pixel array PXA, a driver circuit GD, a driver circuit SD, a protection circuit PRT, and a driver circuit TSD are provided over a substrate BS, for example.

The substrate BS functions as, for example, a support to be provided with the pixel array PXA, the driver circuit GD, the driver circuit SD, the protection circuit PRT, and the driver circuit TSD. Note that some or all of the above-listed circuits may be directly formed on the substrate BS or may be mounted on the substrate BS by a COG (Chip On Glass) method or the like. Some or all of the above-listed circuits may be mounted on an FPC (Flexible Printed Circuit), which is electrically connected to the substrate BS, by a COF (Chip On Film) method or the like.

As the substrate BS, a semiconductor substrate (e.g., a single crystal substrate containing silicon or germanium as a material) can be used, for example. Besides the semiconductor substrate, examples of the substrate BS include an SOI (Silicon On Insulator) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, and paper or a base material film containing a fibrous material. Examples of the glass substrate include barium borosilicate glass, aluminoborosilicate glass, and soda lime glass. Examples of the flexible substrate, the attachment film, the base material film, and the like include plastics typified by polyethylene terephthalate (PET), polyethylene naphthalate (PEN), polyethersulfone (PES), and polytetrafluoroethylene (PTFE). Another example is a synthetic resin such as an acrylic resin. Other examples include polypropylene, polyester, polyvinyl fluoride, and polyvinyl chloride. Other examples include polyamide, polyimide, aramid, an epoxy resin, an inorganic vapor deposition film, and paper. Note that in the case where the manufacturing process of the display apparatus DSP involves heat treatment, a highly heat-resistant material is preferably selected for the substrate BS.

The pixel array PXA includes, for example, a plurality of pixel circuits PX. In the pixel array PXA, the plurality of pixel circuits PX are arranged in an array. In the pixel array PXA, the arrangement of the plurality of pixel circuits PX is any one of matrix arrangement, stripe arrangement, S-stripe arrangement, delta arrangement, Bayer arrangement, and PenTile arrangement, for example. Note that in FIG. 1, the pixel circuit PX positioned in the i-th row and the j-th column (i is an integer greater than or equal to 1 and j is an integer greater than or equal to 1) among the plurality of pixel circuits PX is denoted by a pixel circuit PX[i,j]. Note that the pixel array PXA may be configured to include not the plurality of pixel circuits PX but only one pixel circuit PX.

The plurality of pixel circuits PX each have, for example, a function of acquiring an image signal transmitted from the driver circuit SD described later and emitting light with the intensity corresponding to the image signal. Note that each pixel circuit PX may include two or more subpixel circuits. The number and emission colors of a plurality of subpixel circuits included in each pixel circuit PX may be determined so that white light emission can be obtained by combining lights emitted from the subpixel circuits, for example. When emission colors of the plurality of subpixel circuits included in the pixel circuit PX are red (R), green (G), and blue (B), for example, the whole pixel circuit PX can be a circuit that enables white light emission.

The screen resolution of the display apparatus DSP is determined in accordance with the number of the pixel circuits PX included in the pixel array PXA. In the case where the screen resolution of the display apparatus DSP is 8K4K, for example, the number of the pixel circuits PX included in the pixel array PXA is 7680×4320. Moreover, in the case where the pixel circuit PX includes three subpixel circuits of red (R), green (G), and blue (B), for example, the total number of the subpixel circuits included in the pixel array PXA is 7680×4320×3. Note that the screen resolution of the display apparatus DSP may be SD (the number of the pixel circuits PX is 720×480), HD (the number of the pixel circuits PX is 1280×720), FHD (the number of the pixel circuits PX is 1920×1080), or 4K2K (the number of the pixel circuits PX is 3840×2160). The screen resolution of the display apparatus DSP is not limited to the above, and may be determined freely in the design phase of the display apparatus DSP.

The diagonal size of a display region (e.g., the pixel array PXA) of the display apparatus DSP can be determined depending on an electronic device including the display apparatus DSP. For example, for application of a large-sized display such as a television device, the diagonal size of the display region is greater than or equal to 20 inches, greater than or equal to 30 inches, greater than or equal to 60 inches, or greater than or equal to 100 inches. For another example, for application of a small- or medium-sized display such as a tablet information terminal or a portable information terminal, the diagonal size of the display region is greater than or equal to 3 inches and less than or equal to 13 inches. For another example, for application of a small-sized display such as an XR device or a wearable information terminal, the diagonal size is, e.g., less than or equal to 10 inches, less than or equal to 5 inches, less than or equal to 1.5 inches, or less than or equal to 1 inch.

The definition (sometimes referred to as pixel density) of the display region of the display apparatus DSP is determined depending on the above-described screen resolution and diagonal size. For example, in the case of using the display apparatus DSP for a large-sized display, the definition of the display region of the display apparatus DSP is preferably higher than or equal to 50 ppi, further preferably higher than or equal to 100 ppi, still further preferably higher than or equal to 150 ppi. For another example, in the case of using the display apparatus DSP for a small- or medium-sized display, the definition of the display region of the display apparatus DSP is preferably higher than or equal to 200 ppi, further preferably higher than or equal to 400 ppi, still further preferably higher than or equal to 800 ppi. For another example, in the case of using the display apparatus DSP for a small-sized display, the definition of the display region of the display apparatus DSP is preferably higher than or equal to 1000 ppi, further preferably higher than or equal to 2000 ppi, still further preferably higher than or equal to 4000 ppi.

There is no particular limitation on the screen ratio (aspect ratio) of the display region (e.g., the pixel array PXA) of the display apparatus DSP. For example, the display region is compatible with a variety of screen ratios such as 1:1 (a square), 4:3, 16:9, 16:10, 21:9, and 32:9.

The driver circuit GD functions as, for example, a gate driver circuit for selecting the pixel circuit PX included in the pixel array PXA, to which an image signal is to be written.

The driver circuit SD functions as, for example, a source driver circuit for transmitting an image signal to the pixel circuit PX included in the pixel array PXA.

The pixel circuit PX[i,j] is electrically connected to the driver circuit GD through a wiring GLS[i], for example. The pixel circuit PX[i,j] is electrically connected to the driver circuit SD through a wiring SLS[j], for example.

The wiring GLS[i] functions as, for example, a wiring for transmitting a selection signal for driving the pixel circuit PX[i,j] from the driver circuit GD to the pixel circuit PX[i,j].

The wiring SLS[j] functions as, for example, a wiring for transmitting an image signal for displaying an image on the pixel circuit PX[i,j] from the driver circuit SD to the pixel circuit PX[i,j].

Note that the wiring GLS[i] may be one wiring or a wiring group including a large number of wirings. Similarly, the wiring SLS[j] may be one wiring or a wiring group including a large number of wirings.

The driver circuit TSD functions as, for example, a circuit for driving a touch sensor provided in a region overlapping with the pixel array PXA in a plan view. Note that in the case where the region is not provided with the touch sensor, the display apparatus DSP is not necessarily provided with the driver circuit TSD.

The protection circuit PRT is, for example, electrically connected to the wiring GLS[i] and another wiring. The protection circuit PRT has a function of, for example, keeping the potential of the wiring GLS[i] within a certain range by establishing electrical continuity between the wiring GLS[i] and another wiring when a potential out of the certain range is applied to the wiring GLS[i].

Similarly, the protection circuit PRT may be, for example, electrically connected to the wiring SLS[j] and another wiring. In this case, the protection circuit PRT preferably has a function of, for example, keeping the potential of the wiring SLS[j] within a certain range by establishing electrical continuity between the wiring SLS[j] and another wiring when a potential out of the certain range is applied to the wiring SLS[j].

The above-described pixel array PXA, driver circuit GD, driver circuit SD, protection circuit PRT, and driver circuit TSD provided in the display apparatus DSP each include a transistor, for example. Various characteristics of a transistor are determined depending on the thicknesses and materials of a semiconductor including a channel formation region, a gate insulator, a source electrode or a drain electrode, a gate electrode, and the like; thus, a transistor with an optimal structure is preferably provided in accordance with a position where the transistor is placed. For example, a level shifter or the like included in the driver circuit SD or the driver circuit GD handles a high voltage and thus preferably includes a transistor having high resistance to a high voltage (a high gate potential, a high source potential, or a high drain potential). In the case where the display apparatus DSP has a high frame rate, a shift register or the like included in the driver circuit SD or the driver circuit GD preferably includes a transistor having a high driving frequency. In the case where the pixel circuit PX is desired to retain data corresponding to an image signal for a long time, a transistor having low off-state current characteristics is preferably used as a write transistor provided in the pixel circuit PX.

Meanwhile, in the case of forming transistors having different structures over the same substrate (e.g., over the substrate BS of the display apparatus in FIG. 1), a larger number of kinds of transistors requires a larger number of manufacturing steps, which sometimes causes an increase in cost, a decrease in yield, or the like.

One embodiment of the present invention is a display apparatus in view of the above, which includes a transistor having high resistance to a high voltage and a transistor having a high driving frequency. Another embodiment of the present invention is a display apparatus in which a transistor having high resistance to a high voltage and a transistor having a high driving frequency are formed without a large increase in the number of manufacturing steps. Note that one embodiment of the present invention may be a display apparatus including a transistor having low off-state current characteristics. The transistor having high resistance to a high voltage and the transistor having a high driving frequency may each have low off-state current characteristics.

### <Structure Example of Transistor>

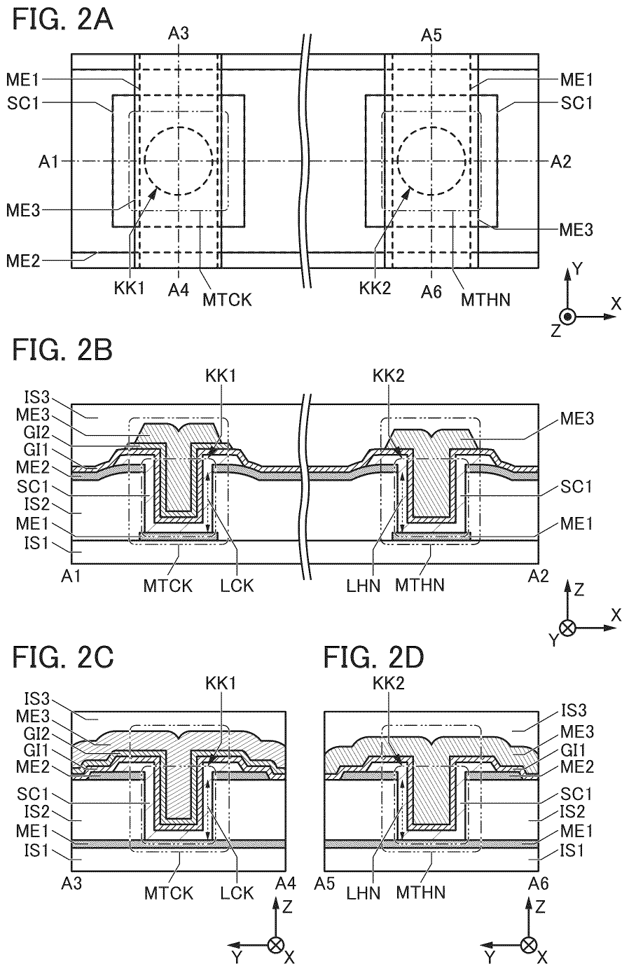

FIG. 2A to FIG. 2D show an example of a semiconductor device (indicating a pixel circuit or a driver circuit, for example) including a transistor MTCK having high resistance to a high voltage and a transistor MTHN having a high driving frequency. Specifically, FIG. 2A is a schematic plan view of the transistor MTCK and the transistor MTHN. FIG. 2B is a schematic cross-sectional view corresponding to a portion along the dashed-dotted line A1-A2 illustrated in FIG. 2A, and is also a schematic cross-sectional view of the transistor MTCK and the transistor MTHN. FIG. 2C is a schematic cross-sectional view corresponding to a portion along the dashed-dotted line A3-A4 illustrated in FIG. 2A, and is also a schematic cross-sectional view of the transistor MTCK. FIG. 2D is a schematic cross-sectional view corresponding to a portion along the dashed-dotted line A5-A6 illustrated in FIG. 2A, and is also a schematic cross-sectional view of the transistor MTHN.

Note that in FIG. 2A to FIG. 2D, the direction of the dashed-dotted line A1-A2 is an X direction, and the direction of the dashed-dotted line A3-A4 or the dashed-dotted line A5-A6 is a Y direction. Moreover, a direction perpendicular to the X direction and the Y direction is a Z direction. The X direction and the Y direction can be directions perpendicular to each other. The definition of the X direction, the Y direction, and the Z direction applies to some of the following drawings and does not apply to other drawings. In the description of the schematic plan view in FIG. 2A and the like, in some cases, the right side, the left side, the upper side, and the lower side are referred to as the X direction, a −X direction, the Y direction, and a −Y direction, respectively. In the description of the schematic cross-sectional view in FIG. 2B and the like, in some cases, the right side, the left side, the upper side, and the lower side are referred to as the X direction, the −X direction, the Z direction, and a −Z direction, respectively. In the description of the schematic cross-sectional views such as FIG. 2C and FIG. 2D, in some cases, the right side, the left side, the upper side, and the lower side are referred to as the −Y direction, a +Y direction, the Z direction, and the −Z direction, respectively.

The transistor MTCK and the transistor MTHN in FIG. 2A to FIG. 2D each include an insulator IS1 to an insulator IS3, an insulator GI1, an insulator GI2, a conductor ME1 to a conductor ME3, and a semiconductor SC1.

The insulator IS1 functions as, for example, a base film above which sources, drains, drains, and channel formation regions of the transistor MTCK and the transistor MTHN are to be provided.

The conductor ME1 is a conductor (sometimes rephrased as a terminal, a wiring, or the like) functioning as one of the source and the drain in each of the transistor MTCK and the transistor MTHN. The conductor ME2 is a conductor (sometimes rephrased as a terminal, a wiring, or the like) functioning as the other of the source and the drain in each of the transistor MTCK and the transistor MTHN.

Note that in FIG. 2A to FIG. 2D, the conductor ME1 is provided as a wiring to extend in the Y direction, for example. The conductor ME2 is provided as a wiring to extend in the X direction, for example.

The insulator IS2 functions as, for example, an interlayer film that separates the source and the drain in each of the transistor MTCK and the transistor MTHN.

In a region of the insulator IS2 where the transistor MTCK is provided, an opening KK1 whose side surface is substantially perpendicular (a taper angle of greater than or equal to 70° and less than or equal to 110°) to an X-Y plane is formed. The semiconductor SC1 including the channel formation region of the transistor MTCK is provided to be in contact with the conductor ME1 and the conductor ME2 through the opening KK1. Similarly, in a region of the insulator IS2 where the transistor MTHN is provided, an opening KK2 whose side surface is substantially perpendicular to the X-Y plane is formed. The semiconductor SC1 including the channel formation region of the transistor MTHN is provided to be in contact with the conductor ME1 and the conductor ME2 through the opening KK2.

In each of the transistor MTCK and the transistor MTHN, the insulator GI1 is provided over the semiconductor SC1. Specifically, the insulator GI1 is positioned above and overlaps with the channel formation region included in the semiconductor SC1 in the plan view. Furthermore, in the transistor MTCK, the insulator GI2 is provided over the insulator GI1. Thus, the insulator GI1 and the insulator GI2 function as a gate insulating film in the transistor MTCK, and the insulator GI1 also functions as a gate insulating film in the transistor MTHN.

In the transistor MTCK, the conductor ME3 is provided over the insulator GI2 to fill the opening KK1. In the transistor MTHN, the conductor ME3 is provided over the insulator GI1 to fill the opening KK2. The conductor ME3 is a conductor (sometimes rephrased as a terminal, a wiring, or the like) functioning as a gate in each of the transistor MTCK and the transistor MTHN.

Note that in FIG. 2A to FIG. 2D, the conductor ME3 is provided as a wiring to extend in the Y direction, for example.

As described above, in each of the transistor MTCK and the transistor MTHN that are illustrated in FIG. 2A to FIG. 2D, the conductor ME1 functioning as one of the source and the drain is positioned below the insulator IS2 serving as an interlayer film, and the conductor ME2 functioning as the other of the source and the drain is positioned above the insulator IS2. Thus, the transistor MTCK and the transistor MTHN each have a structure in which the channel formation region is provided along the opening in the first insulator.

As described above, the transistor MTCK and the transistor MTHN each have a structure in which a source electrode and a drain electrode are positioned at different levels, and a current flowing through a semiconductor layer flows in the height direction. In other words, the channel length direction includes a component of the height direction (the vertical direction), so that the transistor MTCK and the transistor MTHN can each also be referred to as a VFET (Vertical Field Effect Transistor), a vertical transistor, a vertical-channel transistor, or the like.

As illustrated in FIG. 2A to FIG. 2D, when the channel formation region of the transistor is provided along the side surface of the opening in the insulator functioning as an interlayer film, the transistor formation area can be smaller than that in the case where the channel formation region of the transistor is provided along the X-Y plane. In each of the transistor MTCK and the transistor MTHN, the source electrode, the semiconductor, and the drain electrode can be provided to overlap with each other; thus, the area occupied by the transistor can be significantly smaller than the area occupied by what is called a planar transistor in which a semiconductor is provided in a planar shape. Thus, when a circuit is formed using one or both of the transistor MTCK and the transistor MTHN, the area of the circuit can be small. This results in a reduction in size of a semiconductor device including the circuit or a display apparatus including the circuit.

The channel length of the transistor MTCK is, for example, a channel length LCK illustrated in FIG. 2B and FIG. 2C, and the channel length of the transistor MTHN is, for example, a channel length LHN illustrated in FIG. 2B and FIG. 2D. The channel length LCK and the channel length LHN can each be regarded as the shortest distance between a portion in contact with the conductor ME1 and a portion in contact with the conductor ME2 in the semiconductor SC1 in the cross-sectional view. Note that the channel length can be the length of the channel formation region between the source and the drain.

The channel length LCK of the transistor MTCK corresponds to the length in the height direction of the opening KK1 in the insulator IS2 in the cross-sectional view. Similarly, the channel length LHN of the transistor MTHN corresponds to the length in the height direction of the opening KK2 in the insulator IS2 in the cross-sectional view. In other words, the channel length LCK and the channel length LHN are determined in accordance with the thickness of the insulator IS2. In the case where the opening KK1 has a tapered shape, the channel length LCK is also determined by the angle formed between the opening KK1 and the formation surface (here, the top surface of the conductor ME2), and the channel length LHN is also determined by the angle formed between the opening KK2 and the formation surface (here, the top surface of the conductor ME2). Thus, the channel length LCK and the channel length LHN can each have a value smaller than that of the resolution limit of a light-exposure apparatus, for example, which enables a transistor having a minute size. Specifically, it is possible to obtain a transistor with an extremely short channel length that could not be obtained with use of a conventional light-exposure apparatus for mass production of flat panel displays (the minimum line width: approximately 2 μm or approximately 1.5 μm, for example). Moreover, it is also possible to obtain a transistor with a channel length less than 10 nm without using an extremely expensive light-exposure apparatus used in the latest LSI technology.

The channel length LCK and the channel length LHN can each be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length LCK and the channel length LHN can each be greater than or equal to 100 nm and less than or equal to 1 μm.

By shortening the channel length LCK and the channel length LHN, the on-state currents of the transistor MTCK and the transistor MTHN can be increased. That is, it is not necessary to increase the gate-source voltage to increase the on-state current. Thus, for example, by using the transistor MTCK and the transistor MTHN in a driver circuit of a large-sized display apparatus or a driver circuit of a high-definition display apparatus, power consumption of these driver circuits, which is related to the gate-source voltage, can be reduced. Moreover, when the transistor MTCK and the transistor MTHN are used in a large-sized display apparatus or a high-definition display apparatus, signal delay in wirings can be reduced and display unevenness can be inhibited even when the number of wirings is increased. Furthermore, since the area occupied by the circuit can be reduced, the bezel of the display apparatus can be narrowed.

Since the gate insulating film of the transistor MTCK includes the insulator GI2, the gate insulating film of the transistor MTCK is thicker than the gate insulating film of the transistor MTHN. In the case where a transistor includes a thick gate insulating film, the transistor can have a gentle gradient of voltage between a gate and a channel formation region in a semiconductor, so that the transistor can have high resistance to a gate potential. Meanwhile, in the case where a transistor includes a thin gate insulating film, an electric field applied from a gate to a channel formation region in a semiconductor rapidly changes when a gate potential is changed, so that the transistor can have a high driving frequency.

That is, the transistor MTCK functions as a transistor having high resistance to a high gate potential (sometimes rephrased as a high gate-source voltage or a high gate-drain voltage), and the transistor MTHN functions as a transistor having a high driving frequency. Note that the transistor MTCK sometimes functions as a transistor having high resistance to a source potential or a drain potential.

The difference between the transistor MTCK and the transistor MTHN is the thickness of the gate insulating film. After the insulator GI1 is formed, the insulator GI2 is formed over the insulator GI1 in a region where the transistor MTCK is to be formed, whereby the transistor MTCK including the thick gate insulating film and the transistor MTHN including the thin gate insulating film can be separately formed in a simplified manner.

The thickness of the insulator GI2 formed after the insulator GI1 is provided can be determined at the phase of the formation step of the insulator GI2. That is, in some cases, the thickness of the gate insulating film of the transistor MTCK can be adjusted even after the insulator GI1 is provided.

Although FIG. 2A to FIG. 2D illustrate the two transistors, the transistor MTCK and the transistor MTHN, as examples, one embodiment of the present invention is not limited thereto. The transistor MTCK is configured to include the gate insulating film including the two films, the insulator GI1 and the insulator GI2, for example; alternatively, the gate insulating film of the transistor MTCK may be an insulating film in which three or more insulators are stacked. For another example, three or more transistors whose gate insulating films have thicknesses different from each other may be included in the same display apparatus.

### <Structure Example of Driver Circuit>

Next, the driver circuit SD, the driver circuit GD, the driver circuit TSD, and the protection circuit PRT of the display apparatus DSP in FIG. 1 are described.

### <<Driver Circuit SD>>

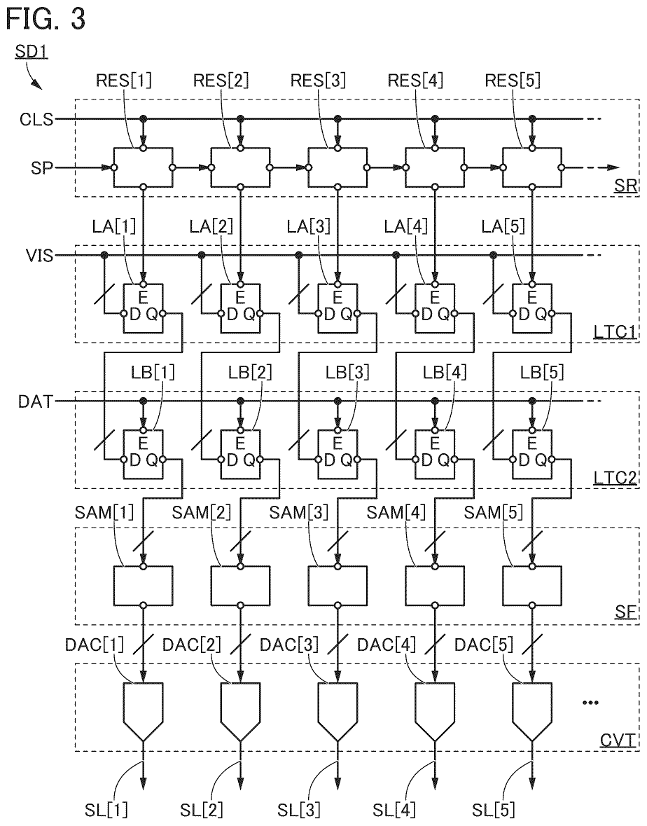

FIG. 3 shows a structure example of the driver circuit SD that can be provided in the display apparatus DSP in FIG. 1. A driver circuit SD1 in FIG. 3 includes, for example, a shift register SR, a retention circuit LTC1, a retention circuit LTC2, an amplifier circuit SF, and a converter circuit CVT.

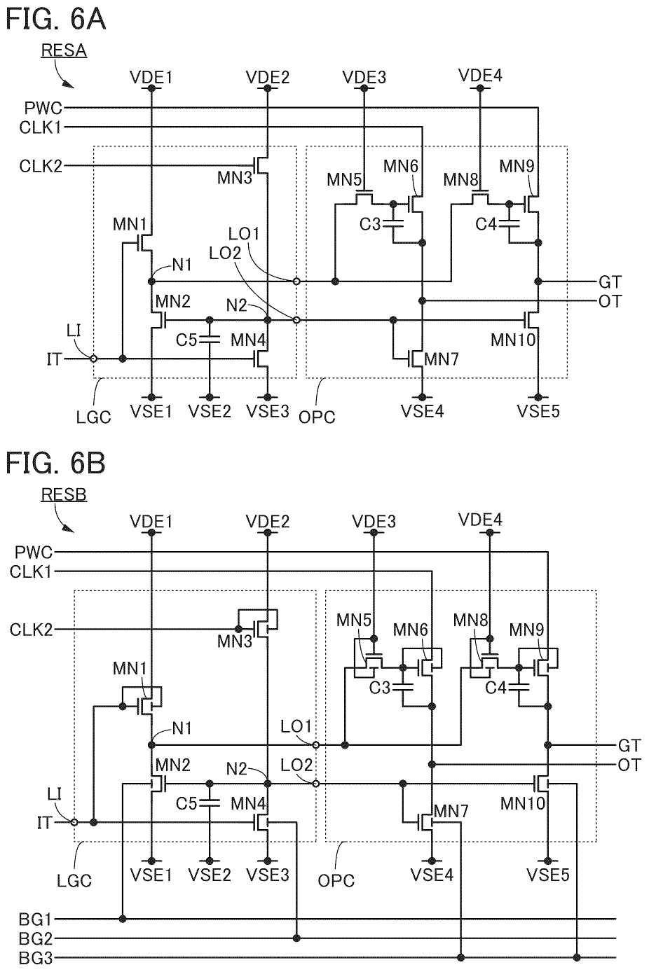

The shift register SR includes, for example, a plurality of memory circuits RES (e.g., flip-flop circuits or register circuits) connected in one column. Specifically, between adjacent memory circuits RES, a first output terminal of the memory circuit RES in the previous stage is electrically connected to a first input terminal of the memory circuit RES in the subsequent stage. A first input terminal of a memory circuit RES[1] at the head (corresponding to a terminal IT of a memory circuit RESA illustrated in FIG. 6A or the like, which is described later) is electrically connected to a wiring SP. Second input terminals of the plurality of memory circuits RES (corresponding to a terminal CLK1, a terminal CLK2, a terminal PWC, and the like of the memory circuit RESA illustrated in FIG. 6A or the like, which is described later) are each electrically connected to a wiring CLS. Note that in FIG. 3, the memory circuit RES[1] to a memory circuit RES[5] are selectively illustrated as the memory circuits RES.

The wiring SP functions as, for example, a wiring for supplying a variable potential (sometimes rephrased as a pulse potential, a pulse voltage, or a pulse signal) to the shift register SR. The wiring SP may function as, for example, a wiring for supplying a fixed potential (e.g., a high-level potential, a low-level potential, a ground potential, or a negative potential). Note that the wiring SP may be one wiring or a plurality of wirings. In this embodiment, the wiring SP functions as a wiring for supplying a start pulse signal to the shift register SR.

The wiring CLS functions as, for example, a wiring for supplying a clock signal to the shift register SR. The wiring CLS may function as, for example, a wiring for supplying a fixed potential (e.g., a high-level potential, a low-level potential, a ground potential, or a negative potential) or a variable potential. Note that the wiring SP may be one wiring or a plurality of wirings.

When a start pulse signal is input from the wiring SP to the first input terminal of the memory circuit RES[1], the start pulse signal is supplied to the memory circuit RES[1], and the memory circuit RES[1] stores information of the start pulse signal. In addition, here, when a clock signal is input from the wiring CLS to the second input terminal of each of the plurality of memory circuits RES, a signal corresponding to the information is transmitted from a first output terminal of the memory circuit RES[1] (for example, corresponding to a terminal OT of the memory circuit RESA in FIG. 6A, which is described later) to a first input terminal of the adjacent memory circuit RES[2], and the memory circuit RES[2] stores the information. That is, the shift register SR has a function of shifting the information retained in the memory circuit RES in the previous stage to the memory circuit RES in the subsequent stage when receiving a clock signal.

The memory circuit RES also has a function of outputting a high-level potential to a second output terminal of the memory circuit RES when a clock signal is input from the wiring CLS to the second input terminal of the memory circuit RES storing information of a start pulse signal.

The retention circuit LTC1 includes a plurality of first latch circuits LA, for example. Input terminals D of the plurality of first latch circuits LA are each electrically connected to a wiring VIS. The second output terminals of the plurality of memory circuits RES (for example, corresponding to a terminal GT of the memory circuit RESA in FIG. 6A, which is described later) included in the shift register SR are electrically connected to enable input terminals E (clock input terminals) of the plurality of first latch circuits LA in a one-to-one correspondence. Note that in FIG. 3, a first latch circuit LA[1] to a first latch circuit LA[5] are selectively illustrated as the first latch circuits LA.

The wiring VIS functions as, for example, a wiring for supplying an image signal (sometimes rephrased as a video signal or a display signal) as digital data to the retention circuit LTC1. Note that the wiring VIS may function as, for example, a wiring for supplying a fixed potential (e.g., a high-level potential, a low-level potential, a ground potential, or a negative potential). In this embodiment, the wiring VIS is a plurality of wirings for transmitting an image signal which is digital data.

The first latch circuit LA has a function of, when a high-level potential is input from the second output terminal of the memory circuit RES to the enable input terminal E of the first latch circuit LA, storing an image signal input from the wiring VIS to an input terminal of the first latch circuit LA. The first latch circuit also has a function of outputting the image signal to an output terminal of the first latch circuit unless the image signal is newly rewritten after the image signal is stored.

That is, a start pulse signal is input from the wiring SP to the shift register SR and clock signals are sequentially input from the wiring CLS to the shift register SR, whereby high-level potentials are sequentially input to the enable input terminals E of the plurality of first latch circuits. Thus, by changing an image signal of the wiring VIS in accordance with a clock signal from the wiring CLS to the shift register SR, the plurality of first latch circuits can store image signals corresponding to respective columns.

The retention circuit LTC2 includes a plurality of second latch circuits LB, for example. The input terminals D of the plurality of second latch circuits LB are electrically connected to the output terminals of the plurality of first latch circuits LA in a one-to-one correspondence. The enable input terminals E of the plurality of second latch circuits LB are each electrically connected to a wiring DAT. Note that in FIG. 3, a second latch circuit LB[1] to a second latch circuit LB[5] are selectively illustrated as the second latch circuits LB.

The wiring DAT functions as, for example, a wiring for supplying a variable potential. Note that the wiring DAT may function as, for example, a wiring for supplying a fixed potential (a high-level potential, a low-level potential, a ground potential, a negative potential, or the like). Note that in this embodiment, the wiring DAT supplies a high-level potential or a low-level potential to the retention circuit LTC2.

When the plurality of first latch circuits LA each store information of an image signal, the wiring DAT is assumed to supply a low-level potential to the enable input terminal E of the second latch circuit. In addition, when the plurality of first latch circuits LA each store information of an image signal, the image signal output from the output terminal of the first latch circuit LA is input to an input terminal of the second latch circuit LB in the same column as the first latch circuit LA. At this time, the second latch circuit LB stores the information of the image signal. That is, storing the information of the image signal in each of the plurality of first latch circuits LA and storing the information of the image signal in each of the plurality of second latch circuits LB are completed at the same time.

After that, by supplying high-level potentials from the wiring DAT to the enable input terminals E of the plurality of second latch circuits LB, the stored image signals are output at a time from output terminals of the plurality of second latch circuits LB.

The amplifier circuit SF includes, for example, a plurality of source follower circuits SAM. Input terminals of the plurality of source follower circuits SAM are electrically connected to the output terminals of the plurality of second latch circuits LB in a one-to-one correspondence. Note that in FIG. 3, a source follower circuit SAM[1] to a source follower circuit SAM[5] are selectively illustrated as the source follower circuits SAM.

The converter circuit CVT includes, for example, a plurality of digital-to-analog converter circuits DAC. Input terminals of the plurality of digital-to-analog converter circuits DAC are electrically connected to output terminals of the plurality of source follower circuits SAM in a one-to-one correspondence. Output terminals of the plurality of digital-to-analog converter circuits DAC are electrically connected to a plurality of wirings SL in a one-to-one correspondence. Note that in FIG. 3, a digital-to-analog converter circuit DAC[1] to a digital-to-analog converter circuit DAC[5] are selectively illustrated as the digital-to-analog converter circuits DAC. In FIG. 3, a wiring SL[1] to a wiring SL[5] are selectively illustrated as the wirings SL.

The digital-to-analog converter circuit DAC has a function of, for example, converting an image signal, which is digital data input to the input terminal of the digital-to-analog converter circuit DAC, into analog data and outputting the analog data to the output terminal of the digital-to-analog converter circuit DAC.

The wiring SL can be, for example, a wiring corresponding to the wiring SLS illustrated in FIG. 1. Thus, the wiring SL can be a wiring for transmitting an image signal, which is analog data, to the pixel circuit.

Since the shift register SR is preferably driven at high speed, the transistor MTHN is preferably used in the memory circuit RES included in the shift register SR. In addition, since the amplifier circuit SF is driven with a high voltage, the transistor MTCK is preferably used in the source follower circuit SAM included in the amplifier circuit SF.

In each of the first latch circuit LA included in the retention circuit LTC1 and the second latch circuit LB included in the retention circuit LTC2, the transistor MTCK may be used or the transistor MTHN may be used. In the first latch circuit LA or the second latch circuit LB, both the transistor MTCK and the transistor MTHN may be used.

By lowering the high-level potentials of a start pulse signal and a clock signal that are input to the shift register SR, the power consumption of the shift register SR can be reduced. Note that in this case, high-level potentials output from the second output terminals of the plurality of memory circuits RES are also lowered; thus, an image signal transmitted from the wiring VIS might not be appropriately taken into one or more of the plurality of first latch circuits LA included in the retention circuit LTC1.

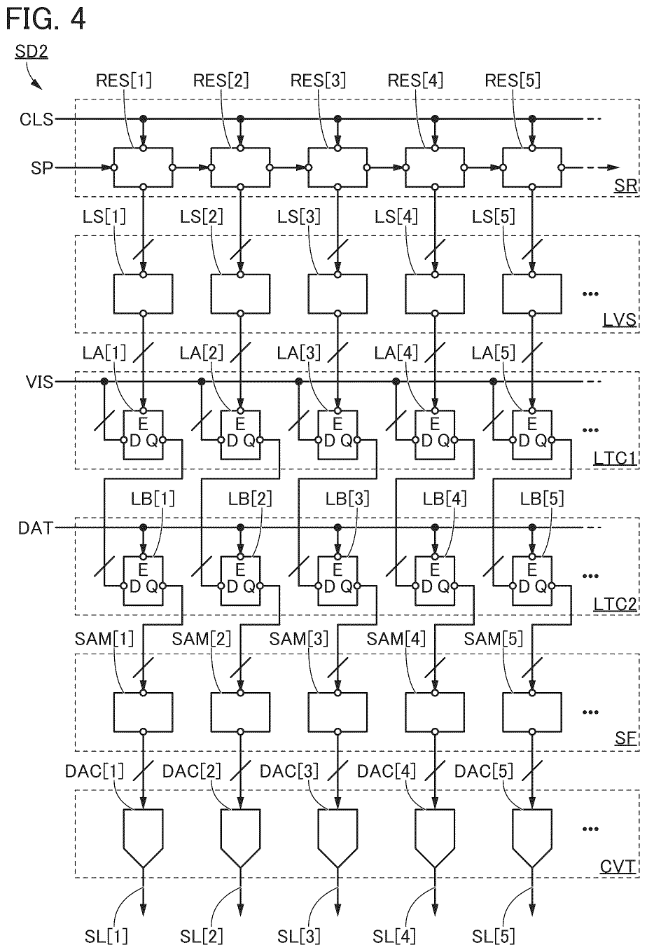

In such a case, the driver circuit SD1 is replaced with a driver circuit SD2 illustrated in FIG. 4. The driver circuit SD2 is different from the driver circuit SD1 in including an amplifier circuit LVS.

In the driver circuit SD2, the amplifier circuit LVS includes a plurality of level shifter circuits LS. Input terminals of the plurality of level shifter circuits LS are electrically connected to the second output terminals of the plurality of memory circuits RES in a one-to-one correspondence. Output terminals of the plurality of level shifter circuits LS are electrically connected to the input terminals of the plurality of first latch circuits LA in a one-to-one correspondence. Note that in FIG. 3, a level shifter circuit LS[1] to a level shifter circuit LS[5] are selectively illustrated as the level shifter circuits LS.

The level shifter circuit LS has a function of, for example, amplifying a high-level potential output from the second output terminal of the memory circuit RES, level-shifting the potential to a higher-level potential, and outputting the higher-level potential to the output terminal of the level shifter circuit LS.

Accordingly, with use of the driver circuit SD2, the higher-level potential obtained by level-shifting the high-level potential output from the second output terminal of the memory circuit RES can be input to the enable input terminal E of each of the plurality of first latch circuits LA, so that an image signal transmitted from the wiring VIS can be easily taken into each of the plurality of first latch circuits LA.

### <<Driver Circuit GD>>

The driver circuit GD includes a shift register, for example. In this case, the shift register included in the driver circuit GD can have a structure similar to that of the shift register SR included in the driver circuit SD described above.

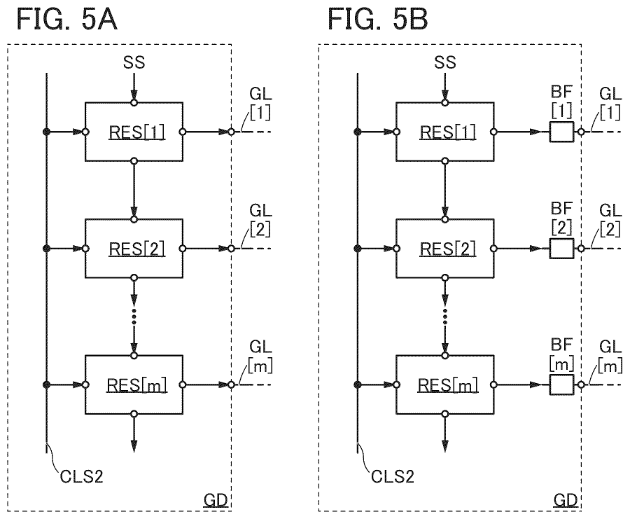

FIG. 5A shows a structure example of the driver circuit GD of one embodiment of the present invention which is applicable to the display apparatus DSP in FIG. 1. The driver circuit GD illustrated in FIG. 5A includes, for example, a memory circuit RES[1] to a memory circuit RES[m] each functioning as a shift register. For the memory circuit RES[1] to the memory circuit RES[m], the description of the plurality of memory circuits RES included in the shift register SR illustrated in FIG. 3 can be referred to.

Like the plurality of memory circuits RES included in the shift register SR illustrated in FIG. 3 and FIG. 4, the memory circuit RES[1] to the memory circuit RES[m] each include a first input terminal, a second input terminal, a first output terminal, and a second output terminal, for example.

Specifically, between adjacent memory circuits RES among the memory circuit RES[1] to the memory circuit RES[m], for example, the first output terminal of the memory circuit RES in the previous stage is electrically connected to the first input terminal of the memory circuit RES in the subsequent stage. The first input terminal of the memory circuit RES[1] at the head is electrically connected to a wiring SS. The second input terminals of the plurality of memory circuits RES are each electrically connected to a wiring CLS2.

For the wiring CLS2, the description of the wiring CLS illustrated in FIG. 3 can be referred to, for example.

A second output terminal of the memory circuit RES[i] is electrically connected to a wiring GL[i], for example.

The memory circuit RES[1] to the memory circuit RES[m] each have a function of retaining information input to the first input terminal and a function of outputting the retained information to one or both of the first output terminal and the second output terminal, for example. Note that for the specific operation, the description of the shift register SR illustrated in FIG. 3 can be referred to.

The above-described information can be, for example, a selection signal for selecting the pixel circuit PX to which image data is to be written in the pixel array PXA. Note that in the driver circuit GD in FIG. 5A, the selection signals are transmitted by the wiring SS, the selection signals are sequentially retained in the memory circuit RES[1] to the memory circuit RES[m], and the selection signals are sequentially transmitted to a wiring GL[1] to a wiring GL[m].

In the driver circuit GD illustrated in FIG. 5A, a first output terminal of the memory circuit RES[m] is illustrated; however, since the memory circuit RES[1] to the memory circuit RES[m] each have a structure of a shift register, the memory circuit RES[m] is not necessarily provided with the first output terminal.

The structure of the driver circuit GD applicable to the display apparatus DSP in FIG. 1 is not limited to that in FIG. 5A. For example, the structure of the driver circuit GD applicable to the display apparatus DSP in FIG. 1 may be that of the driver circuit GD illustrated in FIG. 5B. The driver circuit GD in FIG. 5B is different from the driver circuit GD in FIG. 5A in including a circuit BF[1] to a circuit BF[m].

In the driver circuit GD in FIG. 5B, input terminals of the circuit BF[1] to the circuit BF[m] are electrically connected to second output terminals of the memory circuit RES[1] to the memory circuit RES[m] in a one-to-one correspondence, and output terminals of the circuit BF[1] to the circuit BF[m] are electrically connected to the wiring GL[1] to the wiring GL[m] in a one-to-one correspondence.

The circuit BF[1] to the circuit BF[m] can each be configured to include an amplifier circuit such as a buffer circuit, an inverter circuit, or a latch circuit, for example. Specifically, the circuit BF[1] to the circuit BF[m] can each have a function of referring to and amplifying a potential of a second output terminal and outputting the amplified potential to the wiring GL. In particular, the amplifier circuit handles a high voltage in some cases and thus preferably includes the transistor MTCK as a transistor having high resistance to voltage. In the case where the amplifier circuit is desired to be driven at higher speed, the transistor MTHN is preferably used as a transistor included in the amplifier circuit.

Note that a wiring other than the wiring CLS and the wiring SS may be provided to extend in the driver circuits GD illustrated in FIG. 5A and FIG. 5B. For example, a wiring for supplying a fixed potential to drive each of the memory circuit RES[1] to the memory circuit RES[m] may be provided to extend.

The driver circuit GD may include a demultiplexer, for example. In the case where a potential corresponding to a signal transmitted by the demultiplexer is a high potential, the demultiplexer preferably includes the transistor MTCK as a transistor having high resistance to voltage. In the case where the demultiplexer is desired to operate at higher speed, a transistor included in the demultiplexer is preferably the transistor MTHN as a transistor having a high driving frequency.

### <<Driver Circuit TSD>>

The driver circuit TSD may include a shift register, for example. Therefore, the shift register included in the driver circuit TSD can have a structure similar to that of the shift register SR included in the driver circuit SD described above.

The driver circuit TSD may include, for example, an amplifier circuit for amplifying a weak signal generated by the touch sensor. The amplifier circuit is sometimes supplied with a high power supply potential for amplifying the signal; in this case, the amplifier circuit preferably includes the transistor MTCK as a transistor having high resistance to voltage.

### <<Protection Circuit PRT>>

The protection circuit PRT has a function of, for example, releasing the charge in the wiring GLS[i] or the wiring SLS[j] to another wiring in order to lower a potential out of a certain range that is supplied to the wiring GLS[i] or the wiring SLS[j]. That is, the protection circuit PRT handles the potential out of the certain range in the wiring GLS[i] or the wiring SLS[f]. Therefore, the protection circuit PRT preferably includes the transistor MTCK as a transistor having high resistance to voltage.

Note that in the case where the protection circuit PRT is desired to operate at higher speed, the protection circuit PRT preferably includes the transistor MTHN, which is a transistor having a high driving frequency.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 2

In this embodiment, the structures of the circuits included in the driver circuit SD described in Embodiment 1 above are described.

### <Shift Register SR>

First, a structure example of the memory circuit RES included in the shift register SR of the driver circuit SD is described.

### <<Structure Example 1 of Memory Circuit RES>>

FIG. 6A shows an example of a circuit structure of the memory circuit RESA that can be used as each of the memory circuit RES[1] to the memory circuit RES[5] that are illustrated in FIG. 3 or FIG. 4.

The memory circuit RESA includes a transistor MN1 to a transistor MN10 and a capacitor C3 to a capacitor C5, for example. As illustrated in FIG. 6A, the memory circuit RESA is a single-polarity circuit not including a p-channel transistor but including an n-channel transistor. Thus, the transistor MN1 to the transistor MN10 are n-channel transistors.

The memory circuit RESA includes the terminal IT, the terminal CLK1, the terminal CLK2, the terminal PWC, the terminal GT, and the terminal OT each functioning as an input terminal or an output terminal.

The memory circuit RESA can be separated into a circuit LGC and a circuit OPC on the basis of the functions. The circuit LGC has a function of, for example, a logic circuit that processes a signal input to the terminal IT, and the circuit OPC has a function of, for example, a logic circuit that generates signals output to the terminal OT and the terminal GT. Note that one or both of the circuit LGC and the circuit OPC may be not a logic circuit but an analog circuit.

As illustrated in FIG. 6A, the circuit LGC includes, for example, the transistor MN1 to the transistor MN4 and the capacitor C5, and the circuit OPC includes, for example, the transistor MN5 to the transistor MN10, the capacitor C3, and the capacitor C4. Note that FIG. 6A shows an example of separating the transistor MN1 to the transistor MN10 and the capacitor C3 to the capacitor C5 into the circuit LGC and the circuit OPC, and the structures of the circuit LGC and the circuit OPC are not particularly limited. For example, the capacitor C5 included in the circuit LGC in FIG. 6A may be included in the circuit OPC.

Note that in this embodiment, the circuit LGC includes a terminal LI, a terminal LO1, and a terminal LO2 for convenience. The terminal LI functions as an input terminal of the circuit LGC, the terminal LO1 functions as a first output terminal of the circuit LGC, and the terminal LO2 functions as a second output terminal of the circuit LGC.

The circuit OPC included in the memory circuit RESA in FIG. 6A has a function of retaining a potential corresponding to a signal input to the terminal IT with use of the capacitor C3 and the capacitor C4. That is, the circuit OPC has a function of retaining a potential output from the terminal LO1 of the circuit LGC. In addition, the circuit LGC included in the memory circuit RESA in FIG. 6A has a function of retaining the potential of the terminal LO2 with use of the capacitor C5.

In the case of making the pixel array PXA of the display apparatus DSP display a moving image smoothly, the frame frequency of the display apparatus DSP is preferably increased. Therefore, in order to increase the frame frequency, a transistor having a high driving frequency is preferably used in the shift register SR included in the driver circuit SD. That is, the transistor MTHN described in Embodiment 1 above is preferably used as each of the transistor MN1 to the transistor MN10.

A gate of the transistor MN1 is electrically connected to the terminal IT through the terminal LI, and a first terminal of the transistor MN1 is electrically connected to a wiring VDE1. A gate of the transistor MN3 is electrically connected to the terminal CLK2, and a first terminal of the transistor MN3 is electrically connected to a wiring VDE2. A gate of the transistor MN2 is electrically connected to a second terminal of the transistor MN3, a first terminal of the transistor MN4, and a first terminal of the capacitor C5, a first terminal of the transistor MN2 is electrically connected to a second terminal of the transistor MN1, and a second terminal of the transistor MN2 is electrically connected to a wiring VSE1. The first terminal of the transistor MN2 is electrically connected to a first terminal of the transistor MN5 and a first terminal of the transistor MN8 through the terminal LO1. The gate of the transistor MN2 is electrically connected to a gate of the transistor MN7 and a gate of the transistor MN10 through the terminal LO2. A gate of the transistor MN4 is electrically connected to the terminal IT through the terminal LI, and a second terminal of the transistor MN4 is electrically connected to a wiring VSE3.

A gate of the transistor MN5 is electrically connected to a wiring VDE3, and a second terminal of the transistor MN5 is electrically connected to a gate of the transistor MN6 and a first terminal of the capacitor C3. A first terminal of the transistor MN6 is electrically connected to the terminal CLK1, and a second terminal of the transistor MN6 is electrically connected to a first terminal of the transistor MN7, a second terminal of the capacitor C3, and the terminal OT. A second terminal of the transistor MN7 is electrically connected to a wiring VSE4.

A gate of the transistor MN8 is electrically connected to a wiring VDE4, and a second terminal of the transistor MN8 is electrically connected to a gate of the transistor MN9 and a first terminal of the capacitor C4. A first terminal of the transistor MN9 is electrically connected to the terminal PWC, and a second terminal of the transistor MN9 is electrically connected to a first terminal of the transistor MN10, a second terminal of the capacitor C4, and the terminal GT. A second terminal of the transistor MN10 is electrically connected to a wiring VSE5.

The terminal IT is a terminal corresponding to the first input terminal of the memory circuit RES in FIG. 3 or FIG. 4.

The terminal CLK1, the terminal CLK2, and the terminal PWC are terminals each corresponding to the second input terminal of the memory circuit RES in FIG. 3 or FIG. 4. Thus, the number of the wirings CLS illustrated in FIG. 3 or FIG. 4 can be three or more.

In particular, the two wirings CLS electrically connected to the terminal CLK1 and the terminal CLK2 and the one wiring CLS electrically connected to the terminal PWC each function as a wiring for supplying a pulse potential. The pulse width may be different between the pulse potential supplied by the one wiring CLS electrically connected to the terminal CLK1 or the terminal CLK2 and the pulse potential supplied by the one wiring CLS electrically connected to the terminal PWC.

In particular, a clock signal with a constant pulse width is preferably transmitted to each of the two wirings CLS electrically connected to the terminal CLK1 and the terminal CLK2. A clock signal including a pulse width that can be changed during the operation of the driver circuit SD is preferably transmitted to the one wiring CLS electrically connected to the terminal PWC. In this case, the pulse width of a clock signal input to the memory circuit RES through the terminal PWC can be set freely during the operation of the driver circuit SD.

The terminal OT is a terminal corresponding to the first output terminal of the memory circuit RES in FIG. 3 or FIG. 4.

The terminal GT is a terminal corresponding to the second output terminal of the memory circuit RES in FIG. 3 or FIG. 4.

The wiring VDE1 to the wiring VDE4 each function as a wiring for supplying a fixed potential, for example. The fixed potential can be a high-level potential, for example. Note that the wiring VDE1 to the wiring VDE4 may supply fixed potentials equal to each other or may supply fixed potentials different from each other. Alternatively, two or more wirings selected from the wiring VDE1 to the wiring VDE4 may supply fixed potentials equal to each other, and the other wiring(s) may supply a potential different from the fixed potentials. Furthermore, the two or more wirings among the wiring VDE1 to the wiring VDE4 which supply fixed potentials equal to each other may be the same wiring. For example, in the case where the wiring VDE1 and the wiring VDE2 supply fixed potentials equal to each other, the wiring VDE1 and the wiring VDE2 may be the same wiring.

One or more of the wiring VDE1 to the wiring VDE4 may be a wiring for supplying not a fixed potential but a variable potential.

The wiring VSE1 to the wiring VSE5 each function as a wiring for supplying a fixed potential, for example. The fixed potential can be, for example, a low-level potential, a ground potential, or a negative potential. Note that the wiring VSE1 to the wiring VSE5 may supply fixed potentials equal to each other or may supply fixed potentials different from each other. Alternatively, two or more wirings selected from the wiring VSE1 to the wiring VSE5 may supply fixed potentials equal to each other, and the other wiring(s) may supply a potential different from the fixed potentials. Furthermore, the two or more wirings among the wiring VSE1 to the wiring VSE5 which supply fixed potentials equal to each other may be the same wiring. For example, in the case where the wiring VSE1 and the wiring VSE2 supply fixed potentials equal to each other, the wiring VSE1 and the wiring VSE2 may be the same wiring.

One or more of the wiring VSE1 to the wiring VSE4 may be a wiring for supplying not a fixed potential but a variable potential.

Here, the operation of the circuit LGC illustrated in FIG. 6A is described assuming that a high-level potential is input to each of the wiring VDE1 and the wiring VDE2 and a low-level potential is input to each of the wiring VSE1 to the wiring VSE3.

When the terminal IT is supplied with a low-level potential and the terminal CLK2 is supplied with a high-level potential, for example, the circuit LGC in FIG. 6A outputs, from the terminal LO1, the low-level potential supplied by the wiring VSE1 and outputs, from the terminal LO2, a potential obtained by subtracting the threshold voltage of the transistor MN3 from the high-level potential supplied by the wiring VDE2. Note that the potential obtained by subtracting the threshold voltage of the transistor MN3 from the high-level potential supplied by the wiring VDE2 is input to the gate of the transistor MN2; thus, to be precise, the potential output from the terminal LO1 may be slightly higher than the low-level potential supplied by the wiring VSE1.

Next, when the terminal IT is supplied with a low-level potential and the terminal CLK2 is supplied with a low-level potential, for example, the circuit LGC outputs, from the terminal LO1, the potential of a node N1, i.e., the low-level potential (or a potential slightly higher than the low-level potential) supplied by the wiring VSE1 and outputs, from the terminal LO2, the potential of a node N2, i.e., the potential obtained by subtracting the threshold voltage of the transistor MN3 from the high-level potential supplied by the wiring VDE2.

When the terminal IT is supplied with a high-level potential and the terminal CLK2 is supplied with a low-level potential, the circuit LGC outputs, from the terminal LO1, a potential obtained by subtracting the threshold voltage of the transistor MN1 from the high-level potential supplied by the wiring VDE1 and outputs, from the terminal LO2, the low-level potential supplied by the wiring VSE3.

Next, when the terminal IT is supplied with a low-level potential and the terminal CLK2 is supplied with a low-level potential, for example, the circuit LGC outputs, from the terminal LO1, the potential of the node N1, i.e., the potential obtained by subtracting the threshold voltage of the transistor MN1 from the high-level potential supplied by the wiring VDE1 and outputs, from the terminal LO2, the potential of the node N2, i.e., the potential obtained by subtracting the low-level potential supplied by the wiring VSE3.

The following is the summary of the above description. When a low-level potential is input to the terminal CLK2 and a high-level potential is input to the terminal IT, ideally, the circuit LGC outputs a high-level potential from the terminal LO1 and outputs a low-level potential from the terminal LO2. In addition, when a high-level potential is input to the terminal CLK2 and a low-level potential is input to the terminal IT, ideally, the circuit LGC outputs a low-level potential from the terminal LO1 and outputs a high-level potential from the terminal LO2. Moreover, when a low-level potential is input to the terminal CLK2 and a low-level potential is input to the terminal IT, the circuit LGC outputs the potential of the node N1 from the terminal LO1 (sometimes rephrased as “retains the potential output from the terminal LO1”) and outputs the potential of the node N2 from the terminal LO2 (sometimes rephrased as “retains the potential output from the terminal LO2”).

Note that with use of the transistor MTCK described in Embodiment 1 as each of the transistor MN1 to the transistor MN10 in the memory circuit RESA in FIG. 6A, the memory circuit RESA can be configured to have high resistance to a high voltage. With use of the transistor MTHN described in Embodiment 1 as each of the transistor MN1 to the transistor MN10 in the memory circuit RESA in FIG. 6A, the memory circuit RESA can operate at higher speed, resulting in a higher frame frequency of the display apparatus DSP.

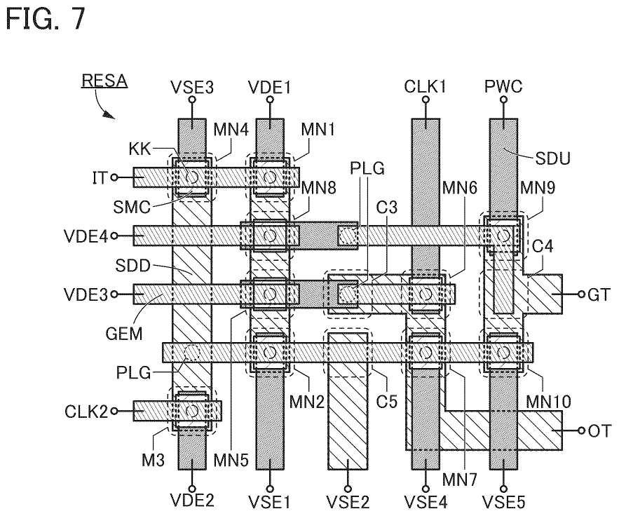

FIG. 7 is a layout (plan view) of the memory circuit RESA in FIG. 6A. In FIG. 7, the transistor MN1 to the transistor MN10 are each illustrated as the transistor MTCK or the transistor MTHN described in Embodiment 1. In FIG. 7, the memory circuit RESA includes a conductor GEM, a conductor SDD, a conductor SDU, a semiconductor SMC, and a conductor PLG. Note that FIG. 7 does not illustrate an insulator included in the memory circuit RESA.

The conductor SDD is positioned below the conductor SDU, for example. The conductor SDU has an opening KK in a region overlapping with the conductor SDD, for example. Note that the opening KK is denoted by a dashed line in FIG. 7. The semiconductor SMC is positioned over the conductor SDU outside a region of the opening KK and the conductor SDD in the region of the opening KK, for example. The conductor GEM is positioned above the semiconductor SMC to fill the opening KK.

The conductor SDD corresponds to the conductor ME1 in FIG. 2A to FIG. 2D, the conductor SDU corresponds to the conductor ME2 in FIG. 2A to FIG. 2D, the semiconductor SMC corresponds to the semiconductor SC1 in FIG. 2A to FIG. 2D, and the conductor GEM corresponds to the conductor ME3 in FIG. 2A to FIG. 2D. The opening KK corresponds to the opening KK1 or the opening KK2 in FIG. 2A to FIG. 2D.

The semiconductor SMC, the conductor GEM, the conductor SDD, and the conductor SDU can each be formed by a photolithography method, for example. Specifically, for example, in the case where the conductor GEM is formed, a conductive material to be the conductor GEM is formed by one or more selected from a sputtering method, a CVD (Chemical Vapor Deposition) method, a PLD (Pulsed Laser Deposition) method, and an ALD (Atomic Layer Deposition) method, and then a desired pattern is formed by a lithography method. The semiconductor SMC, the conductor SDD, and the conductor SDU can also be formed in a manner similar to the above.

Furthermore, insulators may be provided between the semiconductor SMC and the conductor GEM, between the conductor SDU and the conductor GEM, and between the conductor SDU and the conductor SDD. In particular, an insulator provided between the semiconductor SMC and the conductor GEM functions as a gate insulating film in some cases.

The conductor PLG functioning as a wiring or a plug is provided between the conductor SDD and the conductor SDU and between the conductor SDU and the conductor GEM. The conductor PLG is formed, for example, in such a manner that an opening portion is formed in the insulator, and the opening portion is filled with a conductive material to be the conductor PLG. Note that after the formation of the conductor PLG, planarization may be performed by planarization treatment using chemical mechanical polishing or the like to align the levels of film surfaces of the conductor PLG and peripheral insulators.

Note that without providing the conductor PLG between the conductor SDU and the conductor GEM, an opening may be provided in the insulator between the conductor SDU and the conductor GEM so that the conductor SDU and the conductor GEM can be in direct contact with each other and the conductor SDU and the conductor GEM can be electrically connected to each other.

In the capacitor C4 in FIG. 7, part of the conductor GEM is used as the first terminal of the capacitor C4, and part of the conductor SDD is used as the second terminal of the capacitor C4. Note that in order to increase the electrostatic capacitance of the capacitor C4, the insulator between the conductor GEM and the conductor SDD may be made thin in a region of the capacitor C4 in FIG. 7. An insulator with a high relative permittivity may be provided between the conductor GEM and the conductor SDD. Note that the description of the capacitor C4 can be referred to for the capacitor C5.

In the capacitor C3 in FIG. 7, part of the conductor SDU is used as the first terminal of the capacitor C3, and part of the conductor SDD is used as the second terminal of the capacitor C3. Thus, in a region of the capacitor C3 in FIG. 7, the conductor GEM and the conductor SDU are electrically connected to each other but the conductor SDU and the conductor SDD are not electrically connected to each other. Note that in order to increase the electrostatic capacitance of the capacitor C3, the insulator between the conductor SDD and the conductor SDU may be made thin in the region of the capacitor C3 in FIG. 7. An insulator with a high relative permittivity may be provided between the conductor SDD and the conductor SDU.

In the memory circuit RESA in FIG. 6A, the transistor MTCK or the transistor MTHN described in Embodiment 1 may be used as some of the transistor MN1 to the transistor MN10, and a transistor having another structure may be used as the other transistors. For example, a transistor containing silicon in a channel formation region (hereinafter, sometimes referred to as a Si transistor) may be used as the transistor included in the circuit LGC, and the transistor MTCK or the transistor MTHN described in Embodiment 1 may be used as the transistor included in the circuit OPC.

Examples of the silicon include amorphous silicon (sometimes referred to as hydrogenated amorphous silicon), microcrystalline silicon, polycrystalline silicon (e.g., low-temperature polysilicon (LTPS)), and single crystal silicon.

Examples of the transistor having another structure include a transistor containing germanium (Ge) or the like in a channel formation region, a transistor containing a compound semiconductor such as zinc selenide (ZnSe), cadmium sulfide (CdS), gallium arsenide (GaAs), indium phosphide (InP), gallium nitride (GaN), or silicon germanium (SiGe) in a channel formation region, a transistor containing a carbon nanotube in a channel formation region, and a transistor containing an organic semiconductor in a channel formation region.

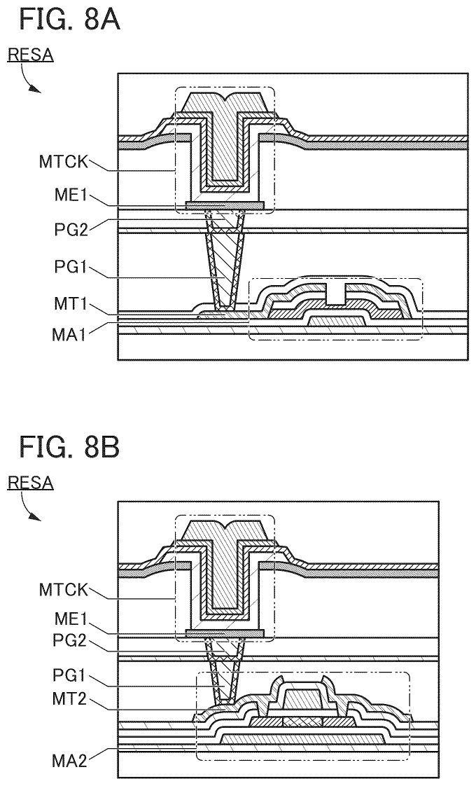

FIG. 8A is a cross-sectional view illustrating some transistors of the memory circuit RESA; FIG. 8A shows a structure example in which an inverted staggered transistor MA1 is provided below and the transistor MTCK is provided above the inverted staggered transistor MA1. Note that in FIG. 8A, a conductor MT1 functioning as a source or a drain of the transistor MA1 is electrically connected to the conductor ME1 of the transistor MTCK through a conductor PG1 and a conductor PG2 each functioning as a wiring or a plug.

The transistor MTCK and the transistor MA1 in FIG. 8A can be, for example, the transistor MN1 and the transistor MN2 of the memory circuit RESA in FIG. 6A. For another example, the transistor MTCK and the transistor MA1 in FIG. 8A can be the transistor MN5 and the transistor MN2 of the memory circuit RESA in FIG. 6A. For another example, the transistor MTCK and the transistor MA1 in FIG. 8A can be the transistor MN8 and the transistor MN2. The transistor MN5 of the memory circuit RESA in FIG. 6A can be the transistor MTCK in FIG. 8A, and the transistor MN1 of the memory circuit RESA in FIG. 6A can be the transistor MA1 in FIG. 8A, for example.

FIG. 8B is a cross-sectional view illustrating some transistors of the memory circuit RESA, which is different from FIG. 8A; FIG. 8B shows a structure example in which a TGTC (Top Gate Top Contact) transistor MA2 is provided below and the transistor MTCK is provided above the transistor MA2. Note that in FIG. 8B, a conductor MT2 functioning as a source or a drain of the transistor MA2 is electrically connected to the conductor ME1 of the transistor MTCK through the conductor PG1 and the conductor PG2 each functioning as a wiring or a plug.

Note that the transistor MA1 and the transistor MA2 illustrated in FIG. 8A and FIG. 8B, respectively, can be Si transistors.

The transistor MTCK illustrated in FIG. 8A and FIG. 8B may be the transistor MTHN described in Embodiment 1.

In some cases, the structure of the transistor included in the memory circuit RESA can also be applied to a structure example of another memory circuit RES described later.

### <<Structure Example 2 of Memory Circuit RES>

The structure of the memory circuit RES that can be provided in the shift register SR is not limited to that of the memory circuit RESA illustrated in FIG. 6A. For example, the structure of the memory circuit RES that can be provided in the shift register SR may be that of a memory circuit RESB illustrated in FIG. 6B.

The memory circuit RESB in FIG. 6B is a modification example of the memory circuit RESA in FIG. 6A and is different from the memory circuit RESA in that the transistors included in the memory circuit RESB are each provided with a back gate.

The transistor MN1 to the transistor MN10 illustrated in FIG. 6A are each an n-channel transistor having a multi-gate structure including gates over and under a channel, and the transistor MN1 to the transistor MN10 each include the gate and the back gate, for example. Note that in this specification and the like, for convenience, the gate is referred to as a first gate (sometimes referred to as a front gate) and the back gate is referred to as a second gate in some cases so that they can be distinguished from each other, for example. In this specification and the like, the first gate and the second gate can be interchanged with each other; thus, the term “gate” can be replaced with the term “back gate”. Similarly, the term “back gate” can be replaced with the term “gate”. As a specific example, a connection structure in which “a gate is electrically connected to a first wiring and a back gate is electrically connected to a second wiring” can be replaced with a connection structure in which “a back gate is electrically connected to the first wiring and a gate is electrically connected to the second wiring”.

Note that the destination to which the back gate of each of the transistor MN1 to the transistor MN10 is electrically connected in FIG. 6B can be determined in the design phase. For example, in a transistor including a back gate, a gate and the back gate may be electrically connected to each other to increase the on-state current of the transistor (this applies to the transistor MN1, the transistor MN3, the transistor MN5, the transistor MN6, the transistor MN8, and the transistor MN9 in FIG. 6B). For another example, in a transistor including a back gate, a wiring electrically connecting the back gate of the transistor to an external circuit may be provided and a potential may be supplied to the back gate of the transistor with the external circuit to change the threshold voltage of the transistor or to reduce the off-state current of the transistor (this applies to the transistor MN2, the transistor MN4, the transistor MN7, and the transistor MN10 in FIG. 6B).

Although the transistor MN1 to the transistor MN10 are n-channel transistors in FIG. 6A and FIG. 6B, the transistor MN1 to the transistor MN10 may be p-channel transistors depending on the situation.

Note that the above description of the transistor sometimes applies to a transistor described in other parts of the specification and a transistor illustrated in other drawings, not only to the transistors illustrated in FIG. 6A and FIG. 6B.

In each of the transistor MN1, the transistor MN3, the transistor MN5, the transistor MN6, the transistor MN8, and the transistor MN9, the gate is electrically connected to the back gate. The second gate of the transistor MN2 is electrically connected to a wiring BG1. The second gate of the transistor MN4 is electrically connected to a wiring BG2. The gate of each of the transistor MN7 and the transistor MN10 is electrically connected to a wiring BG3.

The wiring BG1 to the wiring BG3 each function as a wiring for supplying a fixed potential, for example. The fixed potential can be, for example, a low-level potential, a ground potential, or a negative potential. Note that the wiring BG1 to the wiring BG3 may supply fixed potentials equal to each other or may supply fixed potentials different from each other. In the case where two or more selected from the wiring BG1 to the wiring BG3 are wirings that supply fixed potentials equal to each other, the selected two or more wirings may be the same wiring. One or more selected from the wiring BG1 to the wiring BG3 may be a wiring for supplying not a fixed potential but a variable potential.

In the case where the wiring BG1 to the wiring BG3 are wirings different from each other, different fixed potentials can be supplied to the back gates of the transistor MN2, the transistor MN4, the transistor MN7, and the transistor MN10. That is, the threshold voltage of the transistor MN2, the threshold voltage of the transistor MN4, and the threshold voltages of the transistor MN7 and the transistor MN10 can be controlled independently.

Thus, for example, when a negative potential is supplied to the back gate of the transistor MN4 and the ground potential or a low-level potential (a potential higher than the negative potential) is supplied to the back gate of each of the transistor MN7 and the transistor MN10, the amounts of off-state currents of the transistor MN7 and the transistor MN10 can be larger than the amount of an off-state current of the transistor MN4. Accordingly, in the case where the memory circuit RESB in FIG. 6B is used as each of the plurality of memory circuits RES in the shift register SR in FIG. 3 or FIG. 4, the driving speed of the shift register provided in the driver circuit SD can be further increased.

### <<Structure Example 3 of Memory Circuit RES>>

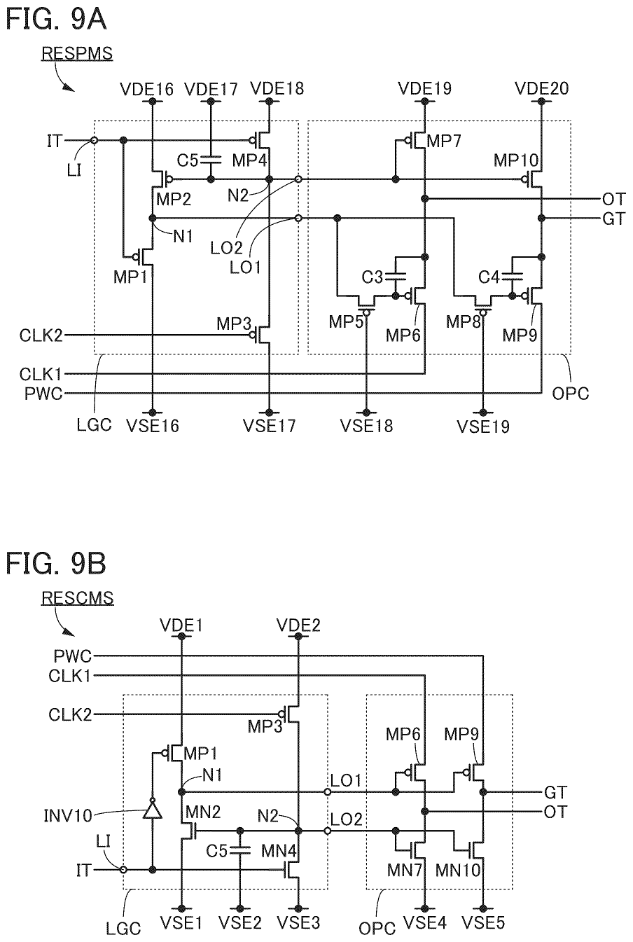

For another example, the structure of the memory circuit RES that can be provided in the shift register SR may be that of a memory circuit RESPMS illustrated in FIG. 9A.

The memory circuit RESPMS has a circuit structure obtained by replacing the memory circuit RESA in FIG. 6A, which is a single-polarity circuit including an n-channel transistor, with a single-polarity circuit including a p-channel transistor.

Like the memory circuit RESA in FIG. 6A, the memory circuit RESPMS includes the circuit LGC and the circuit OPC. The circuit LGC includes, for example, a transistor MP1 to a transistor MP4 and the capacitor C5, and the circuit OPC includes, for example, a transistor MP5 to a transistor MP10, the capacitor C3, and the capacitor C4. Note that as described above, the transistor MP1 to the transistor MP10 are p-channel transistors.

A gate of the transistor MP1 is electrically connected to the terminal IT through the terminal LI, and a first terminal of the transistor MP1 is electrically connected to a wiring VSE16. A gate of the transistor MP3 is electrically connected to the terminal CLK2, and a first terminal of the transistor MP3 is electrically connected to a wiring VSE17. A gate of the transistor MP2 is electrically connected to a second terminal of the transistor MP3, a first terminal of the transistor MP4, and the first terminal of the capacitor C5, a first terminal of the transistor MP2 is electrically connected to a second terminal of the transistor MP1, and a second terminal of the transistor MP2 is electrically connected to a wiring VDE16. The first terminal of the transistor MP2 is electrically connected to a first terminal of the transistor MP5 and a first terminal of the transistor MP8 through the terminal LO1. The gate of the transistor MP2 is electrically connected to a gate of the transistor MP7 and a gate of the transistor MP10 through the terminal LO2. A gate of the transistor MP4 is electrically connected to the terminal IT through the terminal LI, and a second terminal of the transistor MP4 is electrically connected to a wiring VDE18.

A gate of the transistor MP5 is electrically connected to the wiring VSE5, and a second terminal of the transistor MP5 is electrically connected to a gate of the transistor MP6 and the first terminal of the capacitor C3. A first terminal of the transistor MP6 is electrically connected to the terminal CLK1, and a second terminal of the transistor MP6 is electrically connected to a first terminal of the transistor MP7, the second terminal of the capacitor C3, and the terminal OT. A second terminal of the transistor MP7 is electrically connected to a wiring VDE19.

A gate of the transistor MP8 is electrically connected to a wiring VSE19, and a second terminal of the transistor MP8 is electrically connected to a gate of the transistor MP9 and the first terminal of the capacitor C4. A first terminal of the transistor MP9 is electrically connected to the terminal PWC, and a second terminal of the transistor MP9 is electrically connected to a first terminal of the transistor MP10, the second terminal of the capacitor C4, and the terminal GT. A second terminal of the transistor MP10 is electrically connected to a wiring VDE20.

The wiring VDE16 to the wiring VDE20 each function as a wiring for supplying a fixed potential, for example. The fixed potential can be a high-level potential, for example. Note that the wiring VDE16 to the wiring VDE20 may supply fixed potentials equal to each other or may supply fixed potentials different from each other. Alternatively, two or more wirings selected from the wiring VDE16 to the wiring VDE20 may supply fixed potentials equal to each other, and the other wiring(s) may supply a potential different from the constant potential. Furthermore, the two or more wirings among the wiring VDE16 to the wiring VDE20 which supply fixed potentials equal to each other may be the same wiring. For example, in the case where the wiring VDE16 and the wiring VDE17 supply fixed potentials equal to each other, the wiring VDE16 and the wiring VDE17 may be the same wiring.

One or more of the wiring VDE16 to the wiring VDE20 may be a wiring for supplying not a fixed potential but a variable potential.

The wiring VSE16 to the wiring VSE19 each function as a wiring for supplying a fixed potential, for example. The fixed potential can be, for example, a low-level potential, a ground potential, or a negative potential. Note that the wiring VSE16 to the wiring VSE19 may supply fixed potentials equal to each other or may supply fixed potentials different from each other. Alternatively, two or more wirings selected from the wiring VSE16 to the wiring VSE19 may supply fixed potentials equal to each other, and the other wiring(s) may supply a potential different from the fixed potentials. Furthermore, the two or more wirings among the wiring VSE16 to the wiring VSE19 which supply fixed potentials equal to each other may be the same wiring. For example, in the case where the wiring VSE16 and the wiring VSE17 supply constant potentials equal to each other, the wiring VSE1 and the wiring VSE17 may be the same wiring.

One or more of the wiring VSE16 to the wiring VSE19 may be a wiring for supplying not a fixed potential but a variable potential.

For the operation of the memory circuit RESPMS, the description of the operation example of the memory circuit RESA in FIG. 6A can be referred to. The circuit LGC in the memory circuit RESPMS is a single-polarity circuit including a p-channel transistor; thus, it should be noted that the logic of a signal, a potential, or the like handled in the memory circuit RESPMS is inverted from the logic of a signal, a potential, or the like handled in the memory circuit RESA in FIG. 6A, which is a single-polarity circuit including an n-channel transistor.

Note that with use of the transistor MTCK described in Embodiment 1 as each of the transistor MP1 to the transistor MP10 in the memory circuit RESPMS in FIG. 9A, the memory circuit RESPMS can be configured to have high resistance to a high voltage. With use of the transistor MTHN described in Embodiment 1 as each of the transistor MP1 to the transistor MP10 in the memory circuit RESPMS in FIG. 9A, the memory circuit RESPMS can operate at higher speed, resulting in a higher frame frequency of the display apparatus DSP.

### <<Structure Example 4 of Memory Circuit RES>>

For another example, the structure of the memory circuit RES that can be provided in the shift register SR may be that of a memory circuit RESCMS illustrated in FIG. 9B.

The memory circuit RESCMS has a circuit structure obtained by replacing the memory circuit RESA in FIG. 6A, which is a single-polarity circuit including an n-channel transistor, with a CMOS (Complementary MOS) circuit including an n-channel transistor and a p-channel transistor.

Like the memory circuit RESA in FIG. 6A, the memory circuit RESCMS includes the circuit LGC and the circuit OPC. The circuit LGC includes, for example, the transistor MP1, the transistor MN2, the transistor MP3, the transistor MN4, the capacitor C5, and an inverter INV10, and the circuit OPC includes, for example, the transistor MP6, the transistor MN7, the transistor MP9, and the transistor MP10. Note that the transistor MP1, the transistor MP3, the transistor MP6, and the transistor MP9 are p-channel transistors, and the transistor MN2, the transistor MN4, the transistor MN7, and the transistor MN10 are n-channel transistors.

The inverter INV10 may be a single-polarity circuit including one of an n-channel transistor and a p-channel transistor or may be a CMOS circuit including both of them.

The gate of the transistor MP1 is electrically connected to an output terminal of the inverter INV10. An input terminal of the inverter INV10 is electrically connected to the terminal IT through the terminal LI. The first terminal of the transistor MP1 is electrically connected to the wiring VDE1. The gate of the transistor MP3 is electrically connected to the terminal CLK2, and the first terminal of the transistor MP3 is electrically connected to the wiring VDE2. The gate of the transistor MN2 is electrically connected to the second terminal of the transistor MP3, the first terminal of the transistor MN4, and the first terminal of the capacitor C5, the first terminal of the transistor MN2 is electrically connected to the second terminal of the transistor MN1, and the second terminal of the transistor MN2 is electrically connected to the wiring VSE1. The first terminal of the transistor MN2 is electrically connected to the gate of the transistor MP6 and the gate of the transistor MP9 through the terminal LO1. The gate of the transistor MN2 is electrically connected to the gate of the transistor MN7 and the gate of the transistor MN10 through the terminal LO2. The gate of the transistor MN4 is electrically connected to the terminal IT through the terminal LI, and the second terminal of the transistor MN4 is electrically connected to the wiring VSE3.

The first terminal of the transistor MP6 is electrically connected to the terminal CLK1, and the second terminal of the transistor MP6 is electrically connected to the first terminal of the transistor MN7 and the terminal OT. The second terminal of the transistor MN7 is electrically connected to the wiring VSE4.

The first terminal of the transistor MP9 is electrically connected to the terminal PWC, and the second terminal of the transistor MP9 is electrically connected to the first terminal of the transistor MN10 and the terminal GT. The second terminal of the transistor MN10 is electrically connected to the wiring VSE5.

For the wiring VDE1, the wiring VDE2, and the wiring VSE1 to the wiring VSE5, the description of the wiring VDE1, the wiring VDE2, and the wiring VSE1 to the wiring VSE5 illustrated in FIG. 6A can be referred to.

For the operation of the memory circuit RESCMS, the description of the operation example of the memory circuit RESA in FIG. 6A can be referred to. Note that the terminal CLK2 in the memory circuit RESPMS is electrically connected to the gate of the transistor MP3, which is a p-channel transistor; thus, it should be noted that the logic of a signal input to the gate of the transistor MP3 in the memory circuit RESCMS is inverted from the logic of a signal input to the gate of the transistor MN3, which is an n-channel transistor, in the memory circuit RESA in FIG. 6A.

Note that with use of the transistor MTCK described in Embodiment 1 as each of the transistor MP1, the transistor MN2, the transistor MP3, the transistor MN4, the transistor MP6, the transistor MN7, the transistor MP9, the transistor MP10, and the transistor included in the inverter INV10 in the memory circuit RESCMS in FIG. 9B, the memory circuit RESCMS can be configured to have high resistance to a high voltage. With use of the transistor MTHN described in Embodiment 1 as each of the above-listed transistors in the memory circuit RESCMS in FIG. 9B, the memory circuit RESCMS can operate at higher speed, resulting in a higher frame frequency of the display apparatus DSP.

### <<Structure Example 5 of Memory Circuit RES>>

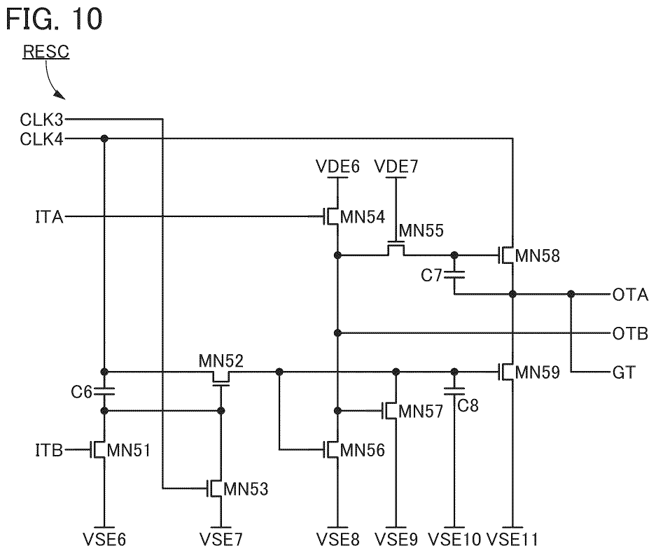

For another example, the structure of the memory circuit RES that can be provided in the shift register SR may be that of a memory circuit RESC illustrated in FIG. 10.

The memory circuit RESC includes a terminal ITA and a terminal ITB functioning as the first input terminals of the memory circuit RES in FIG. 3 or FIG. 4 and a terminal OTA and a terminal OTB functioning as the first output terminals of the memory circuit RES in FIG. 3 or FIG. 4. That is, the memory circuit RESC is different from the memory circuit RESA in including two first input terminals and two first output terminals.

The terminal OTA of the memory circuit RESC in the previous stage is electrically connected to the terminal ITA of the memory circuit RESC in the subsequent stage, and the terminal OTB of the memory circuit RESC in the previous stage is electrically connected to the terminal ITB of the memory circuit RESC in the subsequent stage.

The memory circuit RESC includes a terminal CLK3 and a terminal CLK4. The terminal CLK3 and the terminal CLK4 are terminals each corresponding to the second input terminal of the memory circuit RES in FIG. 3 or FIG. 4. Thus, the number of the wirings CLS illustrated in FIG. 3 or FIG. 4 can be two or more.

In particular, the one wiring CLS electrically connected to the terminal CLK3 or the terminal CLK4 and the one wiring CLS electrically connected to the terminal PWC each function as a wiring for supplying a pulse potential. The pulse width may be different between the pulse potential supplied to the terminal CLK3 and the pulse potential supplied to the terminal CLK4.

Like the memory circuit RESA, the memory circuit RESC includes the terminal GT. The terminal GT is a terminal corresponding to the second output terminal of the memory circuit RES in FIG. 3 or FIG. 4.

The memory circuit RESC includes a transistor MN51 to a transistor MN59 and a capacitor C6 to a capacitor C8, for example. As illustrated in FIG. 10, the memory circuit RESC is a single-polarity circuit not including a p-channel transistor but including an n-channel transistor.

In the memory circuit RESC in FIG. 10, each of the transistor MN51 to the transistor MN59 has a single-gate structure, but may be a transistor having a multi-gate structure including gates over and under a channel.

In the case of making the pixel array PXA of the display apparatus DSP display a moving image smoothly, the frame frequency of the display apparatus DSP is preferably increased. Therefore, in order to increase the frame frequency, a transistor having a high driving frequency is preferably used in the shift register SR included in the driver circuit SD. That is, the transistor MTHN described in Embodiment 1 above is preferably used as each of the transistor MN51 to the transistor MN59.

A first terminal of the capacitor C6 is electrically connected to a first terminal of the transistor MN52 and the terminal CLK4, and a second terminal of the capacitor C6 is electrically connected to a first terminal of the transistor MN51, a gate of the transistor MN52, and a first terminal of the transistor MN53. A second terminal of the transistor MN51 is electrically connected to a wiring VSE6, and a gate of the transistor MN51 is electrically connected to the terminal ITB. A second terminal of the transistor MN53 is electrically connected to a wiring VSE7, and a gate of the transistor MN53 is electrically connected to the terminal CLK3. A second terminal of the transistor MN52 is electrically connected to a gate of the transistor MN56, a first terminal of the transistor MN57, a gate of the transistor MN59, and a first terminal of the capacitor C8. A second terminal of the transistor MN57 is electrically connected to a wiring VSE9. A second terminal of the capacitor C8 is electrically connected to a wiring VSE10.

A first terminal of the transistor MN54 is electrically connected to a wiring VDE6, and a second terminal of the transistor MN54 is electrically connected to a first terminal of the transistor MN55, a gate of the transistor MN57, a first terminal of the transistor MN56, and the terminal OTB. A second terminal of the transistor MN56 is electrically connected to a wiring VSE8. A second terminal of the transistor MN55 is electrically connected to a gate the transistor MN58 and a first terminal of the capacitor C7, and a gate of the transistor MN55 is electrically connected to a wiring VDE7. A first terminal of the transistor MN58 is electrically connected to the terminal CLK4, a second terminal of the transistor MN58 is electrically connected to a second terminal of the capacitor C7, a first terminal of the transistor MN59, the terminal OTA, and the terminal GT, and a second terminal of the transistor MN59 is electrically connected to a wiring VSE11.

The wiring VDE6 and the wiring VDE7 each function as a wiring for supplying a fixed potential, for example. The fixed potential can be a high-level potential, for example. Note that the wiring VDE6 and the wiring VDE7 may supply fixed potentials equal to each other or may supply fixed potentials different from each other. In the case where the wiring VDE6 and the wiring VDE7 supply fixed potentials equal to each other, the wiring VDE6 and the wiring VDE7 may be the same wiring.

One or both of the wiring VDE6 and the wiring VDE7 may be a wiring for supplying not a fixed potential but a variable potential.

The wiring VSE6 to the wiring VSE11 each function as a wiring for supplying a fixed potential, for example. The fixed potential can be, for example, a low-level potential, a ground potential, or a negative potential. Note that the wiring VSE6 to the wiring VSE11 may supply fixed potentials equal to each other or may supply fixed potentials different from each other. Alternatively, two or more wirings selected from the wiring VSE6 to the wiring VSE11 may supply fixed potentials equal to each other, and the other wiring(s) may supply a potential different from the fixed potentials. Furthermore, the two or more wirings among the wiring VSE6 to the wiring VSE11 which supply fixed potentials equal to each other may be the same wiring. For example, in the case where the wiring VSE6 and the wiring VSE7 supply fixed potentials equal to each other, the wiring VSE6 and the wiring VSE7 may be the same wiring.

One or more of the wiring VSE6 to the wiring VSE11 may be a wiring for supplying not a fixed potential but a variable potential.

In the case of making the pixel array PXA of the display apparatus DSP display a moving image smoothly, in order to increase the frame frequency of the display apparatus DSP, a transistor having a high driving frequency is preferably used in the shift register SR included in the driver circuit SD. Thus, the transistor MTHN described in Embodiment 1 above is preferably used as each of the transistor MN51 to the transistor MN59.

### <<Structure Example 6 of Memory Circuit RES>>

The semiconductor device of one embodiment of the present invention can have a structure in which part of the memory circuit RES is driven at a low power supply voltage and another part of the memory circuit RES is driven at a high power supply voltage. As a specific example, the case is considered where a low power supply voltage is supplied to the shift register SR in the driver circuit SD1 in FIG. 3 to drive the shift register SR. Note that the power supply voltage can be, for example, a potential difference between the high-level potential supplied by the wiring VDE1 to the wiring VDE4 and the low-level potential supplied by the wiring VSE1 to the wiring VSE5 in FIG. 6A. For another example, the power supply voltage can be the voltage amplitude of the clock signal supplied by the terminal CLK1, the terminal CLK2, and the terminal PWC in FIG. 6A. For another example, the power supply voltage can be a potential difference between the high potential and the low potential of the start pulse signal input to the shift register SR.

By lowering a power supply voltage to be supplied to the shift register SR, the power consumption of the shift register can be reduced.

Note that lowering a power supply voltage to be supplied to the shift register SR also lowers voltages output from the first output terminal and the second output terminal of the memory circuit RES provided in the shift register SR. The voltages output from the first output terminal and the second output terminal of the shift register SR can each be a potential difference between a high-level potential and a low-level potential that can be output from the terminal.

As a specific example, in the case of the memory circuit RESA in FIG. 6A, a potential (a high-level potential or a low-level potential) corresponding to the clock signal of the terminal CLK1 or the low-level potential supplied by the wiring VSE4 is output from the terminal OT (corresponding to the first output terminal of the memory circuit RES in FIG. 3 or FIG. 4), and a potential (a high-level potential or a low-level potential) corresponding to the clock signal of the terminal PWC or the low-level potential supplied by the wiring VSE5 is output from the terminal GT (corresponding to the second output terminal of the memory circuit RES in FIG. 3 or FIG. 4).

When the voltage of a signal (a potential difference between a high potential and a low potential of a signal) output from the second output terminal of the memory circuit RES provided in the shift register SR is lowered, the low voltage is input to the enable input terminal of each of the plurality of first latch circuits LA included in the retention circuit LTC1 in FIG. 3. When the voltage of the signal input to the enable input terminal of the first latch circuit LA is lowered, an image signal transmitted from the wiring VIS might not be appropriately taken into one or more of the plurality of first latch circuits LA.

The semiconductor device of one embodiment of the present invention is the memory circuit RES or the shift register SR including the memory circuit RES, in which part of the memory circuit RES is driven at a low power supply voltage and another part of the memory circuit RES is driven at a high power supply voltage, whereby a low voltage can be output from the first output terminal of the memory circuit RES and a high voltage can be output from the second output terminal of the memory circuit RES. Specifically, the semiconductor device of one embodiment of the present invention is the memory circuit RES or the shift register SR including the memory circuit RES in FIG. 3 or FIG. 4, in which a signal with a low voltage (e.g., a potential difference between a high-level potential and a low-level potential) is transmitted from the memory circuit RES in the previous stage to the memory circuit RES in the subsequent stage, and a signal with a high voltage (e.g., a potential difference between a potential higher than a high-level potential and a low-level potential) is transmitted from the memory circuit RES to the enable input terminal of the first latch circuit LA. Structure examples of the semiconductor device are described below.

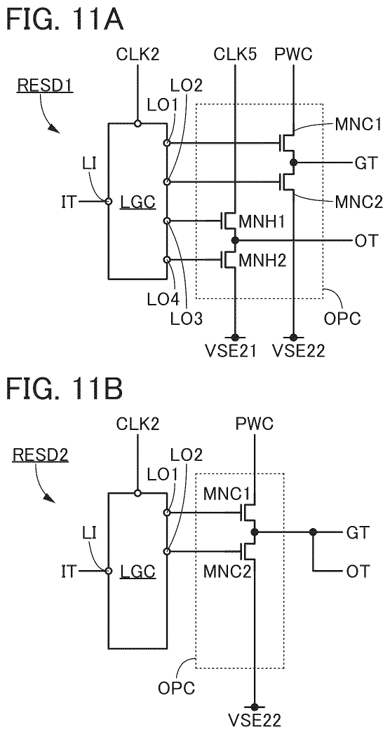

A memory circuit RESD1 illustrated in FIG. 11A shows an example of a circuit structure of a memory circuit that can be used as each of the plurality of memory circuits RES included in the shift register SR in FIG. 3 or FIG. 4.

The memory circuit RESD1 illustrated in FIG. 11A includes the circuit LGC and the circuit OPC. Note that the circuit OPC included in the memory circuit RESD1 has a structure different from that of the circuit OPC illustrated in FIG. 6A and FIG. 6B.

In the memory circuit RESD1 in FIG. 11A, the circuit OPC includes a transistor MNC1, a transistor MNC2, a transistor MNH1, and a transistor MNH2.

The circuit LGC includes the terminal LI and the terminal LO1 to a terminal LO4.

A first terminal of the transistor MNC1 is electrically connected to the terminal PWC, a second terminal of the transistor MNC1 is electrically connected to a first terminal of the transistor MNC2 and the terminal GT, and a gate of the transistor MNC1 is electrically connected to the terminal LO1. A second terminal of the transistor MNC2 is electrically connected to a wiring VSE22, and a gate of the transistor MNC2 is electrically connected to the terminal LO2. A first terminal of the transistor MNH1 is electrically connected to a terminal CLK5, a second terminal of the transistor MNH1 is electrically connected to a first terminal of the transistor MNH2 and the terminal OT, and a gate of the transistor MNH1 is electrically connected to the terminal LO3. A second terminal of the transistor MNH2 is electrically connected to a wiring VSE21, and a gate of the transistor MNH2 is electrically connected to the terminal LO4.

Like the circuit LGC of the memory circuit RESA in FIG. 6A, ideally, the circuit LGC of the memory circuit RESD1 in FIG. 11A has a function of outputting a high-level potential from the terminal LO1 and outputting a low-level potential from the terminal LO2 when a low-level potential is input to the terminal CLK2 and a high-level potential is input to the terminal IT. Ideally, the circuit LGC in FIG. 11A has a function of outputting a low-level potential from the terminal LO1 and outputting a high-level potential from the terminal LO2 when a high-level potential is input to the terminal CLK2 and a low-level potential is input to the terminal IT. The circuit LGC in FIG. 11A has a function of retaining the potential of the terminal LO1 and retaining the potential of the terminal LO2 when a low-level potential is input to the terminal CLK2 and a low-level potential is input to the terminal IT.

Ideally, the circuit LGC in FIG. 11A may have a function of outputting a high-level potential also from the terminal LO3 and outputting a low-level potential also from the terminal LO4 when a low-level potential is input to the terminal CLK2 and a high-level potential is input to the terminal IT in the circuit LGC. Ideally, the circuit LGC in FIG. 11A may have a function of outputting a low-level potential from the terminal LO3 and outputting a high-level potential from the terminal LO4 when a high-level potential is input to the terminal CLK2 and a low-level potential is input to the terminal IT. The circuit LGC in FIG. 11A may have a function retaining the potential of the terminal LO3 and retaining the potential of the terminal LO4 when a low-level potential is input to the terminal CLK2 and a low-level potential is input to the terminal IT. Thus, the terminal LO1 and the terminal LO3 may be electrically connected to each other, and the terminal LO2 and the terminal LO4 may be electrically connected to each other.

The circuit LGC of the memory circuit RESD1 in FIG. 11A can have a structure similar to that of the circuit LGC of the memory circuit RESA in FIG. 6A. For example, in the circuit LGC of the memory circuit RESA in FIG. 6A, the terminal LO3 is provided to be electrically connected to the second terminal of the transistor MN1 and the first terminal of the transistor MN2, and the terminal LO4 is provided to be electrically connected to the gate of the transistor MN2, the second terminal of the transistor MN3, the first terminal of the transistor MN4, and the first terminal of the capacitor C5.

Like the terminal CLK2 and the terminal PWC of the memory circuit RESA in FIG. 6A, the terminal CLK2 and the terminal PWC are terminals each corresponding to the second input terminal of the memory circuit RES in FIG. 3, for example. The terminal CLK5 is also a terminal corresponding to the second input terminal of the memory circuit RES in FIG. 3. Thus, the number of the wirings CLS illustrated in FIG. 3 can be three or more.

Like the terminal OT of the memory circuit RESA in FIG. 6A, the terminal OT is a terminal corresponding to the first output terminal of the memory circuit RES in FIG. 3, for example. Like the terminal GT of the memory circuit RESA in FIG. 6A, the terminal GT is a terminal corresponding to the second output terminal of the memory circuit RES in FIG. 3, for example.

The wiring VSE21 and the wiring VSE22 each function as a wiring for supplying a fixed potential, for example. The fixed potential can be a low-level potential, for example. Note that the wiring VSE21 and the wiring VSE22 may be supplied with fixed potentials equal to each other or may be supplied with fixed potentials different from each other. Note that in the case where the wiring VSE21 and the wiring VSE22 are supplied with fixed potentials equal to each other, the wiring VSE1 and the wiring VSE2 may be the same wiring.

Here, an operation method of the memory circuit RESD1 illustrated in FIG. 11A is considered.

A start pulse signal from the wiring SP or a signal from the terminal OT of the memory circuit RESD1 in the previous stage is input to the terminal IT of the memory circuit RESD1. Note that the high potential side and the low potential side of such a signal are a high-level potential V_{H} and a low-level potential V_{L}, respectively. In this case, the voltage amplitude of each signal is V_{H}−V_{L}.

Clock signals are input to the terminal CLK2 and the terminal CLK5 of the memory circuit RESD1. Note that the high potential side and the low potential side of each clock signal are a high-level potential V_{H} and a low-level potential V_{L}, respectively. That is, a potential difference between the high potential side and the low potential side of the clock signal is V_{H}−V_{L}.

The wiring VSE21 and the wiring VSE22 each function as a wiring for supplying a low-level potential V_{L} to the memory circuit RESD1.

A clock signal is supplied to the terminal PWC of the memory circuit RESD1. Note that a potential difference between the high potential side and the low potential side of the clock signal supplied to the terminal PWC is larger than the potential difference V_{H}−V_{L} between the high potential side and the low potential side of each of the clock signals supplied to the terminal CLK2 and the terminal CLK5.

For example, the high potential side of the clock signal supplied to the terminal PWC may be V_{EXH} higher than V_{H} and the low potential side may be V_{L}, in which case a potential difference between the high potential side and the low potential side of the clock signal is V_{EXH}−V_{L}. Note that in the following description, the high potential side and the low potential side of the clock signal supplied to the terminal PWC are referred to as V_{EXH} and V_{L}, respectively.

As described above, in the circuit LGC, in the case where V_{EXH} that is the high potential side of the clock signal is input to the terminal PWC while the high-level potential V_{H} is output from the terminal LO1 and the low-level potential V_{L} is output from the terminal LO2, the memory circuit RESD1 outputs, from the terminal GT, a potential obtained by subtracting the threshold voltage of the transistor MNC1 from V_{EXH}. After that, when V_{EXH} that is the high potential side of the clock signal input to the terminal PWC changes to V_{L} that is the low potential side, the memory circuit RESD1 outputs V_{L} from the terminal GT.

In the circuit LGC, while the low-level potential V_{L} is output from the terminal LO1 and the high-level potential V_{H} is output from the terminal LO2, the transistor MNC1 is in an off state and the transistor MNC2 is in an on state. Thus, the memory circuit RESD1 outputs V_{L} from the terminal GT.

As described above, since the memory circuit RESD1 sometimes outputs V_{EXH} higher than V_{H} from the terminal GT, a transistor having high resistance to voltage is preferably used as each of the transistor MNC1 and the transistor MNC2. That is, the transistor MTCK including the thick gate insulating film described in Embodiment 1 is preferably used as each of the transistor MNC1 and the transistor MNC2.

In the circuit LGC, in the case where V_{H} that is the high potential side of the clock signal is input to the terminal CLK5 while the high-level potential V_{H} is output from the terminal LO3 and the low-level potential V_{L} is output from the terminal LO4, the memory circuit RESD1 outputs, from the terminal OT, a potential obtained by subtracting the threshold voltage of the transistor MNH1 from V_{H}. After that, when V_{H} that is the high potential side of the clock signal input to the terminal CLK5 changes to V_{L} that is the low potential side, the memory circuit RESD1 outputs V_{L} from the terminal OT.

In the circuit LGC, while the low-level potential V_{L} is output from the terminal LO3 and the high-level potential V_{H} is output from the terminal LO4, the transistor MNH1 is in an off state and the transistor MNH2 is in an on state. Thus, the memory circuit RESD1 outputs V_{L} from the terminal OT.

As described above, the memory circuit RESD1 sometimes outputs V_{H} from the terminal OT as the high-level potential. Since V_{H} is a potential lower than V_{EXH}, a transistor having a lower resistance to voltage than the transistor MTCK can be used as each of the transistor MNH1 and the transistor MNH2. In addition, since the shift register SR including the memory circuit RESD1 is preferably driven at high speed, a transistor having a high driving frequency is preferably used as each of the transistor MNH1 and the transistor MNH2. That is, the transistor MTHN including the thin gate insulating film described in Embodiment 1 is preferably used as each of the transistor MNH1 and the transistor MNH2.

The transistor MTHN including the thin gate insulating film described in Embodiment 1 may also be used as the transistor included in the circuit LGC of the memory circuit RESD1. In this case, the circuit LGC can be driven at high speed.

When the transistor MTCK described in Embodiment 1 is used as each of the transistor MNC1 and the transistor MNC2 in the circuit structure of the memory circuit RESD1 in FIG. 11A, V_{EXH} higher than the high-level potential V_{H} can be output from the terminal GT of the memory circuit RESD1. Moreover, when the transistor MTHN described in Embodiment 1 is used as each of the transistor included in the circuit LGC, the transistor MNH1, and the transistor MNH2, the circuit LGC can be driven at high speed and the transistor MNH1 and the transistor MNH2 can each have a high driving frequency.

When the memory circuit RESD1 in FIG. 11A is used as the memory circuit RES provided in the shift register SR in FIG. 3, a signal whose high potential side is V_{EXH} higher than V_{H} can be output from the second output terminal of the memory circuit RES. Accordingly, V_{EXH} is input to the enable input terminal of each of the plurality of first latch circuits LA included in the retention circuit LTC1 in FIG. 3. That is, V_{EXH}−V_{L}, which is a voltage of a signal (a potential difference between a high potential and a low potential of a signal) higher than V_{H}−V_{L}, is input to the enable input terminal, so that an image signal transmitted from the wiring VIS can be easily taken into the first latch circuit.

Note that the structure of the memory circuit RES of the semiconductor device of one embodiment of the present invention is not limited to that of the memory circuit RESD1 in FIG. 11A. The structure of the memory circuit RES of the semiconductor device of one embodiment of the present invention may be a structure modified from that of the memory circuit RESD1 in FIG. 11A depending on the situation.

### <<Structure Example 7 of Memory Circuit RES>>

A memory circuit RESD2 illustrated in FIG. 11B is a modification example of the memory circuit RESD1 in FIG. 11A and is different from the memory circuit RESD1 in that the transistor MNH1 and the transistor MNH2 are not provided and the terminal OT is electrically connected to the terminal GT.

In the memory circuit RESD2 in FIG. 11B, the circuit OPC includes the transistor MNC1 and the transistor MNC2.

The circuit LGC includes the terminal LI, the terminal LO1, and the terminal LO2.

The first terminal of the transistor MNC1 is electrically connected to the terminal PWC, the second terminal of the transistor MNC1 is electrically connected to the first terminal of the transistor MNC2, the terminal GT, and the terminal OT, and the gate of the transistor MNC1 is electrically connected to the terminal LO1. The second terminal of the transistor MNC2 is electrically connected to the wiring VSE22, and the gate of the transistor MNC2 is electrically connected to the terminal LO2.

Like the circuit LGC of the memory circuit RESA in FIG. 6A, ideally, the circuit LGC of the memory circuit RESD2 in FIG. 11B has a function of outputting a high-level potential from the terminal LO1 and outputting a low-level potential from the terminal LO2 when a low-level potential is input to the terminal CLK2 and a high-level potential is input to the terminal IT. Ideally, the circuit LGC in FIG. 11A has a function of outputting a low-level potential from the terminal LO1 and outputting a high-level potential from the terminal LO2 when a high-level potential is input to the terminal CLK2 and a low-level potential is input to the terminal IT. The circuit LGC in FIG. 11A has a function of retaining the potential of the terminal LO1 and retaining the potential of the terminal LO2 when a low-level potential is input to the terminal CLK2 and a low-level potential is input to the terminal IT.

In the memory circuit RESD2 in FIG. 11B, a clock signal with a potential difference V_{EXH}−V_{L} between the high potential side and the low potential side is supplied to the terminal PWC, as in the memory circuit RESD1 in FIG. 11A. The wiring VSE22 functions as a wiring for supplying the low-level potential V_{L} to the memory circuit RESD2.

Accordingly, in the memory circuit RESD2 in FIG. 11B, the high potential side and the low potential side of the signal output from the terminal GT are V_{EXH} and V_{L}, respectively, as in the memory circuit RESD1 in FIG. 11A. Furthermore, the high potential side and the low potential side of the signal output from the terminal OT are also V_{EXH} and V_{L}, respectively.

When the memory circuit RESD2 in FIG. 11B is used as the memory circuit RES in FIG. 3, a signal whose high potential side is V_{EXH} higher than V_{H} can be output not only from the second output terminal but also from the first output terminal of the memory circuit RES. That is, the signal whose high potential side and low potential side are V_{EXH} and V_{L}, respectively, can also be transmitted to a first input terminal of a memory circuit in the subsequent stage, which is electrically connected to the first output terminal of the memory circuit RES.

### <<Structure Example 8 of Memory Circuit RES>>

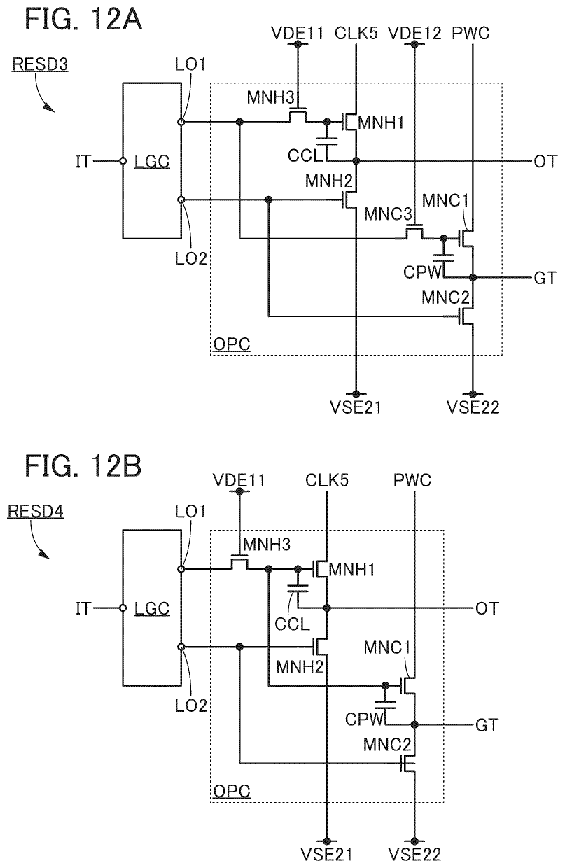

A memory circuit RESD3 illustrated in FIG. 12A is a modification example of the memory circuit RESD1 in FIG. 11A and is different from the memory circuit RESD1 in that a transistor MNC3, a transistor MNH3, a capacitor CPW, and a capacitor CCL are additionally provided and the circuit LGC is not provided with the terminal LO3 and the terminal LO4.

In the memory circuit RESD3 in FIG. 12A, the circuit OPC includes the transistor MNC1, the transistor MNC2, the transistor MNC3, the transistor MNH1, the transistor MNH2, the transistor MNH3, the capacitor CPW, and the capacitor CCL.

A first terminal of the transistor MNC3 is electrically connected to a first terminal of the transistor MNH3 and the terminal LO1. The gate of the transistor MNC2 is electrically connected to the gate of the transistor MNH2 and the terminal LO2. A second terminal of the transistor MNC3 is electrically connected to the gate of the transistor MNC1 and a first terminal of the capacitor CPW, and a gate of the transistor MNC3 is electrically connected to a wiring VDE12. The first terminal of the transistor MNC1 is electrically connected to the terminal PWC, and the second terminal of the transistor MNC1 is electrically connected to the first terminal of the transistor MNC2, a second terminal of the capacitor CPW, and the terminal GT. The second terminal of the transistor MNC2 is electrically connected to the wiring VSE22. A second terminal of the transistor MNH3 is electrically connected to the gate of the transistor MNH1 and a first terminal of the capacitor CCL, and a gate of the transistor MNH3 is electrically connected to a wiring VDE11. The first terminal of the transistor MNH1 is electrically connected to the terminal CLK5, and the second terminal of the transistor MNH1 is electrically connected to the first terminal of the transistor MNH2, a second terminal of the capacitor CCL, and the terminal OT. The second terminal of the transistor MNH2 is electrically connected to the wiring VSE21.

For the circuit LGC in FIG. 12A, the description of the circuit LGC in FIG. 11B can be referred to.

For the terminal CLK5 and the terminal PWC illustrated in FIG. 12A, the description of the terminal CLK5 and the terminal PWC of the memory circuit RESD2 in FIG. 11B can be referred to.

The wiring VDE11 and the wiring VDE12 each function as a wiring for supplying a fixed potential, for example. The fixed potential can be a high-level potential, for example. Note that the wiring VDE11 and the wiring VDE12 may be supplied with fixed potentials equal to each other or may be supplied with fixed potentials different from each other. Note that in the case where the wiring VDE11 and the wiring VDE12 are supplied with fixed potentials equal to each other, the wiring VDE11 and the wiring VDE12 may be the same wiring. Here, the wiring VDE11 and the wiring VDE12 are each a wiring for supplying V_{H} as a high-level potential.

Next, an example of an operation with a connection structure between the transistor MNC1 to the transistor MNC3 and the capacitor CPW is described.

First, the case is considered where a low-level potential V_{L} is input from the terminal LO1 to the first terminal of the transistor MNC3, and a high-level potential V_{H} is input from the terminal LO2 to the gate of the transistor MNC2. At this time, since the high-level potential V_{H} is input to the gate of the transistor MNC3, the transistor MNC3 is in an on state and the potentials of the second terminal of the transistor MNC3, the gate of the transistor MNC1, and the first terminal of the capacitor CPW are V_{L}. Meanwhile, since the high-level potential V_{H} is input to the second terminal of the transistor MNC2, the transistor MNC2 is in an on state and V_{L} is output from the terminal GT.

When the potential input from the terminal LO1 to the first terminal of the transistor MNC3 changes from V_{L} to V_{H}, the potentials of the second terminal of the transistor MNC3, the gate of the transistor MNC1, and the first terminal of the capacitor CPW increase from V_{L} to V_{H}−V_{th_MNC3}, so that the transistor MNC3 is brought into an off state. Note that V_{th_MNC3} is the threshold voltage of the transistor MNC3.

When the potential input from the terminal LO2 to the gate of the transistor MNC2 changes from V_{H} to V_{L}, the transistor MNC2 is brought into an off state and the potential of the terminal GT remains V_{L}.

Here, the case is considered where a low-level potential V_{L} is input from the terminal PWC to the first terminal of the transistor MNC1. At this time, the potential of the gate of the transistor MNC1 is V_{H}−V_{th_MNC3} and the potential of the second terminal of the transistor MNC1 is V_{L}; thus, the potential of the terminal GT remains V_{L}.

When the potential input from the terminal PWC to the first terminal of the transistor MNC1 changes from V_{L} to V_{EXH}, the potential of the second terminal of the transistor MNC1 (the terminal GT) increases from V_{L}. At this time, the second terminal of the transistor MNC3, the gate of the transistor MNC1, and the first terminal of the capacitor CPW are in a floating state; thus, when the potential of the second terminal of the capacitor CPW (the terminal GT) increases, the potentials of the second terminal of the transistor MNC3, the gate of the transistor MNC1, and the first terminal of the capacitor CPW also increase owing to capacitive coupling of the capacitor CPW. Accordingly, the gate-source voltage of the transistor MNC1 does not change even when the potential of the terminal GT increases, so that a current keeps flowing between the first terminal and the second terminal of the transistor MNC1 until the potential of the terminal GT reaches V_{EXH}.

By utilizing the capacitive coupling of the capacitor CPW in such a manner, the potential of the gate of the transistor MNC3 can be increased. In this specification and the like, increasing the gate potential with an increase in the potential of the first terminal or the second terminal of a transistor by utilizing capacitive coupling is referred to as a bootstrap.

Note that in the case where the transistor MNC1 has a large gate capacitance between the gate and the channel formation region (sometimes including one or both of the first terminal and the second terminal depending on the situation), the circuit OPC may have a structure not provided with the capacitor CPW. In this case, the circuit area of the circuit OPC can be reduced.

In the connection structure between the transistor MNH1 to the transistor MNH3 and the capacitor CCL, a high-level potential V_{H} that is the high potential side of a signal flowing from the terminal CLK5 can be output to the terminal OT by a bootstrap using the capacitor CCL, as in the connection structure between the transistor MNC1 to the transistor MNC3 and the capacitor CPW.

As described above, a voltage of V_{EXH} higher than V_{H} is sometimes added to the potential V_{H}−V_{th_MNC3} of the second terminal of the transistor MNC3 by a bootstrap using the capacitor CPW. Therefore, a transistor having high resistance to voltage is preferably used as the transistor MNC3. That is, the transistor MTCK including the thick gate insulating film described in Embodiment 1 is preferably used as the transistor MNC3.

In addition, since the shift register SR including the memory circuit RESD3 is preferably driven at high speed, a transistor having a high driving frequency is preferably used as the transistor MNH3. That is, the transistor MTHN including the thin gate insulating film described in Embodiment 1 is preferably used as the transistor MNH3.

Note that a voltage higher than V_{H} is sometimes applied to the second terminal of the transistor MNH3 by a bootstrap using the capacitor CCL. Therefore, a transistor having high resistance to voltage may be used as the transistor MNH3. That is, the transistor MTCK including the thick gate insulating film described in Embodiment 1 may be used as the transistor MNH3.

For the transistor MNH1, the transistor MNH2, the transistor MNC1, and the transistor MNC2, the description of the transistor MNH1, the transistor MNH2, the transistor MNC1, and the transistor MNC2 provided in the memory circuit RESD1 in FIG. 11 can be referred to.

The structure of the memory circuit RESD3 in FIG. 12A may be modified to that of a memory circuit RESD4 illustrated in FIG. 12B. The memory circuit RESD4 in FIG. 12B has a structure in which the transistor MNH3 and the transistor MNC3 in the circuit OPC of the memory circuit RESD3 in FIG. 12A are combined into the transistor MNH3.

Specifically, the circuit OPC of the memory circuit RESD4 in FIG. 12B has a structure in which the second terminal of the transistor MNH3 is electrically connected to the gate of the transistor MNH1, the first terminal of the capacitor CCL, the gate of the transistor MNC1, and the first terminal of the capacitor CPW.

In the memory circuit RESD4 in FIG. 12B, the potential of the gate of the transistor MNC1 can be increased by a bootstrap using the capacitor CPW, and the potential of the gate of the transistor MNH1 can be increased by a bootstrap using the capacitor CCL, as in the memory circuit RESD3 in FIG. 12A.

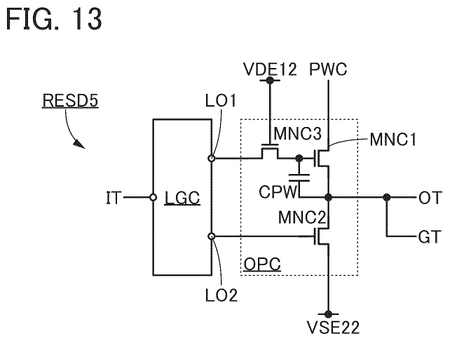

The structure of the memory circuit RESD3 in FIG. 12A may be modified to that of a memory circuit RESD5 illustrated in FIG. 13. The memory circuit RESD5 illustrated in FIG. 13 has a structure in which the terminal OT and the terminal GT of the memory circuit RESD3 in FIG. 12A are combined.

Specifically, in the memory circuit RESD5 in FIG. 13, the transistor MNH1 to the transistor MNH3 and the capacitor CCL are not provided, and the terminal OT is electrically connected to the terminal GT, the second terminal of the transistor MNC1, the second terminal of the capacitor CPW, and the first terminal of the transistor MNC2, unlike in the memory circuit RESD3 in FIG. 12A.

In the memory circuit RESD5 in FIG. 13, the potential of the gate of the transistor MNC1 can be increased by a bootstrap using the capacitor CPW, as in the memory circuit RESD3 in FIG. 12A. In the memory circuit RESD5 in FIG. 13, a signal whose high potential side is V_{EXH} higher than a high-level potential V_{H} and whose low potential side is V_{L} can be output from the terminal OT, as in the memory circuit RESD2 in FIG. 11B.

### <<Structure Example 9 of Memory Circuit RES>>

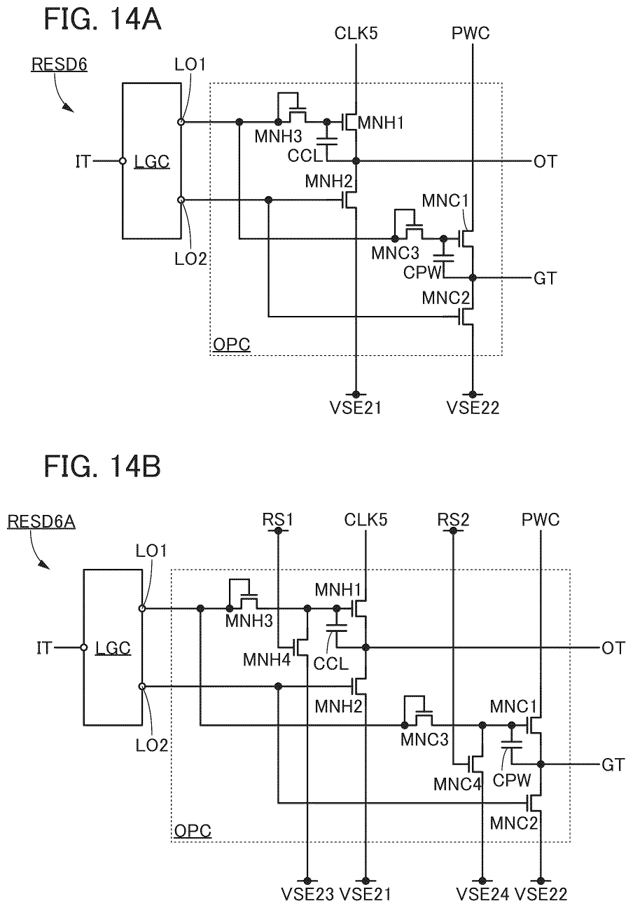

A memory circuit RESD6 illustrated in FIG. 14A is a modification example of the memory circuit RESD3 in FIG. 12A and is different from the memory circuit RESD3 in that the gate of the transistor MNC3 is electrically connected not to the wiring VDE12 but to the first terminal of the transistor MNC3 and the gate of the transistor MNH3 is electrically connected not to the wiring VDE11 but to the first terminal of the transistor MNH3.

In FIG. 14A, since the first terminal of the transistor MNC3 and the gate of the transistor MNC3 are electrically connected to each other, the transistor MNC3 can be said to be diode-connected. Hence, for example, when a high-level potential V_{H} is input from the terminal LO1 of the circuit LGC to the first terminal of the transistor MNC3, the potentials of the first terminal and the gate of the transistor MNC3 each become the high-level potential V_{H}; thus, the potentials of the second terminal of the transistor MNC3, the gate of the transistor MNC3, and the first terminal of the capacitor CPW each become V_{H}−V_{th_MNC3}.

When the potential of the second terminal of the transistor MNC3 reaches V_{H}−V_{th_MNC3}, the transistor MNC3 is brought into an off state; thus, an electrical connection point of the second terminal of the transistor MNC3, the gate of the transistor MNC1, and the first terminal of the capacitor CPW is brought into a floating state. Thus, the potential V_{H}−V_{th_MNC3} of the gate of the transistor MNC1 can be further increased by a bootstrap using the capacitor CPW. Note that even when the potential of the gate of the transistor MNC1 (the potential of the second terminal of the transistor MNC3) is increased, the transistor MNC3 is not brought into an on state.

When the potential V_{High}−V_{th_MNC3} of the first terminal of the capacitor CPW (the potential of the gate of the transistor MNC1) is desired to be decreased, that is, when the charge accumulated in the first terminal of the capacitor CPW (or the gate of the transistor MNC1) is desired to be released, the circuit OPC in FIG. 14A should be further modified.

Similarly, in FIG. 14A, since the first terminal of the transistor MNH3 and the gate of the transistor MNH3 are electrically connected to each other, the transistor MNH3 can be said to be diode-connected. Hence, for example, when a high-level potential V_{H} is input from the terminal LO1 of the circuit LGC to the first terminal of the transistor MNH3, the potentials of the first terminal and the gate of the transistor MNH3 each become the high-level potential V_{H}; thus, the potentials of the second terminal of the transistor MNH3, the gate of the transistor MNH3, and the first terminal of the capacitor CCL each become V_{H}−V_{th_MNH3}.

When the potential of the second terminal of the transistor MNH3 reaches V_{H}−V_{th_MNH3}, the transistor MNH3 is brought into an off state; thus, an electrical connection point of the second terminal of the transistor MNH3, the gate of the transistor MNH1, and the first terminal of the capacitor CCL is brought into a floating state. Thus, the potential V_{H}−V_{th_MNC3} of the gate of the transistor MNH1 can be further increased by a bootstrap using the capacitor CCL. Note that even when the potential of the gate of the transistor MNH1 (the potential of the second terminal of the transistor MNH3) is increased, the transistor MNH3 is not brought into an on state.

When the potential V_{High}−V_{th_MNH3} of the first terminal of the capacitor CCL (the potential of the gate of the transistor MNH1) is desired to be decreased, that is, when the charge accumulated in the first terminal of the capacitor CCL (or the gate of the transistor MNH1) is desired to be released, the circuit OPC in FIG. 14A should be further modified.

The circuit OPC of a memory circuit RESD6A illustrated in FIG. 14B is a modification example of the circuit OPC of the memory circuit RESD6 in FIG. 14A and is different from the circuit OPC of the memory circuit RESD6 in FIG. 14A in that the charge accumulated in the first terminal of the capacitor CPW (or the gate of the transistor MNC1) and the first terminal of the capacitor CCL (or the gate of the transistor MNH1) can be released. Specifically, the circuit OPC of the memory circuit RESD6A illustrated in FIG. 14B is different from the circuit OPC of the memory circuit RESD6 in FIG. 14A in including a transistor MNC4 and a transistor MNH4.

A first terminal of the transistor MNC4 is electrically connected to the second terminal of the transistor MNC3, the gate of the transistor MNC1, and the first terminal of the capacitor CPW, a second terminal of the transistor MNC4 is electrically connected to a wiring VSE23, and a gate of the transistor MNC4 is electrically connected to a wiring RS1. The first terminal of the transistor MNC4 is electrically connected to the second terminal of the transistor MNH3, the gate of the transistor MNH1, and the first terminal of the capacitor CCL, a second terminal of the transistor MNH4 is electrically connected to a wiring VSE24, and a gate of the transistor MNH4 is electrically connected to a wiring RS2.

Like the wiring VSE21 or the wiring VSE22, the wiring VSE23 and the wiring VSE24 each function as a wiring for supplying a fixed potential, for example. The fixed potential is, for example, a low-level potential. Other examples of the fixed potential include a ground potential and a negative potential. Depending on the situation, the wiring VSE23 and the wiring VSE24 may each function as a wiring for supplying a variable potential.

Here, the wiring VSE23 and the wiring VSE24 each function as a wiring for supplying a low-level potential V_{L}.

The wiring RS1 functions as a wiring for transmitting a signal for selecting whether the charge accumulated in the first terminal of the capacitor CCL (or the gate of the transistor MNH1) is released or not, for example. Specifically, for example, in the case where the charge in the first terminal of the capacitor CCL (the charge in the gate of the transistor MNH1) is not released, the wiring RS1 is supplied with the low-level potential V_{L} as a signal to bring the transistor MNH4 into an off state. For example, in the case where the charge in the first terminal of the capacitor CCL (the charge in the gate of the transistor MNH1) is released, the wiring RS1 is supplied with the high-level potential V_{H} as a signal to bring the transistor MNH4 into an on state.

In the case where the potential of the first terminal of the capacitor CCL (the potential of the gate of the transistor MNH1) is desired to be increased (in the case where the potential is desired to be V_{H}−V_{th_MNH3}; note that V_{th_MNH3} is the threshold voltage of the transistor MNH3), for example, the low-level potential V_{L} is supplied to the wiring RS1 to bring the transistor MNH3 into an off state and then the high-level potential V_{H} is supplied from the terminal LO1 of the circuit LGC to the first terminal of the transistor MNH3. In the case where the potential of the first terminal of the capacitor CCL (the potential of the gate of the transistor MNH1) is desired to be decreased (in the case where the potential is desired to be V_{L}), the low-level potential V_{L} is supplied from the terminal LO1 of the circuit LGC to the first terminal of the transistor MNH3 to bring the transistor MNH3 into an off state and then the high-level potential V_{H} is supplied to the wiring RS1 to bring the transistor MNH4 into an on state. Here, when the potential supplied by the wiring VSE23 is the low-level potential V_{L}, the charge in the first terminal of the capacitor CCL (the charge in the gate of the transistor MNH1) flows to the wiring VSE23, whereby the potential of the first terminal of the capacitor CCL (the potential of the gate of the transistor MNH1) becomes V_{L}.

Similarly, the wiring RS2 functions as a wiring for transmitting a signal for selecting whether the charge accumulated in the first terminal of the capacitor CPW (the gate of the transistor MNC1) is released or not, for example. Specifically, for example, in the case where the charge in the first terminal of the capacitor CPW (or the gate of the transistor MNC1) is not released, the wiring RS2 is supplied with the low-level potential V_{L} as a signal to bring the transistor MNC4 into an off state. For example, in the case where the charge in the first terminal of the capacitor CPW (or the gate of the transistor MNC1) is released, the wiring RS2 is supplied with the high-level potential V_{H} as a signal to bring the transistor MNC4 into an on state.

In the case where the potential of the first terminal of the capacitor CPW (the potential of the gate of the transistor MNC1) is desired to be increased (in the case where the potential is desired to be V_{H}−V_{th_MNC3}), for example, the low-level potential V_{L} is supplied to the wiring RS2 to bring the transistor MNC3 into an off state and then the high-level potential V_{H} is supplied from the terminal LO1 of the circuit LGC to the first terminal of the transistor MNC3. In the case where the potential of the first terminal of the capacitor CPW (the potential of the gate of the transistor MNC1) is desired to be decreased (in the case where the potential is desired to be V_{L}), the low-level potential V_{L} is supplied from the terminal LO1 of the circuit LGC to the first terminal of the transistor MNC3 to bring the transistor MNC3 into an off state and then the high-level potential V_{H} is supplied to the wiring RS2 to bring the transistor MNC4 into an on state. Here, when the potential supplied by the wiring VSE24 is the low-level potential V_{L}, the charge in the first terminal of the capacitor CCL (the charge in the gate of the transistor MNC1) flows to the wiring VSE24, whereby the potential of the first terminal of the capacitor CPW (the potential of the gate of the transistor MNC1) becomes V_{L}.

Note that the transistor MTCK described in Embodiment 1 above can be used as the transistor MNC4, for example. The transistor MTHN described in Embodiment 1 above can be used as the transistor MNH4, for example. Depending on the situation, the transistor MTHN described in Embodiment 1 above may be used as the transistor MNC4, for example, and the transistor MTCK described in Embodiment 1 above may be used as the transistor MNH4, for example.

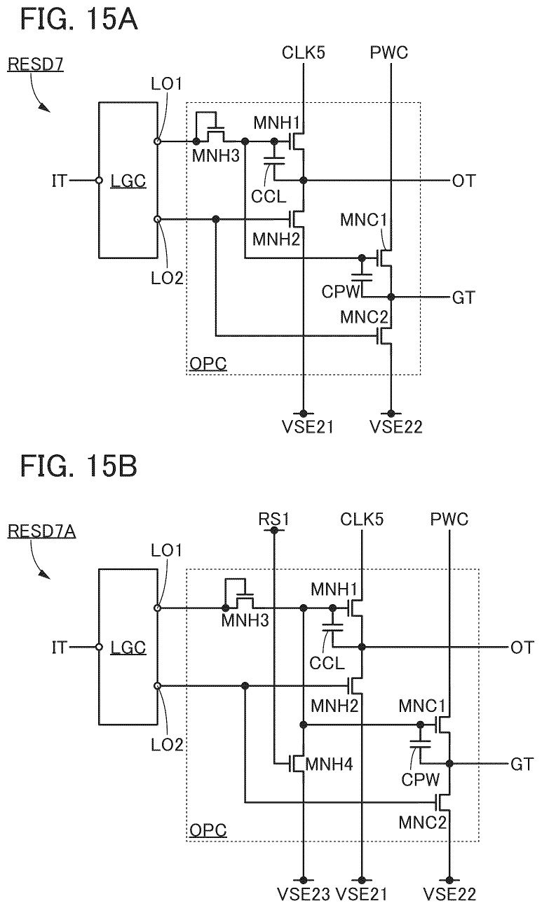

The structure of the memory circuit RESD6 in FIG. 14A may be modified to that of a memory circuit RESD7 illustrated in FIG. 15A. Like the memory circuit RESD4 in FIG. 12B, the memory circuit RESD7 in FIG. 15A has a structure in which the transistor MNH3 and the transistor MNC3 in the circuit OPC of the memory circuit RESD6 in FIG. 14A are combined into the transistor MNH3.

Specifically, the circuit OPC of the memory circuit RESD7 in FIG. 15A has a structure in which the second terminal of the transistor MNH3 is electrically connected to the gate of the transistor MNH1, the first terminal of the capacitor CCL, the gate of the transistor MNC1, and the first terminal of the capacitor CPW.

In the memory circuit RESD7 in FIG. 15A, the transistor MNH3 is diode-connected as in the memory circuit RESD6 in FIG. 14A, and the gate of the transistor MNH1 and the gate of the transistor MNC1 can each be supplied with V_{H}−V_{th_MNH3} as a potential obtained by subtracting the threshold voltage of the transistor MNC1 from a high-level potential output from the terminal LO1 of the circuit LGC. In the memory circuit RESD7 in FIG. 15A, the potential of the gate of the transistor MNC1 can be increased by a bootstrap using the capacitor CPW and the potential of the gate of the transistor MNH1 can be increased by a bootstrap using the capacitor CCL.

In the memory circuit RESD7 in FIG. 15A, in the case where the potential of the first terminal of the capacitor CPW (the potential of the gate of the transistor MNC1) and the potential of the first terminal of the capacitor CCL (the potential of the gate of the transistor MNH1) are desired to be decreased, that is, in the case where the charge accumulated in the first terminal of the capacitor CPW (or the gate of the transistor MNC1) and the first terminal of the capacitor CCL (or the gate of the transistor MNH1) is desired to be released, the circuit OPC in FIG. 15A should be further modified, as in the memory circuit RESD6 in FIG. 14A.

The circuit OPC of a memory circuit RESD7A illustrated in FIG. 15B is a modification example of the circuit OPC of the memory circuit RESD7 in FIG. 15A and is different from the circuit OPC of the memory circuit RESD7 in FIG. 15A in that the charge accumulated in the first terminal of the capacitor CPW (or the gate of the transistor MNC1) and the first terminal of the capacitor CCL (or the gate of the transistor MNH1) can be released. Specifically, the circuit OPC of the memory circuit RESD7A illustrated in FIG. 15B is different from the circuit OPC of the memory circuit RESD7 in FIG. 15A in including the transistor MNH4.

A first terminal of the transistor MNH4 is electrically connected to the gate of the transistor MNC1, the first terminal of the capacitor CPW, the second terminal of the transistor MNH3, the gate of the transistor MNH1, and the first terminal of the capacitor CCL, the second terminal of the transistor MNH4 is electrically connected to the wiring VSE23, and the gate of the transistor MNH4 is electrically connected to the wiring RS1.

For the wiring RS1 and the wiring VSE23, the description of the wiring RS1 and the wiring VSE23 illustrated in FIG. 14B can be referred to.

For the operation example of the memory circuit RESD7A in FIG. 15B, the description of the operation example of the memory circuit RESD6A in FIG. 14B can be referred to.

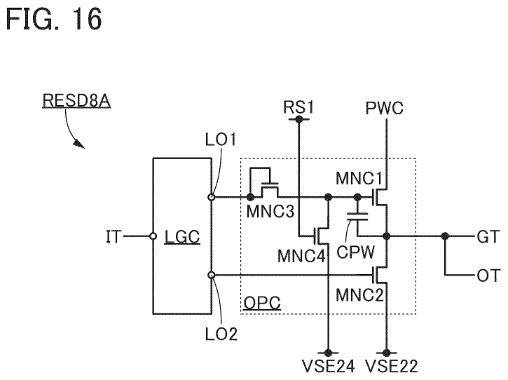

The structure of the memory circuit RESD6 in FIG. 14A may be modified to that of a memory circuit RESD8A illustrated in FIG. 16. The memory circuit RESD8A illustrated in FIG. 16 has a structure in which the terminal OT and the terminal GT of the memory circuit RESD6A in FIG. 14B are combined.

Specifically, in the memory circuit RESD8A in FIG. 16, the transistor MNH1 to the transistor MNH4 and the capacitor CCL are not provided, and the terminal OT is electrically connected to the terminal GT, the second terminal of the transistor MNC1, the second terminal of the capacitor CPW, and the first terminal of the transistor MNC2, unlike in the memory circuit RESD6A in FIG. 14B.

In the memory circuit RESD8A in FIG. 16, the potential of the gate of the transistor MNC1 can be increased by a bootstrap using the capacitor CPW, as in the memory circuit RESD5 in FIG. 13. In the memory circuit RESD8A in FIG. 16, a signal whose high potential side is V_{EXH} higher than a high-level potential V_{H} and whose low potential side is V_{L} can be output from the terminal OT, as in the memory circuit RESD5 in FIG. 13.

### <<Structure Example 10 of Memory Circuit RES>>

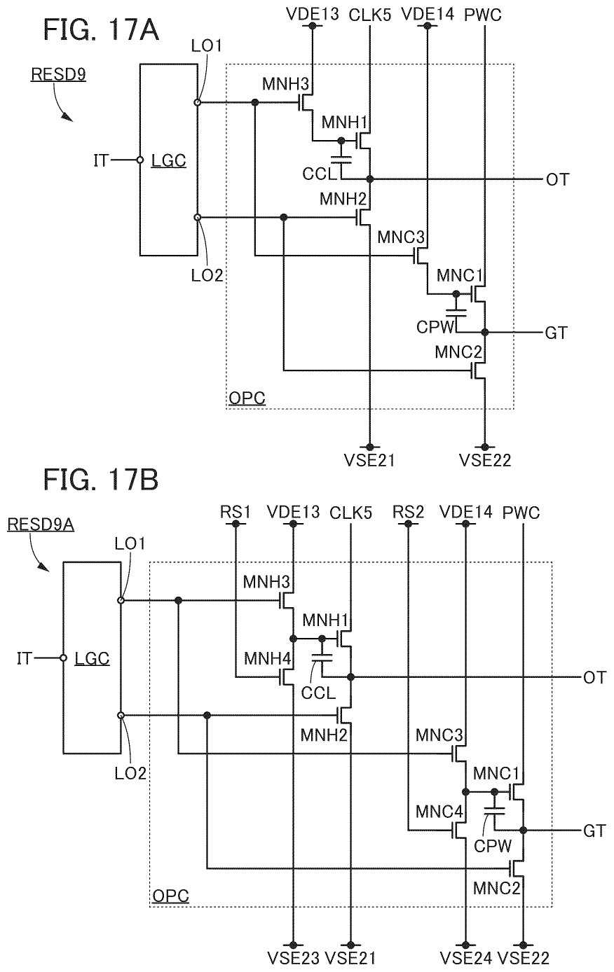

A memory circuit RESD9 illustrated in FIG. 17A is a modification example of the memory circuit RESD3 in FIG. 12A and is different from the memory circuit RESD3 in that the gate of the transistor MNC3 is electrically connected not to the wiring VDE12 but to the terminal LO1 of the circuit LGC, the first terminal of the transistor MNC3 is electrically connected to a wiring VDE14, the gate of the transistor MNH3 is electrically connected not to the wiring VDE11 but to the terminal LO1 of the circuit LGC, and the first terminal of the transistor MNH3 is electrically connected to a wiring VDE13.

The wiring VDE13 and the wiring VDE14 each function as a wiring for supplying a fixed potential, for example. The fixed potential can be a high-level potential, for example. Note that the wiring VDE13 and the wiring VDE14 may be supplied with fixed potentials equal to each other or may be supplied with fixed potentials different from each other. Note that in the case where the wiring VDE13 and the wiring VDE14 are supplied with fixed potentials equal to each other, the wiring VDE13 and the wiring VDE14 may be the same wiring. Here, the wiring VDE13 and the wiring VDE14 are each a wiring for supplying V_{H} as a high-level potential.

An operation example of the memory circuit RESD9 in FIG. 17A is described. A high-level potential V_{H} is assumed to be input to each of the gate of the transistor MNH3 and the gate of the transistor MNC3 from the terminal LO1 of the circuit LGC, for example. The potential of the first terminal of the capacitor CCL (the potential of the gate of the transistor MNH1) and the potential of the first terminal of the capacitor CPW (the potential of the gate of the transistor MNC1) are each a low-level potential V_{L}.

Since the gate-source voltage (at this timing, the gate-second terminal voltage) of the transistor MNH3 is V_{H}−V_{L}, the transistor MNH3 is in an on state. Consequently, a current flows from the wiring VDE13 to the first terminal of the capacitor CCL (or the gate of the transistor MNH1) through the transistor MNH3 and charge is accumulated in the first terminal of the capacitor CCL, so that the potential of the first terminal of the capacitor CCL (the potential of the gate of the transistor MNH1) increases until the transistor MNH3 is brought into an off state. Specifically, the transistor MNH3 is brought into an off state when the gate-source voltage of the transistor MNH3 decreases to V_{th_MNH3}; thus, at this time, the potential of a first terminal of a capacitor CCL1 (the potential of the second terminal of the transistor MNH3) is V_{H}−V_{th_MNH3}.

Similarly, since the gate-source voltage (at this timing, the gate-second terminal voltage) of the transistor MNC3 is V_{H}−V_{L}, the transistor MNC3 is in an on state. Consequently, a current flows from the wiring VDE14 to the first terminal of the capacitor CPW (or the gate of the transistor MNC1) through the transistor MNC3 and charge is accumulated in the first terminal of the capacitor CPW, so that the potential of the first terminal of the capacitor CPW (the potential of the gate of the transistor MNC1) increases until the transistor MNC3 is brought into an off state. Specifically, the transistor MNC3 is brought into an off state when the gate-source voltage of the transistor MNC3 decreases to V_{th_MNC3}; thus, at this time, the potential of a first terminal of a capacitor CPW1 (the potential of the second terminal of the transistor MNC3) is V_{H}−V_{th_MNC3}.

When the potential of the second terminal of the transistor MNH3 reaches V_{H}−V_{th_MNH3}, the transistor MNH3 is brought into an off state; thus, an electrical connection point of the second terminal of the transistor MNH3, the gate of the transistor MNH1, and the first terminal of the capacitor CCL is brought into a floating state. After that, a low-level potential V_{L} is supplied from the terminal LO1 of the circuit LGC to the gate of the transistor MNH3. Then, V_{H} is supplied from the terminal CLK5 to the first terminal of the transistor MNH1, whereby the potential V_{H}−V_{th_MNH3} of the gate of the transistor MNH1 can be further increased by a bootstrap using the capacitor CCL. Note that even when the potential of the gate of the transistor MNH1 (the potential of the second terminal of the transistor MNH3) is increased, the transistor MNH3 is not brought into an on state.

Similarly, when the potential of the second terminal of the transistor MNC3 reaches V_{H}−V_{th_MNC3}, the transistor MNC3 is brought into an off state; thus, an electrical connection point of the second terminal of the transistor MNC3, the gate of the transistor MNC1, and the first terminal of the capacitor CPW is brought into a floating state. After that, the low-level potential V_{L} is supplied from the terminal LO1 of the circuit LGC to the gate of the transistor MNC3. Then, V_{EXH} is supplied from the terminal PWC to the first terminal of the transistor MNC1, whereby the potential V_{H}−V_{th_MNC3} of the gate of the transistor MNC1 can be further increased by a bootstrap using the capacitor CPW. Note that even when the potential of the gate of the transistor MNC1 (the potential of the second terminal of the transistor MNC3) is increased, the transistor MNC3 is not brought into an on state.

When the potential V_{H}−V_{th_MNH3} of the first terminal of the capacitor CCL (the gate of the transistor MNH1) is desired to be decreased, that is, when the charge accumulated in the first terminal of the capacitor CCL (or the gate of the transistor MNH1) is desired to be released, the circuit OPC of the memory circuit RESD9 in FIG. 17A should be further modified. Similarly, when the potential V_{H}−V_{th_MNH3} of the first terminal of the capacitor CPW (the potential of the gate of the transistor MNC1) is desired to be decreased, that is, when the charge accumulated in the first terminal of the capacitor CPW (or the gate of the transistor MNC1) is desired to be released, the circuit OPC of the memory circuit RESD9 in FIG. 17A should be further modified.

The circuit OPC of a memory circuit RESD9A illustrated in FIG. 17B is a modification example of the circuit OPC of the memory circuit RESD9 in FIG. 17A and is different from the circuit OPC of the memory circuit RESD9 in FIG. 17A in that the charge accumulated in the first terminal of the capacitor CPW (or the gate of the transistor MNC1) can be released and the charge accumulated in the first terminal of the capacitor CCL (or the gate of the transistor MNH1) can be released. Specifically, the circuit OPC of the memory circuit RESD9A illustrated in FIG. 17B is different from the circuit OPC of the memory circuit RESD9 in FIG. 17A in including the transistor MNC4 and the transistor MNH4.

The first terminal of the transistor MNC4 is electrically connected to the second terminal of the transistor MNC3, the gate of the transistor MNC1, and the first terminal of the capacitor CPW, the second terminal of the transistor MNC4 is electrically connected to the wiring VSE23, and the gate of the transistor MNC4 is electrically connected to the wiring RS1. The first terminal of the transistor MNC4 is electrically connected to the second terminal of the transistor MNH3, the gate of the transistor MNH1, and the first terminal of the capacitor CCL, the second terminal of the transistor MNH4 is electrically connected to the wiring VSE24, and the gate of the transistor MNH4 is electrically connected to the wiring RS2.

For the wiring VSE23 and the wiring VSE24, the description of the wiring VSE23 and the wiring VSE24 of the memory circuit RESD6A in FIG. 14B can be referred to. Similarly, for the wiring RS1 and the wiring RS2, the description of the wiring RS1 and the wiring RS2 of the memory circuit RESD6A in FIG. 14B can be referred to. For the transistor MNH4 and the transistor MNC4, the description of the transistor MNH4 and the transistor MNC4 in the memory circuit RESD6A in FIG. 14B can be referred to.

In the case where the potential of the first terminal of the capacitor CCL (the potential of the gate of the transistor MNH1) is desired to be decreased (in the case where the potential is desired to be V_{L}), for example, the low-level potential V_{L} is supplied from the terminal LO1 of the circuit LGC to the first terminal of the transistor MNH3 to bring the transistor MNH3 into an off state and then the high-level potential V_{H} is supplied to the wiring RS1 to bring the transistor MNH4 into an on state. Here, when the potential supplied by the wiring VSE23 is the low-level potential V_{L}, the charge in the first terminal of the capacitor CCL (the charge in the gate of the transistor MNH1) flows to the wiring VSE23, whereby the potential of the first terminal of the capacitor CCL (the potential of the gate of the transistor MNH1) becomes V_{L}.

In the case where the potential of the first terminal of the capacitor CPW (the potential of the gate of the transistor MNC1) is desired to be decreased (in the case where the potential is desired to be V_{L}), for example, the low-level potential V_{L} is supplied from the terminal LO1 of the circuit LGC to the first terminal of the transistor MNC3 to bring the transistor MNC3 into an off state and then the high-level potential V_{H} is supplied to the wiring RS2 to bring the transistor MNC4 into an on state. Here, when the potential supplied by the wiring VSE24 is the low-level potential V_{L}, the charge in the first terminal of the capacitor CCL (the charge in the gate of the transistor MNC1) flows to the wiring VSE24, whereby the potential of the first terminal of the capacitor CPW (the potential of the gate of the transistor MNC1) becomes V_{L}.

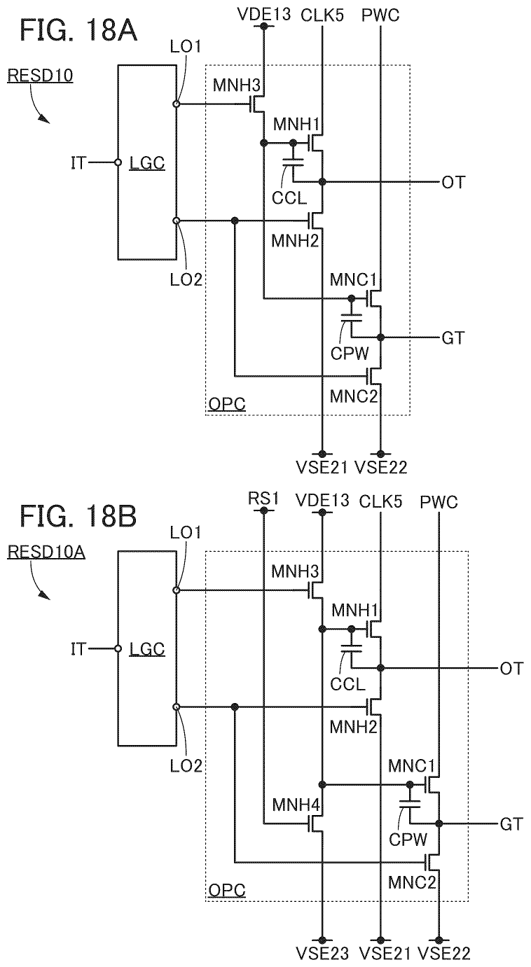

The structure of the memory circuit RESD9 in FIG. 16 may be modified to that of a memory circuit RESD10 illustrated in FIG. 18A. Like the memory circuit RESD4 in FIG. 12B and the memory circuit RESD7 in FIG. 15A, the memory circuit RESD10 illustrated in FIG. 18A has a structure in which the transistor MNH3 and the transistor MNC3 in the circuit OPC of the memory circuit RESD9 in FIG. 14A are combined into the transistor MNH3.

Specifically, the circuit OPC of the memory circuit RESD10 in FIG. 18A has a structure in which the second terminal of the transistor MNH3 is electrically connected to the gate of the transistor MNH1, the first terminal of the capacitor CCL, the gate of the transistor MNC1, and the first terminal of the capacitor CPW.

In the memory circuit RESD10 in FIG. 18A, the terminal LO1 of the circuit LGC is electrically connected to the gate of the transistor MNH3 as in the memory circuit RESD9 in FIG. 17A, and V_{H}−V_{th_MNH3} can be supplied from the wiring VDE13 to each of the gate of the transistor MNH1 and the gate of the transistor MNC1 as a potential obtained by subtracting the threshold voltage of the transistor MNH3. In the memory circuit RESD10 in FIG. 18A, the potential of the gate of the transistor MNC1 can be increased by a bootstrap using the capacitor CPW and the potential of the gate of the transistor MNH1 can be increased by a bootstrap using the capacitor CCL.

In the memory circuit RESD10 in FIG. 18A, in the case where the potential of the first terminal of the capacitor CPW (the potential of the gate of the transistor MNC1) and the potential of the first terminal of the capacitor CCL (the potential of the gate of the transistor MNH1) are desired to be decreased, that is, in the case where the charge accumulated in the first terminal of the capacitor CPW (or the gate of the transistor MNC1) and the first terminal of the capacitor CCL (or the gate of the transistor MNH1) is desired to be released, the circuit OPC in FIG. 18A should be further modified, as in the memory circuit RESD9 in FIG. 17A.

The circuit OPC of a memory circuit RESD10A illustrated in FIG. 18B is a modification example of the circuit OPC of the memory circuit RESD10 in FIG. 18A and is different from the circuit OPC of the memory circuit RESD10 in FIG. 18A in that the charge accumulated in the first terminal of the capacitor CPW (or the gate of the transistor MNC1) and the first terminal of the capacitor CCL (or the gate of the transistor MNH1) can be released. Specifically, the circuit OPC of the memory circuit RESD10A illustrated in FIG. 18B is different from the circuit OPC of the memory circuit RESD10 in FIG. 18A in including the transistor MNH4.

The first terminal of the transistor MNH4 is electrically connected to the gate of the transistor MNC1, the first terminal of the capacitor CPW, the second terminal of the transistor MNH3, the gate of the transistor MNH1, and the first terminal of the capacitor CCL, the second terminal of the transistor MNH4 is electrically connected to the wiring VSE23, and the gate of the transistor MNH4 is electrically connected to the wiring RS1.

For the wiring RS1 and the wiring VSE23, the description of the wiring RS1 and the wiring VSE23 illustrated in FIG. 17B can be referred to.

For the operation example of the memory circuit RESD10A in FIG. 18B, the description of the operation example of the memory circuit RESD9A in FIG. 17B can be referred to.

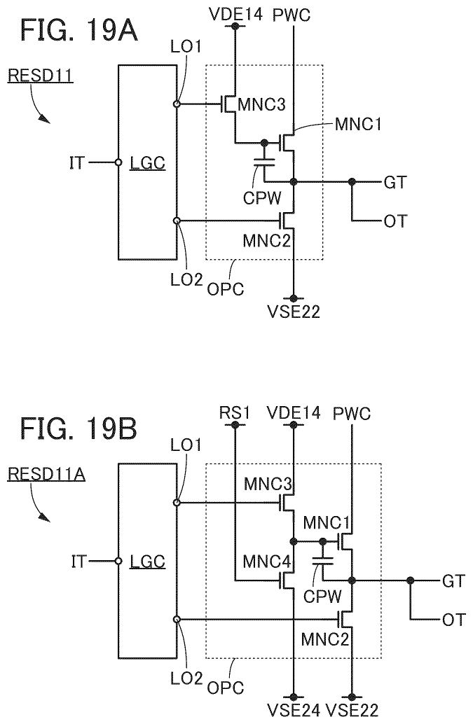

The structure of the memory circuit RESD9 in FIG. 17A may be modified to that of a memory circuit RESD11 illustrated in FIG. 19A. The memory circuit RESD11 illustrated in FIG. 19 has a structure in which the terminal OT and the terminal GT of the memory circuit RESD9 in FIG. 17A are combined.

Specifically, in the memory circuit RESD11 in FIG. 19A, the transistor MNH1 to the transistor MNH4 and the capacitor CCL are not provided, and the terminal OT is electrically connected to the terminal GT, the second terminal of the transistor MNC1, the second terminal of the capacitor CPW, and the first terminal of the transistor MNC2, unlike in the memory circuit RESD9 in FIG. 17A.

In the memory circuit RESD11 in FIG. 19A, the potential of the gate of the transistor MNC1 can be increased by a bootstrap using the capacitor CPW, as in the memory circuit RESD5 in FIG. 13 and the memory circuit RESD8A in FIG. 16. In the memory circuit RESD11 in FIG. 19A, a signal whose high potential side is V_{EXH} higher than a high-level potential V_{H} and whose low potential side is V_{L} can be output from the terminal OT, as in the memory circuit RESD5 in FIG. 13 and the memory circuit RESD8A in FIG. 16.

Furthermore, the structure of the memory circuit RESD11 in FIG. 19A may be modified so that the charge accumulated in the first terminal of the capacitor CPW (or the gate of the transistor MNC1) can be released. Specifically, as illustrated in a memory circuit RESD11A in FIG. 19B, the transistor MNC4 may be provided in the circuit OPC as in the memory circuit RESD9A in FIG. 17B. For the operation example of the memory circuit RESD11A in FIG. 19B, the description of the operation example of the memory circuit RESD9A in FIG. 17B can be referred to.

### <<Structure Example 11 of Memory Circuit RES>>

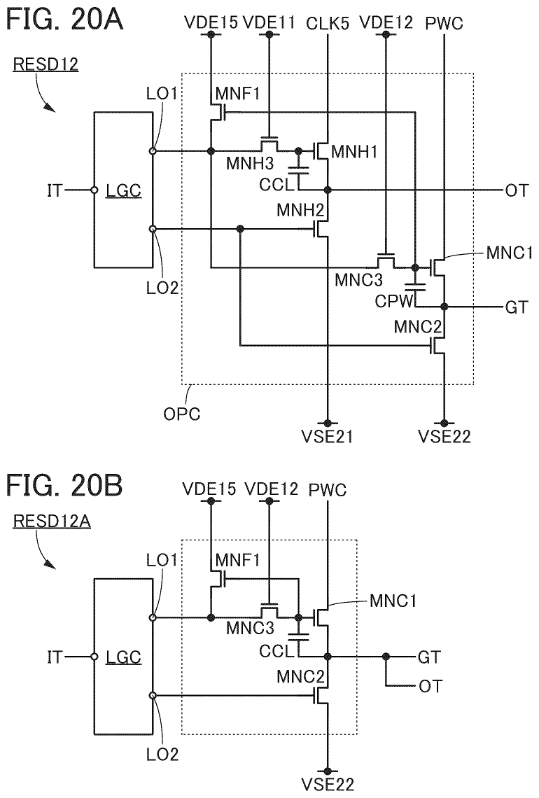

A memory circuit RESD12 illustrated in FIG. 20A is a modification example of the memory circuit RESD3 in FIG. 12A and is different from the memory circuit RESD3 in that a transistor MNF1 is provided. That is, in the memory circuit RESD12 in FIG. 20A, the circuit OPC includes the transistor MNF1 in addition to the transistor MNH1 to the transistor MNH3, the transistor MNC1 to the transistor MNC3, the capacitor CCL, and the capacitor CPW.

The connection structure of the circuit OPC of the memory circuit RESD12 in FIG. 20A includes, in addition to the connection structure of the memory circuit RESD3 in FIG. 12A, a structure in which a first terminal of the transistor MNF1 is electrically connected to the terminal LO1 of the circuit LGC, the first terminal of the transistor MNH3, and the first terminal of the transistor MNC3, a second terminal of the transistor MNF1 is electrically connected to a wiring VDE15, and a gate of the transistor MNF1 is electrically connected to the second terminal of the transistor MNC3, the gate of the transistor MNC1, and the first terminal of the capacitor CPW.

The wiring VDE15 functions as a wiring for supplying a fixed potential, for example. The fixed potential can be a high-level potential, for example. Note that the fixed potential supplied by the wiring VDE15 may be equal to or different from those supplied by the wiring VDE11 and the wiring VDE12. The fixed potential supplied by the wiring VDE15 may be equal to two of those supplied by the wiring VDE11 and the wiring VDE12. In particular, in the case where the wiring VDE11, the wiring VDE12, and the wiring VDE15 supply fixed potentials equal to each other, the wiring VDE11, the wiring VDE12, and the wiring VDE15 may be the same wiring. Here, the wiring VDE11, the wiring VDE12, and the wiring VDE15 are each a wiring for supplying V_{H} as a high-level potential.

For the circuit LGC, the description of the circuit LGC in the memory circuit RESD3 in FIG. 12A can be referred to.

For the terminal PWC, the wiring VSE21, and the wiring VSE22, the description of the terminal PWC, the wiring VSE21, and the wiring VSE22 in the memory circuit RESD3 in FIG. 12A can be referred to.

Next, an operation example of the circuit OPC of the memory circuit RESD12 in FIG. 20A is described.

First, the case is considered where a low-level potential V_{L} is input from the terminal LO1 to each of the first terminal of the transistor MNH3 and the first terminal of the transistor MNC3, and a high-level potential V_{H} is input from the terminal LO2 to each of the gate of the transistor MNH2 and the gate of the transistor MNC2.

At this time, since the high-level potential V_{H} is input to the gate of the transistor MNH3, the transistor MNH3 is in an on state, and the potentials of the second terminal of the transistor MNH3, the gate of the transistor MNH1, and the first terminal of the capacitor CCL are V_{L}. In addition, since the high-level potential V_{H} is input to the gate of the transistor MNC3, the transistor MNC3 is in an on state, and the potentials of the second terminal of the transistor MNC3, the gate of the transistor MNC1, the gate of the transistor MNF1, and the first terminal of the capacitor CPW are also V_{L}. Thus, the transistor MNH1, the transistor MNC1, and the transistor MNF1 are in an off state.

Meanwhile, since the high-level potential V_{H} is input to the second terminal of the transistor MNH2, the transistor MNH2 is in an on state, and V_{L} is output from the terminal OT. Since the high-level potential V_{H} is input to the second terminal of the transistor MNC2, the transistor MNC2 is in an on state, and V_{L} is output from the terminal GT.

Next, when the potential input from the terminal LO1 to each of the first terminal of the transistor MNH3 and the first terminal of the transistor MNC3 changes from V_{L} to V_{H}, the potentials of the second terminal of the transistor MNH3, the gate of the transistor MNH1, and the first terminal of the capacitor CCL increase from V_{L} to V_{H}−V_{th_MNH3} to bring the transistor MNH3 into an off state, and the potentials of the second terminal of the transistor MNC3, the gate of the transistor MNC1, and the first terminal of the capacitor CPW increase from V_{L} to V_{H}−V_{th_MNC3} to bring the transistor MNC3 into an off state. Note that V_{th_MNH3} is the threshold voltage of the transistor MNH3, and V_{th_MNC3} is the threshold voltage of the transistor MNC3.

When the potential input from the terminal LO2 to each of the gate of the transistor MNH2 and the gate of the transistor MNC2 changes from V_{H} to V_{L}, the transistor MNH2 and the transistor MNC2 are brought into an off state, and the potential of the terminal OT and the potential of the terminal GT each remain V_{L}.

At this time, the potential of the gate of the transistor MNF1 is V_{H}−V_{th_MNC3}. The potential of the first terminal of the transistor MNF1 is V_{H} supplied from the terminal LO1, and the potential of the second terminal of the transistor MNF1 is V_{H} supplied from the wiring VDE15; thus, the transistor MNF1 is in an off state as long as the threshold voltage of the transistor MNF1 is an appropriate value.

For example, in the case where input of the high-level potential V_{H} from the terminal LO1 of the circuit LGC to each of the first terminal of the transistor MNH3 and the first terminal of the transistor MNC3 is stopped and the potential of the first terminal of the transistor MNF1 decreases due to a leakage current (e.g., a leakage current to the terminal LO1 of the circuit LGC) or the like, the transistor MNF1 is brought into an on state, charge is supplied from the wiring VDE15 to each of the first terminal of the transistor MNH3 and the first terminal of the transistor MNC3, and the potential of the first terminal of the transistor MNF1 increases to a potential (here, V_{MNF1}) corresponding to the potential V_{H}−V_{th_MNC3} of the gate of the transistor MNF1 and the threshold voltage of the transistor MNF1. Note that V_{MNF1} is preferably a potential lower than V_{H} and as close to V_{H} as possible.

That is, even when the circuit LGC is stopped, the potentials of the first terminal of the transistor MNH3 and the first terminal of the transistor MNC3 do not decrease to V_{L} and can be V_{MNF1}, for example, in the circuit OPC of the memory circuit RESD12 in FIG. 20A. Thus, in some cases, the circuit LGC can be a circuit capable of a temporary stop.

The case is considered where a low-level potential V_{L} is input from the terminal CLK5 to the first terminal of the transistor MNH1 when the potentials of the gate of the transistor MNH1 and the first terminal of the capacitor CCL are each V_{H}−V_{th_MNH3}. At this time, the potential of the gate of the transistor MNH1 is V_{H}−V_{th_MNH3} and the potential of the second terminal of the transistor MNH1 is V_{L}; thus, the potential of the terminal OT remains V_{L}.

Then, when the potential input from the terminal CLK5 to the first terminal of the transistor MNH1 changes from V_{L} to V_{H}, the potential of the second terminal of the transistor MNH1 (the potential of the terminal OT) increases from V_{L}. At this time, the second terminal of the transistor MNH3, the gate of the transistor MNH1, and the first terminal of the capacitor CCL are in a floating state; thus, the potentials of the second terminal of the transistor MNH3, the gate of the transistor MNH1, and the first terminal of the capacitor CCL are increased by a bootstrap using the capacitor CCL. Accordingly, the gate-source voltage of the transistor MNH1 does not change even when the potential of the terminal OT increases, so that a current keeps flowing between the first terminal and the second terminal of the transistor MNH1 until the potential of the terminal OT reaches V_{H}.

In the above-described manner, the circuit OPC of the memory circuit RESD12 in FIG. 20A can output a signal whose high potential side and low potential side are V_{H} and V_{L}, respectively, to the terminal OT.

Similarly, the case is considered where a low-level potential V_{L} is input from the terminal PWC to the first terminal of the transistor MNC1 when the potentials of the gate of the transistor MNC1 and the first terminal of the capacitor CPW are each V_{H}−V_{th_MNC3}. At this time, the potential of the gate of the transistor MNC1 is V_{H}−V_{th_MNC3} and the potential of the second terminal of the transistor MNC1 is V_{L}; thus, the potential of the terminal GT remains V_{L}.

Then, when the potential input from the terminal PWC to the first terminal of the transistor MNC1 changes from V_{L} to V_{EXH}, the potential of the second terminal of the transistor MNC1 (the potential of the terminal GT) increases from V_{L}. At this time, the second terminal of the transistor MNC3, the gate of the transistor MNC1, and the first terminal of the capacitor CPW are in a floating state; thus, the potentials of the second terminal of the transistor MNC3, the gate of the transistor MNC1, and the first terminal of the capacitor CPW are increased by a bootstrap using the capacitor CPW. Accordingly, the gate-source voltage of the transistor MNC1 does not change even when the potential of the terminal GT increases, so that a current keeps flowing between the first terminal and the second terminal of the transistor MNC1 until the potential of the terminal GT reaches V_{EXH}.

When the potential of the terminal GT reaches V_{EXH}, the potentials of the second terminal of the transistor MNC3, the gate of the transistor MNC1, and the first terminal of the capacitor CPW each become V_{H}−V_{th_MNC3}+(V_{EXH}−V_{L}). The potential of the first terminal of the transistor MNF1 is V_{H} (or V_{MNF1}), and the potential of the second terminal of the transistor MNF1 is V_{H}; thus, the transistor MNF1 can be in an on state as long as the threshold voltage of the transistor MNF1 is an appropriate value.

Accordingly, electrical continuity is established between the wiring VDE15 and the first terminals of the transistor MNH3 and the transistor MNC3, so that V_{H} is supplied from the wiring VDE15 to each of the first terminal of the transistor MNH3 and the first terminal of the transistor MNC3.

Here, electrical continuity is established between the wiring VDE15 and the first terminals of the transistor MNH3 and the transistor MNC3 even when the circuit LGC is stopped, for example; thus, the first terminal of the transistor MNH3 and the first terminal of the transistor MNC3 are not brought into a floating state. Therefore, even when noise is input to each of the first terminal of the transistor MNH3 and the transistor MNC3, the potentials of the first terminal of the transistor MNH3 and the first terminal of the transistor MNC3 are less likely to change. Accordingly, potentials output from the terminal OT and the terminal GT are also less likely to change, so that signals output from the terminal OT and the terminal GT of the memory circuit RESD12 can be stabilized.

In the above-described manner, the circuit OPC of the memory circuit RESD12 in FIG. 20A can output a signal whose high potential side and low potential side are V_{EXH} and V_{L}, respectively, to the terminal GT. Furthermore, even when noise is input to the circuit OPC of the memory circuit RESD12 in FIG. 20A, signals output from the terminal OT and the terminal GT can be stabilized.

Note that a potential higher than V_{H}−V_{th_MNC3} is input to the gate of the transistor MNF1 by a bootstrap using the capacitor CPW; thus, a transistor having high resistance to voltage is preferably used as the transistor MNF1. That is, the transistor MTCK including the thick gate insulating film described in Embodiment 1 is preferably used as the transistor MNF1.

In addition, since the shift register SR including the memory circuit RESD12 in FIG. 20A is preferably driven at high speed, a transistor having a high driving frequency may be used as the transistor MNF1. That is, the transistor MTHN including the thin gate insulating film described in Embodiment 1 may be used as the transistor MNF1.

For the transistor MNH1 to the transistor MNH3 and the transistor MNC1 to the transistor MNC3, the description of the transistor MNH1 to the transistor MNH3 and the transistor MNC1 to the transistor MNC3 provided in the memory circuit RESD3 in FIG. 12 can be referred to.

The structure of the memory circuit RESD12 in FIG. 20A may be modified to that of a memory circuit RESD12A illustrated in FIG. 20B. The memory circuit RESD12A illustrated in FIG. 20B has a structure in which the terminal OT and the terminal GT of the memory circuit RESD12 in FIG. 20A are combined.

Specifically, in the memory circuit RESD12A in FIG. 20B, the transistor MNH1 to the transistor MNH3 and the capacitor CCL are not provided, and the terminal OT is electrically connected to the terminal GT, the second terminal of the transistor MNC1, the second terminal of the capacitor CPW, and the first terminal of the transistor MNC2, unlike in the memory circuit RESD12A in FIG. 20A.

In the memory circuit RESD12A in FIG. 20B, the potential of the gate of the transistor MNC1 can be increased by a bootstrap using the capacitor CPW, as in the memory circuit RESD5 in FIG. 13, the memory circuit RESD8A in FIG. 16, the memory circuit RESD11 in FIG. 19A, and the memory circuit RESD11A in FIG. 19B. In the memory circuit RESD12A illustrated in FIG. 20B, a signal whose high potential side is V_{EXH} higher than a high-level potential V_{H} and whose low potential side is V_{L} can be output from the terminal OT, as in the memory circuit RESD5 in FIG. 13, the memory circuit RESD8A in FIG. 16, the memory circuit RESD11 in FIG. 19A, and the memory circuit RESD11A in FIG. 19B.

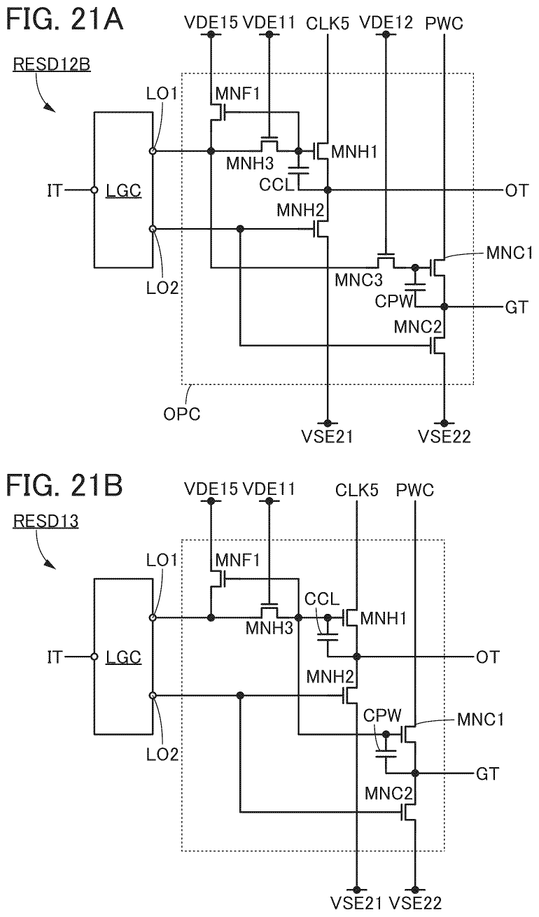

The structure of the memory circuit RESD12 in FIG. 20A may be modified to that of a memory circuit RESD12B illustrated in FIG. 21A. The memory circuit RESD12B illustrated in FIG. 21A is different from the memory circuit RESD12 in FIG. 20A in that the gate of the transistor MNF1 is electrically connected not to the second terminal of the transistor MNC3, the gate of the transistor MNC1, and the first terminal of the capacitor CPW but to the second terminal of the transistor MNH3, the gate of the transistor MNH1, and the first terminal of the capacitor CCL.

The memory circuit RESD12B illustrated in FIG. 21A has a structure in which the potential of the gate of the transistor MNF1 is increased by a bootstrap using the capacitor CCL to bring the transistor MNF1 into an on state. The potential of the gate of the transistor MNF1 increased by the bootstrap using the capacitor CCL is lower than the potential of the gate of the transistor MNF1 increased by the bootstrap using the capacitor CPW in the memory circuit RESD12 in FIG. 21A; however, by increasing the potential of the gate of the transistor MNF1 by the bootstrap using the capacitor CCL, the transistor MNF1 can sometimes be brought into an on state adequately also in the structure of the memory circuit RESD12B in FIG. 21A. That is, as in the memory circuit RESD12 in FIG. 20A, signals output from the terminal OT and the terminal GT can be stabilized.

The structure of the memory circuit RESD12 in FIG. 20A may be modified to that of a memory circuit RESD13 illustrated in FIG. 21B. The memory circuit RESD13 in FIG. 21B has a structure in which the transistor MNH3 and the transistor MNC3 in the circuit OPC of the memory circuit RESD12 in FIG. 20A are combined into the transistor MNH3.

Specifically, the circuit OPC of the memory circuit RESD13 in FIG. 21B has a structure in which the second terminal of the transistor MNH3 is electrically connected to the gate of the transistor MNH1, the first terminal of the capacitor CCL, the gate of the transistor MNC1, the first terminal of the capacitor CPW, and the gate of the transistor MNF1.

In the memory circuit RESD13 in FIG. 21B, the potential of the gate of the transistor MNC1 can be increased by a bootstrap using the capacitor CPW and the potential of the gate of the transistor MNH1 can be increased by a bootstrap using the capacitor CCL, as in the memory circuit RESD12 in FIG. 20A.

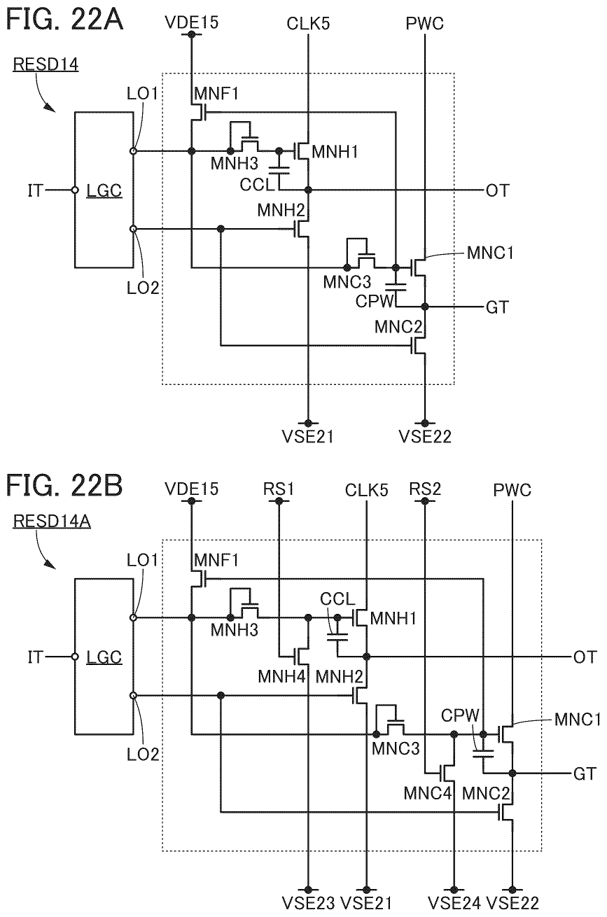

The structure of the memory circuit RESD12 in FIG. 20A may be modified to that of a memory circuit RESD14 illustrated in FIG. 22A. The memory circuit RESD14 in FIG. 22A is different from the memory circuit RESD12 in that the gate of the transistor MNH3 is electrically connected not to the wiring VDE11 but to the first terminal of the transistor MNH3 and the gate of the transistor MNC3 is electrically connected not to the wiring VDE12 but to the first terminal of the transistor MNC3, as in the memory circuit RESD6 in FIG. 14A.

That is, in the memory circuit RESD14 illustrated in FIG. 22A, the transistor MNH3 and the transistor MNC3 are each diode-connected; thus, as in the memory circuit RESD6 in FIG. 14A, a high-level potential V_{H} is supplied from the terminal LO1 of a circuit LGC1 to each of the first terminal of the transistor MNH3 and the first terminal of the transistor MNC3, whereby the potentials of the second terminal of the transistor MNH3, the gate of the transistor MNH1, and the first terminal of the capacitor CCL each become V_{H}−V_{th_MNH3}, and the potentials of the second terminal of the transistor MNC3, the gate of the transistor MNC1, and the first terminal of the capacitor CPW each become V_{H}−V_{th_MNH3}. After that, when the high-level potential V_{H} is input from the terminal CLK5, a bootstrap using the capacitor CCL is caused; thus, the potential of the terminal OT increases to V_{H}. Similarly, when a high-level potential V_{EXH} is input from the terminal PWC, a bootstrap using the capacitor CPW is caused; thus, the potential of the terminal GT increases to V_{EXH}. This increases also the potential of the gate of the transistor MNF1, so that the transistor MNF1 can be brought into an on state, and electrical continuity can be established between the wiring VDE15 and the first terminals of the transistor MNH3 and the transistor MNC3. Therefore, as in the memory circuit RESD12 in FIG. 20A, signals output from the terminal OT and the terminal GT can be stabilized.

When the potential V_{High}−V_{th_MNH3} of the first terminal of the capacitor CCL (the potential of the gate of the transistor MNH1) is desired to be decreased, that is, when the charge accumulated in the first terminal of the capacitor CCL (or the gate of the transistor MNH1) is desired to be released, the circuit OPC in FIG. 22A should be further modified. Similarly, when the potential V_{High}−V_{th_MNC3} of the first terminal of the capacitor CPW (the potential of the gate of the transistor MNC1) is desired to be decreased, that is, when the charge accumulated in the first terminal of the capacitor CPW (or the gate of the transistor MNC1) is desired to be released, the circuit OPC in FIG. 22A should be further modified, as in the memory circuit RESD6 in FIG. 14A and the memory circuit RESD7 in FIG. 15A.

The circuit OPC of a memory circuit RESD14A illustrated in FIG. 22B is a modification example of the circuit OPC of the memory circuit RESD14 in FIG. 22A and is different from the circuit OPC of the memory circuit RESD14 in FIG. 22A in that the charge accumulated in the first terminal of the capacitor CCL (or the gate of the transistor MNH1) and the first terminal of the capacitor CPW (or the gate of the transistor MNC1) can be released. Specifically, the circuit OPC of the memory circuit RESD14A illustrated in FIG. 22B is different from the circuit OPC of the memory circuit RESD14 in FIG. 22A in including the transistor MNC4 and the transistor MNH4.

The first terminal of the transistor MNH4 is electrically connected to the gate of the transistor MNH1, the first terminal of the capacitor CCL, and the second terminal of the transistor MNH3, the second terminal of the transistor MNH4 is electrically connected to the wiring VSE23, and the gate of the transistor MNH4 is electrically connected to the wiring RS1. The first terminal of the transistor MNC4 is electrically connected to the second terminal of the transistor MNC3, the gate of the transistor MNC1, the first terminal of the capacitor CPW, and the gate of the transistor MNF1, the second terminal of the transistor MNC4 is electrically connected to the wiring VSE24, and the gate of the transistor MNC4 is electrically connected to the wiring RS2.

For the wiring RS1, the wiring RS2, the wiring VSE23, and the wiring VSE24, the description of the wiring RS1, the wiring RS2, the wiring VSE23, and the wiring VSE24 of the memory circuit RESD6A illustrated in FIG. 14B can be referred to. For the transistor MNH4 and the transistor MNC4, the description of the transistor MNH4 and the transistor MNC4 in the memory circuit RESD6A in FIG. 14B can be referred to.

In the case where the potential of the first terminal of the capacitor CCL (the potential of the gate of the transistor MNH1) is desired to be increased (in the case where the potential is desired to be V_{H}−V_{th_MNH3}), for example, the low-level potential V_{L} is supplied to the wiring RS1 to bring the transistor MNH4 into an off state and then the high-level potential V_{H} is supplied from the terminal LO1 of the circuit LGC to the first terminal of the transistor MNH3. In the case where the potential of the first terminal of the capacitor CCL (the potential of the gate of the transistor MNH1) is desired to be decreased (in the case where the potential is desired to be V_{L}), the low-level potential V_{L} is supplied from the terminal LO1 of the circuit LGC to the first terminal of the transistor MNH3 to bring the transistor MNH3 into an off state and then the high-level potential V_{H} is supplied to the wiring RS1 to bring the transistor MNH4 into an on state. Here, when the potential supplied by the wiring VSE23 is the low-level potential V_{L}, the charge in the first terminal of the capacitor CCL (the charge in the gate of the transistor MNH1) flows to the wiring VSE23, whereby the potential of the first terminal of the capacitor CCL (the potential of the gate of the transistor MNH1) becomes V_{L}.

In the case where the potential of the first terminal of the capacitor CPW (the potential of the gate of the transistor MNC1) is desired to be increased (in the case where the potential is desired to be V_{H}−V_{th_MNC3}), for example, the low-level potential V_{L} is supplied to the wiring RS2 to bring the transistor MNC4 into an off state and then the high-level potential V_{H} is supplied from the terminal LO1 of the circuit LGC to the first terminal of the transistor MNC3. In the case where the potential of the first terminal of the capacitor CPW (the potential of the gate of the transistor MNC1) is desired to be decreased (in the case where the potential is desired to be V_{L}), the low-level potential V_{L} is supplied from the terminal LO1 of the circuit LGC to the first terminal of the transistor MNC3 to bring the transistor MNC3 into an off state and then the high-level potential V_{H} is supplied to the wiring RS2 to bring the transistor MNC4 into an on state. Here, when the potential supplied by the wiring VSE24 is the low-level potential V_{L}, the charge in the first terminal of the capacitor CCL (the charge in the gate of the transistor MNC1) flows to the wiring VSE24, whereby the potential of the first terminal of the capacitor CPW (the potential of the gate of the transistor MNC1) becomes V_{L}.

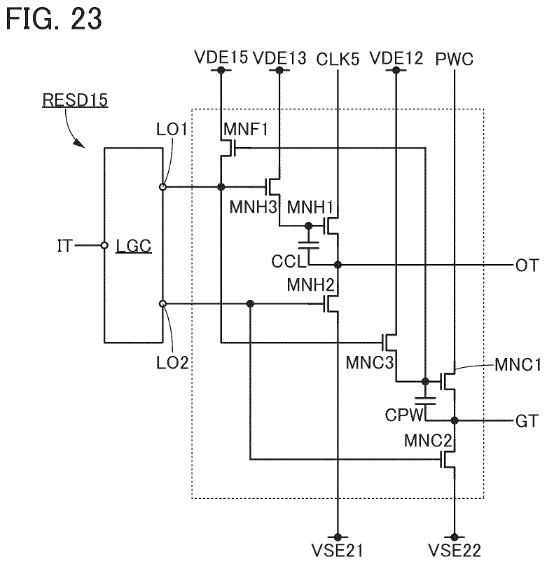

The structure of the memory circuit RESD12 in FIG. 20A may be modified to that of a memory circuit RESD15 illustrated in FIG. 23. The memory circuit RESD15 in FIG. 23 is different from the memory circuit RESD12 in that the gate of the transistor MNH3 is electrically connected not to the wiring VDE11 but to the terminal LO1 of the circuit LGC, the first terminal of the transistor MNH3 is electrically connected to the wiring VDE13, the gate of the transistor MNC3 is electrically connected not to the wiring VDE12 but to the terminal LO1 of the circuit LGC, and the first terminal of the transistor MNC3 is electrically connected to the wiring VDE14, as in the memory circuit RESD9 in FIG. 17A.

For the wiring VDE13 and the wiring VDE14, the description of the wiring VDE13 and the wiring VDE14 of the memory circuit RESD9 in FIG. 17A can be referred to.

In the memory circuit RESD15 in FIG. 23, when a high-level potential V_{H} is supplied from the terminal LO1 of the circuit LGC1 to each of the gate of the transistor MNH3 and the gate of the transistor MNC3, the potentials of the second terminal of the transistor MNH3, the gate of the transistor MNH1, and the first terminal of the capacitor CCL each reach V_{H}−V_{th_MNH3}, whereby the transistor MNH3 is brought into an off state. In addition, the potentials of the second terminal of the transistor MNC3, the gate of the transistor MNC1, the gate of the transistor MNF1, and the first terminal of the capacitor CPW each reach V_{H}−V_{th_MNC3}, whereby the transistor MNC3 is brought into an off state.

After that, when the high-level potential V_{H} is input from the terminal CLK5, a bootstrap using the capacitor CCL is caused; thus, the potential of the terminal OT increases to V_{H}. Similarly, when a high-level potential V_{EXH} is input from the terminal PWC, a bootstrap using the capacitor CPW is caused; thus, the potential of the terminal GT increases to V_{EXH}. This increases also the potential of the gate of the transistor MNF1, so that the transistor MNF1 can be brought into an on state, and electrical continuity can be established between the wiring VDE15 and the first terminals of the transistor MNH3 and the transistor MNC3. Therefore, as in the memory circuit RESD12 in FIG. 20A, signals output from the terminal OT and the terminal GT can be stabilized.

When the potential V_{High}−V_{th_MNH3} of the first terminal of the capacitor CCL (the potential of the gate of the transistor MNH1) is desired to be decreased, that is, when the charge accumulated in the first terminal of the capacitor CCL (or the gate of the transistor MNH1) is desired to be released, the circuit OPC in FIG. 23 should be further modified. Similarly, when the potential V_{High}−V_{th_MNC3} of the first terminal of the capacitor CPW (the potential of the gate of the transistor MNC1) is desired to be decreased, that is, when the charge accumulated in the first terminal of the capacitor CPW (or the gate of the transistor MNC1) is desired to be released, the circuit OPC in FIG. 23 should be further modified, as in the memory circuit RESD9 in FIG. 17A.

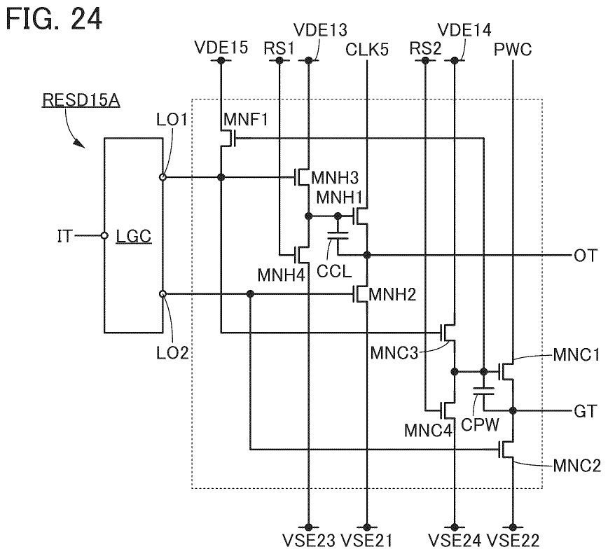

The circuit OPC of a memory circuit RESD15A illustrated in FIG. 24 is a modification example of the circuit OPC of the memory circuit RESD15 in FIG. 23 and is different from the circuit OPC of the memory circuit RESD15 in FIG. 23 in that the charge accumulated in the first terminal of the capacitor CCL (or the gate of the transistor MNH1) and the first terminal of the capacitor CPW (or the gate of the transistor MNC1) can be released. Specifically, the circuit OPC of the memory circuit RESD15A illustrated in FIG. 24 is different from the circuit OPC of the memory circuit RESD15 in FIG. 23 in including the transistor MNC4 and the transistor MNH4.

The first terminal of the transistor MNH4 is electrically connected to the gate of the transistor MNH1, the first terminal of the capacitor CCL, and the second terminal of the transistor MNH3, the second terminal of the transistor MNH4 is electrically connected to the wiring VSE23, and the gate of the transistor MNH4 is electrically connected to the wiring RS1. The first terminal of the transistor MNC4 is electrically connected to the second terminal of the transistor MNC3, the gate of the transistor MNC1, the first terminal of the capacitor CPW, and the gate of the transistor MNF1, the second terminal of the transistor MNC4 is electrically connected to the wiring VSE24, and the gate of the transistor MNC4 is electrically connected to the wiring RS2.

For the wiring RS1, the wiring RS2, the wiring VSE23, and the wiring VSE24, the description of the wiring RS1, the wiring RS2, the wiring VSE23, and the wiring VSE24 of the memory circuit RESD9A illustrated in FIG. 17B can be referred to.

In the case where the potential of the first terminal of the capacitor CCL (the potential of the gate of the transistor MNH1) is desired to be increased (in the case where the potential is desired to be V_{H}−V_{th_MNH3}), for example, the low-level potential V_{L} is supplied to the wiring RS1 to bring the transistor MNH4 into an off state and then the high-level potential V_{H} is supplied from the terminal LO1 of the circuit LGC to the gate of the transistor MNH3. In the case where the potential of the first terminal of the capacitor CCL (the potential of the gate of the transistor MNH1) is desired to be decreased (in the case where the potential is desired to be V_{L}), the low-level potential V_{L} is supplied from the terminal LO1 of the circuit LGC to the gate of the transistor MNH3 to bring the transistor MNH3 into an off state and then the high-level potential V_{H} is supplied to the wiring RS1 to bring the transistor MNH4 into an on state. Here, when the potential supplied by the wiring VSE23 is the low-level potential V_{L}, the charge in the first terminal of the capacitor CCL (the charge in the gate of the transistor MNH1) flows to the wiring VSE23, whereby the potential of the first terminal of the capacitor CCL (the potential of the gate of the transistor MNH1) becomes V_{L}.

In the case where the potential of the first terminal of the capacitor CPW (the potential of the gate of the transistor MNC1) is desired to be increased (in the case where the potential is desired to be V_{H}−V_{th_MNC3}), for example, the low-level potential V_{L} is supplied to the wiring RS2 to bring the transistor MNC4 into an off state and then the high-level potential V_{H} is supplied from the terminal LO1 of the circuit LGC to the gate of the transistor MNC3. In the case where the potential of the first terminal of the capacitor CPW (the potential of the gate of the transistor MNC1) is desired to be decreased (in the case where the potential is desired to be V_{L}), the low-level potential V_{L} is supplied from the terminal LO1 of the circuit LGC to the gate of the transistor MNC3 to bring the transistor MNC3 into an off state and then the high-level potential V_{H} is supplied to the wiring RS2 to bring the transistor MNC4 into an on state. Here, when the potential supplied by the wiring VSE24 is the low-level potential V_{L}, the charge in the first terminal of the capacitor CCL (the charge in the gate of the transistor MNC1) flows to the wiring VSE24, whereby the potential of the first terminal of the capacitor CPW (the potential of the gate of the transistor MNC1) becomes V_{L}.

### <Level Shifter Circuit LS>

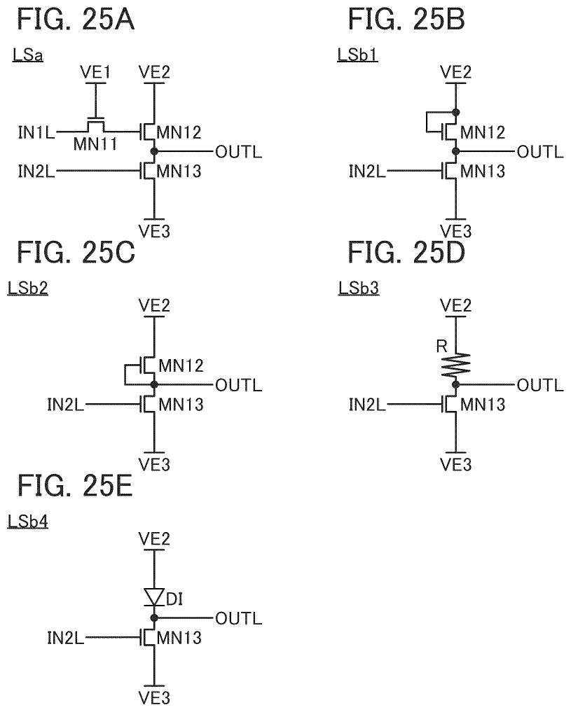

Next, the level shifter circuit LS included in the amplifier circuit LVS of the driver circuit SD2 in FIG. 4 is described. FIG. 25A shows an example of a circuit structure of a level shifter circuit that can be used as each of the level shifter circuit LS[1] to the level shifter circuit LS[5] in FIG. 4.

A level shifter circuit LSa illustrated in FIG. 25A is a structure example of a circuit that can be used as the level shifter circuit LS in FIG. 4, and includes a transistor MN11 to a transistor MN13. As illustrated in FIG. 25A, the level shifter circuit LSa is a single-polarity circuit not including a p-channel transistor but including an n-channel transistor.

The level shifter circuit LSa includes a terminal IN1L, a terminal IN2L, and a terminal OUTL.

A gate of the transistor MN11 is electrically connected to a wiring VE1, a first terminal of the transistor MN11 is electrically connected to the terminal IN1L, and a second terminal of the transistor MN11 is electrically connected to a gate of the transistor MN12. A first terminal of the transistor MN12 is electrically connected to a wiring VE2. A gate of the transistor MN13 is electrically connected to the terminal IN2L, a first terminal of the transistor MN13 is electrically connected to a second terminal of the transistor MN12 and the terminal OUTL, and a second terminal of the transistor MN13 is electrically connected to a wiring VE3.

The terminal IN1L corresponds to the input terminal of the level shifter circuit LS in FIG. 4, for example.

To the terminal IN2L, for example, a signal obtained by inverting the logic of a signal input to the terminal IN1L is input. For example, when a low-level potential is input to the terminal IN1L, a high-level potential is input to the terminal IN2L. For another example, when a high-level potential is input to the terminal IN1L, a low-level potential is input to the terminal IN2L. Thus, it is preferable that an output terminal of an inverter be electrically connected to the terminal IN2L and the terminal IN1L be electrically connected to an input terminal of the inverter, for example.

The terminal OUTL corresponds to the output terminal of the level shifter circuit LS in FIG. 4, for example.

The wiring VE1 functions as a wiring for supplying a fixed potential, for example. Note that the fixed potential is preferably a potential with the same level as a high-level potential that can be output from the second output terminal of the memory circuit RES. The wiring VE1 may be a wiring for supplying not a fixed potential but a variable potential.

The wiring VE2 functions as a wiring for supplying a fixed potential, for example. Note that the fixed potential is preferably a potential higher than a high-level potential that can be output from the second output terminal of the memory circuit RES. Alternatively, the fixed potential may be a potential with the same level as a low-level potential that can be output from the second output terminal of the memory circuit RES. The wiring VE2 may be a wiring for supplying not a fixed potential but a variable potential.

The wiring VE3 functions as a wiring for supplying a fixed potential, for example. Note that the fixed potential is preferably a low-level potential that can be output from the second output terminal of the memory circuit RES or a ground potential. The wiring VE3 may be a wiring for supplying not a fixed potential but a variable potential.

In the level shifter circuit LSa, the transistor MN11 has a function of transmitting a signal from the terminal IN1L to the gate of the transistor MN12. Therefore, a transistor having a high driving frequency is preferably used as the transistor MN11. That is, the transistor MTHN described in Embodiment 1 above is preferably used as the transistor MN11. Note that in the case where the transistor MN11 is desired to have high resistance to voltage, not the transistor MTHN but the transistor MTCK may be used as the transistor MN11.

In the level shifter circuit LSa, as described above, a potential higher than a high-level potential that can be output from the second output terminal of the memory circuit RES is supplied from the wiring VE2 to each of the first terminal and the second terminal of the transistor MN12 or the first terminal of the transistor MN13. Therefore, a transistor having high resistance to voltage is preferably used as each of the transistor MN12 and the transistor MN13. That is, the transistor MTCK described in Embodiment 1 above is preferably used as each of the transistor MN12 and the transistor MN13. Note that in the case where the transistor MN12 and the transistor MN13 are each desired to have a high driving frequency, not the transistor MTCK but the transistor MTHN may be used as each of the transistor MN12 and the transistor MN13.

Next, a modification example of the level shifter circuit LSa is described.

A level shifter circuit LSb1 illustrated in FIG. 25B is a modification example of the level shifter circuit LSa in FIG. 25A and is different from the level shifter circuit LSa in that the transistor MN11 is not provided and the gate of the transistor MN12 is electrically connected to the first terminal of the transistor MN12.

The inverted signal of the signal input to the terminal IN1L is input to the terminal IN2L of the level shifter circuit LSa; similarly, in the level shifter circuit LSb1, the inverted signal of a signal output from the second output terminal of the memory circuit RES is input to the terminal IN2L of a level shifter LSB1.

Note that the structure of the level shifter circuit LSb1 can be modified in the circuit design phase.

A level shifter circuit LSb2 illustrated in FIG. 25C may be used as the level shifter circuit LS included in the amplifier circuit LVS illustrated in FIG. 3 or FIG. 4, for example. The level shifter circuit LSb2 illustrated in FIG. 25C is a modification example of the level shifter circuit LSb1 in FIG. 25B and is different from the level shifter circuit LSb1 in that the gate of the transistor MN12 is electrically connected not to the first terminal of the transistor MN12 but to the second terminal of the transistor MN12.

The transistor MN12 illustrated in FIG. 25C is a normally-on transistor.

Note that in this specification and the like, normally off in an OS transistor means that a current per micrometer of channel width that flows through the transistor when the gate-source voltage is 0 V is lower than or equal to 1×10⁻²⁰ A at room temperature, lower than or equal to 1×10⁻¹⁸ A at 85° C., or lower than or equal to 1×10⁻¹⁶ A at 125° C. Meanwhile, normally on means a state where a channel exists even when the gate-source voltage is 0 V, and a current flows through a transistor.

A level shifter circuit LSb3 illustrated in FIG. 25D may be used as the level shifter circuit LS included in the amplifier circuit LVS illustrated in FIG. 3 or FIG. 4, for example. The level shifter circuit LSb3 illustrated in FIG. 25D is a modification example of the level shifter circuit LSb1 in FIG. 25B and is different from the level shifter circuit LSb1 in that the transistor MN12 is replaced with a resistor R.

A first terminal of the resistor R is electrically connected to the wiring VE2, and a second terminal of the resistor R is electrically connected to the first terminal of the transistor MN13 and the terminal OUTL.

A level shifter circuit LSb4 illustrated in FIG. 25E may be used as the level shifter circuit LS included in the amplifier circuit LVS illustrated in FIG. 3 or FIG. 4, for example. The level shifter circuit LSb4 illustrated in FIG. 25E is a modification example of the level shifter circuit LSb1 in FIG. 25B and is different from the level shifter circuit LSb1 in that the transistor MN12 is replaced with a diode DI.

An input terminal of the diode is electrically connected to the wiring VE2, and an output terminal of the diode is electrically connected to the first terminal of the transistor MN13 and the terminal OUTL.

### <Retention Circuit LTC1 or Retention Circuit LTC2>

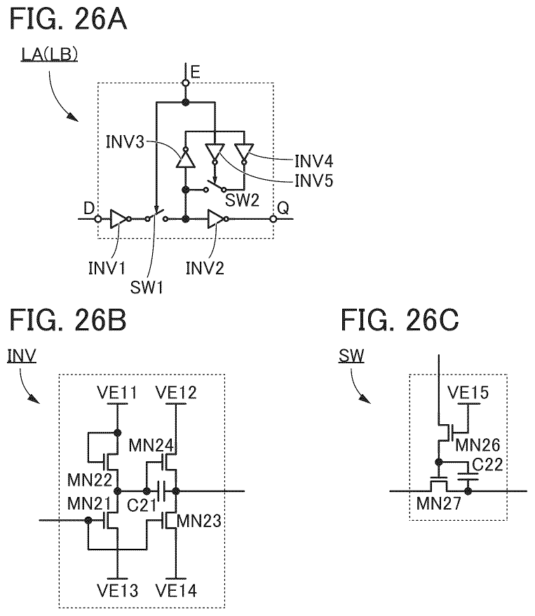

Next, the first latch circuit LA and the second latch circuit LB respectively included in the retention circuit LTC1 and the retention circuit LTC2 illustrated in FIG. 3 or FIG. 4 are described. FIG. 26A shows an example of a circuit structure of a latch circuit that can be used as the first latch circuit LA or the second latch circuit LB illustrated in FIG. 3 or FIG. 4.

The first latch circuit LA (the second latch circuit LB) illustrated in FIG. 26A includes an inverter INV1 to an inverter INV5, a switch SW1, and a switch SW2. The first latch circuit LA (the second latch circuit LB) includes the input terminal D, an output terminal Q, and the enable input terminal E.

As the switch SW1 or the switch SW2, an electrical switch such as an analog switch or a mechanical switch may be used, for example. One electrical switch may be an OS transistor.

In this specification and the like, each of the switch SW1 and the switch SW2 illustrated in FIG. 26A is in an on state when a high-level potential is supplied to a control terminal, and is in an off state when a low-level potential is supplied to the control terminal.

An input terminal of the inverter INV1 is electrically connected to the input terminal D, and an output terminal of the inverter INV1 is electrically connected to a first terminal of the switch SW1. An input terminal of the inverter INV2 is electrically connected to an input terminal of the inverter INV3, a second terminal of the switch SW1, and a first terminal of the switch SW2, and an output terminal of the inverter INV2 is electrically connected to the output terminal Q. An output terminal of the inverter INV3 is electrically connected to an input terminal of the inverter INV4, and an output terminal of the inverter INV4 is electrically connected to a second terminal of the switch SW2. An input terminal of the inverter INV5 is electrically connected to the enable input terminal E and the control terminal of the switch SW1, and an output terminal of the inverter INV5 is electrically connected to the control terminal of the switch SW2.

While a high-level potential is input to the enable input terminal E of the first latch circuit LA (the second latch circuit LB) illustrated in FIG. 26A, the switch SW1 is in a conduction state and the switch SW2 is in a non-conduction state. Thus, a signal input to the input terminal D is output to the output terminal Q through the inverter INV1 and the inverter INV2. A signal input to the input terminal D is input to the first terminal of the switch SW2 through the inverter INV1, the inverter INV3, and the inverter INV4.

Here, when the high-level potential input to the enable input terminal E changes to a low-level potential, the switch SW1 is brought into a non-conduction state and the switch SW2 is brought into a conduction state. Here, the signal previously input to the input terminal D can be retained by the inverter INV3 and the inverter INV4. The signal is output to the output terminal Q through the inverter INV2.

FIG. 26B shows an example of a circuit structure of an inverter that can be used as each of the inverter INV1 to the inverter INV5. An inverter INV illustrated in FIG. 26B includes a transistor MN21 to a transistor MN24 and a capacitor C21. As illustrated in FIG. 26B, the inverter INV is a single-polarity circuit not including a p-channel transistor but including an n-channel transistor.

An input terminal of the inverter INV is electrically connected to a gate of the transistor MN21 and a gate of the transistor MN23. A gate of the transistor MN22 is electrically connected to a first terminal of the transistor MN22 and a wiring VE11, and a second terminal of the transistor MN22 is electrically connected to a first terminal of the transistor MN21, a gate of the transistor MN24, and a first terminal of the capacitor C21. A second terminal of the transistor MN21 is electrically connected to a wiring VE13. A first terminal of the transistor MN24 is electrically connected to a wiring VE12, and a second terminal of the transistor MN24 is electrically connected to a second terminal of the capacitor C21, a first terminal of the transistor MN23, and an output terminal of the inverter INV. A second terminal of the transistor MN23 is electrically connected to a wiring VE14.

The wiring VE11 and the wiring VE12 each function as a wiring for supplying a fixed potential, for example. The fixed potential is preferably a high-level potential. The fixed potentials supplied by the wiring VE11 and the wiring VE12 may be equal to each other or different from each other. Note that one or both of the wiring VE11 and the wiring VE12 may be a wiring for supplying not a fixed potential but a variable potential.

The wiring VE13 and the wiring VE14 each function as a wiring for supplying a fixed potential, for example. The fixed potential is preferably a low-level potential or a ground potential. The fixed potentials supplied by the wiring VE13 and the wiring VE14 may be equal to each other or different from each other. Note that one or both of the wiring VE11 and the wiring VE12 may be a wiring for supplying not a fixed potential but a variable potential.

In the inverter INV, the transistor MN21 to the transistor MN24 each function as a circuit element for inverting the logic of a signal from the input terminal of the inverter INV and outputting the signal with the inverted logic to the output terminal of the inverter INV. Therefore, the time it takes after the signal is input to the input terminal of the inverter INV until the signal is output from the output terminal of the inverter INV is preferably short. In other words, a transistor having a high driving frequency is preferably used as each of the transistor MN21 to the transistor MN24 provided in the inverter INV. That is, the transistor MTHN described in Embodiment 1 above is preferably used as each of the transistor MN21 to the transistor MN24.

Note that in the case where the transistor MN21 to the transistor MN24 are each desired to have high resistance to voltage, not the transistor MTCK but the transistor MTHN may be used as each of the transistor MN21 to the transistor MN24.

FIG. 26C illustrates a circuit structure of a switch that can be used as each of the switch SW1 and the switch SW2. A switch SW illustrated in FIG. 26C includes a transistor MN26, a transistor MN27, and a capacitor C22. As illustrated in FIG. 26C, the switch SW is a single-polarity circuit not including a p-channel transistor but including an n-channel transistor.

A first terminal of the transistor MN26 is electrically connected to the enable input terminal E of the switch SW, a second terminal of the transistor MN26 is electrically connected to a gate of the transistor MN27 and a first terminal of the capacitor C22, and a gate of the transistor MN26 is electrically connected to a wiring VE15. A first terminal of the transistor MN27 is electrically connected to a first terminal of the switch SW, and a second terminal of the transistor MN27 is electrically connected to a second terminal of the capacitor C22 and the second terminal of the switch SW2.

The wiring VE15 functions as a wiring for supplying a fixed potential, for example. The fixed potential is preferably a high-level potential. The fixed potentials supplied by the wiring VE15 may be equal to each other or different from each other. Note that one or both of the wiring VE15 may be a wiring for supplying not a fixed potential but a variable potential.

In the switch SW, the transistor MN27 functions as a circuit element that switches electrical continuity and electrical discontinuity between the input terminal and the output terminal of the switch SW. Therefore, the transistor MN27 preferably has a high switching speed. Therefore, a transistor having a high driving frequency is preferably used as the transistor MN27 provided in the switch SW. That is, the transistor MTHN described in Embodiment 1 above is preferably used as the transistor MN27. Note that in the case where the transistor MN27 is desired to have high resistance to voltage, not the transistor MTHN but the transistor MTCK may be used as the transistor MN27.

In the case where the transistor MN26 is desired to have high resistance to voltage, the transistor MTCK is used. In the case where a high driving frequency is desired, the transistor MTHN is used.

### <Amplifier Circuit SF>

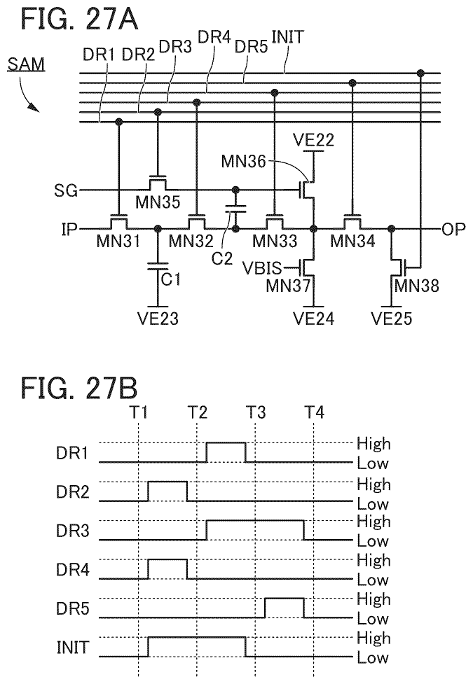

Next, the source follower circuit SAM[1] to the source follower circuit SAM[5] that are illustrated in FIG. 3 or FIG. 4 and included in the amplifier circuit SF are described. FIG. 27A shows an example of a circuit structure of a source follower circuit that can be used as each of the source follower circuit SAM[1] to the source follower circuit SAM[5] that are illustrated in FIG. 3 or FIG. 4.

A source follower circuit SAM illustrated in FIG. 27A includes a transistor MN31 to a transistor MN38, a capacitor C1, and a capacitor C2. The source follower circuit SAM includes a terminal IP and a terminal OP.

A first terminal of the transistor MN31 is electrically connected to the terminal IP, a second terminal of the transistor MN31 is electrically connected to a first terminal of the transistor MN32 and a first terminal of the capacitor C1, and a gate of the transistor MN31 is electrically connected to a wiring DR1. A second terminal of the capacitor C1 is electrically connected to a wiring VE23. A first terminal of the transistor MN35 is electrically connected to a wiring SG, a second terminal of the transistor MN35 is electrically connected to a gate of the transistor MN36 and a first terminal of the capacitor C2, and a gate of the transistor MN35 is electrically connected to a wiring DR2. A second terminal of the transistor MN32 is electrically connected to a first terminal of the transistor MN33 and a second terminal of the capacitor C2, and a gate of the transistor MN32 is electrically connected to a wiring DR3. A first terminal of the transistor MN36 is electrically connected to a wiring VE22, and a second terminal of the transistor MN36 is electrically connected to a second terminal of the transistor MN33, a first terminal of the transistor MN37, and a first terminal of the transistor MN34. A gate of the transistor MN33 is electrically connected to a wiring DR4. A second terminal of the transistor MN37 is electrically connected to a wiring VE24, and a gate of the transistor MN37 is electrically connected to a wiring VBIS. A second terminal of the transistor MN34 is electrically connected to a first terminal of the transistor MN38 and the terminal OP, and a gate of the transistor MN34 is electrically connected to a wiring DR5. A second terminal of the transistor MN38 is electrically connected to a wiring VE25, and a gate of the transistor MN38 is electrically connected to a wiring INIT.

The wiring DR1 to the wiring DR5 and the wiring INIT each function as a wiring for transmitting a signal for controlling the source follower circuit SAM. Thus, signals transmitted by the wiring DR1 to the wiring DR5 and the wiring INIT are preferably variable potentials.

The wiring SG functions as a wiring for supplying a fixed potential, for example. Note that the fixed potential is preferably higher than or equal to a low-level potential supplied by the wiring VE23 to the wiring VE25 described later or higher than or equal to a ground potential and lower than or equal to a high-level potential supplied by the wiring VE22. The fixed potential may be a potential out of the above range. The wiring SG may be a wiring for supplying not a fixed potential but a variable potential.

The wiring VE22 functions as a wiring for supplying a fixed potential, for example. The fixed potential is preferably a high-level potential. Note that the wiring VE22 may be a wiring for supplying not a fixed potential but a variable potential.

The wiring VE23 to the wiring VE25 each function as a wiring for supplying a fixed potential, for example. The fixed potential is preferably a low-level potential or a ground potential. The fixed potentials supplied by the wiring VE23 to the wiring VE25 may be equal to each other or different from each other. Note that one or more of the wiring VE23 to the wiring VE25 may be a wiring for supplying not a fixed potential but a variable potential.

The wiring VBIS functions as a wiring for supplying a fixed potential to the gate of the transistor MN37. The wiring VE24 is electrically connected to the second terminal of the transistor MN37; in the case where the wiring VE24 supplies a fixed potential to the second terminal of the transistor MN37, the transistor MN37 functions as a constant current source.

The terminal IP corresponds to the input terminal of the source follower circuit SAM in FIG. 3 or FIG. 4, for example.

The terminal OP corresponds to the output terminal of the source follower circuit SAM in FIG. 3 or FIG. 4, for example.

FIG. 27B is a timing chart showing an operation example of the source follower circuit SAM illustrated in FIG. 27A. The timing chart in FIG. 27B shows changes in the potentials of the wiring DR1 to the wiring DR5 and the wiring INIT in a period from time T1 to time T4 and around the period. Note that in the timing chart in FIG. 27B, a high-level potential is denoted by “High” and a low-level potential is denoted by “Low”.

The wiring VE22 is a wiring for supplying a high-level potential V_{DH}. The wiring VE23 to the wiring VE25 each function as a wiring for supplying a low-level potential V_{SS}. The wiring SG functions as a wiring for supplying a reference potential V_{X}.

In a period from the time T1 to the time T2, initialization is performed in the source follower circuit SAM. Specifically, the wiring DR1, the wiring DR3, and the wiring DR5 each have a low-level potential, and the wiring DR2, the wiring DR4, and the wiring INIT each have a high-level potential.

Accordingly, the transistor MN31, the transistor MN32, and the transistor MN34 are brought into an off state. The transistor MN33, the transistor MN35, and the transistor MN38 are brought into an on state. Since the transistor MN35 is in an on state, electrical continuity is established between the first terminal of the capacitor C2 and the wiring SG, so that the potential of the first terminal of the capacitor C2 becomes the potential V_{X} supplied by the wiring SG.

Since the transistor MN33 is in an on state, electrical continuity is established between the second terminal of the capacitor C2 and the wiring VE22. At this time, the potential of the second terminal of the capacitor C2 increases until the amount of current flowing between a source and a drain of the transistor MN36 becomes equal to the amount of current flowing between a source and a drain of the transistor MN37. This is because as the potential of the second terminal of the capacitor C2 increases, the gate-source voltage of the transistor MN36 decreases, leading to a reduction in the amount of current flowing between the source and the drain of the transistor MN36. Note that the potential of the second terminal of the capacitor C2 at this time is V_{Y}.

That is, by performing the operation in the period from the time T1 to the time T2, the amount of current flowing between the source and the drain of the transistor MN36 can be set to the amount of current flowing between the source and the drain of the transistor MN37. In this case, by changing the potential of the wiring DR2 from the high-level potential to a low-level potential to bring the transistor MN35 into an off state, a voltage between the first terminal and the second terminal of the capacitor C2 corresponding to the amount of current can be retained.

Since the transistor MN38 is in an on state, electrical continuity is established between the terminal OP and the wiring VE25. Thus, the potential of the terminal OP becomes V_{SS} supplied by the wiring VE25.

In a period from the time T2 to the time T3, an input signal is input to the terminal IP of the source follower circuit SAM. At this time, the wiring DR1 and the wiring DR3 each have a high-level potential, and the wiring DR2, the wiring DR4, and the wiring DR5 each have a low-level potential. Note that in the period from the time T2 to the time T3 in the timing chart in FIG. 27B, the wiring INIT has a high-level potential but may have a low-level potential.

At this time, the transistor MN31 and the transistor MN32 are brought into an on state. The transistor MN33, the transistor MN34, and the transistor MN35 are brought into an off state. Since the transistor MN31 and the transistor MN32 are in an on state, electrical continuity is established between the terminal IP and the second terminal of the capacitor C2, so that the potential V_{Y} of the second terminal of the capacitor C2 increases to a potential Vᵢₙ corresponding to an input signal supplied by the terminal IP. Moreover, at this time, since the first terminal of the capacitor C2 is in a floating state, the potential of the second terminal of the capacitor C2 changes, whereby the potential of the first terminal of the capacitor C2 also changes. When the capacitive coupling coefficient of the capacitor C2 and parasitic capacitance therearound is denoted by K, the potential of the first terminal of the capacitor C2 changes from V_{X} to V_{X}+K(Vᵢₙ−V_{Y}). Here, K is 1, and the potential of the first terminal of the capacitor C2 is assumed to be V_{X}+Vᵢₙ−V_{Y}. Accordingly, in the transistor MN36, the gate-source voltage increases and the amount of current flowing between the source and the drain also increases.

In a period from the time T3 to the time T4, an output signal is output from the terminal OP of the source follower circuit SAM. At this time, the wiring DR3 and the wiring DR5 each have a high-level potential, and the wiring DR1, the wiring DR2, the wiring DR4, and the wiring INIT each have a low-level potential.

At this time, the transistor MN32 and the transistor MN34 are brought into an on state. The transistor MN31, the transistor MN33, the transistor MN35, and the transistor MN38 are brought into an off state. Since the transistor MN34 is in an on state, electrical continuity is established between the terminal OP and the second terminal of the transistor MN36, so that the potential of the terminal OP changes to a potential corresponding to a gate-source voltage V_{GS} of the transistor MN36. Note that when a potential output from the terminal OP is denoted by V_{OUT}, V_{OUT}=Vᵢₙ−V_{Y}+V_{X}−V_{GS} is satisfied.

Since the transistor MN31 and the transistor MN33 are in an off state, the first terminal of the capacitor C1 and the second terminal of the capacitor C2 are in a floating state. The potentials of the first terminal of the capacitor C1 and the second terminal of the capacitor C2 are retained by the capacitor C1. That is, the source follower circuit SAM illustrated in FIG. 27A also has a function of a sample-and-hold circuit. Thus, after the potential corresponding to the input signal input from the terminal IP is retained in each of the capacitor C1 and the capacitor C2, the retention circuit LTC2 that inputs a signal to the terminal IP can be stopped.

In the source follower circuit SAM, the transistor MN31 to the transistor MN35, the transistor MN37, and the transistor MN38 each have a function of transmitting a signal from the terminal IP to the terminal OP. Therefore, a transistor having a high driving frequency is preferably used as each of the above-described transistors. That is, the transistor MTHN described in Embodiment 1 above is preferably used as each of the transistor MN31 to the transistor MN35, the transistor MN37, and the transistor MN38. Note that in the case where the transistor MN31 to the transistor MN35, the transistor MN37, and the transistor MN38 are each desired to have high resistance to voltage, not the transistor MTHN but the transistor MTCK may be used as each of the above-described transistors.

In the level shifter circuit LS, the gate of the transistor MN36 is supplied with a voltage increased owing to capacitive coupling. Therefore, a transistor having high resistance to voltage is preferably used as the transistor MN36. That is, the transistor MTCK described in Embodiment 1 above is preferably used as the transistor MN36. Note that in the case where the transistor MN36 is desired to have a high driving frequency, not the transistor MTCK but the transistor MTHN may be used as the transistor MN36.

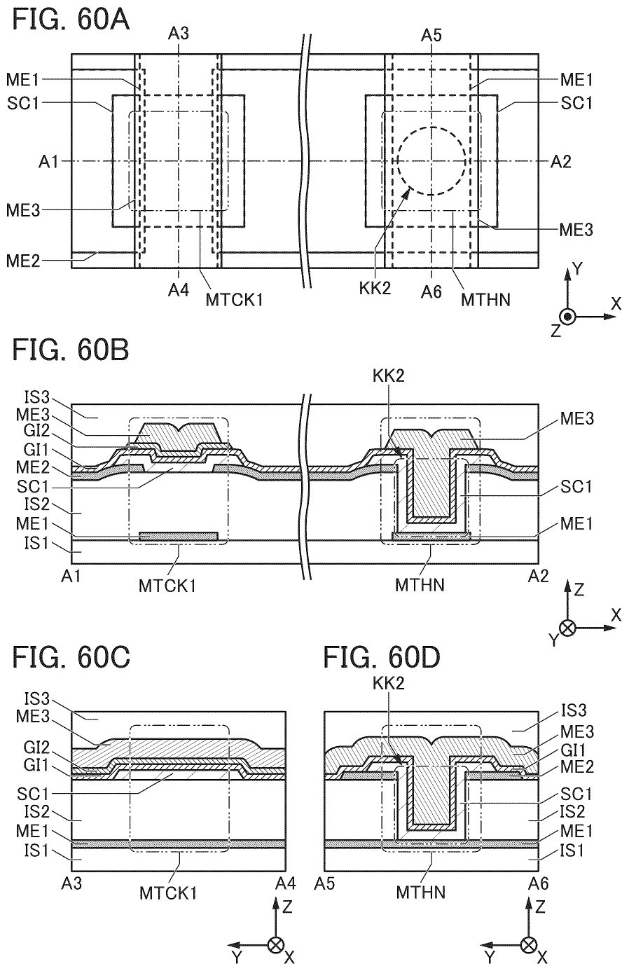

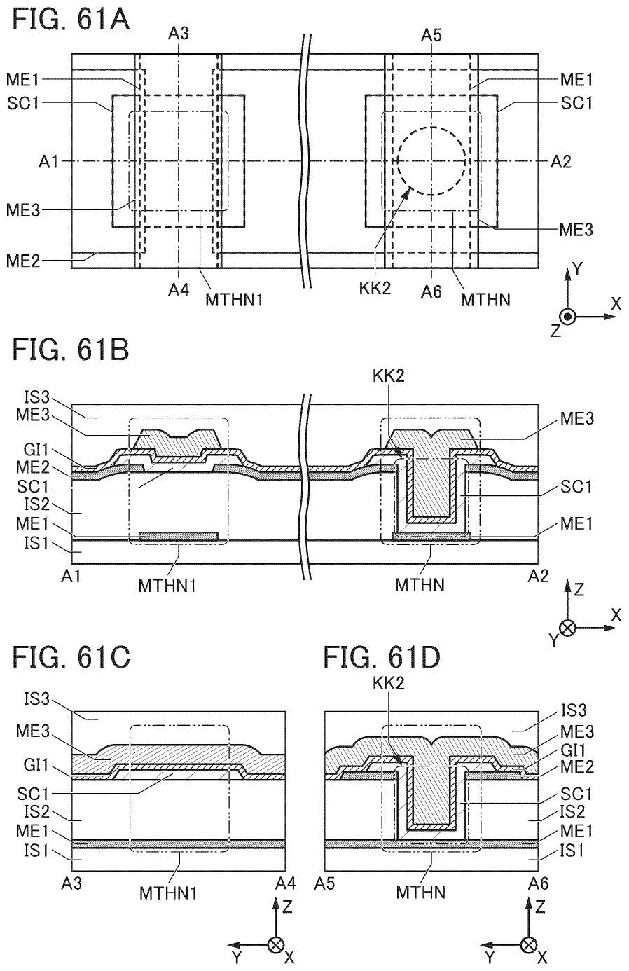

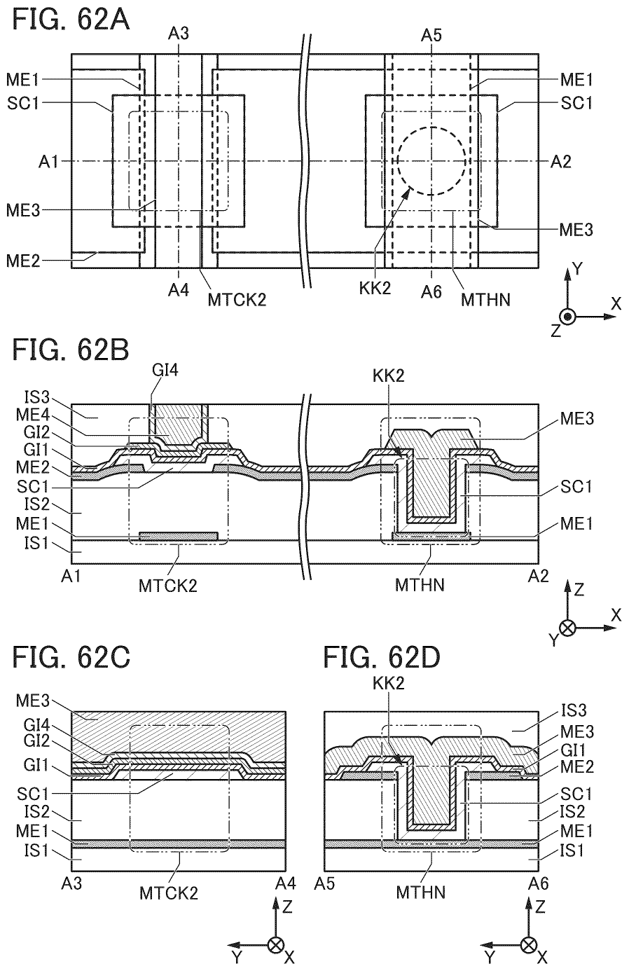

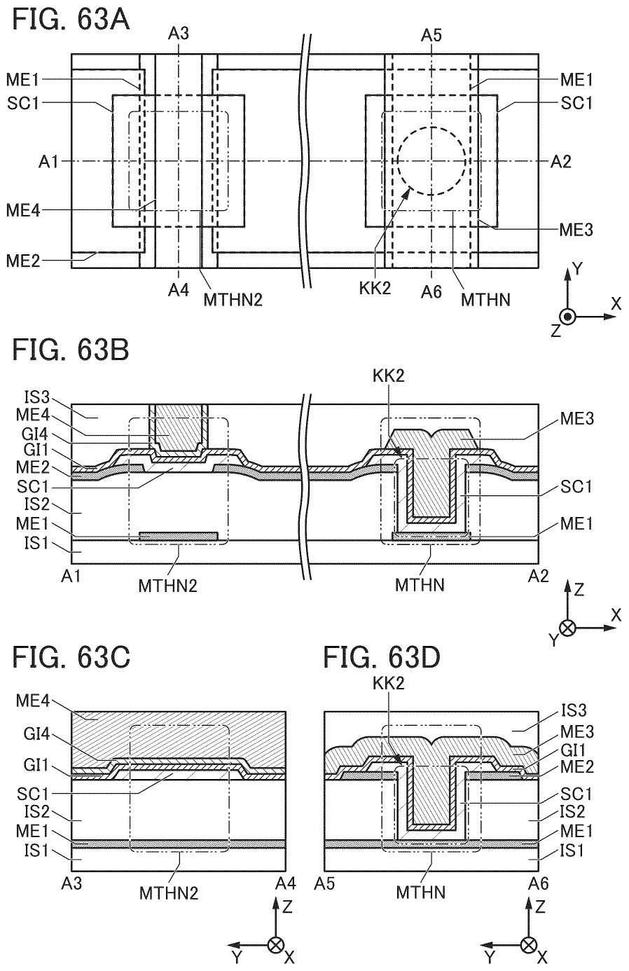

In the case where the amount of current flowing between the source and the drain of the transistor MN37 is desired to be reduced, for example, the transistor MTCK may be used as the transistor MN37. Alternatively, it is possible to use any of a transistor MTCK1 illustrated in FIG. 60A to FIG. 60C, a transistor MTHN1 illustrated in FIG. 61A to FIG. 61C, a transistor MTCK2 illustrated in FIG. 62A to FIG. 62C, and a transistor MTHN2 illustrated in FIG. 63A to FIG. 63C each having a channel length (e.g., a length from a source electrode to a drain electrode in a channel formation region) that is longer than those of the transistor MTCK and the transistor MTHN. Note that the transistor MTCK1, the transistor MTHN1, the transistor MTCK2, and the transistor MTHN2 will be described later in Embodiment 4.

Note that a circuit that can be used as the source follower circuit SAM in FIG. 3 or FIG. 4 is not limited to the above-described source follower circuit SAM in FIG. 27A. As a circuit that can be used as the source follower circuit SAM in FIG. 3 or FIG. 4, a circuit obtained by modifying the source follower circuit SAM in FIG. 27A can be used.

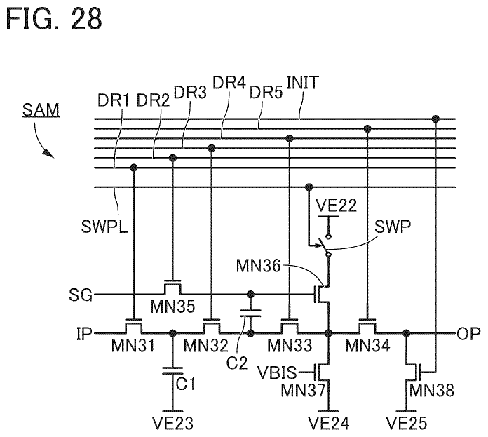

For example, the source follower circuit SAM in FIG. 27A may be modified to the source follower circuit SAM illustrated in FIG. 28. The source follower circuit illustrated in FIG. 28 is different from the source follower circuit SAM in FIG. 27A in that a switch SWP is provided between the first terminal of the transistor MN36 and the wiring VE22.

In the source follower circuit SAM in FIG. 28, a first terminal of the switch SWP is electrically connected to the wiring VE22, a second terminal of the switch SWP is electrically connected to the first terminal of the transistor MN36, and a control terminal of the switch SWP is electrically connected to a wiring SWPL.

The wiring SWPL functions as, for example, a wiring for transmitting a signal for switching the on state and the off state of the switch SWP.

In the source follower circuit SAM in FIG. 28, the switch SWP has a function of establishing or breaking electrical continuity between the wiring VE22 and the first terminal of the transistor MN36. Thus, for example, by bringing the switch SWP into an off state, power supply from the wiring VE22 to the first terminal of the transistor MN36 can be stopped; as a result, the source follower circuit SAM in FIG. 28 can be temporarily stopped. Therefore, power supply is not performed while the operation of the source follower circuit SAM in FIG. 28 is stopped, so that power consumption of the source follower circuit SAM can be reduced.

### <Modification Example>

In each of the driver circuit SD1 illustrated in FIG. 3 and the driver circuit SD2 illustrated in FIG. 4, the retention circuit LTC1 and the retention circuit LTC2 are electrically connected to each other successively. In other words, the first latch circuit LA and the second latch circuit LB are electrically connected to each other successively. That is, when an image signal is input to the driver circuit SD1 or the driver circuit SD2, the image signal is transmitted to the amplifier circuit SF side through the first latch circuit LA and the second latch circuit LB; thus, the image signal output from the second latch circuit LB might be attenuated as compared with the image signal input to the driver circuit SD1 or the driver circuit SD2.

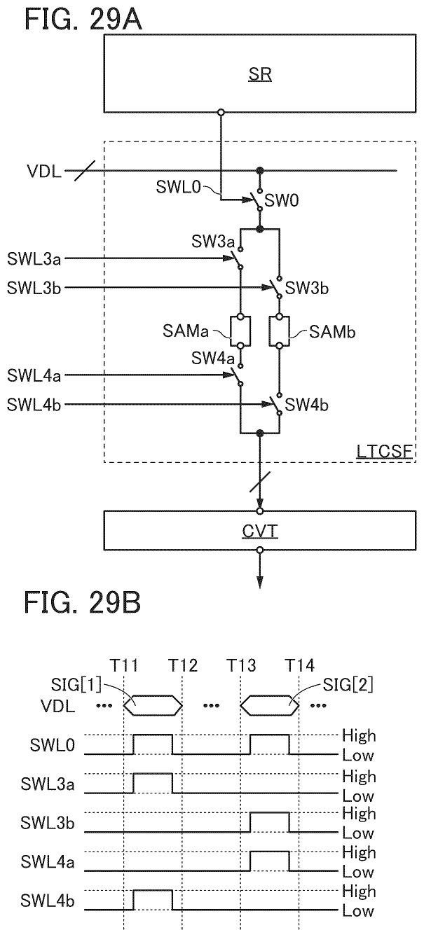

A circuit LTCSF illustrated in FIG. 29A has a structure in view of the above problem and has a function of a latch circuit that temporarily retains an image signal and a function of a source follower circuit that amplifies an image signal. Note that FIG. 29A also illustrates the shift register SR and the converter circuit CVT to show the electrical connection structure of the circuit LTCSF.

The circuit LTCSF includes a switch SW0, a switch SW3a, a switch SW3b, a switch SW4a, a switch SW4b, a source follower circuit SAMa, and a source follower circuit SAMb.

As each of the switch SW0, the switch SW3a, the switch SW3b, and the switch SW4a, a switch that can be used as the switch SW1 or the switch SW2 described above can be used, for example.

In this specification and the like, each of the switch SW0, the switch SW3a, the switch SW3b, and the switch SW4a illustrated in FIG. 29A is in an on state when a high-level potential is supplied to a control terminal, and is in an off state when a low-level potential is supplied to the control terminal.

As each of the source follower circuit SAMa and the source follower circuit SAMb, the source follower circuit SAM illustrated in FIG. 27A can be used, for example.

A first terminal of the switch SW0 is electrically connected to a wiring VDL, a second terminal of the switch SW0 is electrically connected to a first terminal of the switch SW3a and a first terminal of the switch SW3b, and the control terminal of the switch SW0 is electrically connected to the shift register SR. In particular, the control terminal of the switch SW0 is preferably electrically connected to the second output terminal of the memory circuit RES included in the shift register SR (not illustrated in FIG. 29A). Here, a wiring that electrically connects the switch SW0 and the shift register SR is referred to as a wiring SWL0 for convenience.

A second terminal of the switch SW3a is electrically connected to an input terminal of the source follower circuit SAMa, and the control terminal of the switch SW3a is electrically connected to a wiring SWL3a. A second terminal of the switch SW3b is electrically connected to an input terminal of the source follower circuit SAMb, and the control terminal of the switch SW3b is electrically connected to a wiring SWL3b.

A first terminal of the switch SW4a is electrically connected to an output terminal of the source follower circuit SAMa, a second terminal of the switch SW4a is electrically connected to an input terminal of the converter circuit CVT, and the control terminal of the switch SW4a is electrically connected to a wiring SWL4a. A first terminal of the switch SW4b is electrically connected to an output terminal of the source follower circuit SAMb, a second terminal of the switch SW4b is electrically connected to the input terminal of the converter circuit CVT, and the control terminal of the switch SW4b is electrically connected to a wiring SWL4b. In particular, the second terminal of the switch SW4a and the second terminal of the switch SW4b are preferably electrically connected to the input terminal of the digital-to-analog converter circuit DAC included in the converter circuit CVT (not illustrated in FIG. 27).

Next, an operation method of the circuit LTCSF is described.

FIG. 29B is a timing chart showing an operation example of the circuit LTCSF illustrated in FIG. 29A. The timing chart in FIG. 29B shows a change in an image signal input to the wiring VDL and changes in the potentials of a wiring SW0, the wiring SWL3a, the wiring SWL3b, the wiring SWL4a, and the wiring SWL4b in a period from time T11 to time T14 and around the period. Note that in the timing chart in FIG. 29B, a high-level potential is denoted by “High” and a low-level potential is denoted by “Low”.

In a period from the time T11 to the time T12, a high-level potential is input from the shift register SR to the control terminal of the switch SW0 through the wiring SWL0. Furthermore, a high-level potential is supplied to each of the wiring SWL3a and the wiring SWL4b, and a high-level potential is input to each of the control terminal of the switch SW3a and the control terminal of the switch SW4b. A low-level potential is supplied to each of the wiring SWL3b and the wiring SWL4a, and a low-level potential is input to each of the control terminal of the switch SW3b and the control terminal of the switch SW4a.

Thus, the switch SW0, the switch SW3a, and the switch SW4b are brought into an on state, and the switch SW3b and the switch SW4a are brought into an off state.

In the period from the time T11 to the time T12, an image signal SIG[1] is input from the wiring VDL to the first terminal of the switch SW0. Thus, the image signal SIG[1] is input to the source follower circuit SAMa through the switch SW0 and the switch SW3a. Accordingly, for example, a potential corresponding to the image signal SIG[1] is retained in each of the first terminal of the capacitor C1 and the second terminal of the capacitor C2 that are illustrated in FIG. 27A, and the amplified image signal SIG[1] is output from the output terminal (the terminal OP) of the source follower circuit SAMa. Since the switch SW4a is in an off state, the image signal SIG[1] output from the output terminal (the terminal OP) of the source follower circuit SAMa does not reach the converter circuit CVT.

Meanwhile, for example, an image signal retained in the source follower circuit SAMb before the time T11 is input to the converter circuit CVT from the output terminal of the source follower circuit SAMb through the switch SW4b. Thus, in the period from the time T11 to the time T12, the image signal is converted from digital data into analog data and then input to the pixel circuit PX of the pixel array PXA.

In a period from the time T13 to the time T14, a high-level potential is input from the shift register SR to the control terminal of the switch SW0 through the wiring SWL0. Furthermore, a high-level potential is supplied to each of the wiring SWL3b and the wiring SWL4a, and a high-level potential is input to each of the control terminal of the switch SW3b and the control terminal of the switch SW4a. A low-level potential is supplied to each of the wiring SWL3a and the wiring SWL4b, and a low-level potential is input to each of the control terminal of the switch SW3a and the control terminal of the switch SW4b.

Thus, the switch SW0, the switch SW3b, and the switch SW4a are brought into an on state, and the switch SW3a and the switch SW4b are brought into an off state.

In the period from the time T13 to the time T14, an image signal SIG[2] is input from the wiring VDL to the first terminal of the switch SW0. Thus, the image signal SIG[2] is input to the source follower circuit SAMb through the switch SW0 and the switch SW3b. Accordingly, for example, a potential corresponding to the image signal SIG[2] is retained in each of the first terminal of the capacitor C1 and the second terminal of the capacitor C2 that are illustrated in FIG. 27A, and the amplified image signal SIG[2] is output from the output terminal (the terminal OP) of the source follower circuit SAMb. Since the switch SW4b is in an off state, the image signal SIG[2] output from the output terminal (the terminal OP) of the source follower circuit SAMb does not reach the converter circuit CVT.

Meanwhile, for example, the image signal SIG[1] retained in the source follower circuit SAMa in the period from the time T11 to the time T12 is input to the converter circuit CVT from the output terminal of the source follower circuit SAMa through the switch SW4a. Thus, in the period from the time T13 to the time T14, the image signal SIG[1] is converted from digital data into analog data and then input to the pixel circuit PX of the pixel array PXA.

As described above, when the source follower circuit SAMa and the source follower circuit SAMb each having a function of retaining a potential corresponding to an input signal are electrically connected to each other in parallel, one of the source follower circuits can retain the input signal and the other of the source follower circuits can output a signal retained in advance. In a structure in which the first latch circuit LA and the second latch circuit LB are electrically connected to each other in series as illustrated in FIG. 3 or FIG. 4, an image signal might be attenuated; however, with use of the circuit LTCSF described above, the image signal can be temporarily retained and the attenuation of the image signal can be prevented.

Note that the semiconductor device of one embodiment of the present invention is not limited to having the structures of the above-described circuits. The semiconductor device of one embodiment of the present invention may have a structure modified from that of the above-described circuits as appropriate.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 3

In this embodiment, circuit structures applicable to the pixel circuit PX described in Embodiment 1 above are described.

### <Structure Example 1 of Pixel Circuit>

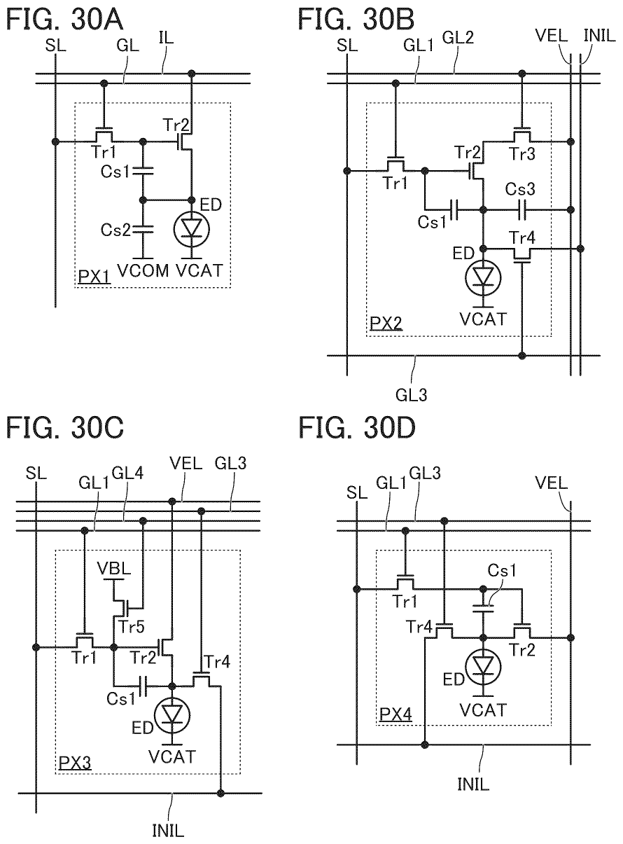

FIG. 30A is a circuit diagram showing a structure example of a circuit that can be used as the pixel circuit PX of the display apparatus DSP described in Embodiment 1.

A pixel circuit PX1 illustrated in FIG. 30A includes a transistor Tr1, a transistor Tr2, a capacitor Cs1, a capacitor Cs2, and a light-emitting device ED, for example.

Examples of the light-emitting device ED include a light-emitting device containing an organic EL material, a light-emitting device containing an inorganic EL material, and a light-emitting diode (e.g., a micro LED (Light Emitting Diode)). The pixel circuit PX1 can be a pixel circuit including one or more selected from the light-emitting devices ED described above. Note that in the description in this embodiment, the pixel circuit PX of the pixel array PXA includes a light-emitting device containing an organic EL material. In particular, the luminance of light emitted from a light-emitting device capable of high luminance light emission can be, for example, higher than or equal to 500 cd/m², preferably higher than or equal to 1000 cd/m² and lower than or equal to 10000 cd/m², further preferably higher than or equal to 2000 cd/m² and lower than or equal to 5000 cd/m².

A first terminal of the transistor Tr1 is electrically connected to the wiring SL, a second terminal of the transistor Tr1 is electrically connected to a gate of the transistor Tr2 and a first terminal of the capacitor Cs1, and a gate of the transistor Tr1 is electrically connected to the wiring GL. A first terminal of the transistor Tr2 is electrically connected to a wiring IL, and a second terminal of the transistor Tr2 is electrically connected to a second terminal of the capacitor Cs1, a first terminal of the capacitor Cs2, and an anode of the light-emitting device ED. A second terminal of the capacitor Cs2 is electrically connected to a wiring VCOM. A cathode of the light-emitting device ED is electrically connected to a wiring VCAT.

The wiring SL is a wiring corresponding to the wiring SLS illustrated in FIG. 1 and the wiring SL[1] to the wiring SL[5] illustrated in FIG. 3 or FIG. 4 and functions as a wiring for transmitting an image signal from the driver circuit SD to the pixel circuit PX1.

The wiring GL is a wiring corresponding to the wiring GLS illustrated in FIG. 1 and the wiring GL[1] to the wiring GL[m] illustrated in FIG. 5 and functions as a wiring for transmitting a selection signal from the driver circuit GD to the pixel circuit PX1.

The wiring IL functions as a wiring for supplying a current to the anode of the light-emitting device ED. Thus, the wiring IL is referred to as a current supply line in some cases.

The wiring VCOM functions as a wiring for supplying a fixed potential to the second terminal of the capacitor Cs2. In particular, the fixed potential is referred to as a common potential in some cases. The common potential can be, for example, a low-level potential, a ground potential, or a negative potential. The wiring VCOM may be a wiring for supplying a common potential also to the second terminal of the capacitor Cs2 provided in another pixel circuit PX1 in the same pixel array PXA.

The wiring VCAT functions as a wiring for supplying a fixed potential to the cathode of the light-emitting device ED. In particular, the fixed potential is referred to as a cathode potential in some cases. The cathode potential can be, for example, a low-level potential, a ground potential, or a negative potential. The wiring VCAT may be a wiring for supplying a cathode potential also to the cathode of the light-emitting device ED provided in another pixel circuit PX1 in the same pixel array PXA.

Note that the common potential supplied by the wiring VCOM and the cathode potential supplied by the wiring VCAT may be potentials equal to each other. In this case, the wiring VCOM and the wiring VCAT may be the same wiring (not illustrated).

The transistor Tr1 functions as a transistor for writing an image signal in the pixel circuit PX. Therefore, in the case where the display apparatus DSP is desired to have a high frame frequency, a transistor having a high driving frequency is preferably used as the transistor Tr1. For example, a transistor including a thin gate insulating film is preferably used as the transistor Tr1. Specifically, for example, the transistor MTHN described in the above embodiment or the transistor MTHN1 or the transistor MTHN2 described in Embodiment 4 is preferably used as the transistor Tr1. Note that in the case where a transistor having high resistance to voltage is desired to be used as the transistor Tr1, the transistor MTCK described in the above embodiment or the transistor MTCK1 or the transistor MTCK2 described in Embodiment 4 may be used, for example.

The transistor Tr2 functions as a driving transistor for controlling the amount of current flowing between the anode and the cathode of the light-emitting device ED in the pixel circuit PX. Therefore, in the case where a potential corresponding to an image signal is a high potential, a transistor having high resistance to voltage is preferably used as the transistor Tr2. For example, a transistor including a thick gate insulating film is preferably used as the transistor Tr2. Specifically, for example, the transistor MTCK described in the above embodiment or the transistor MTCK1 or the transistor MTCK2 described in Embodiment 4 is preferably used as the transistor Tr2. Note that in the case where a transistor having a high driving frequency is desired to be used as the transistor Tr2, the transistor MTHN described in the above embodiment or the transistor MTHN1 or the transistor MTHN2 described in Embodiment 4 may be used, for example.

### <Structure Example 2 of Pixel Circuit>

FIG. 30B is a circuit diagram showing a structure example of a circuit that can be used as the pixel circuit PX of the display apparatus DSP described in Embodiment 1 and is different from the pixel circuit in FIG. 30A.

A pixel circuit PX2 illustrated in FIG. 30B includes the transistor Tr1, the transistor Tr2, a transistor Tr3, a transistor Tr4, the capacitor Cs1, a capacitor Cs3, and the light-emitting device ED, for example.

For the transistor Tr1, the transistor Tr2, the capacitor Cs1, and the light-emitting device ED, the description of the transistor Tr1, the transistor Tr2, the capacitor Cs1, and the light-emitting device ED included in the pixel circuit PX1 can be referred to.

The pixel circuit PX2 not only emits light with an emission intensity corresponding to an input image signal but also has a function of correcting the threshold voltage of the transistor Tr2, which is a driving transistor.

The first terminal of the transistor Tr1 is electrically connected to the wiring SL, the second terminal of the transistor Tr1 is electrically connected to the gate of the transistor Tr2 and the first terminal of the capacitor Cs1, and the gate of the transistor Tr1 is electrically connected to a wiring GL1. The first terminal of the transistor Tr2 is electrically connected to a first terminal of the transistor Tr3, and the second terminal of the transistor Tr2 is electrically connected to the second terminal of the capacitor Cs1, a first terminal of the capacitor Cs3, a first terminal of the transistor Tr4, and the anode of the light-emitting device ED. A second terminal of the transistor Tr3 is electrically connected to a wiring VEL, and a gate of the transistor Tr3 is electrically connected to a wiring GL2. A second terminal of the capacitor Cs3 is electrically connected to the wiring VEL. A second terminal of the transistor Tr4 is electrically connected to a wiring IN1L, and a gate of the transistor Tr4 is electrically connected to a wiring GL3. The cathode of the light-emitting device ED is electrically connected to the wiring VCAT.

For the wiring SL and the wiring VCAT, the description of the wiring SL and the wiring VCAT electrically connected to the pixel circuit PX1 in FIG. 30A can be referred to.

The wiring GL1, the wiring GL2, and the wiring GL3 are wirings corresponding to the wiring GLS illustrated in FIG. 1, and each function as a wiring for transmitting a selection signal from the driver circuit GD to the pixel circuit PX.

The wiring VEL functions as a wiring for supplying a potential to the anode of the light-emitting device ED.

The wiring IN1L functions as a wiring for supplying a potential to the anode of the light-emitting device ED. In particular, the potential can be an initialization potential for resetting the anode potential of the light-emitting device ED, for example.

A transistor having high resistance to voltage is preferably used as each of the transistor Tr3 and the transistor Tr4. For example, a transistor including a thick gate insulating film is preferably used as each of the transistor Tr3 and the transistor Tr4. Specifically, for example, the transistor MTCK described in the above embodiment or the transistor MTCK1 or the transistor MTCK2 described in Embodiment 4 is preferably used as each of the transistor Tr3 and the transistor Tr4. Note that in the case where a transistor having a high driving frequency is desired to be used as each of the transistor Tr3 and the transistor Tr4, the transistor MTHN described in the above embodiment or the transistor MTHN1 or the transistor MTHN2 described in Embodiment 4 may be used, for example.

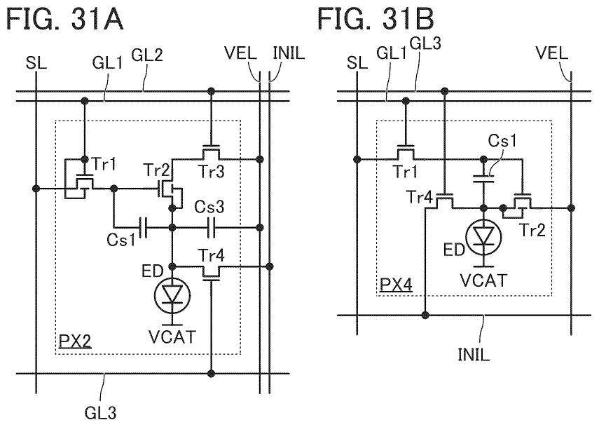

In the pixel circuit PX2, the transistor Tr1 and the transistor Tr2 may each be a transistor including a back gate. Specifically, as illustrated in FIG. 31A, the pixel circuit PX2 may have a structure in which the back gate of the transistor Tr1 is electrically connected to the gate of the transistor Tr1, and the back gate of the transistor Tr2 is electrically connected to the second terminal of the transistor Tr2. In that case, the transistor MTHN1 or the transistor MTHN2 including a back gate electrode and described in Embodiment 4 is preferably used as the transistor Tr1, for example. In addition, the transistor MTCK1 or the transistor MTCK2 including a back gate electrode and described in Embodiment 4 is preferably used as the transistor Tr2, for example.

### <Structure Example 3 of Pixel Circuit>

FIG. 30C is a circuit diagram showing a structure example of a circuit that can be used as the pixel circuit PX of the display apparatus DSP described in Embodiment 1 and is different from the pixel circuits in FIG. 30A and FIG. 30B.

A pixel circuit PX3 illustrated in FIG. 30C includes the transistor Tr1, the transistor Tr2, the transistor Tr4, a transistor Tr5, the capacitor Cs1, and the light-emitting device ED, for example.

For the transistor Tr1, the transistor Tr2, the transistor Tr4, the capacitor Cs1, and the light-emitting device ED, the description of the transistor Tr1, the transistor Tr2, the transistor Tr4, the capacitor Cs1, and the light-emitting device ED included in the pixel circuit PX2 can be referred to.

Like the pixel circuit PX2, the pixel circuit PX3 not only emits light with an emission intensity corresponding to an input image signal but also has a function of correcting the threshold voltage of the transistor Tr2, which is a driving transistor.

The first terminal of the transistor Tr1 is electrically connected to the wiring SL, the second terminal of the transistor Tr1 is electrically connected to the gate of the transistor Tr2, a first terminal of the transistor Tr5, and the first terminal of the capacitor Cs1, and the gate of the transistor Tr1 is electrically connected to the wiring GL1. The first terminal of the transistor Tr2 is electrically connected to the wiring VEL, and the second terminal of the transistor Tr2 is electrically connected to the second terminal of the capacitor Cs1, the first terminal of the transistor Tr4, and the anode of the light-emitting device ED. A second terminal of the transistor Tr5 is electrically connected to a wiring VBL, and a gate of the transistor Tr5 is electrically connected to a wiring GL4. The second terminal of the transistor Tr4 is electrically connected to the wiring IN1L, and the gate of the transistor Tr4 is electrically connected to the wiring GL3. The cathode of the light-emitting device ED is electrically connected to the wiring VCAT.

For the wiring SL, the wiring VCAT, the wiring VEL, and the wiring IN1L, the description of the wiring SL, the wiring VCAT, the wiring VEL, and the wiring IN1L that are electrically connected to the pixel circuit PX2 in FIG. 30B can be referred to.

The wiring GL1, the wiring GL3, and the wiring GL4 are wirings corresponding to the wiring GLS illustrated in FIG. 1, and each function as a wiring for transmitting a selection signal from the driver circuit GD to the pixel circuit PX.

The wiring VBL functions as a wiring for supplying a fixed potential to the first terminal of the capacitor Cs1. The fixed potential is, for example, a potential input to the gate of the transistor Tr2 in correction of the threshold voltage of the transistor Tr2, and is preferably substantially equal to a potential supplied by the wiring VEL.

A transistor having high resistance to voltage is preferably used as the transistor Tr5. For example, a transistor including a thick gate insulating film is preferably used as the transistor Tr5. Specifically, for example, the transistor MTCK described in the above embodiment or the transistor MTCK1 or the transistor MTCK2 described in Embodiment 4 is preferably used as the transistor Tr5. Note that in the case where a transistor having a high driving frequency is desired to be used as the transistor Tr5, the transistor MTHN described in the above embodiment or the transistor MTHN1 or the transistor MTHN2 described in Embodiment 4 may be used, for example.

### <Structure Example 4 of Pixel Circuit>

FIG. 30D is a circuit diagram showing a structure example of a circuit that can be used as the pixel circuit PX of the display apparatus DSP described in Embodiment 1 and is different from the pixel circuits in FIG. 30A to FIG. 30C.

A pixel circuit PX4 illustrated in FIG. 30D includes the transistor Tr1, the transistor Tr2, the transistor Tr4, the capacitor Cs1, and the light-emitting device ED, for example.

For the transistor Tr1, the transistor Tr2, the transistor Tr4, the capacitor Cs1, and the light-emitting device ED, the description of the transistor Tr1, the transistor Tr2, the transistor Tr4, the capacitor Cs1, and the light-emitting device ED included in the pixel circuit PX3 can be referred to.

Like the pixel circuit PX1, the pixel circuit PX4 also has a function of emitting light with an emission intensity corresponding to an input image signal.

The first terminal of the transistor Tr1 is electrically connected to the wiring SL, the second terminal of the transistor Tr1 is electrically connected to the gate of the transistor Tr2 and the first terminal of the capacitor Cs1, and the gate of the transistor Tr1 is electrically connected to a wiring GL1. The first terminal of the transistor Tr2 is electrically connected to the wiring VEL, and the second terminal of the transistor Tr2 is electrically connected to the second terminal of the capacitor Cs1, the first terminal of the transistor Tr4, and the anode of the light-emitting device ED. The second terminal of the transistor Tr4 is electrically connected to the wiring IN1L, and the gate of the transistor Tr4 is electrically connected to the wiring GL3. The cathode of the light-emitting device ED is electrically connected to the wiring VCAT.

For the wiring SL, the wiring VCAT, the wiring IN1L, the wiring GL1, and the wiring GL3, the description of the wiring SL and the wiring VCAT electrically connected to the pixel circuit PX3 in FIG. 30C can be referred to.

In the pixel circuit PX4, the transistor Tr2 may be a transistor including a back gate. Specifically, as illustrated in FIG. 31B, the pixel circuit PX4 may have a structure in which the back gate of the transistor Tr2 is electrically connected to the second terminal of the transistor Tr2. In that case, the transistor MTCK1 or the transistor MTCK2 including a back gate electrode and described in the above embodiment is preferably used as the transistor Tr2, for example.

### <Structure Example 5 of Pixel Circuit>

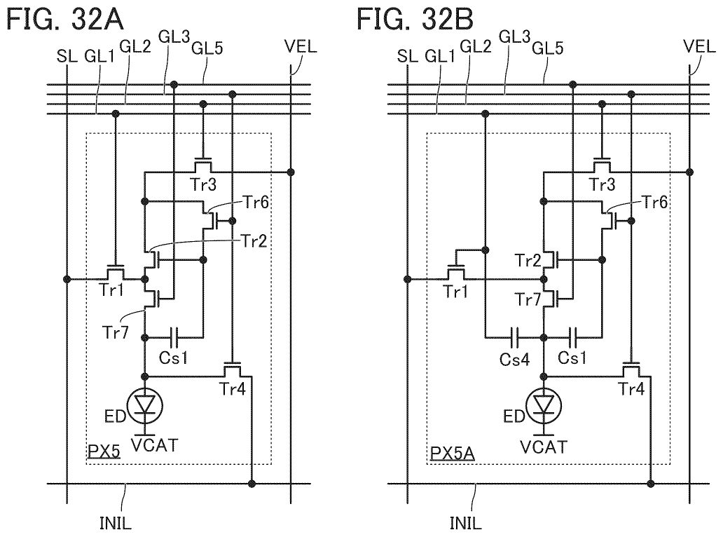

FIG. 32A is a circuit diagram showing a structure example of a circuit that can be used as the pixel circuit PX of the display apparatus DSP described in Embodiment 1 and is different from the pixel circuits in FIG. 30A to FIG. 30D.

A pixel circuit PX5 illustrated in FIG. 32A includes the transistor Tr1 to the transistor Tr4, a transistor Tr6, a transistor Tr7, the capacitor Cs1, and the light-emitting device ED, for example.

For the transistor Tr1 to the transistor Tr4, the capacitor Cs1, and the light-emitting device ED, the description of the transistor Tr1 to the transistor Tr4, the capacitor Cs1, and the light-emitting device ED included in the pixel circuit PX2 can be referred to.

Like the pixel circuit PX2 and the pixel circuit PX3, the pixel circuit PX5 not only emits light with an emission intensity corresponding to an input image signal but also has a function of correcting the threshold voltage of the transistor Tr2, which is a driving transistor.

The first terminal of the transistor Tr1 is electrically connected to the wiring SL, the second terminal of the transistor Tr1 is electrically connected to the first terminal of the transistor Tr2 and a first terminal of the transistor Tr7, and the gate of the transistor Tr1 is electrically connected to the wiring GL1. The second terminal of the transistor Tr2 is electrically connected to the first terminal of the transistor Tr3 and a first terminal of the transistor Tr6, and the gate of the transistor Tr2 is electrically connected to a second terminal of the transistor Tr6 and the first terminal of the capacitor Cs1. The second terminal of the transistor Tr3 is electrically connected to the wiring VEL, and the gate of the transistor Tr3 is electrically connected to the wiring GL2. A gate of the transistor Tr6 is electrically connected to the gate of the transistor Tr4 and the wiring GL3. A second terminal of the transistor Tr7 is electrically connected to the first terminal of the transistor Tr4, the second terminal of the capacitor Cs1, and the anode of the light-emitting device ED. The second terminal of the transistor Tr4 is electrically connected to the wiring IN1L. The cathode of the light-emitting device ED is electrically connected to the wiring VCAT.

For the wiring SL, the wiring VCAT, the wiring VEL, and the wiring IN1L, the description of the wiring SL, the wiring VCAT, the wiring VEL, and the wiring IN1L that are electrically connected to the pixel circuit PX2 in FIG. 30B can be referred to.

The wiring GL1, the wiring GL2, the wiring GL3, and the wiring GL5 are wirings corresponding to the wiring GLS illustrated in FIG. 1, and each function as a wiring for transmitting a selection signal from the driver circuit GD to the pixel circuit PX.

A transistor having high resistance to voltage is preferably used as each of the transistor Tr6 and the transistor Tr7. For example, a transistor including a thick gate insulating film is preferably used as each of the transistor Tr6 and the transistor Tr7. Specifically, for example, the transistor MTCK described in the above embodiment or the transistor MTCK1 or the transistor MTCK2 described in Embodiment 4 is preferably used as each of the transistor Tr6 and the transistor Tr7. Note that in the case where a transistor having a high driving frequency is desired to be used as each of the transistor Tr6 and the transistor Tr7, the transistor MTHN described in the above embodiment or the transistor MTHN1 or the transistor MTHN2 described in Embodiment 4 may be used, for example.

Note that the pixel circuit of the semiconductor device of one embodiment of the present invention is not limited to having the structure of the pixel circuit PX5 illustrated in FIG. 32A, and may have a circuit structure modified from that of the pixel circuit PX5 as appropriate.

For example, like a pixel circuit PX5A illustrated in FIG. 32B, the pixel circuit PX5 in FIG. 32A may be provided with a capacitor Cs4. A first terminal of the capacitor Cs4 is electrically connected to the gate of the transistor Tr1 and the wiring GL1, and a second terminal of the capacitor Cs4 is electrically connected to the first terminal of the transistor Tr4, the second terminal of the transistor Tr7, the second terminal of the capacitor Cs1, and the anode of the light-emitting device ED.

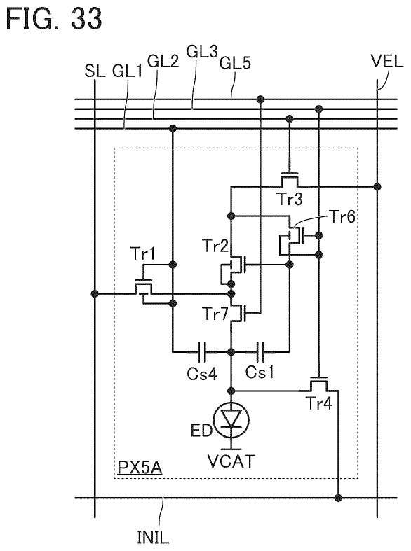

In the pixel circuit PX5A, the transistor Tr1, the transistor Tr2, and the transistor Tr6 may each be a transistor including a back gate. Specifically, as illustrated in FIG. 33, the pixel circuit PX5A may have a structure in which the back gate of the transistor Tr1 is electrically connected to the gate of the transistor Tr1, the back gate of the transistor Tr2 is electrically connected to the second terminal of the transistor Tr2, and the back gate of the transistor Tr6 is electrically connected to the gate of the transistor Tr6. In that case, the transistor MTHN1 or the transistor MTHN2 including a back gate electrode and described in Embodiment 4 is preferably used as the transistor Tr1, for example. In addition, the transistor MTCK1 or the transistor MTCK2 including a back gate electrode and described in Embodiment 4 is preferably used as each of the transistor Tr2 and the transistor Tr6, for example.

### <Structure Example 6 of Pixel Circuit>

In Structure example 1 of pixel circuit to Structure example 5 of pixel circuit above, the structure examples of the pixel circuit PX including the light-emitting device ED are described; for another example, the pixel circuit PX provided in the display apparatus DSP described in Embodiment 1 above may include a liquid crystal display device.

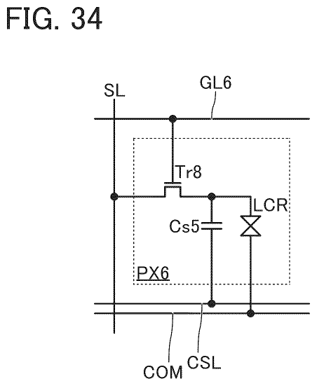

A pixel circuit PX6 illustrated in FIG. 34 is a pixel circuit that can be used as the pixel circuit PX described in Embodiment 1 above and is different from the pixel circuit PX1 to the pixel circuit PX5 and the pixel circuit PX5A in including a liquid crystal display device LCR.

The pixel circuit PX6 includes a transistor Tr8, a capacitor Cs5, and the liquid crystal display device LCR, for example.

A first terminal of the transistor Tr8 is electrically connected to a first terminal of the capacitor Cs5 and a first terminal of the liquid crystal display device LCR, a second terminal of the transistor Tr8 is electrically connected to the wiring SL, and a gate of the transistor Tr8 is electrically connected to a wiring GL6. A second terminal of the capacitor Cs5 is electrically connected to a wiring CSL. A second terminal of the liquid crystal display device LCR is electrically connected to a wiring COM.

The wiring SL is a wiring corresponding to the wiring SLS illustrated in FIG. 1 and the wiring SL[1] to the wiring SL[5] illustrated in FIG. 3 or FIG. 4 and functions as a wiring for transmitting an image signal from the driver circuit SD to the pixel circuit PX6.

The wiring GL6 is a wiring corresponding to the wiring GLS illustrated in FIG. 1 and the wiring GL[1] to the wiring GL[m] illustrated in FIG. 5 and functions as a wiring for transmitting a selection signal from the driver circuit GD to the pixel circuit PX6.

The wiring CSL functions as a wiring for supplying a fixed potential to the second terminal of the capacitor Cs5. The fixed potential can be, for example, a low-level potential, a ground potential, or a negative potential. The wiring CSL may be a wiring for supplying a common potential also to the second terminal of the capacitor Cs2 provided in another pixel circuit PX1 in the same pixel array PXA.

The wiring COM functions as a wiring for supplying a fixed potential to the second terminal of the liquid crystal display device LCR. In particular, the fixed potential is referred to as a common potential in some cases. The common potential can be, for example, a low-level potential, a ground potential, or a negative potential. The wiring COM may be a wiring for supplying a common potential also to the second terminal of the liquid crystal display device LCR provided in another pixel circuit PX6 in the same pixel array PXA.

Note that the fixed potential supplied by the wiring CSL and the common potential supplied by the wiring COM may be potentials equal to each other. In this case, the wiring CSL and the wiring COM may be the same wiring (not illustrated).

The transistor Tr8 functions as a transistor for writing an image signal in the pixel circuit PX6. Therefore, in the case where the display apparatus DSP is desired to have a high frame frequency, a transistor having a high driving frequency is preferably used as the transistor Tr8. For example, a transistor including a thin gate insulating film is preferably used as the transistor Tr8. Specifically, for example, the transistor MTHN described in the above embodiment or the transistor MTHN1 or the transistor MTHN2 described in Embodiment 4 is preferably used as the transistor Tr8. Note that in the case where a transistor having high resistance to voltage is desired to be used as the transistor Tr8, the transistor MTCK described in the above embodiment or the transistor MTCK1 or the transistor MTCK2 described in Embodiment 4 may be used, for example.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 4

In this embodiment, a method for manufacturing the transistor MTCK having high resistance to a high voltage and the transistor MTHN having a high driving frequency, which are described in the above embodiment, will be described.

### <Manufacturing Method Example>

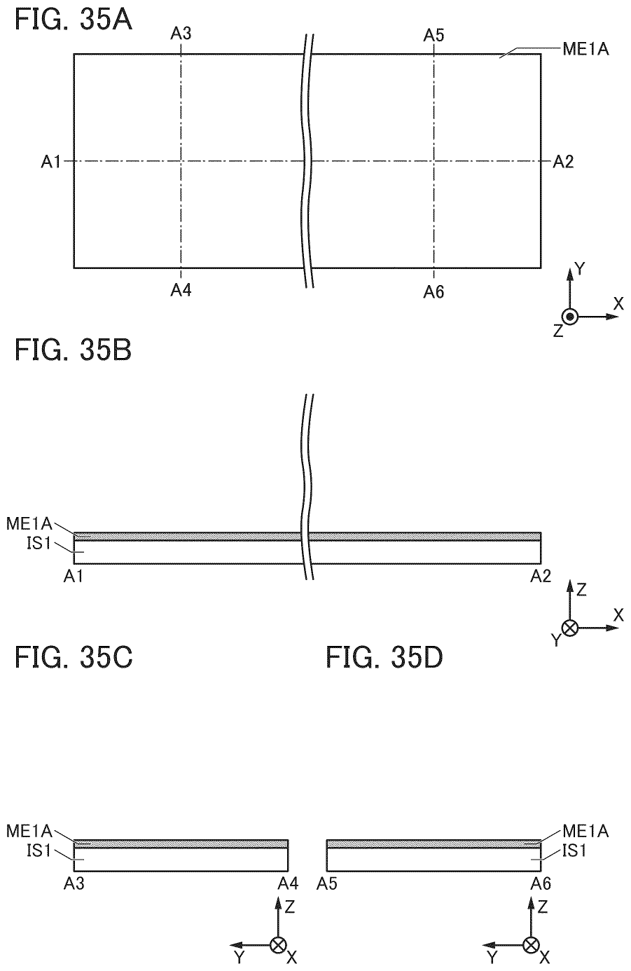

An example of the method for manufacturing the transistor MTCK and the transistor MTHN that are illustrated in FIG. 2A to FIG. 2D is described with reference to FIG. 35A to FIG. 45D.

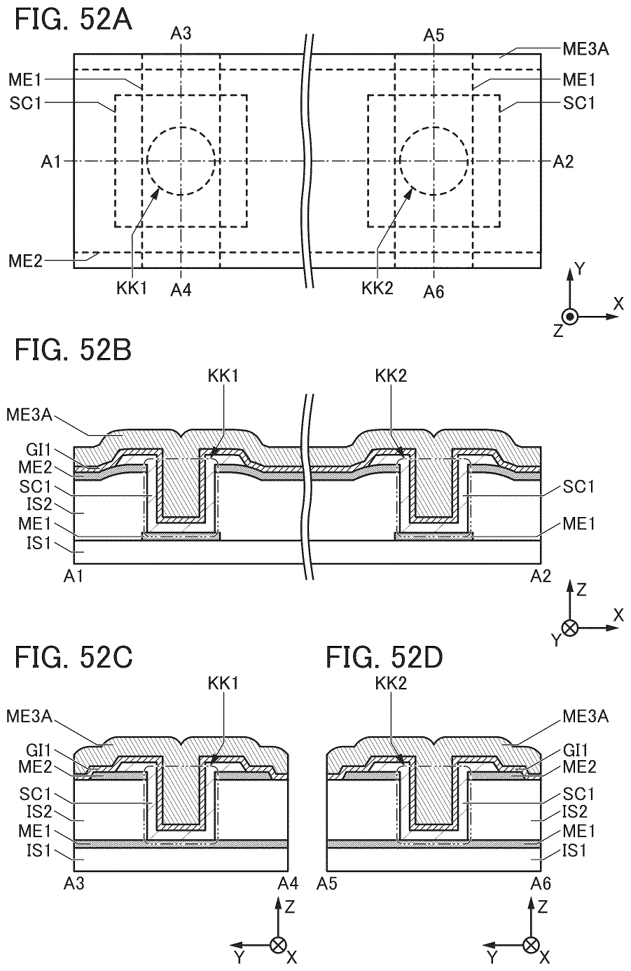

In each of FIG. 35A to FIG. 45D, A is a schematic plan view. Moreover, B of each drawing is a schematic cross-sectional view corresponding to a portion along the dashed-dotted line A1-A2 illustrated in A of the corresponding drawing, and is also a schematic cross-sectional view in the X direction. Furthermore, C of each drawing is a schematic cross-sectional view corresponding to a portion along the dashed-dotted line A3-A4 illustrated in A of the corresponding drawing, and is also a schematic cross-sectional view in the Y direction. Furthermore, D of each drawing is a schematic cross-sectional view corresponding to a portion along the dashed-dotted line A5-A6 illustrated in A of the corresponding drawing, and is also a schematic cross-sectional view in the Y direction. Note that for clarity of the drawing, some components are not illustrated in the schematic plan view of A of each drawing. The above description is also referred to for FIG. 52A to FIG. 56D and FIG. 65A to FIG. 73D, which are not described in this manufacturing method example.

Hereinafter, a film of an insulating material for forming an insulator, a film of a conductive material for forming a conductor, or a film of a semiconductor material for forming a semiconductor can be formed by a film formation method such as a sputtering method, a CVD method, an MBE (Molecular Beam Epitaxy) method, a PLD method, or an ALD method as appropriate.

First, a substrate (not illustrated) is prepared, and the insulator IS1 and a conductive film ME1A are formed in this order over the substrate (see FIG. 35A to FIG. 35D).

As the substrate, a semiconductor substrate (e.g., a single crystal substrate containing silicon or germanium as a material) can be used, for example. Besides the semiconductor substrate, for example, an SOI (Silicon On Insulator) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, or paper or a base material film containing a fibrous material can be used as the substrate. Examples of the glass substrate include barium borosilicate glass, aluminoborosilicate glass, and soda lime glass. As examples of the flexible substrate, the attachment film, and the base material film, the following is given. Examples include plastics typified by polyethylene terephthalate (PET), polyethylene naphthalate (PEN), polyethersulfone (PES), and polytetrafluoroethylene (PTFE). Another example is a synthetic resin such as an acrylic resin. Other examples include polypropylene, polyester, polyvinyl fluoride, and polyvinyl chloride. Other examples include polyamide, polyimide, aramid, an epoxy resin, an inorganic vapor deposition film, and paper. Note that in the case where the manufacturing process of the display apparatus DSP in Embodiment 1 involves heat treatment, a highly heat-resistant substrate is preferably selected as the substrate. Alternatively, these substrates provided with elements may be used. Examples of the element provided for the substrate include a capacitor, a resistor, a switching element, a light-emitting element, and a storage element.

The insulator IS1 functions as an interlayer film, for example. For the insulator IS1 functioning as an interlayer film, silicon oxide, silicon oxynitride, silicon nitride oxide, or silicon nitride can be used, for example. Alternatively, for the insulator IS1, silicon oxide to which fluorine is added, silicon oxide to which carbon is added, silicon oxide to which carbon and nitrogen are added, or porous silicon oxide can be used, for example. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed. Alternatively, for the insulator IS1, a resin can be used, for example. A material used for the insulator IS1 may be an appropriate combination of the above-described insulating materials.

An insulating material with a low relative permittivity is preferably used for the insulator IS1. When an insulating material with a low relative permittivity is used for an interlayer film, parasitic capacitance generated between wirings can be reduced. Specifically, the relative permittivity of the insulator IS1 is preferably lower than 4, further preferably lower than 3, for example. Examples of an insulating material with a low relative permittivity include silicon oxide, silicon oxynitride, and silicon nitride oxide.

The conductive film ME1A is a film to be the conductor ME1 in a later step. Part of the conductor ME1 functions also as one of the source electrode and the drain electrode of the transistor MTCK. Similarly, another part of the conductor ME1 functions also as one of the source electrode and the drain electrode of the transistor MTHN. Therefore, a material having high conductivity is preferably used for the conductive film ME1A.

For the conductive film ME1A, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing two or more selected from the above metal elements; or an alloy containing a combination of two or more selected from the above metal elements, for example. Alternatively, for the conductive film ME1A, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, or an oxide containing lanthanum and nickel, for example. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. As the conductor, a semiconductor having high electrical conductivity, typified by polycrystalline silicon containing an impurity element (e.g., phosphorus or arsenic), or silicide (e.g., nickel silicide) may be used, for example.

A stack of a plurality of conductive films formed of the above-described materials may be used. For example, a stacked-layer structure combining a material containing the above metal element and a conductive material containing oxygen may be employed. Alternatively, a stacked-layer structure combining a material containing the above metal element and a conductive material containing nitrogen may be employed. A stacked-layer structure combining a material containing the above metal element, a conductive material containing oxygen, and a conductive material containing nitrogen may be employed.

The conductor ME1 may include, for example, a first conductor and a second conductor surrounded by the first conductor (not illustrated). For the first conductor, any of titanium, titanium nitride, tantalum, tantalum nitride, ruthenium, and ruthenium oxide, which are conductive materials having a function of inhibiting diffusion of oxygen, may be used, and for the second conductor, a conductive material containing any of tungsten, copper, and aluminum, which have high conductivity, as its main component may be used. When the second conductor is surrounded by the first conductor, a reduction in conductivity due to oxidation of the first conductor can be prevented.

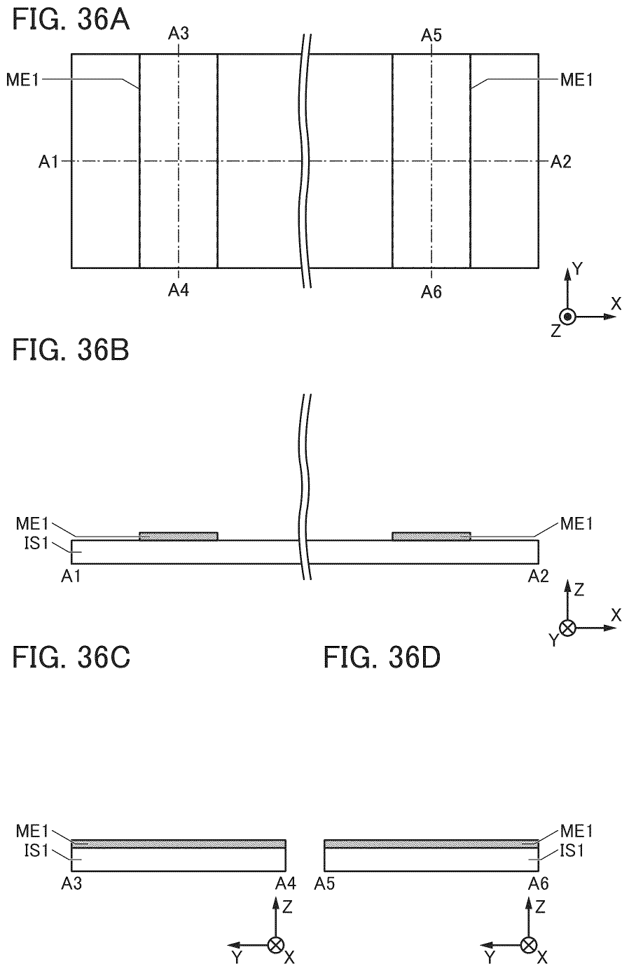

Next, the conductive film ME1A is processed into a band shape by a lithography method to form the conductor ME1 (see FIG. 36A to FIG. 36D). In particular, here, the conductor ME1 is formed so that part of the conductor ME1 can extend in a direction parallel to the dashed-dotted line A3-A4 (the Y direction) and another part of the conductor ME1 can extend in a direction parallel to the dashed-dotted line A5-A6 (the Y direction). A dry etching method or a wet etching method can be employed for the processing, and processing by a dry etching method is particularly suitable for microfabrication.

Note that in a lithography method, first, a resist is exposed to light through a mask. Next, a region exposed to light is removed or left using a developing solution, so that a resist mask is formed. Then, etching treatment through the resist mask is performed, whereby a conductor, a semiconductor, an insulator, or the like can be processed into a desired shape. The resist mask is formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that a mask is unnecessary in the case of using an electron beam or an ion beam. The resist mask can be removed by dry etching treatment such as ashing, wet etching treatment, wet etching treatment after dry etching treatment, or dry etching treatment after wet etching treatment.

In addition, a hard mask formed of an insulator or a conductor may be used under the resist mask. In the case of using a hard mask, a hard mask with a desired shape can be formed in the following manner: an insulating film or a conductive film that is the hard mask material is formed over the conductive film ME1A, a resist mask is formed thereover, and then the hard mask material is etched. The etching of the conductive film ME1A and the like may be performed after removing the resist mask or with the resist mask remaining. In the latter case, the resist mask sometimes disappears during the etching. The hard mask may be removed by etching after the etching of the conductive film ME1A and the like. Meanwhile, the hard mask is not necessarily removed in the case where the hard mask material does not affect later steps or can be utilized in later steps.

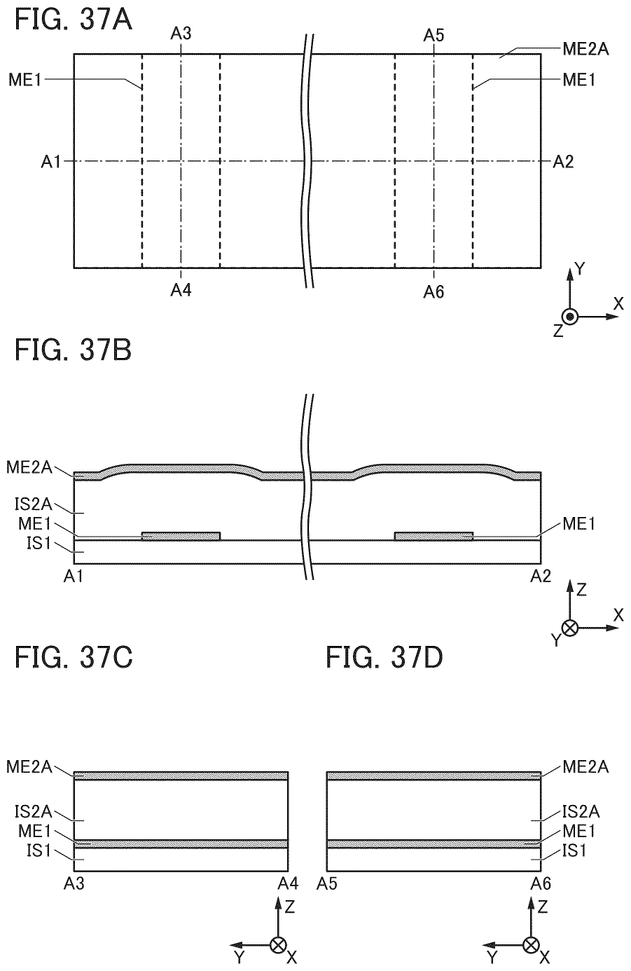

Next, an insulating film IS2A is formed over the conductor ME1 (see FIG. 37A to FIG. 37D). The insulating film IS2A can be formed by a film formation method such as a sputtering method, a CVD method, an MBE method, a PLD method, or an ALD method, for example. After the insulating film IS2A is formed, planarization treatment may be performed on the insulating film IS2A by a chemical mechanical polishing (CMP) method or the like to planarize the top surface of the insulating film IS2A (not illustrated).

The insulating film IS2A is a film to be the insulator IS2 in a later step. The insulator IS2 functions as an interlayer film, for example. Thus, the insulator IS2 preferably contains an insulating material with a low relative permittivity. When an insulating material with a low relative permittivity is used for an interlayer film, parasitic capacitance generated between wirings can be reduced.

For the insulating film IS2A, a material that can be used for the insulator IS1 can be used, for example. In particular, in the case where the semiconductor SC1 formed in a later step is a metal oxide functioning as an oxide semiconductor, any of silicon oxide, silicon oxynitride, and porous silicon oxide is preferably used for the insulating film IS2A, for example. With these materials, a region containing oxygen released by heating can be easily formed, and the released oxygen can be supplied to the metal oxide. This reduces the carrier concentration of the metal oxide at the interface between the semiconductor SC1 and the insulator IS2 in contact with each other and the vicinity of the interface, so that the interface and the vicinity of the interface in the semiconductor SC1 become i-type or substantially i-type. Accordingly, the interface and the vicinity of the interface in the semiconductor SC1 function as the channel formation region in the transistor MTCK or the transistor MTHN.

Next, a conductive film ME2A is formed over the insulating film IS2A (see FIG. 37A to FIG. 37D).

The conductive film ME2A is a film to be the conductor ME2 in a later step. Part of the conductor ME2 functions also as the other of the source electrode and the drain electrode of the transistor MTCK. Another part of the conductor ME2 functions also as the other of the source electrode and the drain electrode of the transistor MTHN. Therefore, a material having high conductivity is preferably used for the conductive film ME2A.

For the conductive film ME2A, a material that can be used for the conductor ME1 can be used, for example.

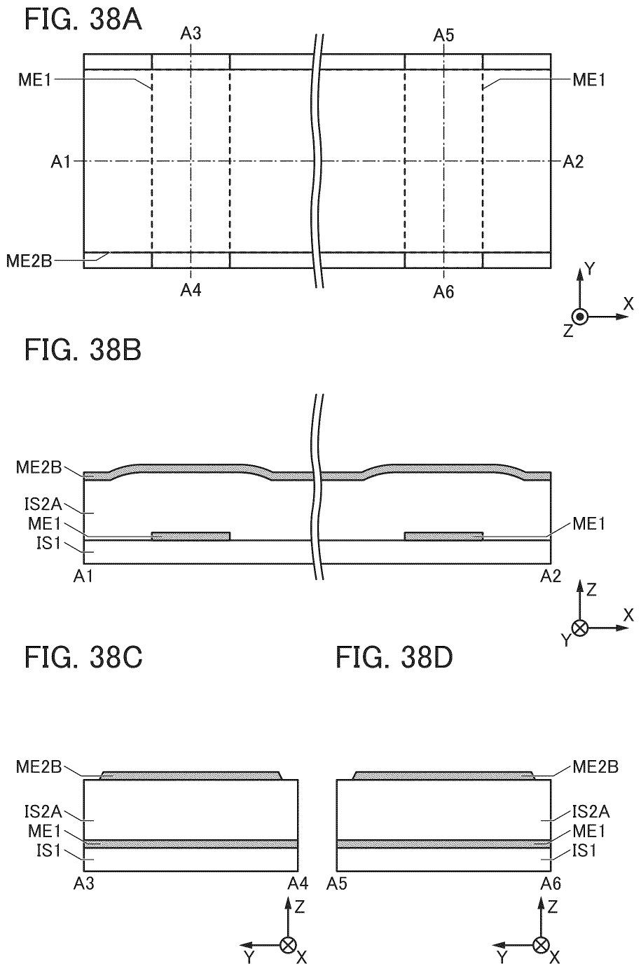

Next, the conductive film ME2A is processed into a band shape by a lithography method to form a conductive film ME2B (see FIG. 38A to FIG. 38D). In particular, here, the conductive film ME2B is formed so as to extend in a direction parallel to the dashed-dotted line A1-A2 (the X direction) and include a region overlapping with part of the conductor ME1. For the lithography method, the lithography method described with reference to FIG. 36A to FIG. 36D can be referred to.

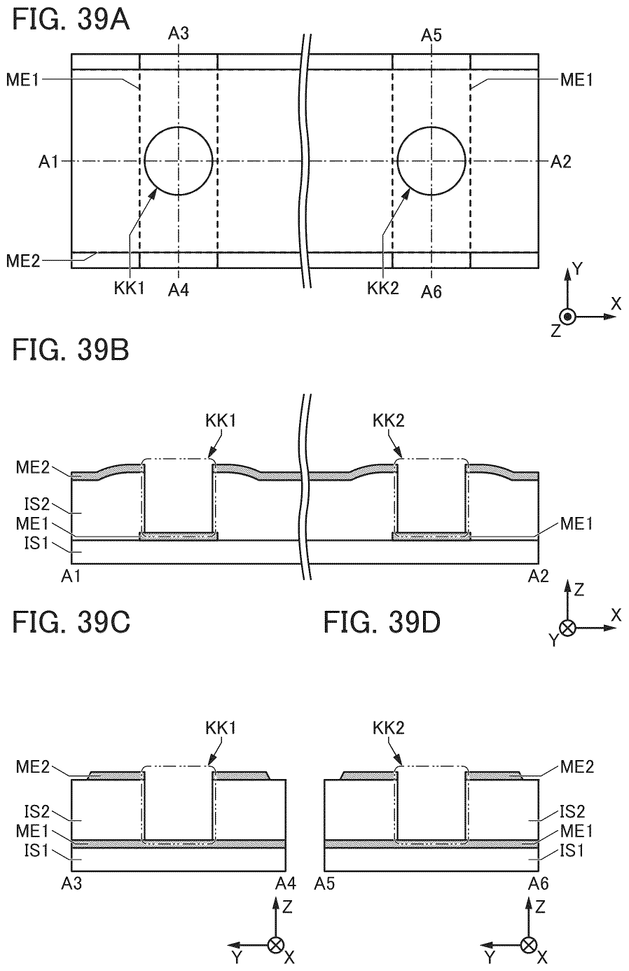

Next, the insulating film IS2A and the conductive film ME2B are processed by a lithography method to form the insulator IS2 and the conductor ME2 having the opening KK1 and the opening KK2 (see FIG. 39A to FIG. 39D). A dry etching method or a wet etching method can be employed for the processing, and processing by a dry etching method is particularly suitable for microfabrication. The insulating film IS2A and the conductive film ME2B may be processed under different conditions.

In FIG. 39A to FIG. 39D, the opening KK1 or the opening KK2 has a tapered shape with a taper angle (greater than or equal to 70° and less than or equal to 110°) with which the opening is substantially perpendicular to the X-Y plane, for example. Alternatively, the opening KK1 or the opening KK2 may have a tapered shape with a taper angle greater than or equal to 30° and less than 70° or a taper angle greater than 0° and less than 30° with respect to the X-Y plane, for example.

Note that in this specification and the like, a tapered shape refers to a shape in which at least part of a side surface of a structure is inclined to a substrate surface. An angle formed between an inclined side surface and a substrate surface is referred to as a taper angle. Specifically, in this specification and the like, a tapered shape having a taper angle greater than 0° and less than or equal to 90° is referred to as a forward tapered shape, and a tapered shape having a taper angle greater than 90° and less than 180° is referred to as an inverse tapered shape.

Although the shape of each of the opening KK1 and the opening KK2 in the plan view is a circle in FIG. 39A, the shape may be a shape with a curve (e.g., an ellipse or a triangle, a quadrangle, a pentagon, or the like with a rounded corner) or a shape with a corner (a polygon such as a triangle, a quadrangle, or a pentagon).

A by-product generated in the above etching step is sometimes formed in a layered manner on the side surfaces of the opening KK1 and the opening KK2 (the side surfaces of the insulator IS2 and the conductor ME2). In that case, the layered by-product is formed between the insulator IS2 and the conductor ME2 and a semiconductor film SC1A described later. Hence, the layered by-product formed in contact with the insulator IS2 and the conductor ME2 is preferably removed.

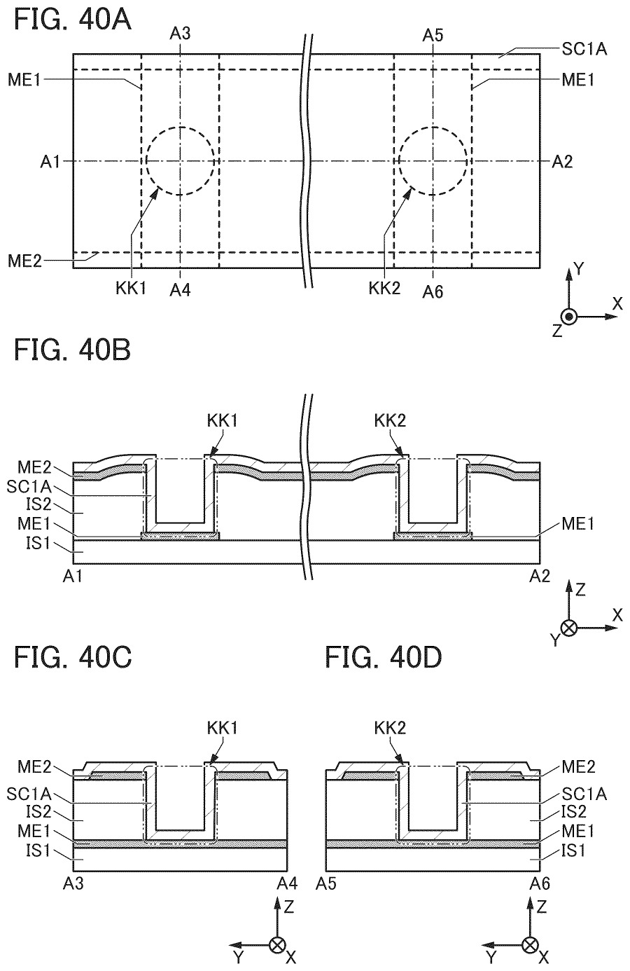

Next, the semiconductor film SC1A is formed over the conductor ME1, the insulator IS2, and the conductor ME2 (see FIG. 40A to FIG. 40D). Specifically, the semiconductor film SC1A is formed on the top surface of the conductor ME1, the side surface of the insulator IS2, and the side surface of the conductor ME2 inside the opening KK1 and the opening KK2. In addition, the semiconductor film SC1A is formed on the top surface of the conductor ME2 and the top surface of the insulator IS2 outside the opening KK1 and the opening KK2. That is, the semiconductor film SC1A is formed on the bottom surface and the inner side surface of the opening KK1 and the bottom surface and the inner side surface of the opening KK2 and over the conductor ME2 and the insulator IS2. The semiconductor film SC1A can be formed by a film formation method such as a sputtering method, a CVD method, an MBE method, a PLD method, or an ALD method. The semiconductor film SC1A is preferably formed by an ALD method. As described above, it is preferable to form the semiconductor film SC1A to have a small thickness, and an unevenness of the thickness needs to be reduced. Meanwhile, since an ALD method is a film formation method in which a precursor and a reactant (e.g., oxidizer) are alternately introduced and the thickness can be adjusted with the number of repetition times of the cycle, accurate control of the thickness is possible. Furthermore, as illustrated in FIG. 40B and FIG. 40D, the semiconductor film SC1A needs to be formed on the bottom surface and the inner side surface of the opening KK1 and the bottom surface and the inner side surface of the opening KK2 so as to have good coverage. In particular, it is preferable that the semiconductor film SC1A be formed with good coverage on the top surface of the conductor ME1 and the side surface of the conductor ME2 in each of the opening KK1 and the opening KK2. By an ALD method, atomic layers can be deposited one by one on the bottom surface and the side surface of each of the openings, whereby the semiconductor film SC1A can be formed in each of the openings with good coverage.

In the case where the side surface of the opening KK1 or the opening KK2 has a tapered shape, the method for forming the semiconductor film SC1A is not limited to an ALD method. For example, a sputtering method may be employed.

The semiconductor film SC1A is a film to be the semiconductor SC1 in a later step. Part of the semiconductor SC1 functions as the channel formation region of each of the transistor MTCK and the transistor MTHN that are formed in a later step. Another part of the semiconductor SC1 may function as one of a pair of electrodes of the capacitor C1 that is formed in a later step.

The semiconductor film SC1A can be a metal oxide functioning as an oxide semiconductor, for example. In this case, the transistor MTCK and the transistor MTHN are OS transistors. The metal oxide preferably contains at least indium or zinc, for example. In particular, indium and zinc are preferably contained. In addition to them, an element M is preferably contained. As the element M, one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, magnesium, cobalt, and antimony can be used. In particular, the element M is preferably one or more of aluminum, gallium, yttrium, and tin. The element M further preferably contains one or both of gallium and tin.

For the semiconductor film SC1A, for example, an In—Ga—Zn oxide is preferably used. In particular, the In—Ga—Zn oxide is further preferably a metal oxide with a composition of In:Ga:Zn=1:1:1 [atomic ratio] or in the neighborhood thereof, a composition of 4:2:3 [atomic ratio] or in the neighborhood thereof, or a composition of 3:1:2 [atomic ratio] or in the neighborhood thereof. For another example, an In—Zn oxide is preferably used for the semiconductor film SC1A. In particular, the In—Zn oxide is further preferably a metal oxide with a composition of In:Zn=4:1 [atomic ratio] or in the neighborhood thereof.

An oxide semiconductor having a low carrier concentration is particularly preferably used for the semiconductor film SC1A. For example, the carrier concentration in an oxide semiconductor in the channel formation region is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film also be reduced. Examples of the impurity include hydrogen and nitrogen. Note that an impurity in an oxide semiconductor refers to, for example, an element other than the main components of the oxide semiconductor. For example, an element with a concentration lower than 0.1 atomic % can be regarded as an impurity.

A transistor including an oxide semiconductor (an OS transistor) is likely to change its electrical characteristics when impurities or oxygen vacancies (hereinafter sometimes referred to as V_{O}) exist in a channel formation region in the oxide semiconductor, which might degrade the reliability. In the OS transistor, a defect that is V_{O} in the oxide semiconductor into which hydrogen enters (hereinafter sometimes referred to as V_{O}H) may be formed and may generate an electron serving as a carrier. When V_{O}H is formed in the channel formation region, the donor concentration in the channel formation region increases in some cases. As the donor concentration in the channel formation region increases, the threshold voltage might vary. Accordingly, when the channel formation region in the oxide semiconductor includes V_{O}, the transistor tends to be normally-on (a state where a channel exists and a current flows through the transistor even when the gate-source voltage is 0 V). Therefore, impurities, oxygen vacancies, and V_{O}H are preferably reduced as much as possible in the channel formation region in the oxide semiconductor.

The semiconductor film SC1A preferably has a stacked-layer structure of a plurality of oxide layers that differ in the atomic ratio of metal atoms. As the metal oxide, for example, a first metal oxide and a second metal oxide formed over the first metal oxide are considered. For example, in the case where the metal oxides each contain at least indium (In) and the element M, the proportion of the number of atoms of the element M contained in the first metal oxide to the number of atoms of all elements that constitute the first metal oxide is preferably higher than the proportion of the number of atoms of the element M contained in the second metal oxide to the number of atoms of all elements that constitute the second metal oxide. In addition, the atomic ratio of the element M to In in the first metal oxide is preferably greater than the atomic ratio of the element M to In in the second metal oxide.

The energy of the conduction band minimum of the first metal oxide is preferably higher than the energy of the conduction band minimum of the second metal oxide. In other words, the electron affinity of the first metal oxide is preferably smaller than the electron affinity of the second metal oxide.

Here, the energy level of the conduction band minimum gently changes at junction portions between the first metal oxide and the second metal oxide. In other words, at junction portions between the first metal oxide and the second metal oxide, the energy level of the conduction band minimum continuously changes or the energy levels are continuously connected. This can be achieved by decreasing the density of defect states in a mixed layer formed at the interface between the first metal oxide and the second metal oxide.

Specifically, when the first metal oxide and the second metal oxide contain the same element (as a main component) in addition to oxygen, a mixed layer with a low density of defect states can be formed. For example, an In—Ga—Zn oxide (indium-gallium-zinc oxide), a Ga—Zn oxide, or gallium oxide can be used as the first metal oxide, in the case where the second metal oxide is an In—Ga—Zn oxide.

Specifically, as the first metal oxide, a metal oxide with a composition of In:Ga:Zn=1:3:4 [atomic ratio] or in the neighborhood thereof, 1:3:2 [atomic ratio] or in the neighborhood thereof, or 1:1:0.5 [atomic ratio] or in the neighborhood thereof can be used. As the second metal oxide, a metal oxide with a composition of In:Ga:Zn=1:1:1 [atomic ratio] or in the neighborhood thereof, 4:2:3 [atomic ratio] or in the neighborhood thereof, or 3:1:2 [atomic ratio] or in the neighborhood thereof can be used. Note that a composition in the neighborhood includes the range of ±30% of an intended atomic ratio.

In this case, the second metal oxide serves as a main carrier path. When the first metal oxide has the above structure, the density of defect states at the interface between the first metal oxide and the second metal oxide can be made low. Thus, the influence of interface scattering on carrier conduction is small, and the transistor can have a high on-state current and high frequency characteristics.

Note that the metal oxide may have a stacked-layer structure of the second metal oxide and the first metal oxide formed over the second metal oxide. This structure can inhibit an increase in the contact resistance between the conductor ME1 or the conductor ME2 and the metal oxide. Furthermore, the second metal oxide can be inhibited from being damaged during formation of the insulator GI1 (described later in detail).

Using the metal oxide for the semiconductor film SC1A may reduce the oxygen concentration in the semiconductor SC1 in the vicinity of the conductor, which is the conductor (corresponding to the conductor ME1 and the conductor ME2 in FIG. 40A to FIG. 40D) provided in contact with the semiconductor SC1. In addition, a metal compound layer, which contains a metal contained in the conductor and a component of the semiconductor SC1, may be formed in the semiconductor SC1 in the vicinity of the conductor. In such cases, a region of the semiconductor SC1 in the vicinity of the conductor has a higher carrier density, thereby becoming a low-resistance region.

Besides a metal oxide, for example, a material containing silicon can be used for the semiconductor SC1. Examples of the silicon include amorphous silicon (sometimes referred to as hydrogenated amorphous silicon), microcrystalline silicon, polycrystalline silicon (including low-temperature polysilicon (LTPS)), and single crystal silicon. During formation of the semiconductor film SC1A in each of the opening KK1 and the opening KK2, a semiconductor region where the semiconductor film SC1A is formed is preferably changed into a low-resistance region at the interface between the semiconductor region and the conductor ME1 in contact with each other and the vicinity thereof and at the interface between the semiconductor region and the conductor ME2 in contact with each other and the vicinity thereof. In this case, the low-resistance region and the semiconductor region are formed in the semiconductor SC1; thus, the transistor MTCK and the transistor MTHN can be Si transistors.

Note that in the description in this embodiment, the semiconductor film SC1A includes a metal oxide functioning as an oxide semiconductor.

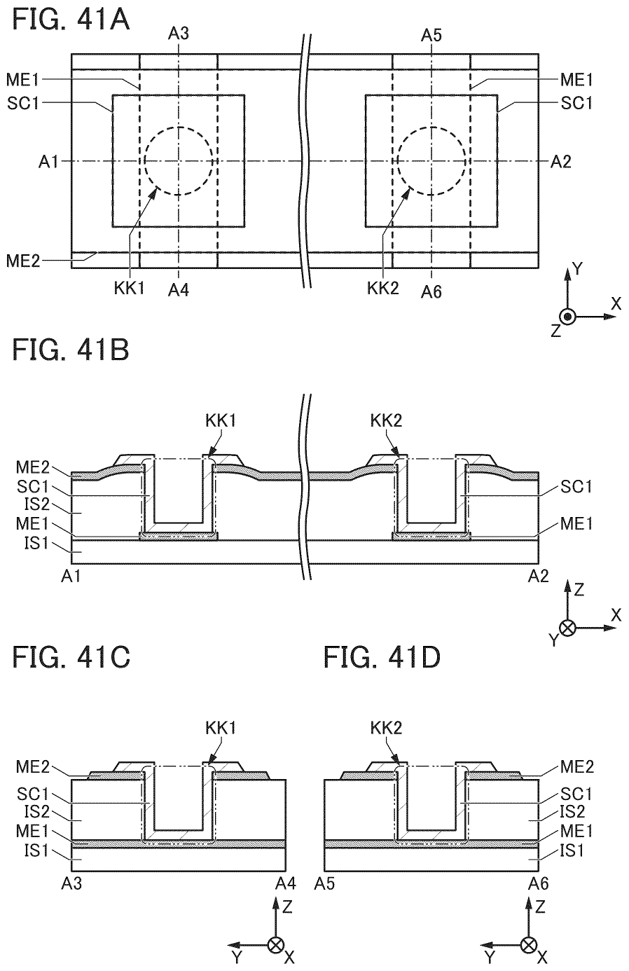

Next, the semiconductor film SC1A is processed by a lithography method to form the semiconductor SC1 so that part of the insulator IS2 and part of the conductor ME2 can be exposed. In particular, the semiconductor SC1 is processed to overlap with the conductor ME2 (see FIG. 41A to FIG. 41D). For the lithography method, the lithography method described with reference to FIG. 36A to FIG. 36D can be referred to.

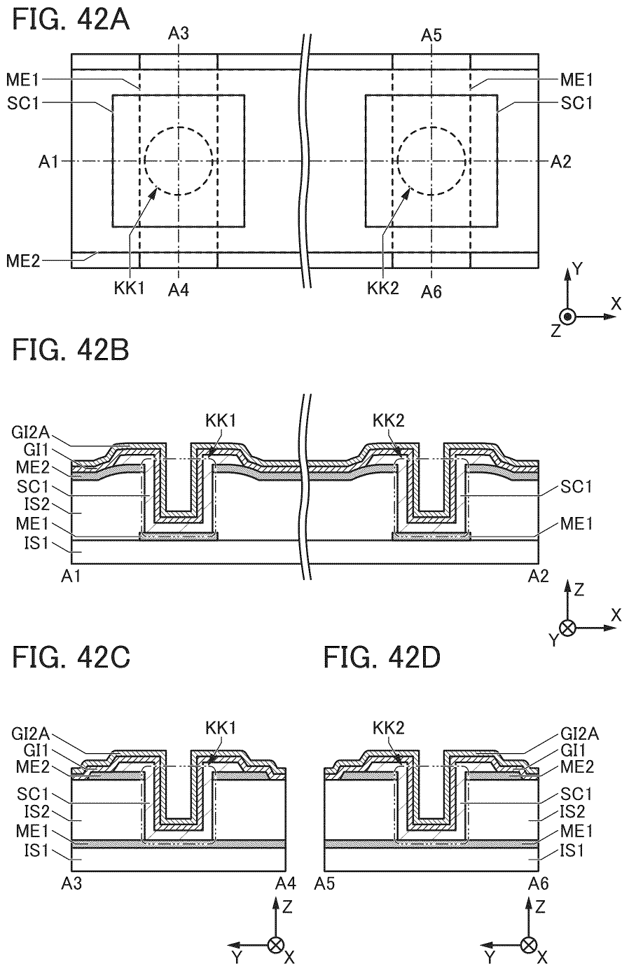

Next, the insulator GI1 and an insulating film GI2A are formed over the insulator IS2, a conductive film ME2, and the semiconductor SC1 (see FIG. 42A to FIG. 42D). In particular, the insulating film GI2A is a film to be the insulator GI2 in a later step. The insulator GI1 and the insulating film GI2A can be formed by a film formation method such as a sputtering method, a CVD method, an MBE method, a PLD method, or an ALD method, for example.

The insulator GI1 and the insulator GI2 function as the gate insulating film of each of the transistor MTCK and the transistor MTHN.

For the insulator GI1 or the insulating film GI2A, a single layer or stacked layers of an insulator containing what is called a high-k material such as aluminum oxide, hafnium oxide, tantalum oxide, zirconium oxide, lead zirconate titanate (PZT), strontium titanate (SrTiO₃), or (Ba,Sr)TiO₃ (BST) is preferably used, for example. Alternatively, for the insulator GI1, as an insulator with a high relative permittivity, an oxide containing aluminum and hafnium, an oxynitride containing aluminum and hafnium, an oxide containing silicon and hafnium, an oxynitride containing silicon and hafnium, or a nitride containing silicon and hafnium may be used.

With further miniaturization and higher integration of a transistor, a problem such as generation of a leakage current may arise because of a thinned gate insulator. When a high-k material is used for the insulator functioning as a gate insulator, a gate potential at the time of the operation of the transistor can be reduced while the physical thickness is maintained.

For the insulator GI1 or the insulating film GI2A, an insulating layer in which the above-described high-k material and silicon oxide or silicon oxynitride are stacked may be used. In this case, the insulating layer having high thermal stability in addition to a high relative permittivity can be used as the gate insulating film of each of the transistor MTCK and the transistor MTHN.

Note that the insulator GI1 and the insulating film GI2A may contain the same material or different materials.

Note that in the case where the semiconductor SC1 contains a metal oxide functioning as an oxide semiconductor, after the insulator GI1 or the insulating film GI2A is formed (before a conductive film ME3A described later is formed at the latest), microwave treatment is preferably performed in an oxygen-containing atmosphere. Here, the microwave treatment refers to, for example, treatment using an apparatus including a power source that generates high-density plasma with use of a microwave. In this specification and the like, a microwave refers to an electromagnetic wave having a frequency greater than or equal to 300 MHz and less than or equal to 300 GHz. Note that in the case where the insulator GI1 or the insulating film GI2A has a stacked-layer structure, the microwave treatment may be performed at the time when the insulator GI1 or the insulating film GI2A is partially formed. For example, in the case where the insulator GI1 or the insulating film GI2A includes a silicon oxide film or a silicon oxynitride film, the microwave treatment may be performed at the time when the silicon oxide film or the silicon oxynitride film is formed.

For the microwave treatment, high-frequency waves such as microwaves or RF, oxygen plasma, oxygen radicals, or the like can be used. In the case of performing the microwave treatment, a microwave treatment apparatus including a power source for generating high-density plasma using microwaves is preferably used, for example. Here, the frequency of the microwave treatment apparatus is set to higher than or equal to 300 MHz and lower than or equal to 300 GHZ, preferably higher than or equal to 2.4 GHz and lower than or equal to 2.5 GHZ, for example, 2.45 GHz. Oxygen radicals at a high density can be generated with high-density plasma. The power of the power source that applies microwaves of the microwave treatment apparatus is set to higher than or equal to 1000 W and lower than or equal to 10000 W, preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be efficiently introduced into the semiconductor SC1, which is a metal oxide. The effect of plasma, microwaves, and the like enables V_{O}H included in a region of the semiconductor SC1 to be cut off, and hydrogen to be removed from the region. That is, V_{O}H included in the region can be reduced. As a result, oxygen vacancies and V_{O}H in the region can be reduced to lower the carrier concentration. In addition, oxygen radicals generated by the oxygen plasma can be supplied to oxygen vacancies formed in the region, thereby further reducing oxygen vacancies in the region and lowering the carrier concentration.

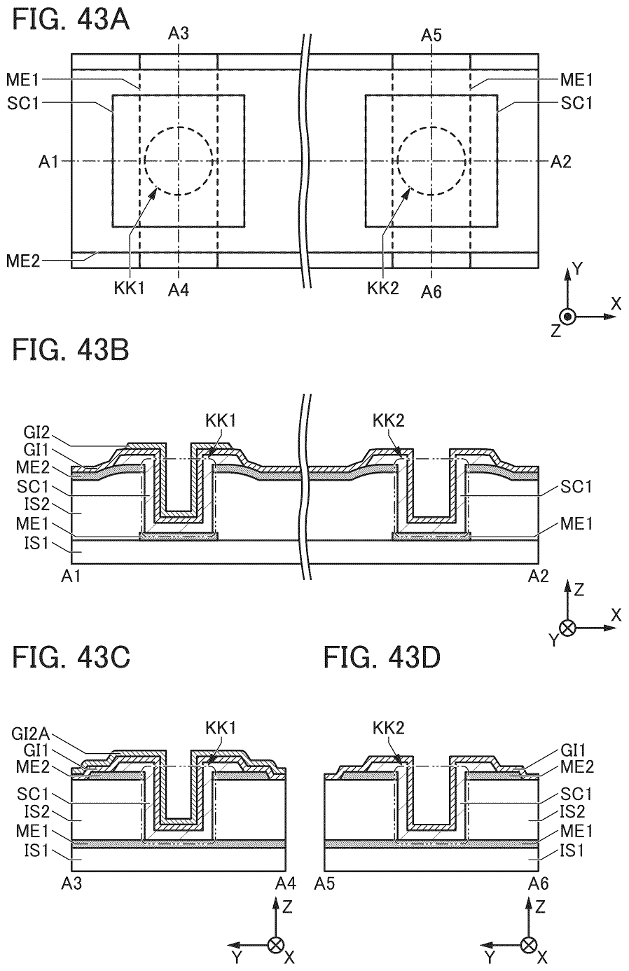

Next, the insulating film GI2A is processed by a lithography method to form the insulator GI2 so that part of the insulator GI1 can be exposed (see FIG. 43A to FIG. 43D). In particular, the insulator GI2 is formed so as to extend in a direction parallel to the dashed-dotted line A3-A4 (the Y direction) and include a region overlapping with the semiconductor SC1 formed in the opening KK1. Meanwhile, it is preferable that the insulator GI2 not be formed at least in a region overlapping with the semiconductor SC1 formed in the opening KK2. For the lithography method, the lithography method described with reference to FIG. 36A to FIG. 36D can be referred to.

Note that in order to form the insulator GI2 optimally, a material having high etching selectivity with respect to the insulator GI1 is preferably used for the insulating film GI2A.

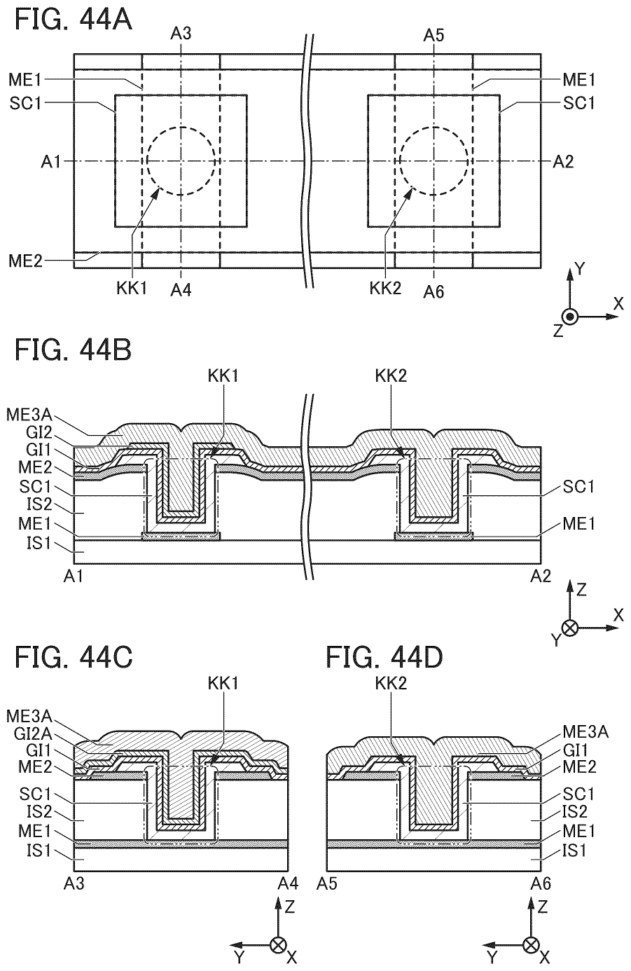

Next, the conductive film ME3A is formed over the insulator GI1 and the insulator GI2 (see FIG. 44A to FIG. 44D). In particular, the conductive film ME3A is formed to fill the opening KK1 and the opening KK2. The conductive film ME3A can be formed by a film formation method such as a sputtering method, a CVD method, an MBE method, a PLD method, or an ALD method, for example.

The conductive film ME3A is a film to be the conductor ME3 in a later step. Part of the conductor ME3 functions also as the gate electrode of the transistor MTCK. Another part of the conductor ME3 functions also as the gate electrode of the transistor MTHN. Therefore, a material having high conductivity is preferably used for the conductive film ME3.

For the conductive film ME3A, a material that can be used for the conductor ME1 can be used, for example.

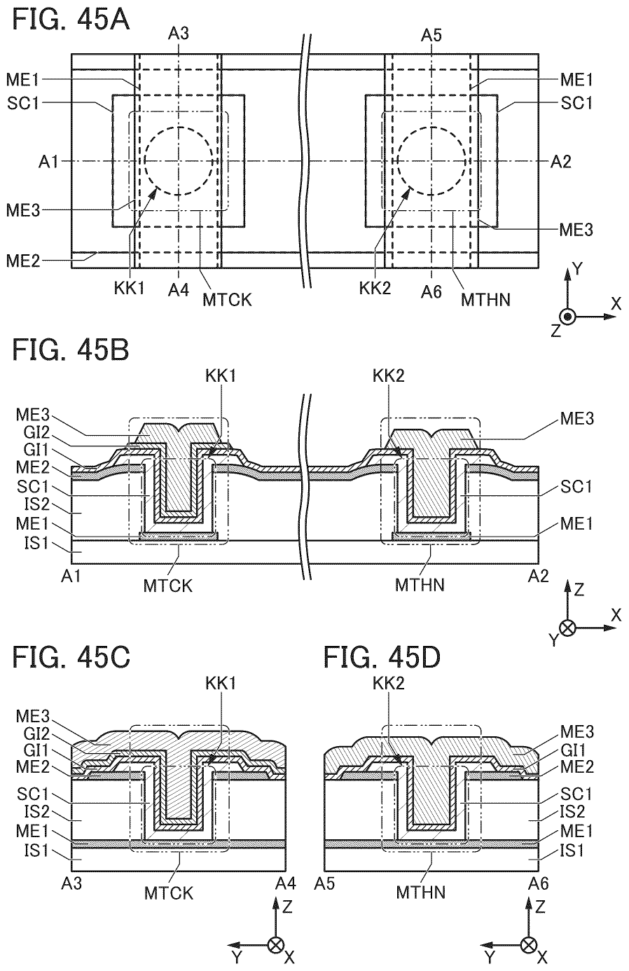

Next, the conductive film ME3A is processed into a band shape by a lithography method to form a conductive film ME3 (see FIG. 45A to FIG. 45D). In particular, here, the conductive film ME3 is formed so that part of the conductive film ME3 can extend in a direction parallel to the dashed-dotted line A3-A4 (the Y direction) and overlap with the conductor ME1. In addition, the conductive film ME3 is formed so that another part of the conductive film ME3 can extend in a direction parallel to the dashed-dotted line A5-A6 (the Y direction) and overlap with another conductor ME1. For the lithography method, the lithography method described with reference to FIG. 36A to FIG. 36D can be referred to.

Next, the insulator IS3 is formed over the insulator GI1, the insulator GI2, and the conductor ME3 (see FIG. 2A to FIG. 2D).

The insulator IS3 is a film functioning as an interlayer film, for example. Thus, the insulator IS3 preferably contains an insulating material with a low relative permittivity. When an insulating material with a low relative permittivity is used for an interlayer film, parasitic capacitance generated between wirings can be reduced.

For the insulator IS3, a material that can be used for the insulator IS1 can be used, for example.

Note that the conductor ME3 is formed below the insulator IS3. Thus, in order to prevent oxidation of the conductor ME3, silicon nitride is preferably used for the insulator IS3 serving as a barrier insulating film that inhibits diffusion of oxygen, for example.

By the above manufacturing method, the transistor MTCK having high resistance to a high voltage and the transistor MTHN having a high driving frequency that are illustrated in FIG. 2A to FIG. 2D can be manufactured.

### <Modification Example>

The method for manufacturing the semiconductor device of one embodiment of the present invention is not limited to the above. In manufacturing the semiconductor device of one embodiment of the present invention, the manufacturing method may be changed as appropriate. Even in the case where the structure of the semiconductor device is changed by a change in the manufacturing method, the semiconductor device can be regarded as one embodiment of the present invention.

### <<Modification Example 1>>

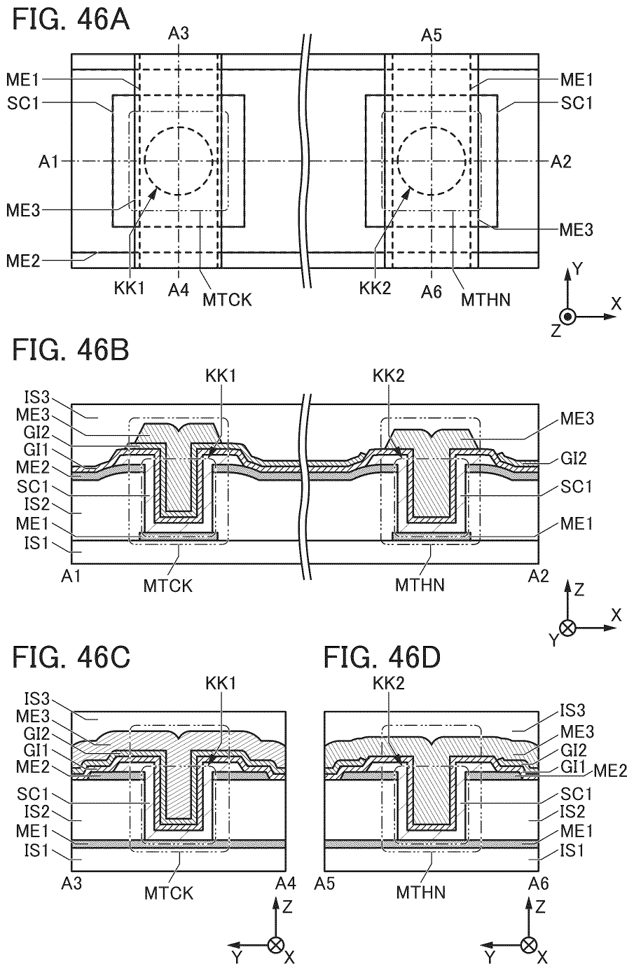

The transistor MTCK and the transistor MTHN that are illustrated in FIG. 46A to FIG. 46D are modification examples of the transistor MTCK and the transistor MTHN in FIG. 2A to FIG. 2D, and the insulator GI2 included in part of the gate insulating film of the transistor MTCK in FIG. 2A to FIG. 2C is also formed over the conductor ME2 included in the transistor MTHN in FIG. 2B and FIG. 2D.

When the insulator GI2 is also formed over the conductor ME2 of the transistor MTHN, for example, the insulator GI1 and the insulator GI2 are positioned between the conductor ME2 and the conductor ME3 as illustrated in FIG. 46D. That is, in the transistor MTHN, the distance between the conductor ME2 and the conductor ME3 can be increased. This can reduce the parasitic capacitance between the conductor ME2 and the conductor ME3 in the transistor MTHN, so that the transistor MTHN can have a higher driving frequency.

### <<Modification Example 2>>

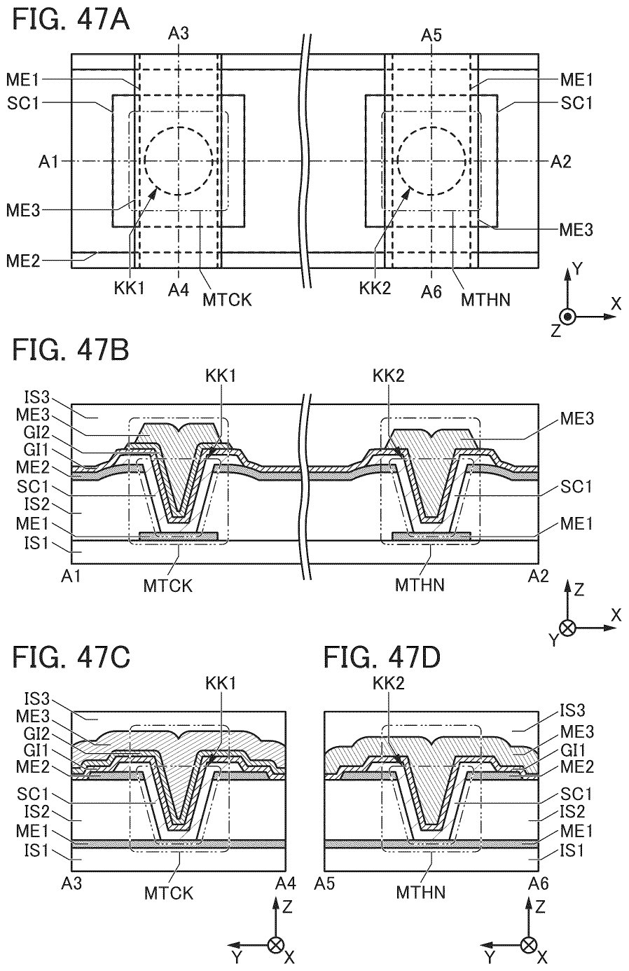

The transistor MTCK and the transistor MTHN that are illustrated in FIG. 47A to FIG. 47D are modification examples of the transistor MTCK and the transistor MTHN in FIG. 2A to FIG. 2D, and the taper angle of each of the opening KK1 in the transistor MTCK and the opening KK2 in the transistor MTHN in FIG. 2A to FIG. 2D is approximately 60°.

The transistor MTCK and the transistor MTHN that are illustrated in FIG. 47A to FIG. 47D can be manufactured by, for example, setting the taper angle of each of the opening KK1 and the opening KK2 to approximately 60° with respect to the surface of the substrate (not illustrated) or the insulator IS1 in the manufacturing step of the transistor MTCK and the transistor MTHN described with reference to FIG. 39A to FIG. 39D.

By setting the taper angle of the opening KK1 to greater than 0° and less than 70° as illustrated in FIG. 47A to FIG. 47D, for example, the coverage with the semiconductor SC1 formed on the side surface of the opening KK1 can be improved; thus, the yield at the time of forming the transistor MTCK can be increased. Similarly, by setting the taper angle of the opening KK2 to greater than 0° and less than 70°, for example, the coverage with the semiconductor SC1 formed on the side surface of the opening KK2 can be improved; thus, the yield at the time of forming the transistor MTHN can be increased.

### <<Modification Example 3>>

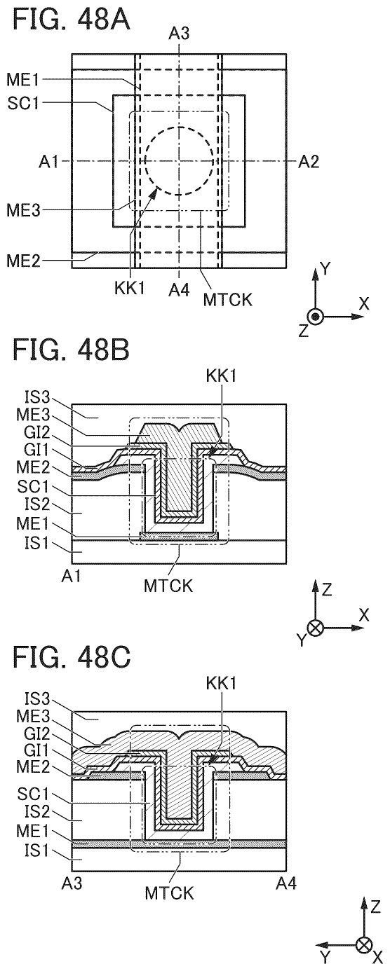

The transistor MTCK illustrated in FIG. 48A to FIG. 48C is a modification example of the transistor MTCK in FIG. 2A to FIG. 2C and is different from the transistor MTCK in FIG. 2A to FIG. 2C in that the insulator GI2 is formed only in a region overlapping with the semiconductor SC1.

The transistor MTCK illustrated in FIG. 48A to FIG. 48C is obtained in the following manner, for example: in the manufacturing step of the transistor MTCK and the transistor MTHN described with reference to FIG. 42A to FIG. 42C, after the insulating film GI2A is formed, the insulating film GI2A is processed by the lithography method described with reference to FIG. 43A to FIG. 43C so that an end portion of the insulator GI2 can be included in the region overlapping with the semiconductor SC1. Thus, an insulator G1 and the conductor ME3 are formed in this order in a region over the conductor ME2 that does not overlap with the semiconductor SC1. In the transistor MTCK in FIG. 2A to FIG. 2C, the insulator G1, the insulator GI2, and the conductor ME3 are formed in this order in a region over the conductor ME2 that does not overlap with the semiconductor SC1; thus, the thickness of the insulator between the conductor ME2 and the conductor ME3 in the region of the transistor MTCK in FIG. 48A to FIG. 48C can be smaller than the thickness of the insulator between the conductor ME2 and the conductor ME3 in the region of the transistor MTCK in FIG. 2A to FIG. 2C.

In the transistor MTCK in FIG. 48A to FIG. 48C, the thickness of the insulator between the conductor ME2 and the conductor ME3 is small in the region over the conductor ME2 that does not overlap with the semiconductor SC1; thus, a capacitor can be provided in the region. Specifically, a capacitor can be provided between the gate and the other of the source and the drain in the transistor MTCK in FIG. 48A to FIG. 48C.

Examples of the structure in which a capacitor is provided between a gate and a source or a drain of a transistor include the above-described electrical connection structure between the transistor MN6 and the capacitor C3 in FIG. 6A and the above-described electrical connection structure between the transistor MN8 and the capacitor C4 in FIG. 6A.

The above-described connection structure, e.g., the case where a gate and a source of a transistor are electrically connected to each other through a capacitor is considered. Here, when the voltage of the capacitor is a gate-source voltage at which the transistor is brought into an on state and a high-level potential is input from a drain, the potential of the source increases owing to a current flowing from the drain to the source. In addition, the potential of the gate of the transistor also increases owing to capacitive coupling of the capacitor in response to the increase in the potential of the source. That is, the above-described connection structure maintains the gate-source voltage even when the potential of the source changes, so that the potential of the source can be increased to a high-level potential supplied from the drain side (corresponding to the bootstrap described with the memory circuit RESD3 in FIG. 14A).

Thus, the transistor MTCK in FIG. 48A to FIG. 48C can be regarded as having a structure suitable for the case of performing a bootstrap, as described above.

### <<Modification Example 4>>

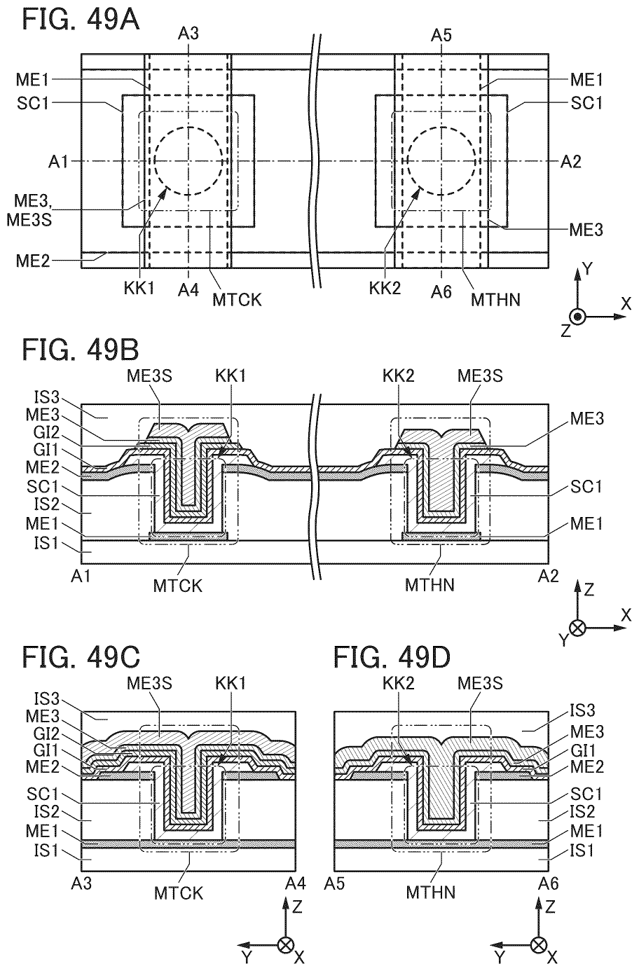

The transistor MTCK and the transistor MTHN that are illustrated in FIG. 49A to FIG. 49D are modification examples of the transistor MTCK and the transistor MTHN in FIG. 2A to FIG. 2D, and the gate electrode of each of the transistor MTCK and the transistor MTHN has a stacked-layer structure of the conductor ME3 and a conductor ME3S.

Specifically, the transistor MTCK illustrated in FIG. 49A to FIG. 49D has a structure in which the conductor ME3 with high coverage is formed on the bottom surface and the inner side surface of the opening KK1, and the conductor ME3S with high conductivity is formed over the conductor ME3, for example. Thus, the conductor ME3S functions as an auxiliary electrode of the conductor ME3.

As a method for forming the conductor ME3 in the transistor MTCK and the transistor MTHN in FIG. 49A to FIG. 49D, an ALD method with high coverage is preferably employed.

As a method for forming the conductor ME3S, for example, a method such as a sputtering method, a CVD method, an MBE method, a PLD method, or an ALD method is employed. In addition, among materials that can be used for the conductor ME1, a material having lower resistivity than the conductor ME3 is preferably used for the conductor ME3S, for example.

Another conductor may also be provided with an auxiliary electrode similar to the conductor ME3S. For example, an auxiliary electrode similar to the conductor ME3S may be provided over one or both of the conductor ME1 and the conductor ME2. The auxiliary electrode may be provided not over the conductor ME1 but under the conductor ME1. Similarly, the auxiliary electrode may be provided not over the conductor ME2 but under the conductor ME2.

By providing the auxiliary electrode over the conductor as in the transistor MTCK and the transistor MTHN that are illustrated in FIG. 49A to FIG. 49D, the electric resistance of the wiring including the conductor and the auxiliary electrode can be reduced, so that the power consumption of the semiconductor device or the display apparatus DSP including the transistor MTCK and the transistor MTHN can be reduced.

### <<Modification Example 5>>

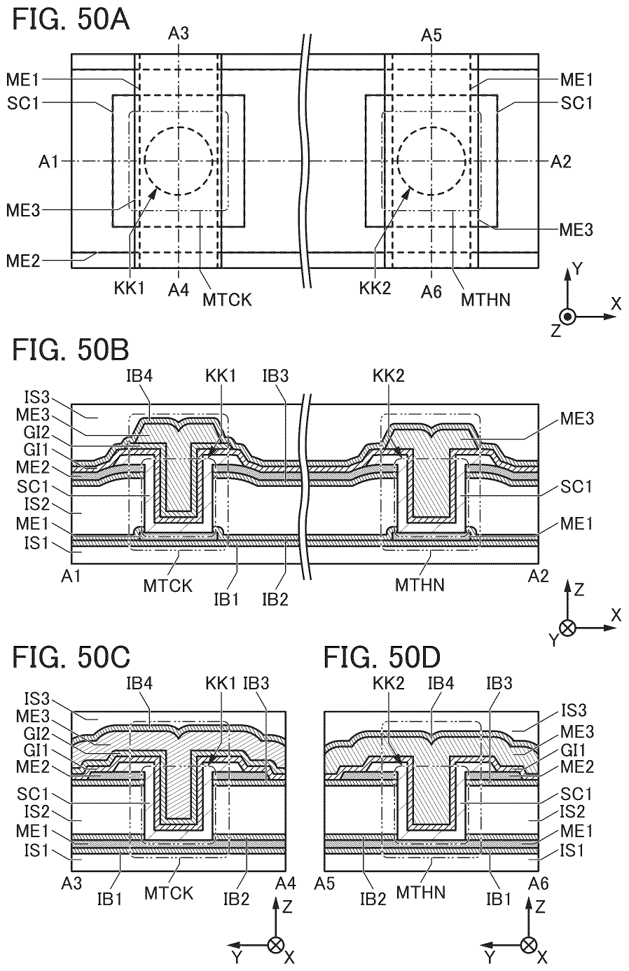

The transistor MTCK and the transistor MTHN that are illustrated in FIG. 50A to FIG. 50D are other modification examples of the transistor MTCK and the transistor MTHN in FIG. 2A to FIG. 2D, and an insulator IB1 is provided on the top surface of the insulator IS1, an insulator IB2 is provided on the top surface of the insulator IB1 and the top surface of the conductor ME1, an insulator IB3 is provided on the top surface of the insulator IS2, and an insulator IB4 is provided on the top surface of the insulator GI1, the top surface of the insulator GI2, and the top surface of the conductor ME3.

As a method for manufacturing the transistor MTCK and the transistor MTHN that are illustrated in FIG. 50A to FIG. 50D, for example, in the manufacturing step of the transistor MTCK and the transistor MTHN in FIG. 35A to FIG. 35D, the insulator IB1 is formed between the formation steps of the insulator IS1 and the conductive film ME1A (not illustrated). Next, after the manufacturing step of the transistor MTCK and the transistor MTHN in FIG. 36A to FIG. 36D, the insulator IB2 is formed on the top surface of the insulator IB1 and the top surface of the conductor ME1 (not illustrated). Next, in the manufacturing step of the transistor MTCK and the transistor MTHN in FIG. 37A to FIG. 37D, the insulator IB3 is formed between the formation steps of the insulating film IS2A and the conductive film ME2A (not illustrated). Next, after the manufacturing step of the transistor MTCK and the transistor MTHN in FIG. 45A to FIG. 45D, the insulator IB4 is formed on the top surface of the insulator GI1, the top surface of the insulator GI2, and the top surface of the conductor ME3 (not illustrated). After that, the insulator IS3 is provided on the top surface of the insulator IB4, so that the transistor MTCK and the transistor MTHN that are illustrated in FIG. 50A to FIG. 50D can be manufactured.

The insulator IB1 preferably functions as, for example, a barrier insulating film that inhibits entry of impurities such as water, hydrogen, nitrogen, and oxygen contained in the insulator IS1 into the conductor ME1 and the semiconductor SC1. Similarly, the insulator IB2 preferably functions as, for example, a barrier insulating film that inhibits entry of impurities such as water, hydrogen, nitrogen, and oxygen contained in the insulator IS2 into the conductor ME1. Similarly, the insulator IB3 preferably functions as, for example, a barrier insulating film that inhibits entry of impurities such as water, hydrogen, nitrogen, and oxygen contained in the insulator IS2 into the conductor ME2. Similarly, the insulator IB4 preferably functions as, for example, a barrier insulating film that inhibits entry of impurities such as water, hydrogen, nitrogen, and oxygen contained in the insulator IS3 into the conductor ME2, the conductor ME3, and the semiconductor SC1.

Accordingly, it is preferable to use, for each of the insulator IB1 to the insulator IB4, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom (an insulating material through which the impurities are unlikely to pass). Alternatively, it is preferable to use an insulating material having a function of inhibiting diffusion of oxygen (e.g., one or both of an oxygen atom and an oxygen molecule) (an insulating material through which the oxygen is unlikely to pass).

An insulator having a function of inhibiting the passage of oxygen and impurities such as water and hydrogen can be formed to have a single layer or a stacked layer including an insulator containing one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum, for example. Specific examples of the insulator having a function of inhibiting the passage of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the insulator having a function of inhibiting the passage of oxygen and impurities such as water and hydrogen include oxides containing aluminum and hafnium (hafnium aluminate). Other examples of the insulator having a function of inhibiting the passage of oxygen and impurities such as water and hydrogen include metal nitrides such as aluminum nitride, aluminum titanium nitride, titanium nitride, silicon nitride oxide, and silicon nitride.

In particular, aluminum oxide or silicon nitride is preferably used for each of the insulator IB1 to the insulator IB4. Accordingly, it is possible to inhibit diffusion of impurities such as water and hydrogen into the transistor MTCK and the transistor MTHN from below the insulator IB1, for example. In addition, it is possible to inhibit diffusion of impurities such as water and hydrogen into the transistor MTCK and the transistor MTHN from above the insulator IB4, for example.

As a method for forming each of the insulator IB1 to the insulator IB4, for example, a method such as a sputtering method, a CVD method, an MBE method, a PLD method, or an ALD method is employed.

The transistor MTCK and the transistor MTHN that are illustrated in FIG. 50A to FIG. 50D may each have a structure not including one or more and three or less selected from the insulator IB1 to the insulator IB4.

As in the transistor MTCK and the transistor MTHN that are illustrated in FIG. 50A to FIG. 50D, the provision of the barrier insulating film can inhibit diffusion of impurities into the conductor and the semiconductor.

### <<Modification Example 6>>

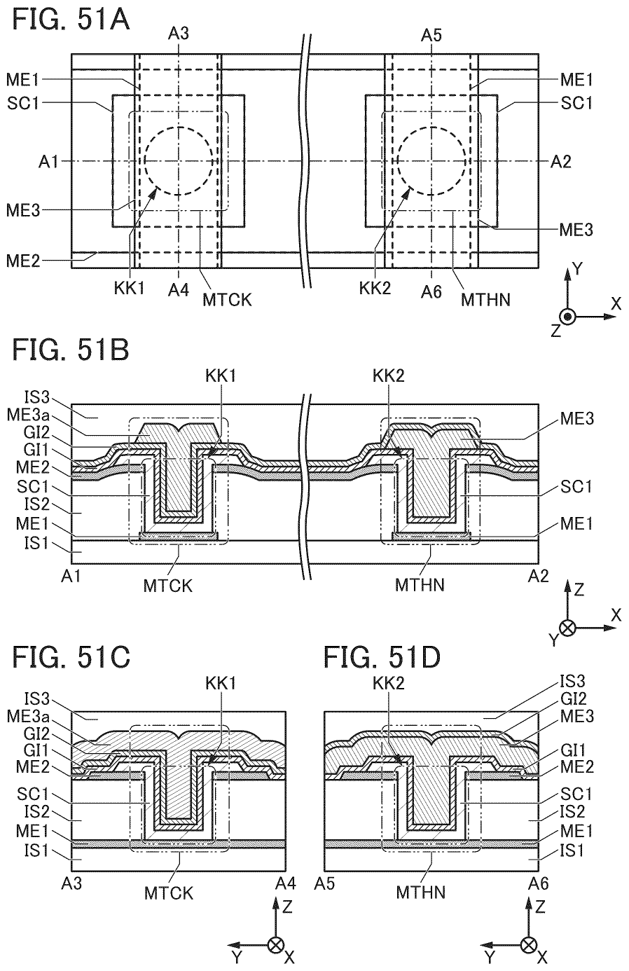

The transistor MTCK and the transistor MTHN that are illustrated in FIG. 51A to FIG. 51D are modification examples of the transistor MTCK and the transistor MTHN in FIG. 2A to FIG. 2D, and the difference is the formation order of the conductor ME3 and the insulator GI2. Thus, in the transistor MTHN, the insulator GI2 is formed on the top surface of the conductor ME3.

Hereinafter, a method for manufacturing the transistor MTCK and the transistor MTHN that are illustrated in FIG. 51A to FIG. 51D will be described. Note that an example of the method for manufacturing the transistor MTCK and the transistor MTHN that are illustrated in FIG. 51A to FIG. 51D are described with reference to FIG. 52A to FIG. 56D.

FIG. 52A to FIG. 52D are schematic views illustrating the middle of the manufacturing process of the transistor MTCK and the transistor MTHN that are illustrated in FIG. 51A to FIG. 51D. Specifically, FIG. 52A to FIG. 52D illustrate a structure in which the insulator GI1 and the conductive film ME3A are formed in this order over the insulator IS2, the conductive film ME2, and the semiconductor SC1 after the manufacturing step of the transistor MTCK and the transistor MTHN in FIG. 41A to FIG. 41D.

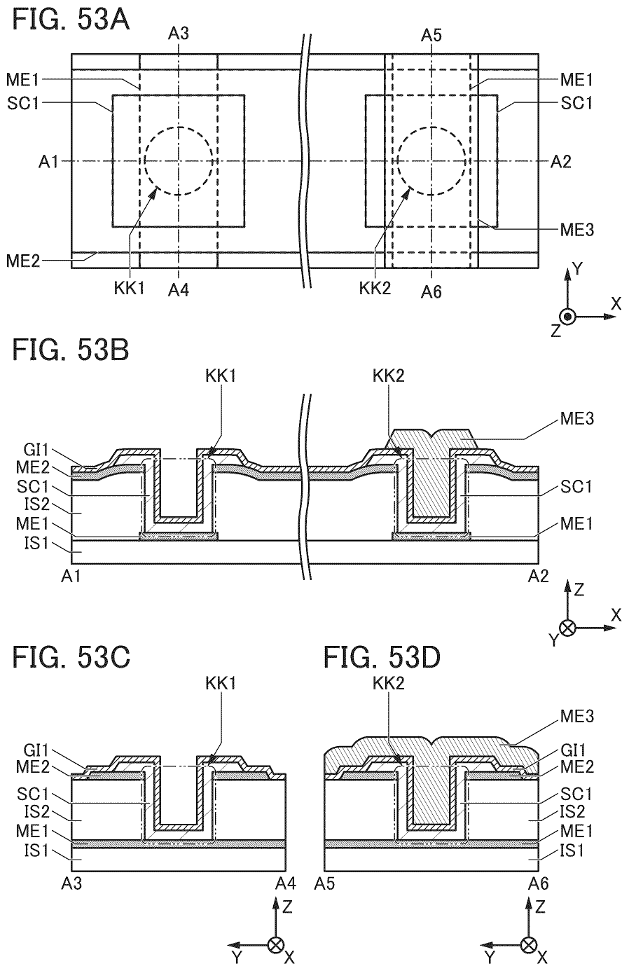

Next, the conductive film ME3A is processed into a band shape by a lithography method to form the conductor ME3 (see FIG. 53A to FIG. 53D). In particular, here, the conductor ME3 is formed so as to extend in a direction parallel to the dashed-dotted line A5-A6 (the Y direction), fill the opening KK2, and include a region overlapping with part of the conductor ME1. For the lithography method, the lithography method described with reference to FIG. 36A to FIG. 36D can be referred to.

The lithography method is preferably employed such that the insulator GI1 remains outside the region where the conductor ME3 is formed.

Part of the conductor ME3 functions as the gate electrode of the transistor MTHN.

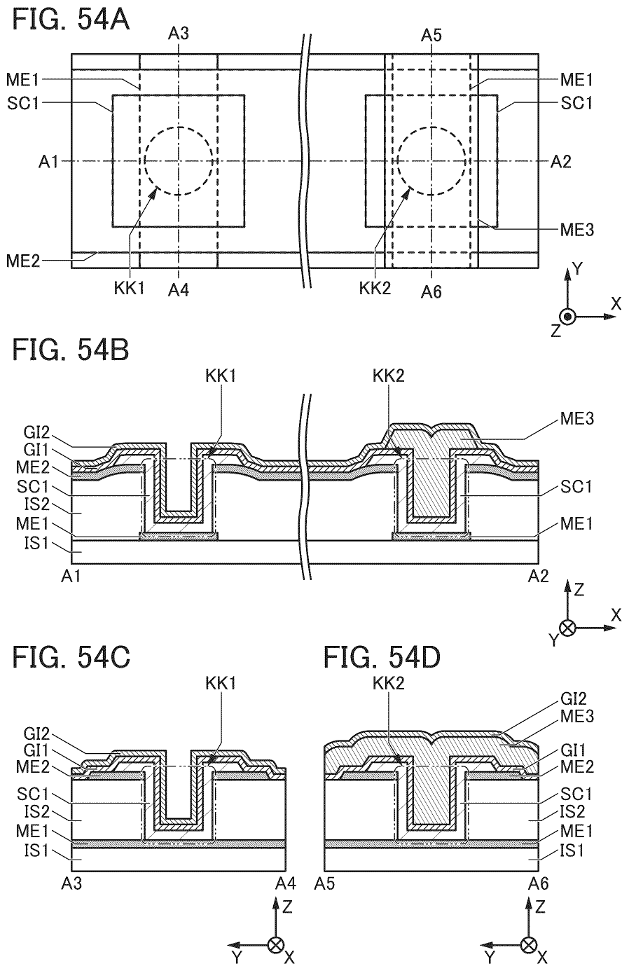

Next, the insulator GI2 is formed over the insulator GI1 and the conductor ME3 (see FIG. 54A to FIG. 54D). In particular, in the opening KK1, it is preferable that the insulator GI2 with good coverage be formed on the insulator GI1. Thus, the insulator GI2 is preferably formed by an ALD method. Alternatively, the insulator GI2 can be formed by a film formation method other than an ALD method, such as a sputtering method, a CVD method, an MBE method, or a PLD method.

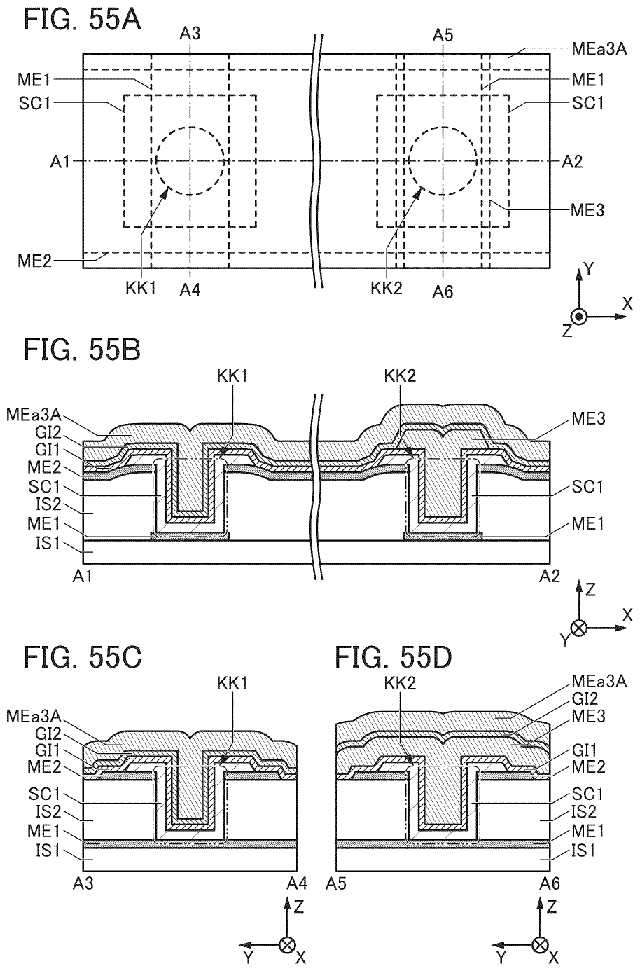

Next, a conductive film MEa3A is formed over the insulator GI2 (see FIG. 55A to FIG. 55D). In particular, the conductive film MEa3A is formed to fill the opening KK1. The conductive film MEa3A can be formed by a film formation method such as a sputtering method, a CVD method, an MBE method, a PLD method, or an ALD method, for example.

The conductive film MEa3A is a film to be a conductor MEa3 in a later step. Part of the conductor MEa3 functions as the gate electrode of the transistor MTCK. For the conductive film MEa3A, a material that can be used for the conductor ME3 can be used.

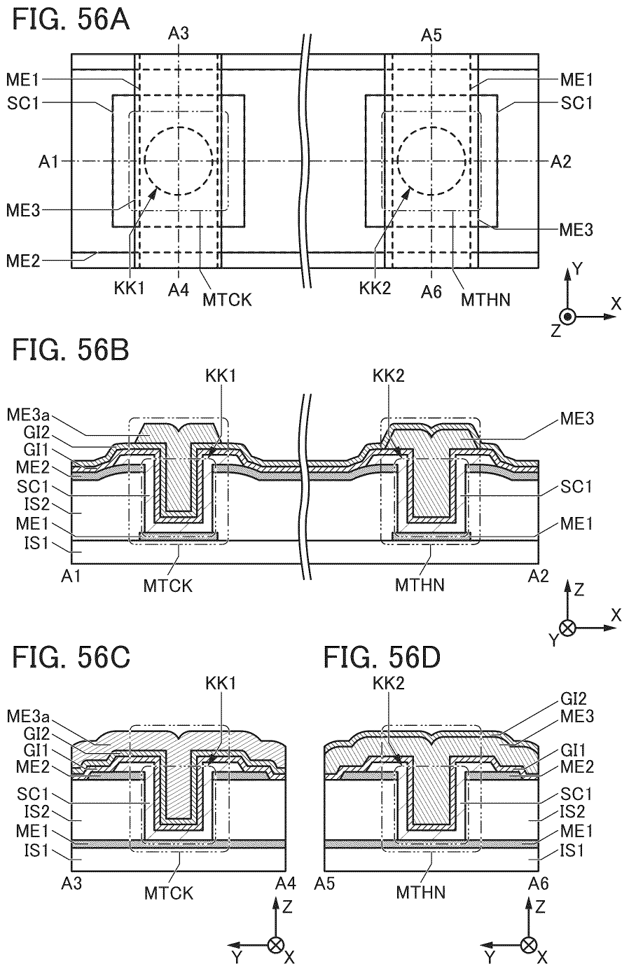

Next, a conductive film ME3aA is processed into a band shape by a lithography method to form a conductive film MEa3 (see FIG. 56A to FIG. 56D). In particular, here, the conductive film MEa3 is formed so that part of the conductive film MEa3 can extend in a direction parallel to the dashed-dotted line A3-A4 (the Y direction) and overlap with the conductor ME1. For the lithography method, the lithography method described with reference to FIG. 36A to FIG. 36D can be referred to.

Next, the insulator IS3 is formed over the insulator GI2 and the conductor MEa3 (see FIG. 51A to FIG. 51D).

Also by employing the above manufacturing method, the transistor MTCK having high resistance to a high voltage and the transistor MTHN having a high driving frequency that are illustrated in FIG. 51A to FIG. 51D can be manufactured.

### <<Modification Example 7>>

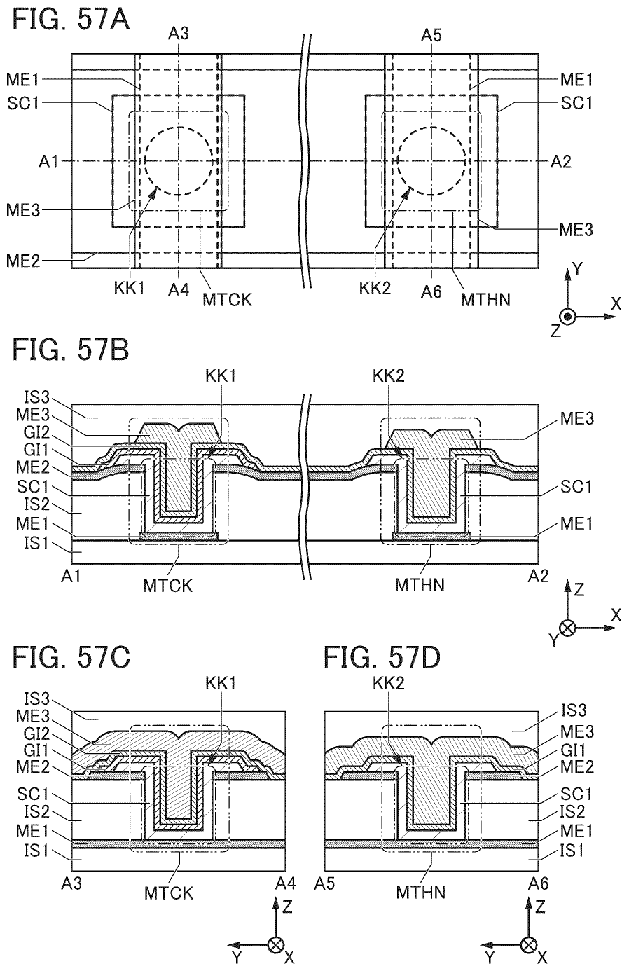

The transistor MTCK and the transistor MTHN that are illustrated in FIG. 57A to FIG. 57D are modification examples of the transistor MTCK and the transistor MTHN in FIG. 2A to FIG. 2D, and the insulator GI1 and the insulator GI2 are formed by different methods.

Specifically, in the transistor MTCK and the transistor MTHN that are illustrated in FIG. 57A to FIG. 57D, for example, the insulator GI1 is formed by the manufacturing method illustrated in FIG. 42A and FIG. 42B as follows: only a film for the insulator GI1 is formed and then a lithography method is employed so that the insulator GI1 can remain over part of the conductor ME2 and the semiconductor SC1. After that, the insulator GI2 is formed by a method similar to the manufacturing method illustrated in FIG. 42A to FIG. 42B, and the manufacturing method illustrated in FIG. 43A and FIG. 43B and subsequent drawings is employed, whereby the transistor MTCK and the transistor MTHN that are illustrated in FIG. 57A to FIG. 57D can be manufactured.

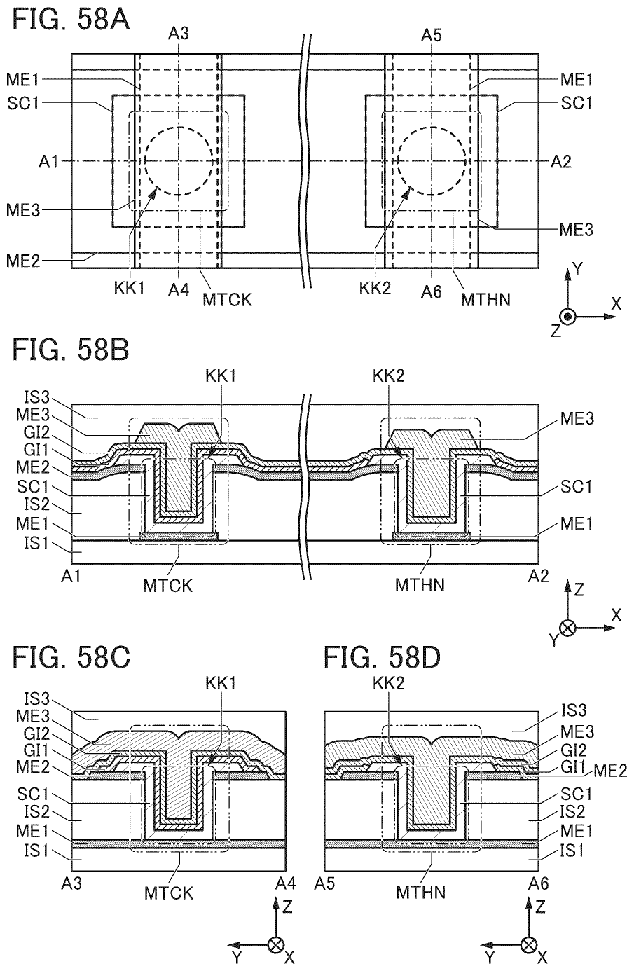

Furthermore, the structures of the transistor MTCK and the transistor MTHN that are illustrated in FIG. 57A to FIG. 57D may be modified to those of the transistor MTCK and the transistor MTHN that are illustrated in FIG. 58A to FIG. 58D. In the transistor MTCK and the transistor MTHN that are illustrated in FIG. 58A to FIG. 58D, the insulator GI1 included in part of the gate insulating film of the transistor MTCK is also formed over the conductor ME2 included in the transistor MTHN in FIG. 58B and FIG. 58D, as in the transistor MTCK and the transistor MTHN in FIG. 46A to FIG. 46D that are described in Modification example 1.

When the insulator GI1 is also formed over the conductor ME2 of the transistor MTHN, for example, the insulator GI1 and the insulator GI2 are positioned between the conductor ME2 and the conductor ME3 as illustrated in FIG. 58D. That is, in the transistor MTHN, the distance between the conductor ME2 and the conductor ME3 can be increased. This can reduce the parasitic capacitance between the conductor ME2 and the conductor ME3 in the transistor MTHN, so that the transistor MTHN can have a higher driving frequency.

### <<Modification Example 8>>

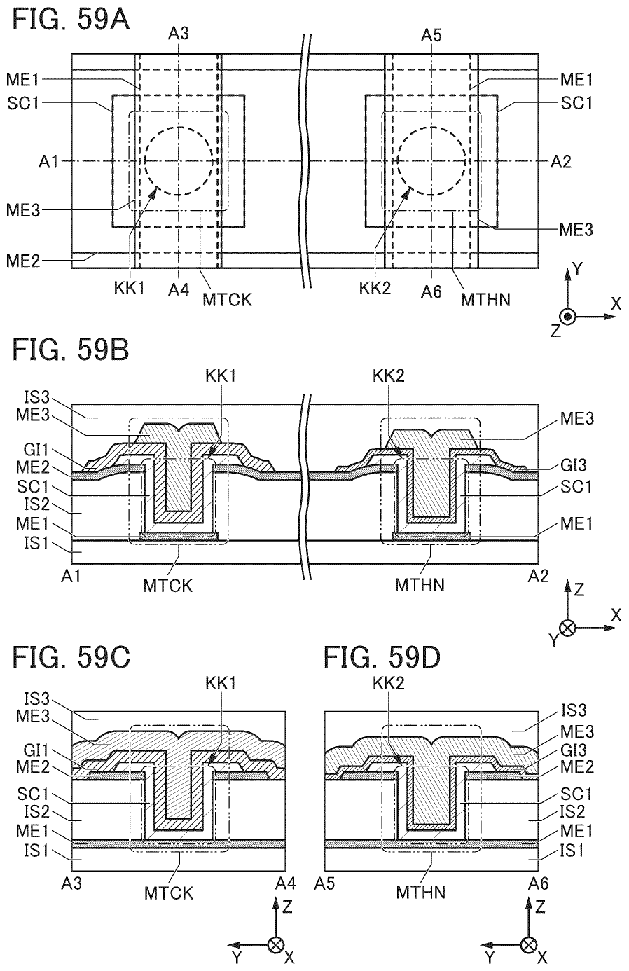

The transistor MTCK and the transistor MTHN that are illustrated in FIG. 59A to FIG. 59D are modification examples of the transistor MTCK and the transistor MTHN in FIG. 2A to FIG. 2D and are different from the transistor MTCK and the transistor MTHN in FIG. 2A to FIG. 2C in that the insulator GI1 is formed as the gate insulating film of the transistor MTCK and an insulator GI3 is formed as the gate insulating film of the transistor MTHN.

Specifically, in the transistor MTCK and the transistor MTHN that are illustrated in FIG. 59A to FIG. 59D, for example, the insulator GI1 is formed as follows after the manufacturing method in FIG. 41A and FIG. 41B is employed: a film for the insulator GI1 is formed and then a lithography method is employed so that the insulator GI1 can remain over the conductor ME2 and the semiconductor SC1 in a region where the transistor MTCK is formed. After that, the insulator GI3 is formed as follows: a film for the insulator GI3 is formed and then a lithography method is employed so that the insulator GI3 can remain over the conductor ME2 and the semiconductor SC1 in a region where the transistor MTHN is formed.

That is, the gate insulating films of the transistor MTCK and the transistor MTHN that are illustrated in FIG. 59A to FIG. 59D are separately formed.

Note that the thickness of the insulator GI1 is larger than the thickness of the insulator GI3. For the insulator GI3, a material that can be used for each of the insulator GI1 and the insulator GI2 can be used.

Although the gate insulating film of the transistor MTCK is formed first in the above manufacturing method, it is also possible that the gate insulating film of the transistor MTHN is formed first and then the gate insulating film of the transistor MTCK is formed.

Also by the above manufacturing method, the transistor MTCK having high resistance to voltage and the transistor MTHN having a high driving frequency can be manufactured.

### <<Modification Example 9>>

The transistor MTCK1 illustrated in FIG. 60A to FIG. 60C is a modification example of the transistor MTCK in FIG. 2A to FIG. 2C, and a channel formation region of the transistor MTCK1 is formed along the direction of the dashed-dotted line A1-A2 (the X direction in an X-Z plane in FIG. 60B).

As a method for manufacturing the transistor MTCK1 illustrated in FIG. 60A to FIG. 60C, for example, in the manufacturing step in FIG. 39A to FIG. 39D, the opening KK1 is not provided in the insulator IS2 and the conductor ME2 is formed as a pair of electrodes. After that, the insulator GI1, the insulator GI2, the conductor ME3, and the insulator IS3 are formed as in the manufacturing steps illustrated in FIG. 40A to FIG. 40D and subsequent drawings, whereby the transistor MTCK1 can be manufactured.

Note that the transistor MTCK1 includes the conductor ME3 functioning as a gate electrode, one of a pair of the conductors ME2 functioning as one of a source electrode and a drain electrode, the other of the pair of conductors ME2 functioning as the other of the source electrode and the drain electrode, and the semiconductor SC1 included in the channel formation region. The transistor MTCK1 has a structure in which the gate electrode is positioned above the channel formation region and the conductor ME1 and the semiconductor SC1 thereover are electrically in contact with each other; thus, the transistor MTCK1 is referred to as a TGTC transistor in some cases.

The transistor MTCK1 also includes the conductor ME1 functioning as the back gate electrode. Like the gate electrode, the back gate electrode has a function of generating an electric field in the semiconductor SC1. In particular, with the back gate electrode, the number of carriers in the semiconductor SC1 can be changed in accordance with a potential applied to the back gate electrode, and as a result, the threshold voltage of the transistor MTCK1 can be changed.

In the case where the conductor ME1 functions as the back gate electrode in the transistor MTCK1, the insulator IS2 functions as the gate insulating film in the transistor MTCK1. In this case, for the insulator IS2, a material that can be used for the insulator GI1 or the insulator GI2 can be used.

In order to distinguish the gate insulating film (the insulator IS2) positioned above the conductor ME1 and positioned below the semiconductor SC1 from the gate insulating film (the insulator GI1 and the insulator GI2) positioned above the semiconductor SC1 and positioned below the conductor ME3, in some cases, the former is referred to as a first gate insulating film or a back gate insulating film, and the latter is referred to as a second gate insulating film.

Note that the transistor MTCK1 illustrated in FIG. 60A to FIG. 60C has a structure including the insulator GI1 and the insulator GI2 as the gate insulating film. Thus, the transistor MTCK1 can be regarded as a transistor having high resistance to voltage.

Alternatively, the gate insulating film of the transistor MTCK1 in FIG. 60A to FIG. 60C does not necessarily include the insulator GI2. The transistor MTHN1 illustrated in FIG. 61A to FIG. 61C has a structure in which the insulator GI2 is not provided in the transistor MTCK1 in FIG. 60A to FIG. 60C, and thus the gate insulating film is thinner than that of the transistor MTCK1. Thus, the transistor MTHN1 can be regarded as a transistor having a higher driving frequency than the transistor MTCK1.

Although FIG. 60A to FIG. 60D illustrate the transistor MTHN that can be formed concurrently with the transistor MTCK1, the transistor MTCK1 can be formed concurrently with the transistor MTCK illustrated in FIG. 2A to FIG. 2C. Similarly, although FIG. 61A to FIG. 61D illustrate the transistor MTHN that can be formed concurrently with the transistor MTHN1, the transistor MTHN1 can be formed concurrently with the transistor MTCK illustrated in FIG. 2A to FIG. 2C.

Although the conductor ME3, which is the gate electrode of the transistor MTCK1, is formed by a lithography method in FIG. 60A to FIG. 60C, the gate electrode of the transistor MTCK1 may be formed by another method.

The transistor MTCK2 illustrated in FIG. 62A to FIG. 62C is a modification example of the transistor MTCK1 in FIG. 60A to FIG. 60C and is different from the transistor MTCK1 in FIG. 60A to FIG. 60C in that a conductor ME4 functioning as a second gate electrode is embedded in an opening provided in the insulator IS3.

As a method for manufacturing the transistor MTCK2, for example, in the manufacturing process of the transistor MTCK1, the conductor ME3 is not formed and the insulator IS3 is formed over the insulator GI1 and the insulator GI2. After that, an opening is formed in a region of the insulator IS3 that overlaps with the conductor ME1, the semiconductor SC1, and the insulator GI2, and an insulator GI4 and the conductor ME4 are formed in this order in the opening. Then, polishing is performed as planarization treatment by a CMP method or the like until the insulator IS3 is exposed, so that the transistor MTCK2 can be manufactured.

Like the insulator GI1 and the insulator GI2, an insulating film GI4 is an insulator functioning as part of the gate insulating film of the transistor MTCK2. Thus, for the insulating film GI4, a material that can be used for the insulator GI1 or the insulator GI2 can be used. Since the insulator GI4 is formed on the side surface of the opening in the insulator IS3, an ALD method with high coverage is preferably employed as a method for forming the insulator GI4.

The insulator GI4 functions as, for example, a film that prevents impurities such as oxygen contained in the insulator IS3 from being diffused into the conductor ME4 and oxidizing the conductor ME4. That is, the insulator GI4 functions as a barrier insulating film. Note that in the case where diffusion of impurities from the insulator IS3 into the conductor ME4 is not necessarily prevented, the insulator GI4 is not necessarily provided in the transistor MTCK2.

The conductor ME4 functions as a gate electrode of the transistor MTCK2. Therefore, for the conductor ME4, a material that can be used for the conductor ME3 can be used.

In the method for manufacturing the transistor MTCK2, the conductor ME4 functioning as the gate electrode is formed in a self-aligned manner to fill the opening formed in the insulator IS3. The transistor MTCK2 in which the gate electrode is formed in a self-aligned manner so as to fill the opening is sometimes referred to as a TGSA s-channel FET (Trench Gate Self Aligned s-channel FET).

Note that the transistor MTCK2 illustrated in FIG. 62A to FIG. 62C has a structure including the insulator GI1 and the insulator GI2 as the gate insulating film. Thus, the transistor MTCK2 can be regarded as a transistor having high resistance to voltage.

Alternatively, the gate insulating film of the transistor MTCK2 in FIG. 62A to FIG. 62C does not necessarily include the insulator GI2. The transistor MTHN2 illustrated in FIG. 63A to FIG. 63C has a structure in which the insulator GI2 is not provided in the transistor MTCK2 in FIG. 62A to FIG. 62C, and thus the gate insulating film is thinner than that of the transistor MTCK2. Thus, the transistor MTHN2 can be regarded as a transistor having a higher driving frequency than the transistor MTCK2.

Although FIG. 62A to FIG. 62D illustrate the transistor MTHN that can be formed concurrently with the transistor MTCK2, the transistor MTCK2 can be formed concurrently with the transistor MTCK illustrated in FIG. 2A to FIG. 2C. Similarly, although FIG. 63A to FIG. 63D illustrate the transistor MTHN that can be formed concurrently with the transistor MTHN2, the transistor MTHN2 can be formed concurrently with the transistor MTCK illustrated in FIG. 2A to FIG. 2C.

### <<Modification Example 10>>

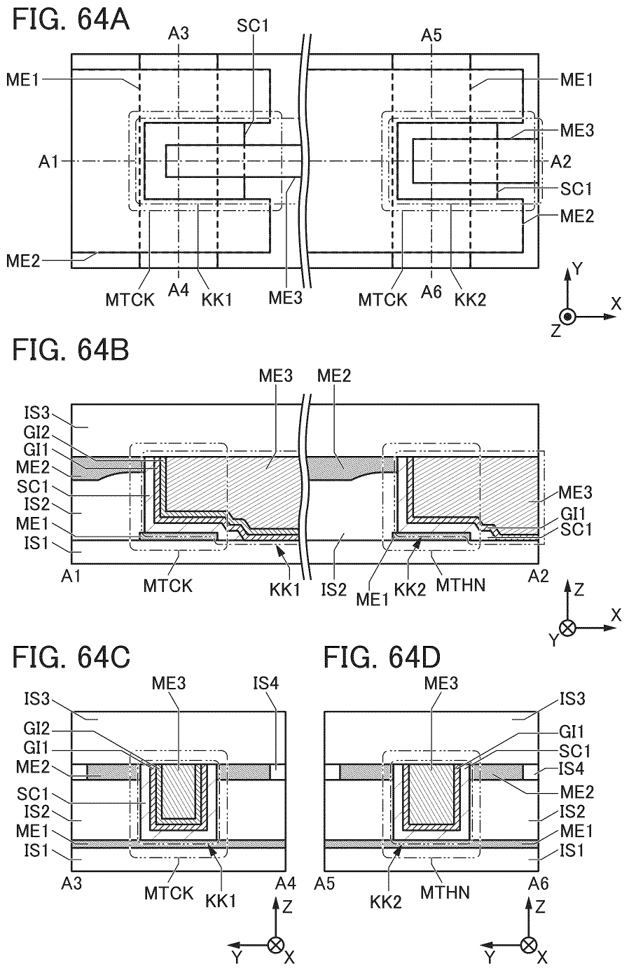

The transistor MTCK and the transistor MTHN that are illustrated in FIG. 64A to FIG. 64D have structures different from those of the transistor MTCK and the transistor MTHN in FIG. 2A to FIG. 2C. Specifically, for example, in a plan view (FIG. 64A) and a cross-sectional view (FIG. 64B), the shape of the opening KK1 of the transistor MTCK is different from that of the opening KK1 of the transistor MTCK in FIG. 2A to FIG. 2C. Similarly, for example, in the plan view (FIG. 64A) and the cross-sectional view (FIG. 64B), the shape of the opening KK2 of the transistor MTHN is different from that of the opening KK2 of the transistor MTHN in FIG. 2A to FIG. 2C.

In the transistor MTCK illustrated in FIG. 64A to FIG. 64D, the opening KK1 is provided to overlap with part of the top surface of the conductor ME1 and part of the top surface of the insulator IS1. In particular, the opening KK1 is formed from above part of the conductor ME1 in the +X direction in the plan view (FIG. 64A). Similarly, in the transistor MTHN illustrated in FIG. 64A to FIG. 64D, the opening KK2 is provided to overlap with part of the top surface of the conductor ME1 and part of the top surface of the insulator IS1. In particular, the opening KK2 is formed from part of the conductor ME1 in the +X direction in the plan view (FIG. 64A).

Thus, the conductor ME3 embedded in the opening KK1 and the opening KK2 extends from part of the conductor ME1 in the +X direction in the plan view (FIG. 64A).

In the plan view of the transistor MTCK (FIG. 64A), the conductor ME2 is provided in part of the periphery of the opening KK1. Specifically, for example, the conductor ME2 has a U-shape and is provided such that the opening KK1 is positioned inside the U-shape. Similarly, in the plan view of the transistor MTHN (FIG. 64A), the conductor ME2 is provided in part of the periphery of the opening KK2. Specifically, for example, the conductor ME2 has a U-shape and is provided such that the opening KK2 is positioned inside the U-shape.

The conductor ME2, the conductor ME3, the semiconductor SC1, the insulator GI1, and the insulator GI2 are substantially level with each other. This structure is obtained by forming the above-listed materials and then performing planarization treatment by a CMP method or the like.

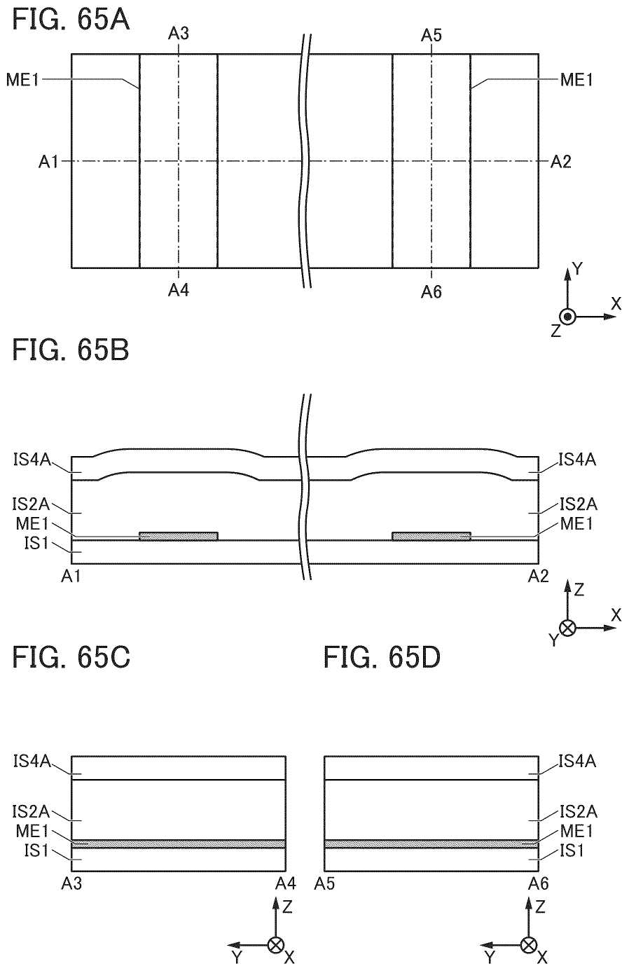

Hereinafter, a method for manufacturing the transistor MTCK and the transistor MTHN that are illustrated in FIG. 64A to FIG. 64D will be described. Note that an example of the method for manufacturing the transistor MTCK and the transistor MTHN that are illustrated in FIG. 64A to FIG. 64D are described with reference to FIG. 65A to FIG. 73D.

FIG. 65A to FIG. 65D are schematic views illustrating the middle of the manufacturing process of the transistor MTCK and the transistor MTHN that are illustrated in FIG. 64A to FIG. 64D. Specifically, FIG. 65A to FIG. 65D illustrate a structure in which the insulating film IS2A and an insulating film IS4A are formed in this order over the insulator IS1 and a conductive film ME1 after the manufacturing step of the transistor MTCK and the transistor MTHN in FIG. 36A to FIG. 36D.

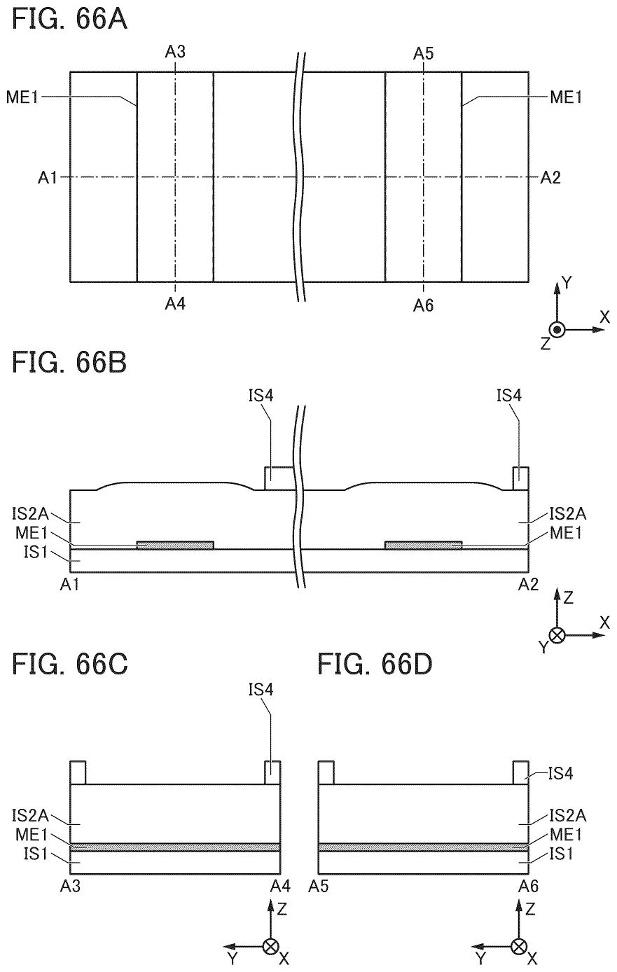

Next, the insulating film IS4A is processed by a lithography method to form an insulator IS4 (see FIG. 66A to FIG. 66D). In particular, here, an opening to be a region where the conductive film ME2B described later is formed is provided in a conductive film IS4A. For the lithography method, the lithography method described with reference to FIG. 36A to FIG. 36D can be referred to.

For the insulating film IS4A, a material that can be used for the insulating film IS2A can be used. In particular, since the insulating film IS4A is processed by a lithography method, as a material used for the insulating film IS4A, it is further preferable to use a material that can be used for the insulating film IS2A and has high etching selectivity with respect to the insulating film IS2A.

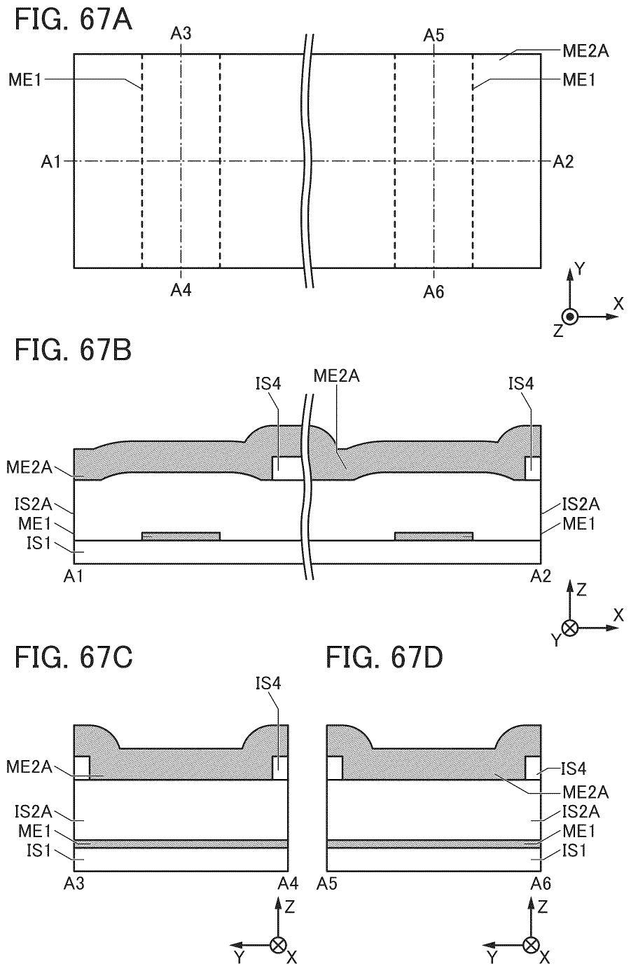

Next, the conductive film ME2A is formed over the insulating film IS2A and the insulator IS4 (see FIG. 67A to FIG. 67D).

The conductive film ME2A is a film to be the conductor ME2 in a later step. Part of the conductor ME2 functions also as the other of the source electrode and the drain electrode of the transistor MTCK. Another part of the conductor ME2 functions also as the other of the source electrode and the drain electrode of the transistor MTHN. Therefore, a material having high conductivity is preferably used for the conductive film ME2A.

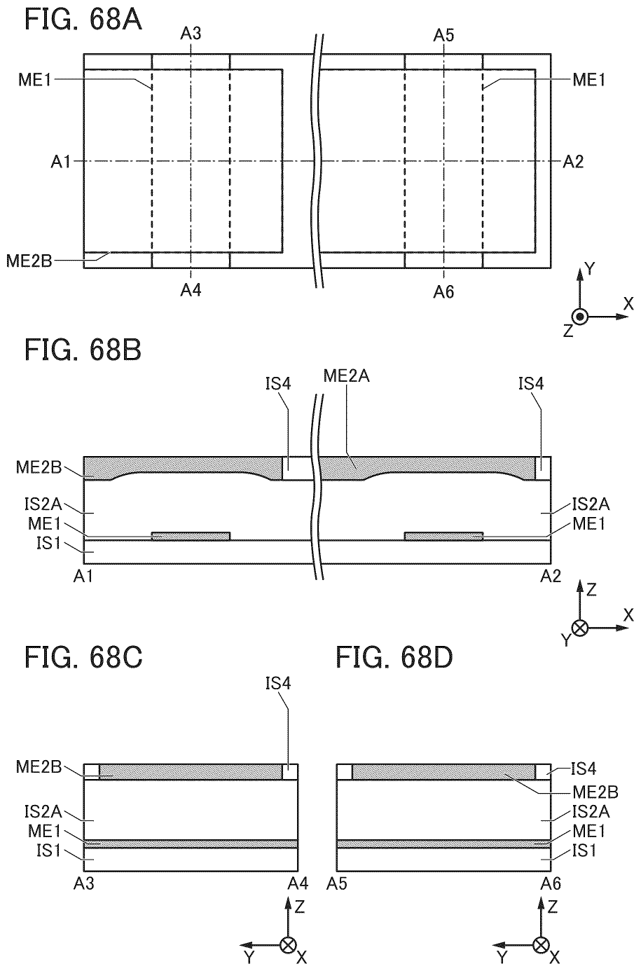

Then, planarization treatment is performed by a CMP method or the like to polish the conductive film ME2A until the insulating film IS4A is exposed. Accordingly, the conductive film ME2A is formed to be embedded as the conductive film ME2B in the opening formed in the insulating film IS4 in the step of FIG. 66A to FIG. 66D (see FIG. 68A to FIG. 68D). That is, the conductive film ME2B is provided in contact with the top surface of the insulating film IS2A and the side surface of the insulator IS4.

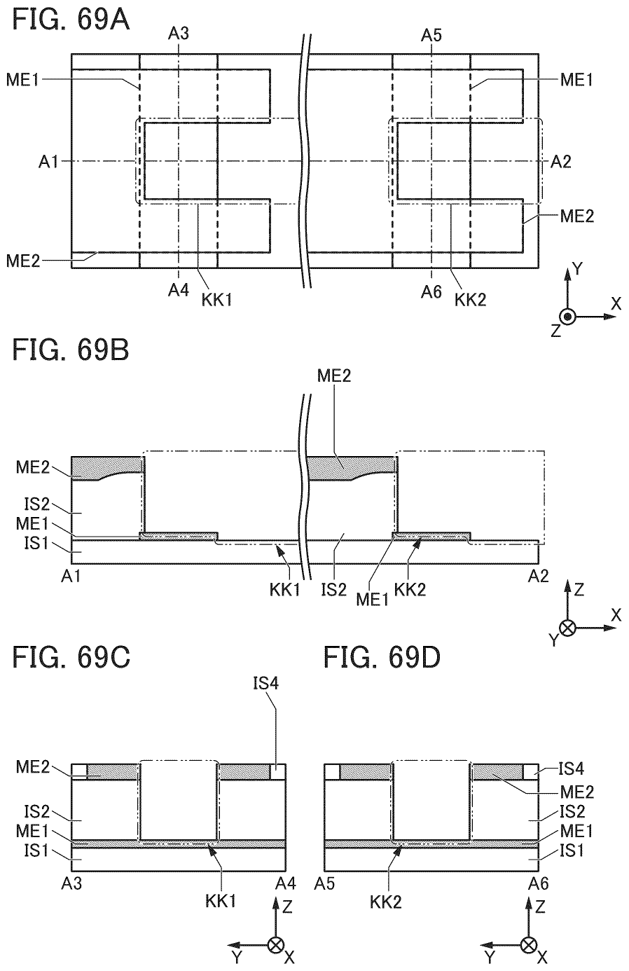

Next, the insulating film IS2A and the conductive film ME2B are processed by a lithography method to form the insulator IS2 and the conductor ME2 having the opening KK1 and the opening KK2 (see FIG. 69A to FIG. 69D). Here, the bottom surfaces of the opening KK1 and the opening KK2 are each provided with the top surface of the conductor ME1 and the top surface of the insulator IS1, unlike in the manufacturing step of the transistor MTCK and the transistor MTHN illustrated in FIG. 39A to FIG. 39D. For the lithography method, the lithography method described with reference to FIG. 36A to FIG. 36D can be referred to.

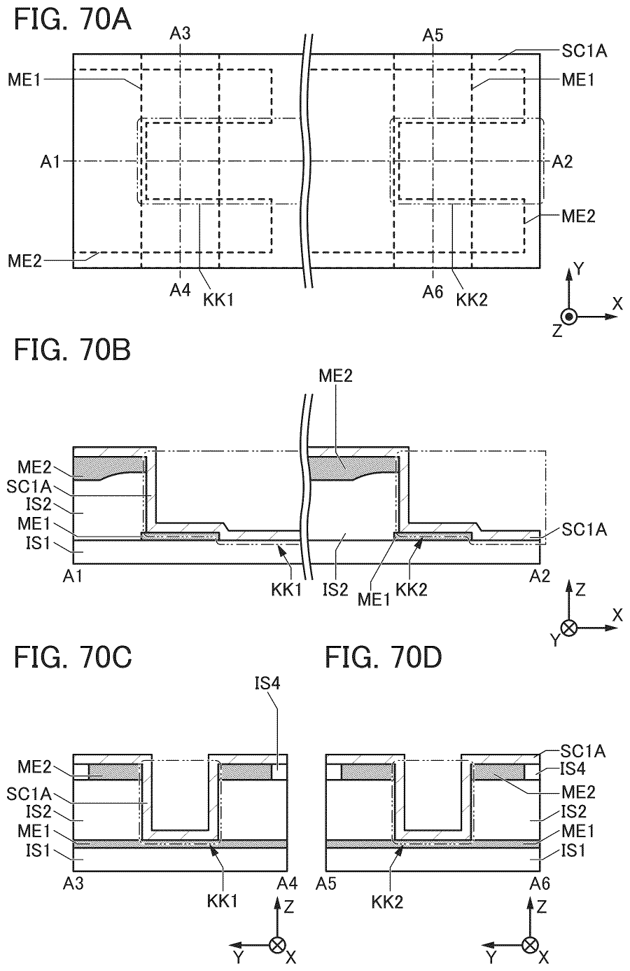

Next, as in the manufacturing step of the transistor MTCK and the transistor MTHN illustrated in FIG. 40A to FIG. 40D, the semiconductor film SC1A is formed over the insulator IS1, the conductor ME1, the insulator IS2, and the conductor ME2 (see FIG. 70A to FIG. 70D).

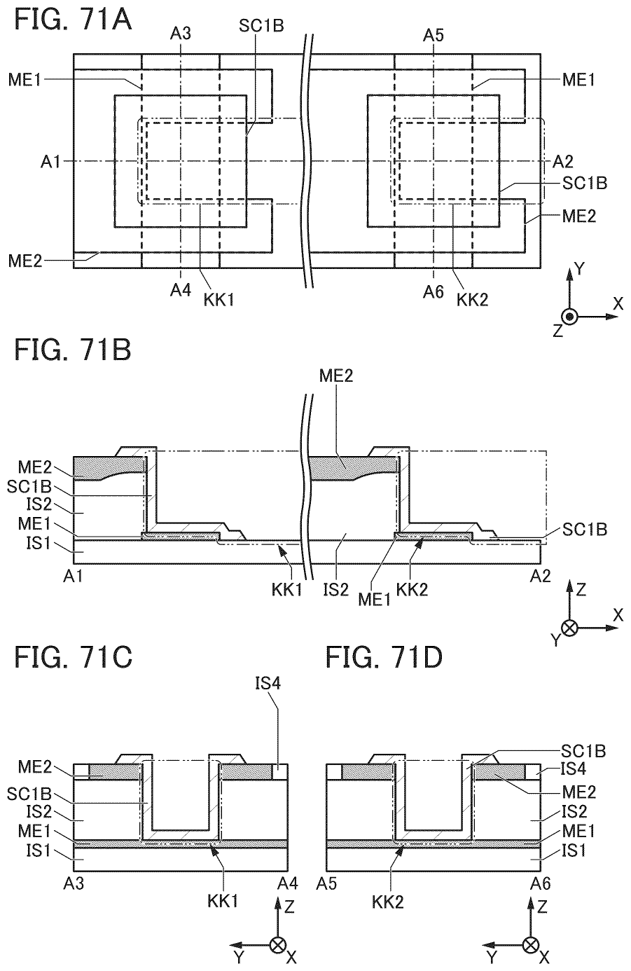

Next, the semiconductor film SC1A is processed by a lithography method to form a semiconductor film SC1B so that part of the insulator IS1, part of the insulator IS2, and part of the conductor ME2 can be exposed (see FIG. 71A to FIG. 71D). That is, the semiconductor film SC1B is provided over part of the insulator IS1, the conductor ME1, the insulator IS2 (part on the side surface of each of the opening KK1 and the opening KK2), and the conductor ME2. For the lithography method, the lithography method described with reference to FIG. 36A to FIG. 36D can be referred to.

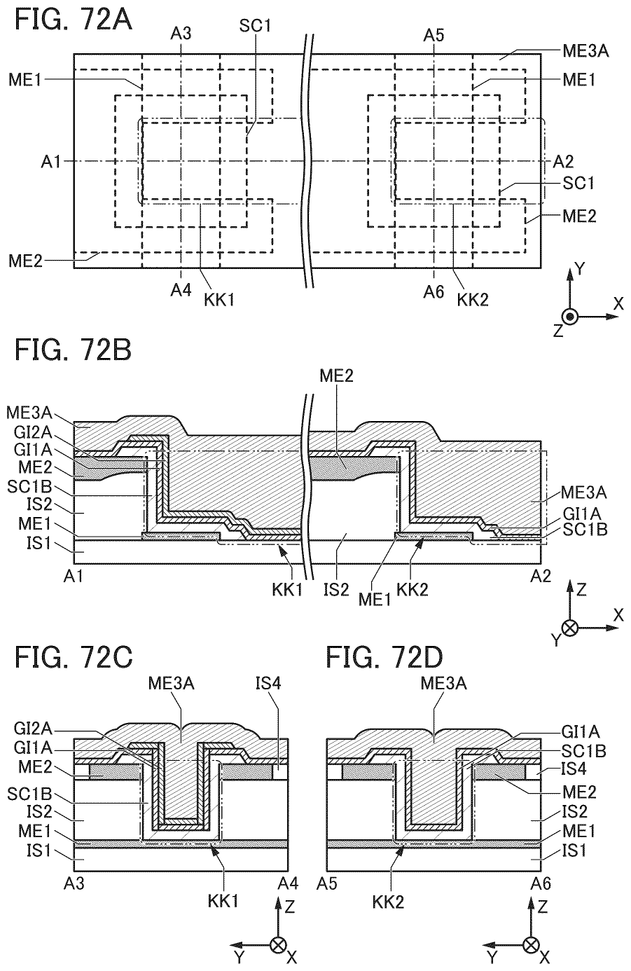

Next, as in the manufacturing steps of the transistor MTCK and the transistor MTHN illustrated in FIG. 42A to FIG. 42D and FIG. 43A to FIG. 43D, an insulating film GILA to be the insulator GI1 is formed over the insulator IS1, the semiconductor film SC1B, and the conductor ME2, and the insulating film GI2A to be the insulator GI2 is formed over the insulating film GI1A (see FIG. 72A to FIG. 72D). In particular, like the insulator GI1 described with reference to FIG. 42A to FIG. 42D, an insulating film GI1 can be formed by a film formation method such as a sputtering method, a CVD method, an MBE method, a PLD method, or an ALD method, for example.

After that, as in the manufacturing step of the transistor MTCK and the transistor MTHN illustrated in FIG. 44A to FIG. 44D, the conductive film ME3A is formed over the insulating film GILA and the insulating film GI2A (see FIG. 72A to FIG. 72D). In particular, the conductive film ME3A is formed to fill the opening KK1 and the opening KK2.

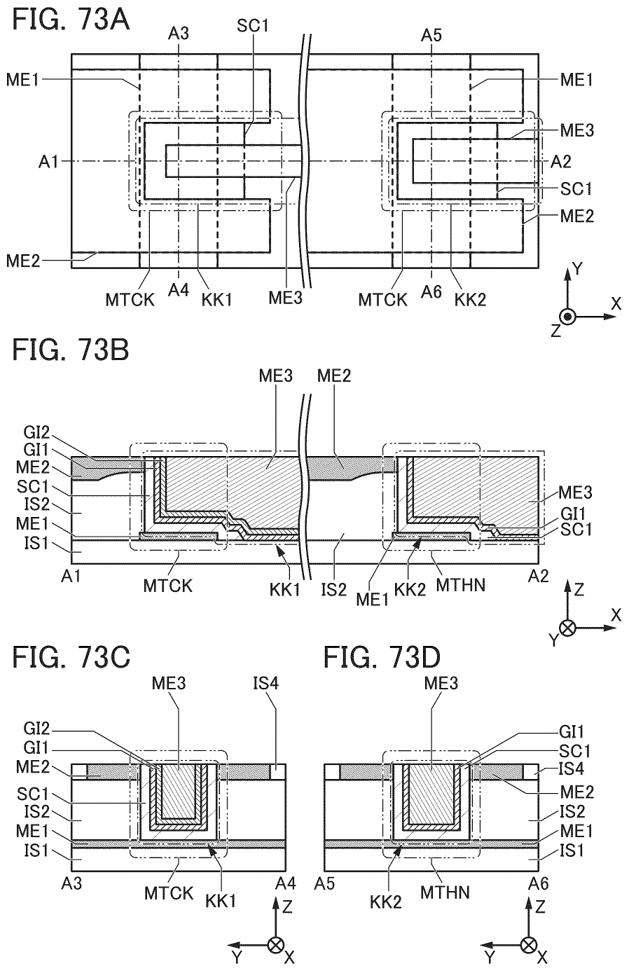

Then, planarization treatment is performed by a CMP method or the like to polish the conductive film ME3A, the insulating film GI2A, the insulating film GILA, and the semiconductor film SC1B until the conductor ME2 and the insulator IS4 are exposed. In this manner, the conductive film ME3A is processed into the conductor ME3, the insulating film GI2A is processed into the insulator GI2, the insulating film GILA is processed into the insulator GI1, and the semiconductor film SC1B is processed into the semiconductor SC1 (see FIG. 73A to FIG. 73C). Moreover, in this manner, the transistor MTCK and the transistor MTHN are formed. Note that in the transistor MTCK and the transistor MTHN that are illustrated in FIG. 73A to FIG. 73C, the conductor ME3 is embedded in the opening KK1 and the opening KK2, and the conductor ME2, the conductor ME3, the semiconductor SC1, the insulator GI1, and the insulator GI2 are substantially level with each other.

Next, the insulator IS3 is formed over the insulator GI1, the insulator GI2, the insulator IS4, the semiconductor SC1, the conductor ME2, and the conductor ME3 (see FIG. 64A to FIG. 64D).

By the above manufacturing method, the transistor having high resistance to a high voltage (the transistor MTCK) and the transistor having a high driving frequency (the transistor MTHN) that are illustrated in FIG. 64A to FIG. 64D can be manufactured.

In particular, in the above-described formation method in which the conductor ME3 is embedded in the opening KK1 and the opening KK2, the conductor ME3 is formed by selecting the conductive film ME3A to be the conductor ME3 in a self-aligned manner without using a mask. Therefore, the conductor ME3 can be formed without an alignment margin, resulting in a reduction in the area occupied by the transistor MTCK or the transistor MTHN.

Since the transistor MTCK and the transistor MTHN that are illustrated in FIG. 64A to FIG. 64D each have a structure in which the conductor ME3 is not formed above the conductor ME2 in the Z direction, the parasitic capacitance between the conductor ME2 and the conductor ME3 can be reduced. Thus, the driving frequency of each of the transistor MTCK and the transistor MTHN can be higher than the driving frequency of each of the transistor MTCK and the transistor MTHN in FIG. 2A to FIG. 2D.

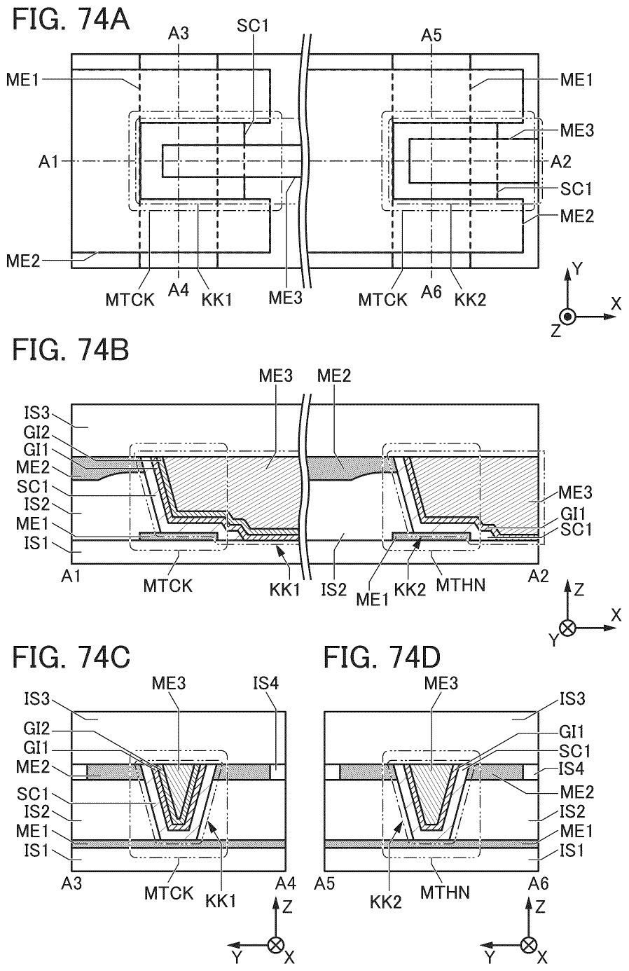

Although the side surfaces of the opening KK1 of the transistor MTCK and the opening KK2 of the transistor MTHN that are illustrated in FIG. 64A to FIG. 64D are formed to be substantially perpendicular to the surface of the substrate (not illustrated) or the insulator IS1, the angle between the side surface and the surface of the substrate (not illustrated) or the insulator IS1 may be greater than 0° and less than 70°. For example, the transistor MTCK and the transistor MTHN may be formed such that the opening KK1 and the opening KK2 each have a taper angle greater than 0° and less than 70°, as illustrated in FIG. 74A to FIG. 74D.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 5

In this embodiment, a transistor whose channel formation region includes an oxide semiconductor (an OS transistor) is described. In the description of the OS transistor, comparison with a transistor whose channel formation region includes silicon (also referred to as a Si transistor) is also described briefly.

### [OS Transistor]

An oxide semiconductor having a low carrier concentration is preferably used for the OS transistor. For example, the carrier concentration of a channel formation region in an oxide semiconductor is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet still further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. Thus, a transistor whose channel formation region is formed in an oxide semiconductor having a high density of trap states has unstable electrical characteristics in some cases.

Accordingly, in order to obtain stable electrical characteristics of the transistor, reducing the concentration of impurities in the oxide semiconductor is effective. In order to reduce the impurity concentration in the oxide semiconductor, the impurity concentration in a film that is adjacent to the oxide semiconductor is preferably reduced. Examples of the impurity include hydrogen and nitrogen. Note that an impurity in an oxide semiconductor refers to, for example, elements other than the main components of the oxide semiconductor. For example, an element with a concentration lower than 0.1 atomic % is regarded as an impurity.

When impurities and oxygen vacancies are in a channel formation region in an oxide semiconductor in the OS transistor, electrical characteristics of the OS transistor easily change, which might degrade the reliability. In the OS transistor, a defect that is an oxygen vacancy in the oxide semiconductor into which hydrogen enters (hereinafter sometimes referred to as V_{O}H) may be formed and may generate an electron serving as a carrier. When V_{O}H is formed in the channel formation region, the donor concentration in the channel formation region increases in some cases. As the donor concentration in the channel formation region increases, the threshold voltage might vary. Accordingly, when the channel formation region in the oxide semiconductor includes oxygen vacancies, the transistor tends to have normally-on characteristics (a state where a channel exists and a current flows through the transistor even when no voltage is applied to the gate electrode or a state where a channel exists and a current flows through the transistor even when the gate-source voltage is 0 V). Therefore, impurities, oxygen vacancies, and V_{O}H are preferably reduced as much as possible in the channel formation region in the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With use of an oxide semiconductor having a larger band gap than silicon, the off-state current (also referred to as off-leakage current or Ioff) of the transistor can be reduced.

In the Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, the OS transistor includes an oxide semiconductor that is a semiconductor material having a wide band gap, and thus can suppress the short-channel effect. In other words, a short-channel effect does not appear or hardly appears in the OS transistor.

The short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes referred to as S value), an increase in leakage current, and the like. Here, the S value means the amount of change in gate voltage in the subthreshold region by which the drain current is changed by one order of magnitude at a constant drain voltage.

The characteristic length is widely used as an indicator of resistance to a short-channel effect. The characteristic length is an indicator of curving of potential in a channel formation region. When the characteristic length is shorter, the potential rises more sharply, which means that the resistance to a short-channel effect is high.

The OS transistor is an accumulation-type transistor and a Si transistor is an inversion-type transistor. Accordingly, the OS transistor has a shorter characteristic length between a source region and a channel formation region and a shorter characteristic length between a drain region and the channel formation region than the Si transistor. Therefore, the OS transistor has higher resistance to a short-channel effect than the Si transistor. That is, in the case where a transistor with a short channel length is desired to be manufactured, the OS transistor is more suitable than the Si transistor.

Even in the case where the carrier concentration in an oxide semiconductor is reduced until a channel formation region becomes an i-type or substantially i-type region, the conduction band minimum of the channel formation region in a short-channel transistor decreases because of the Conduction-Band-Lowering (CBL) effect; thus, the energy difference between the conduction band minimum of a source region or a drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source region and the drain region become n⁺-type regions.

The OS transistor having the above structure enables a semiconductor device to have favorable electrical characteristics even when the semiconductor device is miniaturized or highly integrated. For example, the semiconductor device can have favorable electrical characteristics even when the OS transistor has a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. In contrast, it is sometimes difficult for the Si transistor to have a gate length less than or equal to 20 nm or less than or equal to 15 nm because of appearance of a short-channel effect. Therefore, the OS transistor can be suitably used as a transistor having a short channel length as compared with the Si transistor. Note that the gate length refers to the length of a gate electrode in a direction in which carriers move inside a channel formation region during an operation of the transistor and to the width of a bottom surface of the gate electrode in a plan view of the transistor.

Miniaturization of the OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz at room temperature, for example.

As described above, the OS transistor has an effect superior to that of the Si transistor, such as a low off-state current and capability of having a short channel length.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 6

In this embodiment, a structure example of a display apparatus of one embodiment of the present invention will be described.

### <Structure Example of Display Apparatus>

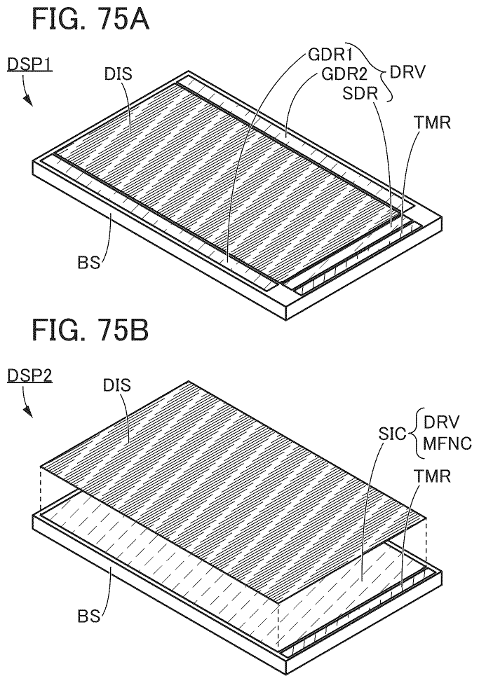

FIG. 75A is a schematic perspective view illustrating a display apparatus of one embodiment of the present invention. A display apparatus DSP1 includes a display region DIS, a driver circuit region DRV, and a terminal region TMR, for example. The display apparatus DSP1 includes the substrate BS, and the display region DIS, the driver circuit region DRV, and the terminal region TMR are located over the substrate BS.

The driver circuit region DRV includes, for example, a driver circuit GDR1, a driver circuit GDR2, and a driver circuit SDR.

As the substrate BS, a semiconductor substrate (e.g., a single crystal substrate containing silicon or germanium as a material) can be used, for example. Besides the semiconductor substrate, any of the following can be used as the substrate BS: an SOI (Silicon On Insulator) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, and paper or a base material film containing a fibrous material. Examples of the glass substrate include barium borosilicate glass, aluminoborosilicate glass, and soda lime glass. Examples of the flexible substrate, the attachment film, the base material film, and the like include plastics typified by polyethylene terephthalate (PET), polyethylene naphthalate (PEN), polyethersulfone (PES), and polytetrafluoroethylene (PTFE). Another example is a synthetic resin such as an acrylic resin. Other examples include polypropylene, polyester, polyvinyl fluoride, and polyvinyl chloride. Other examples include polyamide, polyimide, aramid, an epoxy resin, an inorganic vapor deposition film, and paper. Note that in the case where the manufacturing process of the display apparatus DSP1 involves heat treatment, a highly heat-resistant material is preferably used for the substrate BS.

In particular, in the case where a semiconductor substrate including silicon as a material is used as the substrate BS, transistors included in the display region DIS and the driver circuit region DRV can be Si transistors and can be formed over the substrate BS.

For example, in the case where transistors included in the display region DIS and the driver circuit region DRV are OS transistors, there is no particular limitation on the substrate where the OS transistor is formed, and as described above, a substrate that can be used as the substrate BS can sometimes be used.

One or more selected from the driver circuit GDR1, the driver circuit GDR2, and the driver circuit SDR included in the driver circuit region DRV may be mounted as an IC (Integrated Circuit) on the substrate BS by a COG (Chip On Glass) technique.

The driver circuit GDR1 and the driver circuit GDR2 each function as a driver circuit for displaying an image on the display region DIS, for example. Specifically, for example, the driver circuit GDR1 and the driver circuit GDR2 each function as a gate driver circuit for the display region DIS. For example, the driver circuit SDR functions as a source driver circuit for the display region DIS.

Thus, for example, the driver circuit GD in FIG. 1 described in the above embodiment can be employed for each of the driver circuit GDR1 and the driver circuit GDR2. In addition, for example, the driver circuit SD in FIG. 1 described in the above embodiment can be used for the driver circuit SDR.

The terminal region TMR includes a terminal for supplying an image signal and a power supply voltage into the display apparatus DSP1 from the outside of the display apparatus DSP1. An FPC (Flexible Printed Circuit) may be electrically connected to the terminal region TMR. A chip may be provided as an IC over the FPC by a COF (Chip On Film) technique. The IC, for example, may include a driver circuit for displaying an image on the display region DIS.

The display region DIS includes, for example, a plurality of pixels. The plurality of pixels may be arranged in a matrix in the display region DIS.

Each of the plurality of pixels can express one color or a plurality of colors. In particular, the plurality of colors can be, for example, three colors of red, green, and blue. Alternatively, the plurality of colors may be two or more colors selected from, for example, red, green, blue, cyan, magenta, yellow, and white. Note that in the case where each of pixels expressing different colors is called a subpixel and white is expressed by a plurality of subpixels expressing different colors, the plurality of subpixels are collectively called a pixel in some cases. In the description in this specification and the like, a subpixel is referred to as a pixel for convenience.

Note that the display apparatus of one embodiment of the present invention is not limited to having the structure of the display apparatus DSP1 illustrated in FIG. 75A. For example, the display apparatus of one embodiment of the present invention may have the structure of the display apparatus DSP2 illustrated in FIG. 75B.

The display apparatus DSP2 illustrated in FIG. 75B includes the display region DIS, a circuit region SIC, and the terminal region TMR, for example. The display apparatus DSP2 further includes the substrate BS, like the display apparatus DSP1. The display apparatus DSP2 is different from the display apparatus DSP1 in that the circuit region SIC and the terminal region TMR are provided over the substrate BS and the display region DIS is provided over the circuit region SIC.

The circuit region SIC includes, for example, the driver circuit region DRV described above. The circuit region SIC may include any of a variety of functional circuits other than the driver circuit region DRV. In this embodiment, the functional circuit is included in a functional circuit region MFNC.

The functional circuit region MFNC may include a GPU (Graphics Processing Unit), for example. In the case where the display apparatus DSP2 includes a touch panel, the functional circuit region MFNC may include a sensor controller for controlling a touch sensor included in the touch panel. Note that the sensor controller corresponds to the driver circuit TSD in the display apparatus in FIG. 1.

In the case where a light-emitting device containing an organic EL material is used as the display element of the display apparatus DSP2, an EL correction circuit may be included in the functional circuit region MFNC. The EL correction circuit has a function of appropriately adjusting the amount of current input to the light-emitting device containing an organic EL material. Since the emission luminance of the light-emitting device containing an organic EL material is proportional to the current, when the characteristics of a driving transistor electrically connected to the light-emitting device are not favorable, the luminance of light emitted from the light-emitting device might be lower than a desired luminance. For example, the EL correction circuit monitors the amount of current flowing through the light-emitting device and increases the amount of current when the amount of current is smaller than a desired amount, whereby the luminance of light emitted from the light-emitting device can be increased. By contrast, when the amount of current is larger than a desired amount, the amount of current flowing through the light-emitting device may be adjusted to be small.

In the case where a liquid crystal element is used as the display element of the display apparatus DSP2, a gamma correction circuit may be included in the functional circuit region MFNC.

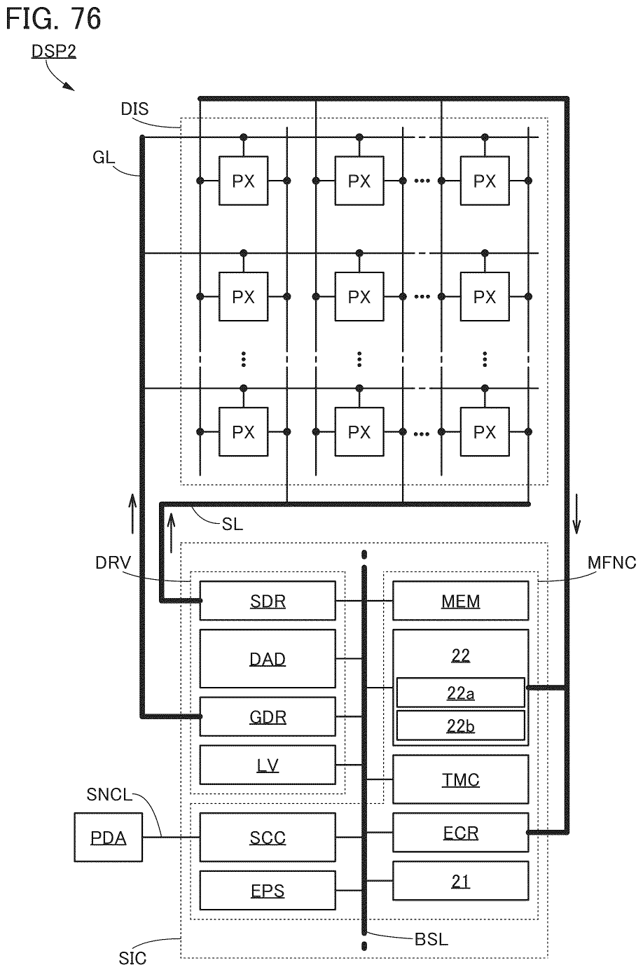

FIG. 76 is a block diagram showing a structure example of the display apparatus DSP2 illustrated in FIG. 75B. The display apparatus DSP2 illustrated in FIG. 76 includes the display region DIS and the circuit region SIC, for example. FIG. 76 illustrates a sensor PDA, and the sensor PDA may be placed inside or outside the display apparatus DSP2.

The display apparatus DSP1 in FIG. 75A may be electrically connected to the functional circuit region MFNC located outside the display apparatus DSP1 through the terminal region TMR. The structure of the display apparatus DSP1 in this case can be regarded as similar to the structure of the display apparatus DSP2 illustrated in FIG. 76.

In FIG. 76, the thick solid lines denote a plurality of wirings or bus wirings.

In FIG. 76, a plurality of pixel circuits PX are arranged in a matrix in the display region DIS, for example. The pixel circuit PX can be, for example, a pixel circuit provided with one or more selected from a liquid crystal display device, a light-emitting device including an organic EL material, a light-emitting device including an inorganic EL material, and a light-emitting device including a light-emitting diode such as a micro LED. Note that in the description in this embodiment, the pixel circuit PX in the display region DIS includes a light-emitting device including an organic EL material.

In FIG. 76, the circuit region SIC includes the driver circuit region DRV and the functional circuit region MFNC, as described above.

The driver circuit region DRV functions as a peripheral circuit for driving the display region DIS, for example. Specifically, the driver circuit region DRV includes, for example, the driver circuit SDR, a digital-to-analog converter circuit DAD, the driver circuit GDR, and a level shifter circuit LV. Note that the driver circuit SDR corresponds to the driver circuit SD in FIG. 1, and the driver circuit GDR corresponds to the driver circuit GD in FIG. 1, for example. The level shifter circuit LV corresponds to the amplifier circuit LVS illustrated in FIG. 4.

The functional circuit region MFNC can be provided with, for example, a memory device storing image data to be displayed on the display region DIS, a decoder for decoding encoded image data, a GPU for processing image data, a power supply circuit, a correction circuit, and a CPU. In FIG. 76, the functional circuit region MFNC includes a memory device MEM, a GPU 22, an EL correction circuit ECR, a timing controller TMC, a CPU (NoffCPU (registered trademark)) 21, a sensor controller SCC, and a power supply circuit EPS, for example.

In the display apparatus DSP2 in FIG. 76, for example, a bus wiring BSL is electrically connected to each of the circuits included in the driver circuit region DRV and each of the circuits included in the functional circuit region MFNC.

The driver circuit SDR has a function of transmitting image data to the pixel circuit PX included in the display region DIS, for example. Thus, the driver circuit SDR is electrically connected to the pixel circuit PX through the wiring SL.

The digital-to-analog converter circuit DAD has a function of, for example, converting image data that has been digitally processed by the GPU or correction circuit described later, into analog data. The image data converted into analog data is transmitted to the display region DIS through the driver circuit SDR. Note that the digital-to-analog converter circuit DAD may be included in the driver circuit SDR, and the image data may be transmitted to the driver circuit SDR, the digital-to-analog converter circuit DAD, and the display region DIS in this order. Note that the digital-to-analog converter circuit DAD corresponds to the converter circuit CVT illustrated in FIG. 3 or FIG. 4.

The driver circuit GDR has a function of selecting the pixel circuit PX to which image data is to be transmitted in the display region DIS, for example. Thus, the driver circuit GDR is electrically connected to the pixel circuit PX through the wiring GL.

The amplifier circuit LVS has a function of converting the signals to be input to the driver circuit SDR, the digital-to-analog converter circuit DAD, the driver circuit GDR, and the like into signals having appropriate levels, for example.

The memory device MEM has a function of storing image data to be displayed on the display region DIS, for example. Note that the memory device MEM can be configured to store the image data as digital data or analog data.

In the case where the memory device MEM stores image data, the memory device MEM is preferably a nonvolatile memory. In this case, a NAND memory or the like can be used as the memory device MEM.

In the case where the memory device MEM stores temporary data generated in the GPU 22, the EL correction circuit ECR, the CPU 21, or the like, the memory device MEM is preferably a volatile memory. In this case, an SRAM (Static Random Access Memory), a DRAM (Dynamic Random Access Memory), or the like can be used as the memory device MEM.

The GPU 22 has a function of performing processing for plotting the image data read from the memory device MEM on the display region DIS, for example. Specifically, the GPU 22 is configured to perform pipeline processing in parallel and thus can perform high-speed processing of the image data to be displayed on the display region DIS. The GPU 22 can also have a function of a decoder for decoding an encoded image.

The functional circuit region MFNC may include a plurality of circuits that can increase the display quality of the display region DIS. As such circuits, for example, correction circuits (dimming or toning correction circuits) that detect and correct color irregularity of an image displayed on the display region DIS to optimize the image may be provided. In the case where the pixel in the display region DIS includes a light-emitting device including an organic EL, the functional circuit region MFNC may be provided with an EL correction circuit. Note that because the description in this embodiment is made on the assumption that the pixel circuit PX in the display region DIS includes the light-emitting device including an organic EL material, the functional circuit region MFNC in this example is provided with the EL correction circuit ECR.

The above-described image correction may be performed using artificial intelligence. For example, it is possible that a current flowing in the display device included in the pixel (or a voltage applied to the display device) is monitored and acquired, an image displayed on the display region DIS is acquired with an image sensor or the like, the current (or voltage) and the image are used as input data in an arithmetic operation of the artificial intelligence (e.g., an artificial neural network), and the output result is used to determine whether the image should be corrected.

Such an arithmetic operation of artificial intelligence can be applied to not only image correction but also upconversion processing on image data. In this case, upconversion of low-screen resolution image data in accordance with the image resolution of the display region DIS allows a high-display-quality image to be displayed on the display region DIS. The arithmetic operation of artificial intelligence can also be applied to downconversion processing on image data.

Note that the above-described arithmetic operation of artificial intelligence can be performed using the GPU 22 included in the functional circuit region MFNC. That is, the GPU 22 can be used to perform arithmetic operations for various kinds of correction (e.g., color irregularity correction or upconversion processing). The GPU 22 may include a circuit 22a that corrects color irregularity and a circuit 22b that performs upconversion processing.

Note that in this specification and the like, a GPU performing an arithmetic operation of artificial intelligence is referred to as an AI accelerator. That is, the GPU included in the functional circuit region MFNC may be replaced with an AI accelerator in the description in this specification and the like.

The timing controller TMC has a function of changing the frame rate at which an image is displayed on the display region DIS. For example, the display apparatus DSP2 can be driven at a frame rate reduced by the timing controller TMC in the case where the display region DIS displays a still image; for another example, the display apparatus DSP2 can be driven at a frame rate increased by the timing controller TMC in the case where the display region DIS displays a moving image. In other words, the display apparatus DSP2 provided with the timing controller TMC can be driven at a frame rate that is changed depending on which of a still image and a moving image is displayed. Specifically, since the frame rate can be lowered when the display region DIS displays a still image, the power consumption of the display apparatus DSP2 can be reduced.

The CPU 21 has a function of, for example, performing general-purpose processing such as execution of an operating system, control of data, and execution of various arithmetic operations and programs. In the display apparatus DSP2, the CPU 21 has a function of, for example, giving an instruction for an operation for writing or reading image data to/from the memory device MEM, an operation for correcting image data, an operation for a sensor described later, or the like. Furthermore, the CPU 21 may have a function of, for example, transmitting a control signal to at least one of the circuits included in the functional circuit region MFNC, such as the memory device, the GPU, the correction circuit, the timing controller, and a high frequency circuit.

The CPU 21 may include a circuit for temporarily backing up data (hereinafter referred to as a backup circuit). The backup circuit is preferably capable of retaining the data even after supply of a power supply voltage is stopped. For example, in the case where the display region DIS displays a still image, the CPU 21 can cease to work until an image different from the currently displayed still image is displayed. Accordingly, dynamic power consumption by the CPU 21 can be reduced in such a manner that the data under processing by the CPU 21 is backed up in the backup circuit and then supply of a power supply voltage to the CPU 21 is stopped to stop the CPU 21. In this specification and the like, a CPU including a backup circuit is referred to as a NoffCPU.

The sensor controller SCC has a function of, for example, controlling the sensor PDA. FIG. 76 illustrates a wiring SNCL as a wiring for electrically connecting the sensor PDA to the sensor controller SCC.

The sensor PDA is, for example, a touch sensor that can be provided above, below, or inside the display region DIS.

Alternatively, the sensor PDA may be an illuminance sensor, for example. Specifically, the illuminance sensor acquiring the intensity of the external light with which the display region DIS is irradiated makes it possible to change the brightness (luminance) of an image displayed on the display region DIS in accordance with the intensity of the external light. For example, under intense external light, the luminance of an image displayed on the display region DIS can be increased to enhance the viewability of the image. By contrast, under weak external light, the luminance of an image displayed on the display region DIS can be lowered to reduce the power consumption.

Alternatively, the sensor PDA can be an image sensor, for example. For example, an image or the like acquired with the image sensor can be displayed on the display region DIS.

The power supply circuit EPS has a function of, for example, generating voltages to be supplied to the circuits included in the driver circuit region DRV, the circuits included in the functional circuit region MFNC, the pixels included in the display region DIS, and the like. Note that the power supply circuit EPS may have a function of selecting a circuit to which a voltage is to be supplied. For example, the power supply circuit EPS stops supply of a voltage to the circuits included in the driver circuit region DRV (e.g., the driver circuit SDR and the digital-to-analog converter circuit DAD) and the circuits included in the functional circuit region MFNC (e.g., the CPU 21 and the GPU 22) during a period in which the display region DIS displays a still image, whereby the power consumption of the whole display apparatus DSP can be reduced.

### <Cross-Sectional Structure Example 1 of Display Apparatus>

Next, a cross-sectional structure example of the display apparatus DSP1 illustrated in FIG. 75A is described.

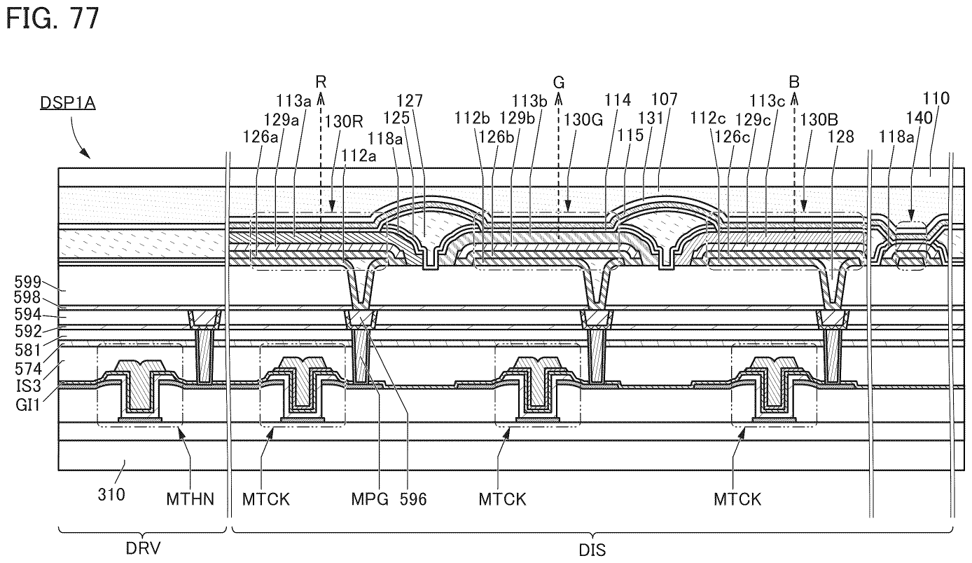

A display apparatus DSP1A illustrated in FIG. 77 is a cross-sectional structure example of the display apparatus DSP1 illustrated in FIG. 75A. The display apparatus DSP1A has a structure provided with a pixel circuit, a driver circuit, and the like over a substrate 310. In the display apparatus DSP1A in FIG. 77, the driver circuit region DRV and the display region DIS that are illustrated in FIG. 75A are illustrated.

The substrate 310 in FIG. 77 corresponds to the substrate BS illustrated in FIG. 75A. The diagonal size of the display apparatus DSP1A can be determined depending on the kind and the size of the substrate 310, for example. For example, in the case where a display apparatus with a diagonal size of greater than or equal to 30 inches, greater than or equal to 50 inches, greater than or equal to 70 inches, or greater than or equal to 100 inches is fabricated for a television device or an electronic device for digital signage application, a glass substrate may be used as the substrate 310. In the case where a display apparatus with a diagonal size of less than or equal to 10 inches, less than or equal to 5 inches, less than or equal to 1.5 inches, less than or equal to 1 inch, or less than or equal to 0.5 inches is fabricated for an XR device or a wearable information terminal, a semiconductor substrate may be used as the substrate 310.

There is no particular limitation on the screen ratio (aspect ratio) of the display apparatus DSP1A. For example, the display apparatus DSP1A is compatible with a variety of screen ratios such as 1:1 (a square), 4:3, 16:9, 16:10, 21:9, and 32:9.

In the display apparatus DSP1A in FIG. 77, the transistor MTHN and the transistor MTCK are formed over the substrate 310. Light-emitting devices 130 (a light-emitting device 130R, a light-emitting device 130G, and a light-emitting device 130B in FIG. 77) are provided above the transistor MTHN and the transistor MTCK.

The transistor MTHN is included in the display region DIS and functions as, for example, a transistor included in the pixel circuit PX. The transistor MTCK functions as a transistor included in the driver circuit region DRV. For example, the transistor MTCK can be the transistor MTCK described in Embodiment 1, and the transistor MTHN can be the transistor MTHN described in Embodiment 1. The light-emitting device 130 can be a light-emitting device included in the pixel circuit PX.

The transistor MTCK and the transistor MTHN are provided over the substrate 310. For the insulator, the conductor, and the semiconductor in the vicinity of the transistor MTCK and the transistor MTHN, Embodiment 1 and Embodiment 3 are referred to.

As described in Embodiment 1 and Embodiment 3, the insulator IS3 is formed above the transistor MTHN and the transistor MTCK. An insulator 574 and an insulator 581 are stacked in this order over the insulator IS3.

The insulator 574 preferably has a function of inhibiting diffusion of impurities such as water and hydrogen (e.g., one or both of a hydrogen atom and a hydrogen molecule). In other words, the insulator 574 preferably functions as a barrier insulating film that inhibits the entry of the impurities into the transistor MTHN and the transistor MTCK. Moreover, the insulator 574 preferably has a function of inhibiting diffusion of oxygen (e.g., one or both of an oxygen atom and an oxygen molecule). For example, the insulator 574 preferably has a lower oxygen permeability than the insulator IS2 and the insulator IS3.

Thus, the insulator 574 preferably functions as a barrier insulating film that inhibits diffusion of impurities such as water and hydrogen. Accordingly, it is preferable to use, for the insulator 574, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom (an insulating material through which the impurities are unlikely to pass). Alternatively, it is preferable to use an insulating material having a function of inhibiting diffusion of oxygen (e.g., one or both of an oxygen atom and an oxygen molecule) (an insulating material through which the oxygen is unlikely to pass).

An insulator having a function of inhibiting the passage of oxygen and impurities such as water and hydrogen can be formed to have a single layer or a stacked layer including an insulator containing one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum, for example. Specific examples of the insulator having a function of inhibiting the passage of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the insulator having a function of inhibiting the passage of oxygen and impurities such as water and hydrogen include oxides containing aluminum and hafnium (hafnium aluminate). Other examples of the insulator having a function of inhibiting the passage of oxygen and impurities such as water and hydrogen include metal nitrides such as aluminum nitride, aluminum titanium nitride, titanium nitride, silicon nitride oxide, and silicon nitride.

In particular, aluminum oxide or silicon nitride is preferably used for the insulator 574. Accordingly, it is possible to inhibit diffusion of impurities such as water and hydrogen to the transistor MTHN side and into the transistor MTCK from above the insulator 574. In addition, it is possible to inhibit diffusion of oxygen contained in the insulator IS3 or the like to above the insulator 574.

The insulator 581 is preferably a film functioning as an interlayer film and having a lower permittivity than the insulator 574. When a material with a low permittivity is used for an interlayer film, parasitic capacitance generated between wirings can be reduced. The relative permittivity of the insulator 581 is preferably lower than 4, further preferably lower than 3, for example. The relative permittivity of the insulator 581 is, for example, preferably 0.7 times or less, further preferably 0.6 times or less the relative permittivity of the insulator 574. When a material with a low permittivity is used for the insulator 581 functioning as an interlayer film, parasitic capacitance generated between wirings can be reduced.

The concentration of impurities such as water and hydrogen in the insulator 581 is preferably reduced. In this case, for the insulator 581, silicon oxide, silicon oxynitride, silicon nitride oxide, or silicon nitride can be used, for example. Alternatively, for the insulator 581, silicon oxide to which fluorine is added, silicon oxide to which carbon is added, silicon oxide to which carbon and nitrogen are added, or porous silicon oxide can be used, for example. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed. Alternatively, for the insulator 581, a resin can be used. A material that can be used for the insulator 581 may be an appropriate combination of the above-described materials.

An insulator 592 and an insulator 594 are stacked in this order over the insulator 574 and the insulator 581.

For the insulator 592, it is preferable to use an insulating film having a barrier property (referred to as a barrier insulating film) which prevents diffusion of impurities such as water and hydrogen from the substrate 310, the transistor MTCK, or the transistor MTHN to a region above the insulator 592 (e.g., the region where the light-emitting device 130R, the light-emitting device 130G, the light-emitting device 130B, and the like are provided). Accordingly, for the insulator 592, it is preferable to use an insulating material that has a function of inhibiting diffusion of impurities such as a hydrogen atom, a hydrogen molecule, and a water molecule (through which the above impurities are less likely to pass). Furthermore, depending on the situation, it is preferable to use, for the insulator 592, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom (an insulating material through which the oxygen is unlikely to pass). Alternatively, the insulator 592 preferably has a function of inhibiting diffusion of oxygen (e.g., one or both of an oxygen atom and an oxygen molecule).

For the film having a barrier property against hydrogen, silicon nitride formed by a CVD method can be used, for example.

The amount of released hydrogen can be analyzed by thermal desorption spectrometry (TDS), for example. The amount of hydrogen released from the insulator 324 that is converted into hydrogen atoms per area of the insulator 324 is less than or equal to 10×10¹⁵ atoms/cm², preferably less than or equal to 5×10¹⁵ atoms/cm² in the TDS in a film-surface temperature range of 50° C. to 500° C., for example.

Like the insulator 581, the insulator 594 is preferably an interlayer film with a low permittivity. Thus, for the insulator 594, a material that can be used for the insulator 581 can be used.

Note that the insulator 594 preferably has a lower permittivity than the insulator 592. The relative permittivity of the insulator 594 is preferably lower than 4, further preferably lower than 3, for example. The relative permittivity of the insulator 594 is, for example, preferably 0.7 times or less, further preferably 0.6 times or less the relative permittivity of the insulator 592. When a material with a low permittivity is used for the insulator 594 functioning as an interlayer film, parasitic capacitance generated between wirings can be reduced.

A conductor MPG functioning as a plug or a wiring is embedded in the insulator GI1 and the insulator IS3, and a conductor 596 functioning as a plug or a wiring is embedded in the insulator 592 and the insulator 594. In particular, the conductor MPG and the conductor 596 are electrically connected to the light-emitting device or the like provided above the insulator 594. A plurality of conductors each having a function of a plug or a wiring are collectively denoted by the same reference numeral in some cases. Moreover, in this specification and the like, a wiring and a plug connected to the wiring may be a single component. That is, part of a conductor functions as a wiring in some cases and part of a conductor functions as a plug in other cases.

As a material of each of plugs and wirings (e.g., the conductor MPG and the conductor 596), a single layer or a stacked layer of one or more conductive materials selected from a metal material, an alloy material, a metal nitride material, and a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used for formation. The use of a low-resistance conductive material can reduce wiring resistance.

An insulator 598 and an insulator 599 are sequentially formed over the insulator 594 and the conductor 596.

Like the insulator 592, for example, the insulator 598 is preferably formed using an insulator having a barrier property against one or more selected from hydrogen, oxygen, and water. Like the insulator 594, the insulator 599 is preferably formed using an insulator having a relatively low dielectric constant to reduce parasitic capacitance generated between wirings. The insulator 599 has functions of an interlayer insulating film and a planarization film.

The light-emitting device 130 and a connection portion 140 are formed over the insulator 599.

The connection portion 140 is referred to as a cathode contact portion in some cases, and is electrically connected to cathode electrodes of the light-emitting device 130R, the light-emitting device 130G, and the light-emitting device 130B. The connection portion 140 in FIG. 77 includes one or more conductors selected from a conductor 112a to a conductor 112c described later, at least one of a conductor 126a to a conductor 126c described later, one or more conductors selected from a conductor 129a to a conductor 129c described later, a common layer 114 described later, and a common electrode 115 described later.

Note that the connection portion 140 may be provided to surround four sides of the display portion in the plan view, or may be provided in the display portion (e.g., between adjacent light-emitting devices 130) (not illustrated).

The light-emitting device 130R includes the conductor 112a, the conductor 126a over the conductor 112a, and the conductor 129a over the conductor 126a. All of the conductor 112a, the conductor 126a, and the conductor 129a can be referred to as a pixel electrode, or one or two of them can be referred to as a pixel electrode. The light-emitting device 130G includes the conductor 112b, the conductor 126b over the conductor 112b, and the conductor 129b over the conductor 126b. As in the light-emitting device 130R, all of the conductor 112b, the conductor 126b, and the conductor 129b can be referred to as a pixel electrode, or one or two of them can be referred to as a pixel electrode. The light-emitting device 130B includes the conductor 112c, the conductor 126c over the conductor 112c, and the conductor 129c over the conductor 126c. As in the light-emitting device 130R and the light-emitting device 130G, all of the conductor 112c, the conductor 126c, and the conductor 129c can be referred to as a pixel electrode, or one or two of them can be referred to as a pixel electrode.

For each of the conductor 112a to the conductor 112c and the conductor 126a to the conductor 126c, a conductive layer functioning as a reflective electrode can be used, for example. For the conductive layer functioning as a reflective electrode, a conductor with high visible-light reflectance such as silver, aluminum, or an alloy film of silver (Ag), palladium (Pd), and copper (Cu) (an Ag—Pd—Cu (APC) film) can be used. For each of the conductor 112a to the conductor 112c and the conductor 126a to the conductor 126c, a stacked-layer film in which a pair of titanium films sandwich aluminum (a film in which Ti, Al, and Ti are stacked in this order), or a stacked-layer film in which a pair of indium tin oxide films sandwich silver (a film in which ITO, Ag, and ITO are stacked in this order) can be used.

For example, a conductive layer functioning as a reflective electrode may be used for each of the conductor 112a to the conductor 112c, and a conductor with a high light-transmitting property may be used for each of the conductor 126a to the conductor 126c. Examples of the conductor with a high light-transmitting property include an alloy of silver and magnesium and indium tin oxide (sometimes referred to as ITO).

A conductive layer functioning as a transparent electrode can be used for each of the conductor 129a to the conductor 129c. For the conductive layer functioning as a transparent electrode, for example, the above-described conductor with a high light-transmitting property can be used.

A microcavity structure may be provided in the light-emitting device 130 to be described in detail later. The microcavity structure refers to a structure in which the distance between the bottom surface of the light-emitting layer and the top surface of a lower electrode is set to a thickness depending on a wavelength of color of light emitted from the light-emitting layer. In that case, a light-transmitting and light-reflective conductive material is preferably used for each of the conductor 129a to the conductor 129c which serve as an upper electrode (a common electrode), and a light-reflective conductive material is preferably used for each of the conductor 112a to the conductor 112c and the conductor 126a to the conductor 126c which serve as lower electrodes (pixel electrodes).

The microcavity structure refers to a structure in which the optical distance between the lower electrode and the light-emitting layer is adjusted to be (2n−1)λ/4 (n is a natural number greater than or equal to 1, and λ is a wavelength of emitted light desired to be amplified). Thus, light that is reflected back by the lower electrode (reflected light) considerably interferes with light that directly enters the upper electrode from the light-emitting layer (incident light). Accordingly, the phases of the reflected light and the incident light each having the wavelength λ can be aligned with each other, and the light emitted from the light-emitting layer can be further amplified. Meanwhile, in the case where the reflected light and the incident light each have a wavelength other than the wavelength λ, their phases are not aligned with each other, resulting in attenuation without resonation.

The conductor 112a is connected to the conductor 596 embedded in the insulator 594 through an opening formed in the insulator 599. An end portion of the conductor 112a is positioned on the outer side of an end portion of the conductor 126a. The end portion of the conductor 126a and an end portion of the conductor 129a are aligned or substantially aligned with each other.

Since the conductor 112b of the light-emitting device 130G and the conductor 112b of the light-emitting device 130B are similar to the conductor 112a of the light-emitting device 130R, detailed description of the conductors is omitted. Since the conductor 126b of the light-emitting device 130G and the conductor 126b of the light-emitting device 130B are similar to the conductor 126a of the light-emitting device 130R, detailed description of the conductors is omitted. Since the conductor 129b of the light-emitting device 130G and the conductor 129c of the light-emitting device 130B are similar to the conductor 129a of the light-emitting device 130R, detailed description of the conductors is omitted.

Depression portions are formed in the conductor 112a, the conductor 112b, and the conductor 112c to cover the openings provided in the insulator 599. A layer 128 is embedded in the depression portions.

The layer 128 has a function of filling the depression portions of the conductor 112a to the conductor 112c. The conductor 126a to the conductor 126c electrically connected to the conductor 112a to the conductor 112c, respectively, are provided over the conductor 112a to the conductor 112c and the layer 128. Thus, regions overlapping with the depression portions of the conductor 112a to the conductor 112c can also be used as the light-emitting regions, increasing the aperture ratio of the pixels.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer containing an organic material can be suitably used for the layer 128. For the layer 128, an acrylic resin, a polyimide resin, an epoxy resin, a polyamide resin, a polyimide-amide resin, a siloxane resin, a benzocyclobutene-based resin, a phenol resin, or a precursor of any of these resins can be used, for example. A photosensitive resin can also be used for the layer 128. As the photosensitive resin, a positive material or a negative material is given.

When a photosensitive resin is used, the layer 128 can be formed through only light-exposure and development steps, reducing the influence of dry etching or wet etching on the surfaces of the conductor 112a, the conductor 112b, and the conductor 112c. When the layer 128 is formed using a negative photosensitive resin, the layer 128 can sometimes be formed using the same photomask (light-exposure mask) as the photomask used for forming the opening in the insulator 599.

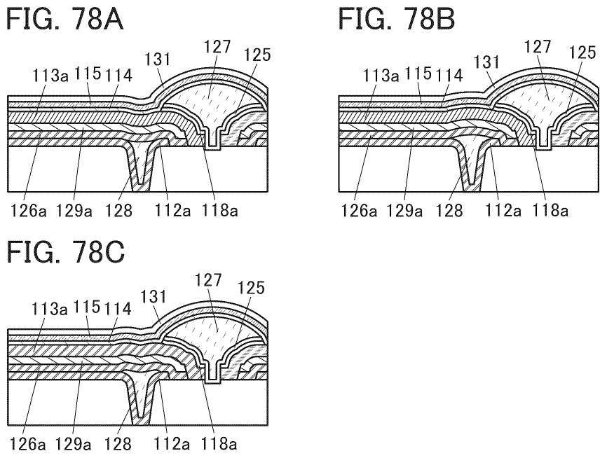

Although FIG. 77 shows an example in which the top surface of the layer 128 includes a flat portion, the shape of the layer 128 is not particularly limited. As illustrated in FIG. 78A, the middle and the vicinity of the top surface of the layer 128 may be concave in the cross-sectional view. Alternatively, as illustrated in FIG. 78B, the middle and the vicinity of the layer 128 may be convex in the cross-sectional view. As illustrated in FIG. 78C, the middle and the vicinity of the layer 128 may be concave and convex.

The light-emitting device 130R includes a first layer 113a, the common layer 114 over the first layer 113a, and the common electrode 115 over the common layer 114. The light-emitting device 130G includes a second layer 113b, the common layer 114 over the second layer 113b, and the common electrode 115 over the common layer 114. The light-emitting device 130B includes a third layer 113c, the common layer 114 over the third layer 113c, and the common electrode 115 over the common layer 114.

The first layer 113a is formed to cover the top surface and side surface of the conductor 126a and the top surface and side surface of the conductor 129a. Similarly, the second layer 113b is formed to cover the top surface and side surface of the conductor 126b and the top surface and side surface of the conductor 129b. Similarly, the third layer 113c is formed to cover the top surface and side surface of the conductor 126c and the top surface and side surface of the conductor 129c. Accordingly, regions provided with the conductor 126a, the conductor 126b, and the conductor 126c can be entirely used as the light-emitting regions of the light-emitting device 130R, the light-emitting device 130G, and the light-emitting device 130B, respectively, increasing the aperture ratio of the pixels.

In the light-emitting device 130R, the first layer 113a and the common layer 114 can be collectively referred to as an EL layer. Similarly, in the light-emitting device 130G, the second layer 113b and the common layer 114 can be collectively referred to as an EL layer. Similarly, in the light-emitting device 130B, the third layer 113c and the common layer 114 can be collectively referred to as an EL layer.

There is no particular limitation on the structure of the light-emitting device in this embodiment, and the light-emitting device can have a single structure or a tandem structure.

The first layer 113a, the second layer 113b, and the third layer 113c each have an island shape after being processed by a photolithography method. Thus, at each of end portions of the first layer 113a, the second layer 113b, and the third layer 113c, an angle between the top surface and side surface is approximately 90°. By contrast, for example, an organic film formed using an FMM (Fine Metal Mask) tends to have a thickness that gradually decreases with decreasing distance to an end portion, and has the top surface forming a slope in an area extending greater than or equal to 1 μm and less than or equal to 10 μm from the end portion, for example; thus, such an organic film has a shape whose top surface and side surface cannot be easily distinguished from each other.

The top surface and side surface of each of the first layer 113a, the second layer 113b, and the third layer 113c are clearly distinguished from each other. Accordingly, as for the first layer 113a and the second layer 113b which are adjacent to each other, one of the side surfaces of the first layer 113a and one of the side surfaces of the second layer 113b face to each other. This applies to a combination of any two of the first layer 113a, the second layer 113b, and the third layer 113c.

The first layer 113a, the second layer 113b, and the third layer 113c each include at least a light-emitting layer. For example, a structure is preferable in which the first layer 113a includes a light-emitting layer that emits red light, the second layer 113b includes a light-emitting layer that emits green light, and the third layer 113c includes a light-emitting layer that emits blue light. Other than the above colors, cyan, magenta, yellow, or white can be employed for the light-emitting layers.

The first layer 113a, the second layer 113b, and the third layer 113c each preferably include a light-emitting layer and a carrier-transport layer (an electron-transport layer or a hole-transport layer) over the light-emitting layer. Since surfaces of the first layer 113a, the second layer 113b, and the third layer 113c may be exposed in the manufacturing process of the display apparatus, providing the carrier-transport layer over the light-emitting layers inhibits the light-emitting layers from being exposed on the outermost surface, so that damage to the light-emitting layers can be reduced. Accordingly, the reliability of the light-emitting devices can be improved.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting device 130R, the light-emitting device 130G, and the light-emitting device 130B.

The common electrode 115 is shared by the light-emitting device 130R, the light-emitting device 130G, and the light-emitting device 130B. As illustrated in FIG. 77, the common electrode 115 shared by the plurality of light-emitting devices is electrically connected to a conductor included in the connection portion 140.

The insulator 125 preferably has a function of a barrier insulating layer against one or both of water and oxygen. Alternatively, the insulator 125 preferably has a function of inhibiting diffusion of one or both of water and oxygen. Alternatively, the insulator 125 preferably has a function of capturing or fixing (also referred to as gettering) one or both of water and oxygen. When the insulator 125 has a function of a barrier insulating layer or a gettering function, entry of impurities (typically, one or both of water and oxygen) that would be diffused into the light-emitting devices from the outside can be inhibited. With this structure, a highly reliable light-emitting device and a highly reliable display panel can be provided.

The insulator 125 preferably has a low impurity concentration. Accordingly, degradation of the EL layer, which is caused by entry of impurities into the EL layer from the insulator 125, can be inhibited. In addition, when the impurity concentration is reduced in the insulator 125, a barrier property against one or both of water and oxygen can be increased. For example, it is desirable that one or both of the hydrogen concentration and the carbon concentration in the insulator 125 be sufficiently low.

As the insulator 127, an insulating layer containing an organic material can be favorably used. As the organic material, a photosensitive organic resin is preferably used; for example, a photosensitive resin composition containing an acrylic resin may be used. The viscosity of the material of the insulator 127 is greater than or equal to 1 cP and less than or equal to 1500 cP, and is preferably greater than or equal to 1 cP and less than or equal to 12 cP. By setting the viscosity of the material of the insulator 127 in the above-described range, the insulator 127 having a tapered shape, which is described later, can be formed relatively easily. Note that in this specification and the like, an acrylic resin refers to not only a polymethacrylic acid ester or a methacrylic resin, but also all the acrylic polymer in a broad sense in some cases.

Note that in this specification and the like, a tapered shape refers to a shape in which at least part of a side surface of a structure is inclined to a substrate surface. For example, a tapered shape preferably includes a region where an angle formed between the inclined side surface and the substrate surface (such an angle is also referred to as a taper angle) is less than 90°.

Note that the organic material that can be used for the insulator 127 is not limited to the above as long as the insulator 127 has a tapered side surface as described later. For the insulator 127, an acrylic resin, a polyimide resin, an epoxy resin, an imide resin, a polyamide resin, a polyimide-amide resin, a silicone resin, a siloxane resin, a benzocyclobutene-based resin, a phenol resin, or a precursor of any of these resins can be used in some cases, for example. Alternatively, an organic material such as polyvinyl alcohol (PVA), polyvinylbutyral (PVB), polyvinylpyrrolidone, polyethylene glycol, polyglycerin, pullulan, water-soluble cellulose, or an alcohol-soluble polyamide resin can be employed for the insulator 127 in some cases. For the insulator 127, for example, a photoresist can be used as the photosensitive resin in some cases. Note that as the photosensitive resin, a positive material or a negative material can be used.

For the insulator 127, a material absorbing visible light may be used. When the insulator 127 absorbs light from the light-emitting device, leakage of light (stray light) from the light-emitting device to the adjacent light-emitting device through the insulator 127 can be inhibited. Thus, the display quality of the display panel can be improved. Since the display quality of the display panel can be improved without using a polarizing plate, the weight and thickness of the display panel can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two colors or three or more colors is particularly preferred, in which case the effect of blocking visible light can be enhanced. In particular, mixing color filter materials of three or more colors enables the formation of a black or nearly black resin layer.

For example, the insulator 127 can be formed by a wet film-formation method such as spin coating, dipping, spray coating, ink-jetting, dispensing, screen printing, offset printing, doctor blade coating, slit coating, roll coating, curtain coating, or knife coating. Specifically, an organic insulating film to be the insulator 127 is preferably formed by spin coating.

The insulator 127 is formed at a temperature lower than the heat resistance temperature of the EL layer. The typical substrate temperature in formation of the insulator 127 is lower than or equal to 200° C., preferably lower than or equal to 180° C., further preferably lower than or equal to 160° C., still further preferably lower than or equal to 150° C., yet still further preferably lower than or equal to 140° C.

The description is made below on the structure of the insulator 127 or the like using the structure of the insulator 127 between the light-emitting device 130R and the light-emitting device 130G as an example. Note that the same applies to the insulator 127 between the light-emitting device 130G and the light-emitting device 130B, the insulator 127 between the light-emitting device 130B and the light-emitting device 130R, and the like. The description made below sometimes using an end portion of the insulator 127 over the second layer 113b as an example applies to an end portion of the insulator 127 over the first layer 113a and an end portion of the insulator 127 over the third layer 113c.

In a cross-sectional view of the display apparatus, the side surface of the insulator 127 preferably has a tapered shape with a taper angle θ1. The taper angle θ1 is an angle formed between the side surface of the insulator 127 and the substrate surface. Note that the taper angle θ1 is not limited to the angle with the substrate surface, and may be an angle formed between the side surface of the insulator 127 and the top surface of the flat portion of the insulator 125 or the top surface of the flat portion of the second layer 113b. When the side surface of the insulator 127 has a tapered shape, the side surface of the insulator 125 and the side surface of the mask layer 118a also have a tapered shape in some cases.

The taper angle θ1 of the insulator 127 is less than 90°, preferably less than or equal to 60°, and further preferably less than or equal to 45°. Such a forward tapered shape of the end portion of the side surface of the insulator 127 can prevent disconnection, local thinning, or the like from occurring in the common layer 114 and the common electrode 115 which are provided over the end portion of the side surface of the insulator 127, leading to film formation with good coverage. The common layer 114 and the common electrode 115 can have improved in-plane uniformity in this manner, whereby the display apparatus can have improved display quality.

The top surface of the insulator 127 preferably has a convex shape in a cross-sectional view of the display apparatus. The top surface of the insulator 127 preferably has a convex shape that bulges gradually toward the center. The insulator 127 preferably has a shape such that the projecting portion at the center portion of the top surface is connected smoothly to the tapered portion of the end portion of the side surface. When the insulator 127 has such a shape, the common layer 114 and the common electrode 115 can be formed with good coverage over the whole the insulator 127.

The insulator 127 is formed in a region between two EL layers (e.g., a region between the first layer 113a and the second layer 113b). At this time, part of the insulator 127 is placed at a position sandwiched between an end portion of the side surface of one of the EL layers (e.g., the first layer 113a) and an end portion of the side surface of the other of the EL layers (e.g., the second layer 113b).

One end portion of the insulator 127 preferably overlaps with the conductor 126a serving as a pixel electrode, and the other end portion of the insulator 127 preferably overlaps with the conductor 126b serving as a pixel electrode. With such a structure, the end portion of the insulator 127 can be formed over a substantially flat region of the first layer 113a (the second layer 113b). This makes it relatively easy to process the tapered shape of the insulator 127 as described above.

By providing the insulator 127 and the like in the above manner, a disconnected portion and a locally thinned portion can be prevented from being formed in the common layer 114 and the common electrode 115 from a substantially flat region in the first layer 113a to a substantially flat region in the second layer 113b. Thus, between the light-emitting devices, a connection defect caused by the disconnected portion and an increase in electric resistance caused by the locally thinned portion can be inhibited from occurring in the common layer 114 and the common electrode 115.

In the display apparatus of this embodiment, the distance between the light-emitting devices can be short. Specifically, the distance between the light-emitting devices, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus of this embodiment includes a region where a distance between two adjacent island-shaped EL layers is less than or equal to 1 μm, preferably less than or equal to 0.5 μm (500 nm), further preferably less than or equal to 100 nm. The distance between the light-emitting devices is shortened in this manner, whereby a display apparatus with high definition and a high aperture ratio can be provided.

A protective layer 131 is provided over the light-emitting device 130. The protective layer 131 is a film serving as a passivation film for protecting the light-emitting devices 130. Provision of the protective layer 131 covering the light-emitting device can inhibit an impurity such as water and oxygen from entering the light-emitting device, and increase the reliability of the light-emitting device 130. For the protective layer 131, aluminum oxide, silicon nitride, or silicon nitride oxide can be used, for example.

The protective layer 131 and a substrate 110 are bonded to each other with an adhesive layer 107. A solid sealing structure, a hollow sealing structure, or the like can be employed to seal the light-emitting devices. In FIG. 77, a solid sealing structure is employed in which a space between the substrate 310 and the substrate 110 is filled with the adhesive layer 107. Alternatively, a hollow sealing structure in which the space is filled with an inert gas (e.g., nitrogen or argon) may be employed. Here, the adhesive layer 107 may be provided not to overlap with the light-emitting devices. The space may be filled with a resin other than the frame-shaped adhesive layer 107.

For the adhesive layer 107, a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-liquid-mixture-type resin may be used. An adhesive sheet may be used.

The display apparatus DSP1A has a top-emission structure. Light from the light-emitting device is emitted toward the substrate 110 side. Thus, for the substrate 110, a material having a high visible-light-transmitting property is preferably used. For example, a substrate having a high visible-light-transmitting property may be selected as the substrate 110 among substrates usable as the substrate 310 and the substrate BS. The pixel electrode contains a material that reflects visible light, and a counter electrode (the common electrode 115) contains a material that transmits visible light.

Note that the display apparatus of one embodiment of the present invention may be not a top-emission display apparatus but a bottom-emission display apparatus where light from the light-emitting device is emitted to the substrate 310 side. In that case, a substrate having a high visible-light-transmitting property is selected as the substrate 310.

### <Cross-Sectional Structure Example 2 of Display Apparatus>

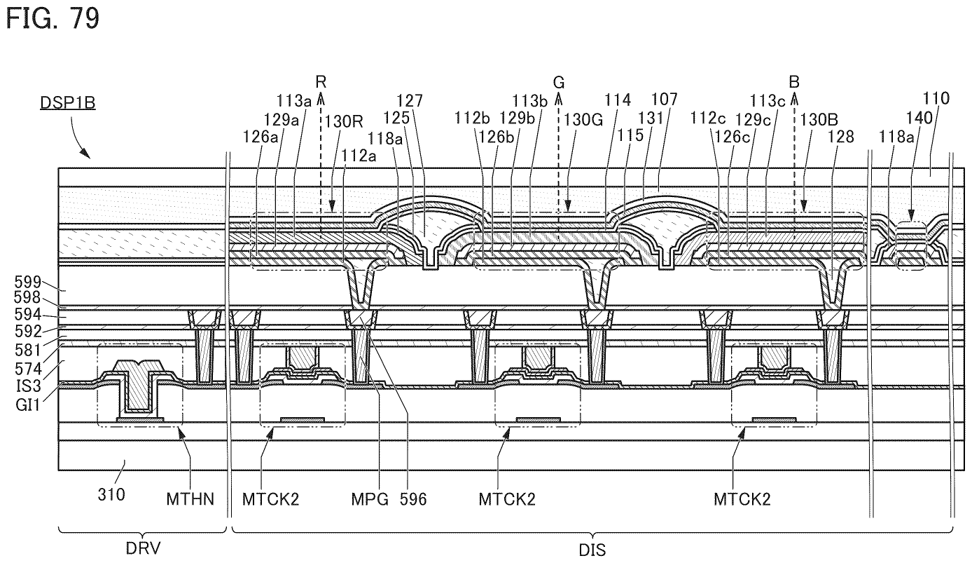

Next, a cross-sectional structure example of the display apparatus DSP1 illustrated in FIG. 75A which is different from the display apparatus DSP1A in FIG. 77 is described. A display apparatus DSP1B illustrated in FIG. 79 is a modification example of the display apparatus DSP1A and is different from the display apparatus DSP1A in the structure of the transistor provided over the substrate 310.

A substrate that can be used as the substrate BS is preferably used as the substrate 310 in the display apparatus DSP1B in FIG. 79.

In the display apparatus DSP1B in FIG. 79, the transistor MTHN and the transistor MTCK2 are formed over the substrate 310. The transistor MTHN in the display apparatus DSP1B corresponds to the transistor MTHN in the display apparatus DSP1A, and the transistor MTCK2 in the display apparatus DSP1B corresponds to the transistor MTCK2 in the display apparatus DSP1A. The transistor MTCK2 can be the transistor MTCK2 described in Embodiment 1, for example.

For the light-emitting devices 130 (the light-emitting device 130R, the light-emitting device 130G, and the light-emitting device 130B in FIG. 79) positioned above the transistor MTHN and the transistor MTCK2, the description of the light-emitting devices 130 in FIG. 77 can be referred to.

The insulator 574 is formed over the transistor MTHN and the transistor MTCK2, and the insulator 581 is formed over the insulator 574. The insulator IS3, the insulator 574, and the insulator 581 are provided with openings and the conductor MPG is embedded in the openings. Note that the insulator 574 and the insulator 581 are described later. For the conductor MPG, the description of the conductor MPG in FIG. 77 can be referred to.

The insulator 592, the insulator 594, and the conductor 596 are formed over the insulator 581 and the conductor MPG. For the insulator 592, the insulator 594, and the conductor 596, the description of the insulator 592, the insulator 594, and the conductor 596 in FIG. 77 can be referred to.

For the description of the light-emitting device 130 and the like positioned over the insulator 594 and the conductor 596, the description of the display apparatus DSP1A in FIG. 77 can be referred to.

### <Cross-Sectional Structure Example 3 of Display Apparatus>

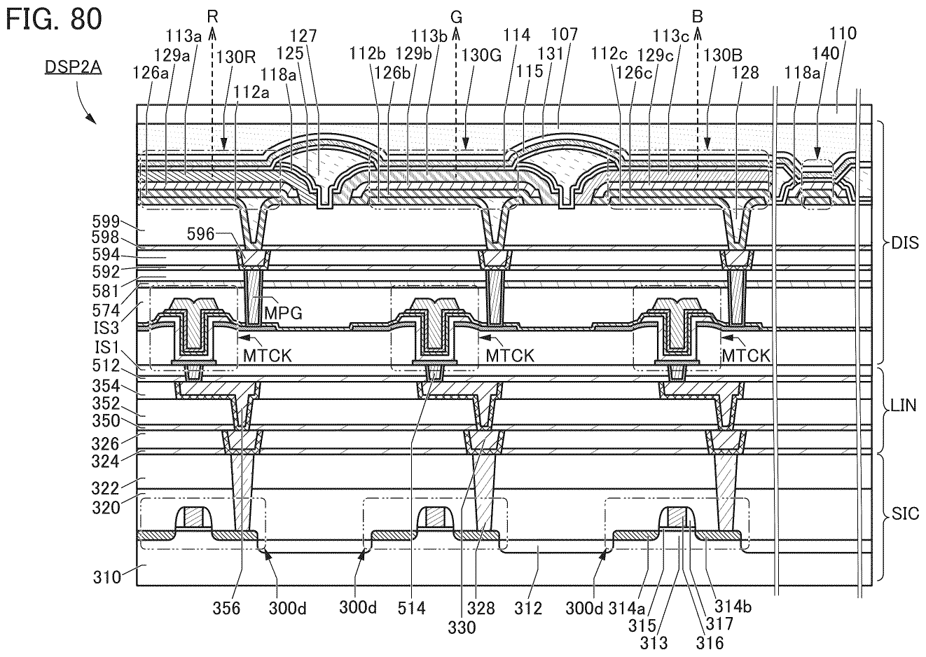

A display apparatus DSP2A in FIG. 80 is a cross-sectional structure example of the display apparatus DSP2 illustrated in FIG. 75B. The display apparatus DSP2A includes a pixel circuit and a driver circuit over the substrate 310, for example. Note that in the display apparatus DSP2A in FIG. 80, not only the circuit region SIC and the display region DIS that are illustrated in FIG. 75B but also a wiring region LIN are illustrated.

The circuit region SIC includes the substrate 310, for example, and a transistor 300d is formed over the substrate 310. The wiring region LIN is provided above the transistor 300d, and the wiring region LIN is provided with a wiring that electrically connects the transistor 300d, the transistor MTCK, the light-emitting device 130R, the light-emitting device 130G, and the light-emitting device 130B. The display region DIS is provided above the wiring region LIN, and the display region DIS includes, for example, the transistor MTCK and the light-emitting device 130 (the light-emitting device 130R, the light-emitting device 130G, and the light-emitting device 130B in FIG. 80).

That is, the transistor 300d can be a transistor included in the circuit region SIC. The transistor MTCK can be a transistor included in the pixel circuit PX. The light-emitting device 130 can be a light-emitting device included in the pixel circuit PX.

For the light-emitting devices 130 (the light-emitting device 130R, the light-emitting device 130G, and the light-emitting device 130B in FIG. 80) positioned above the transistor MTCK, the description of the light-emitting devices 130 in FIG. 77 can be referred to.

As the substrate 310, a substrate that can be used as the substrate BS can be used, for example. In the description in this embodiment, the substrate 310 is a semiconductor substrate containing silicon as a material. Therefore, a transistor included in the circuit region SIC can be a Si transistor.

For the screen ratio (aspect ratio) of the display apparatus DSP2A, the description of the screen ratio of the display apparatus DSP1 can be referred to. For the diagonal size of the display apparatus DSP2A, the description of the diagonal size of the display apparatus DSP1 can be referred to.

The transistor 300d includes an element isolation layer 312, a conductor 316, an insulator 315, an insulator 317, a semiconductor region 313 that is part of the substrate 310, and a low-resistance region 314a and a low-resistance region 314b that function as a source region and a drain region. Thus, the transistor 300 is a Si transistor. Although FIG. 80 illustrates a structure in which one of a source and a drain of the transistor 300d is electrically connected to a conductor 330, a conductor 356, and a conductor 514, which are described later, through a conductor 328 described later, the electrical connection structure in the display apparatus of one embodiment of the present invention is not limited thereto. The display apparatus of one embodiment of the present invention may have a structure in which, for example, a gate of the transistor 300d is electrically connected to the conductor 514 through the conductor 328.

The transistor 300d can be a fin type when, for example, the top surface of the semiconductor region 313 and the side surface thereof in the channel width direction are covered with the conductor 316 with the insulator 315 functioning as a gate insulator therebetween. The effective channel width can be increased in the fin-type transistor 300, so that the on-state characteristics of the transistor 300 can be improved. In addition, contribution of the electric field of a gate electrode can be increased, so that the off-state characteristics of the transistor 300 can be improved. The transistor 300 may have a planar structure instead of a fin-type structure.

Note that the transistor 300 may be either a p-channel transistor or an n-channel transistor. Alternatively, a plurality of the transistors 300 may be provided and both the p-channel transistor and the n-channel transistor may be used.

A region of the semiconductor region 313 where a channel is formed, a region in the vicinity thereof, and the low-resistance region 314a and the low-resistance region 314b that function as the source region and the drain region preferably contain a silicon-based semiconductor, specifically, preferably contain single crystal silicon. Alternatively, each of the regions may be formed using germanium, silicon germanium, gallium arsenide, aluminum gallium arsenide, or gallium nitride, for example. A structure using silicon whose effective mass is controlled by applying stress to the crystal lattice and changing the lattice spacing may be employed. Alternatively, the transistor 300d may be a HEMT (High Electron Mobility Transistor) using gallium arsenide and aluminum gallium arsenide, for example.

For the conductor 316 functioning as the gate electrode, a semiconductor material such as silicon containing an element that imparts n-type conductivity, such as arsenic or phosphorus, or an element that imparts p-type conductivity, such as boron or aluminum, can be used. Alternatively, for the conductor 316, a conductive material such as a metal material, an alloy material, or a metal oxide material can be used, for example.

Note that since the work function depends on the material of a conductor, the threshold voltage of the transistor can be adjusted by selecting the material of the conductor. Specifically, it is preferable to use one or both of titanium nitride and tantalum nitride as the material of the conductor. Moreover, in order to ensure both conductivity and embeddability, it is preferable to use stacked layers of metal materials of one or both of tungsten and aluminum for the conductor, and it is particularly preferable to use tungsten in terms of heat resistance.

The element isolation layer 312 is provided to separate a plurality of transistors formed on the substrate 310 from each other. The element isolation layer can be formed by, for example, a LOCOS (Local Oxidation of Silicon) method, an STI (Shallow Trench Isolation) method, or a mesa isolation method.

Over the transistor 300 illustrated in FIG. 80, an insulator 320 and an insulator 322 are sequentially stacked from the substrate 310 side.

For each of the insulator 320 and the insulator 322, one or more selected from silicon oxide, silicon oxynitride, silicon nitride oxide, silicon nitride, aluminum oxide, aluminum oxynitride, aluminum nitride oxide, and aluminum nitride are used, for example.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition. In the case where silicon nitride oxide is described, it refers to a material that contains more nitrogen than oxygen in its composition.

The insulator 322 may have a function of a planarization film for eliminating a level difference caused by the transistor 300 or the like covered with the insulator 320 and the insulator 322. For example, the top surface of the insulator 322 may be planarized by planarization treatment using a chemical mechanical polishing (CMP) method to improve planarity.

The conductor 328 connected to the transistor MTCK and the like provided above the insulator 322 is embedded in the insulator 320 and the insulator 322. Note that the conductor 328 has a function of a plug or a wiring. Therefore, for the conductor 328, a material that can be used for the conductor MPG described above can be used.

In the display apparatus DSP2A, the wiring region LIN is provided over the transistor 300d. The wiring region LIN includes, for example, the insulator 324, an insulator 326, the conductor 330, an insulator 350, an insulator 352, an insulator 354, and the conductor 356.

Over the insulator 322 and the conductor 328, the insulator 324 and the insulator 326 are sequentially stacked. An opening is formed in the insulator 324 and the insulator 326 in a region overlapping with the conductor 328. In addition, the conductor 330 is embedded in the opening.

The insulator 350, the insulator 352, and the insulator 354 are sequentially stacked over the insulator 326 and the conductor 330. An opening is formed in the insulator 350, the insulator 352, and the insulator 354 in a region overlapping with the conductor 330. The conductor 356 is embedded in the opening.

The conductor 330 and the conductor 356 have a function of a plug or a wiring that is connected to the transistor 300d. Note that the conductor 330 and the conductor 356 can be provided using a material similar to that for the conductor 328 or the conductor 596.

Note that like the insulator 592, for example, each of the insulator 324 and the insulator 350 is preferably formed using an insulator having a barrier property against one or more selected from hydrogen, oxygen, and water. Like the insulator 594, each of the insulator 326, the insulator 352, and the insulator 354 is preferably formed using an insulator having a relatively low dielectric constant to reduce parasitic capacitance generated between wirings. Each of the insulator 326, the insulator 352, and the insulator 354 has functions of an interlayer insulating film and a planarization film. Furthermore, each of the insulator 326, the insulator 352, and the insulator 354 preferably includes an insulator having a barrier property against one or more selected from hydrogen, oxygen, and water.

For the insulator having a barrier property against hydrogen, silicon nitride formed by a CVD method, which can also be used for the insulator 592, can be used, for example.

An insulator 512 is provided above the insulator 354 and the conductor 356. The insulator IS1 is provided over the insulator 512. The conductor 514 functioning as a plug or a wiring is embedded in the insulator IS1 and the insulator 512. Accordingly, one of the source and the drain of the transistor MTCK is electrically connected to one of the source and the drain of the transistor 300d. Note that for the conductor 514, a material that can be used for the conductor MPG can be used, for example.

The transistor MTCK is provided over the insulator IS1 and the conductor 514. The insulator 574 is formed over the transistor MTCK, and the insulator 581 is formed over the insulator 574. The conductor MPG functioning as a plug or a wiring is embedded in the insulator IS3, the insulator 574, and the insulator 581.

For the transistor MTCK and the insulator, the conductor, and the like in the vicinity of the transistor MTCK, the description of the transistor MTCK of the display apparatus DSP1A in FIG. 77 can be referred to.

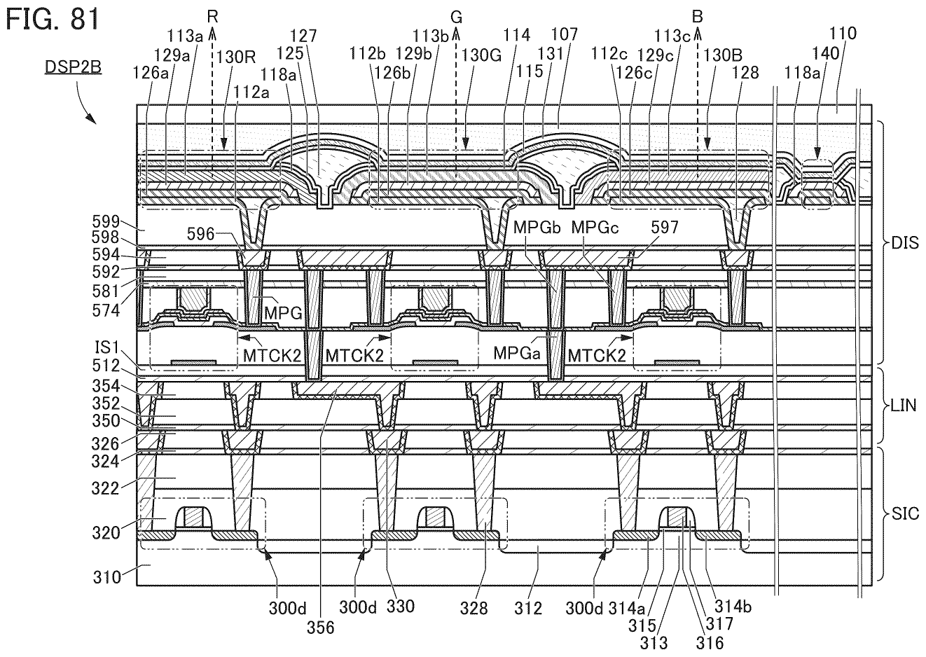

Although the display region DIS of the display apparatus DSP2A in FIG. 80 has a structure including the transistor MTCK, the display apparatus of one embodiment of the present invention may include the transistor MTCK2 instead of the transistor MTCK as in a display apparatus DSP2B illustrated in FIG. 81.

In the display apparatus DSP2B illustrated in FIG. 81, a conductor MPGa, a conductor MPGb, a conductor MPGc, and a conductor 597 each functioning as a plug or a wiring are embedded in insulators in the vicinity of the transistor MTCK2 to electrically connect the transistor MTCK2 and the transistor 300d. Specifically, the conductor MPGa is embedded in the insulator IS1 and the insulator IS2, the conductor MPGb and the conductor MPGc are embedded in the insulator GI1 and the insulator IS3, and the conductor 597 is embedded in the insulator 592 and the insulator 594. Thus, the transistor 300d and the transistor MTCK2 are electrically connected to each other through the conductor 328, the conductor 330, the conductor 356, the conductor MPGa, the conductor MPGb, the conductor 597, and the conductor MPGc.

For each of the conductor MPGa to the conductor MPGc, a material that can be used for the conductor MPG can be used. For the conductor 597, a material that can be used for the conductor 596 can be used.

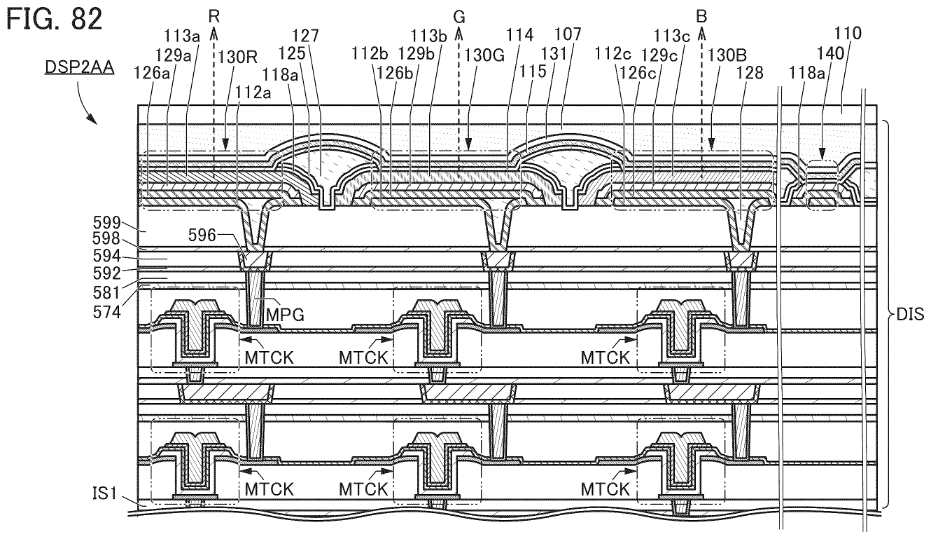

Although the display region DIS of the display apparatus DSP2A in FIG. 80 has a structure in which the transistor MTCK is included in one layer, the display apparatus of one embodiment of the present invention may have a structure in which a plurality of layers are provided in the display region DIS and the transistor MTCK is included in each of the plurality of layers as in a display apparatus DSP2AA illustrated in FIG. 82.

Note that although the display region DIS in the display apparatus DSP2AA in FIG. 82 is selectively illustrated, the wiring region LIN and the circuit region SIC are provided below the display region DIS.

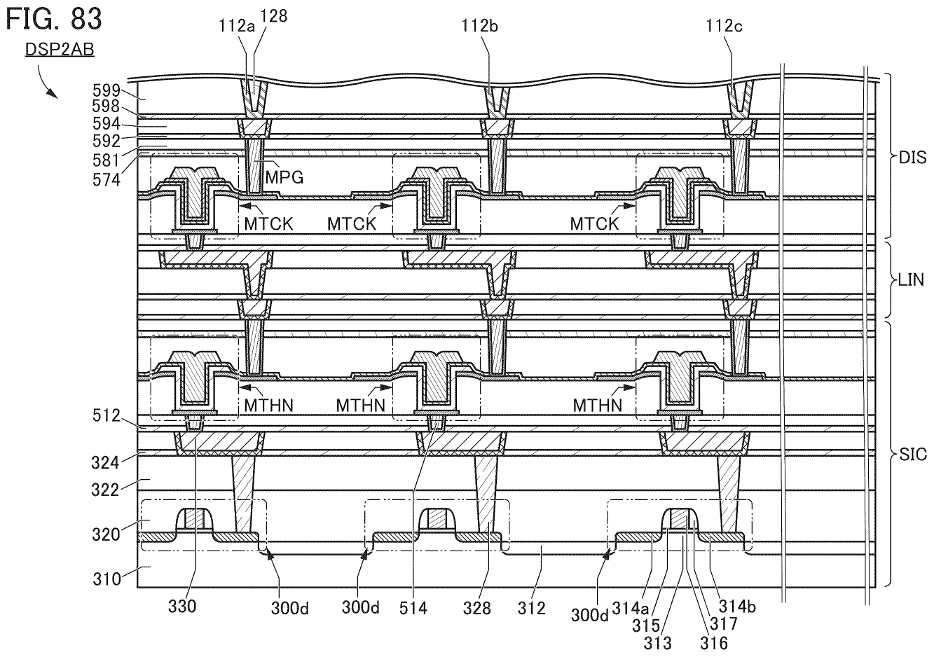

The display region DIS of the display apparatus DSP2A in FIG. 80 has a structure in which the transistor 300d is included in one layer in the circuit region SIC: alternatively, in the circuit region SIC of the display apparatus of one embodiment of the present invention, one layer including the transistor MTHN may be provided above the transistor 300d as in a display apparatus DSP2AB illustrated in FIG. 83. In the circuit region SIC, the number of layers including the transistor MTHN may be one or more (not illustrated).

Note that although part of the display region DIS, the wiring region LIN, and the circuit region SIC in the display apparatus DSP2AB in FIG. 83 are selectively illustrated, the light-emitting device 130 is provided above the transistor MTCK in the display region DIS.

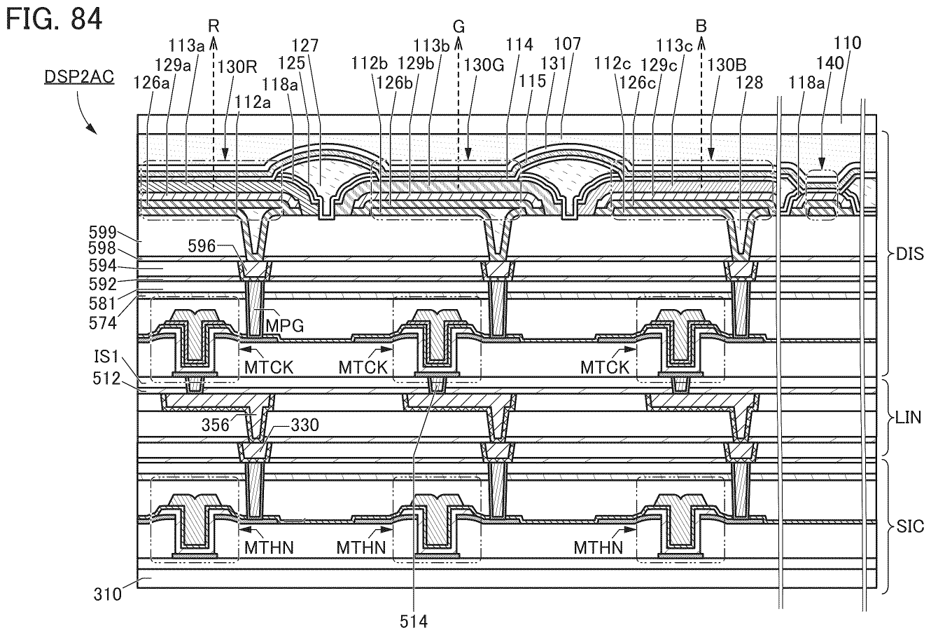

The structure of the transistor 300d in the display apparatus DSP2A in FIG. 80 may be modified to the structure of the transistor MTHN, for example. A display apparatus DSP2AC illustrated in FIG. 84 is a modification example of the display apparatus DSP2A in FIG. 80 and the transistor 300d has a structure similar to the structure of the transistor MTHN in FIG. 2A, FIG. 2B, and FIG. 2D.

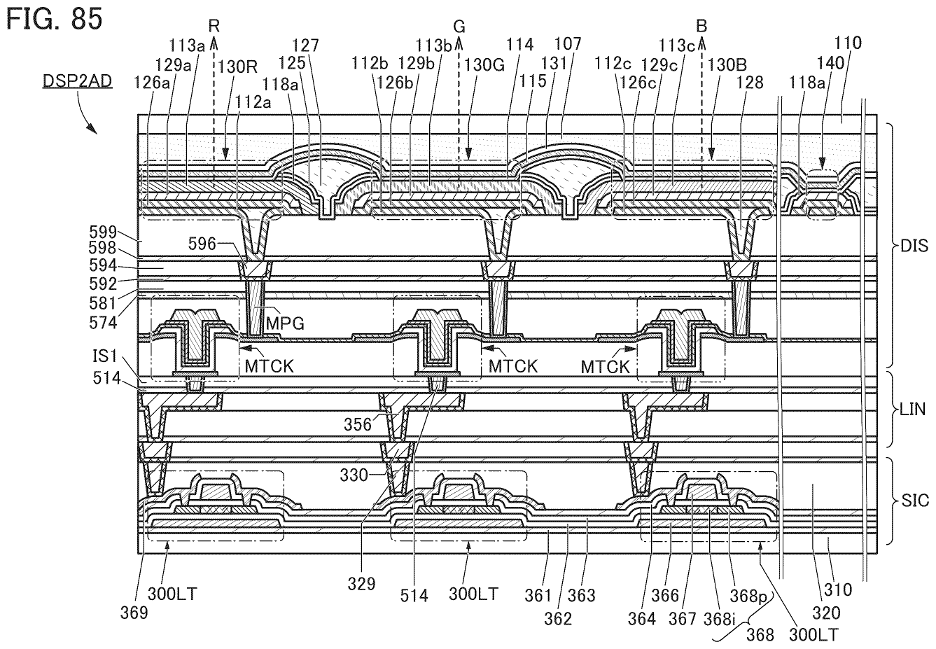

The transistor 300d in the display apparatus DSP2A in FIG. 80 may be a transistor containing low-temperature polysilicon in its channel formation region (hereinafter referred to as an LTPS transistor), for example. A display apparatus DSP2AD illustrated in FIG. 85 is a modification example of the display apparatus DSP2A in FIG. 80 and the structure of the transistor 300d is the structure of a transistor 300LT, which is an LTPS transistor. Note that the structure of the transistor 300LT is referred to as a TGTC structure in some cases.

The transistor 300LT is provided over the substrate 310. The transistor 300LT includes an insulator 361, an insulator 362, an insulator 363, an insulator 364, a conductor 366, a conductor 367, a low-resistance region 368p, a semiconductor region 368i, and a conductor 369. Here, a plurality of layers obtained by processing the same conductive film are shown with the same hatching pattern. In this specification and the like, the low-resistance region 368p and the semiconductor region 368i are collectively referred to as a semiconductor layer 368. In particular, when, for example, low-temperature polysilicon is used as a semiconductor material contained in the semiconductor layer 368, the transistor 300LT can be an LTPS transistor. The LTPS transistor has high field-effect mobility and excellent frequency characteristics.

In FIG. 85, the conductor 367 functions as a first gate (sometimes referred to as one of a gate and a back gate) of the transistor 300LT. The conductor 366 functions as a second gate (sometimes referred to as the other of the gate and the back gate) of the transistor 300LT. One of the pair of low-resistance regions 368p in the semiconductor layer 368 functions as one of a source and a drain of the transistor 300LT, and the other of the pair of low-resistance regions 368p in the semiconductor layer 368 functions as the other of the source and the drain of the transistor 300LT. The insulator 363 functions as a first gate insulating film in the transistor 300LT, and the insulator 362 functions as a second gate insulating film in the transistor 300LT.

In FIG. 85, the insulator 361 is formed over the substrate 310. The conductor 366 is formed in a region over the insulator 361. The insulator 362 is formed to cover the insulator 361 and the conductor 366. The semiconductor layer 368 is formed in a region overlapping with the conductor 366 and the insulator 362 and being over the insulator 362. The insulator 363 is formed to cover the insulator 362 and the semiconductor layer 368. The conductor 367 is formed in a region overlapping with the conductor 366, the insulator 362, the semiconductor layer 368, and the insulator 363 and being over the insulator 363. The insulator 364 is formed to cover the insulator 363 and the conductor 367. An opening portion is formed in the insulator 363 and the insulator 364 in regions overlapping with the low-resistance region 368p, and the conductor 369 is formed over the insulator 364 to fill the opening portion.

For each of the insulator 361, the insulator 362, the insulator 363, and the insulator 364, one or more selected from silicon oxide, silicon oxynitride, silicon nitride oxide, silicon nitride, aluminum oxide, aluminum oxynitride, aluminum nitride oxide, and aluminum nitride are used, for example.

In particular, a barrier insulating film that inhibits diffusion of impurities (e.g., a metal ion, a metal atom, an oxygen atom, an oxygen molecule, a hydrogen atom, a hydrogen molecule, and a water molecule) from a region below the insulator 361 (e.g., the substrate 310) is preferably used as the insulator 361.

The low-resistance region 368p is a region containing an impurity element. For example, in the case where the transistor 300LT is an n-channel transistor, phosphorus or arsenic is added to the low-resistance region 368p. In contrast, in the case where the transistor 300LT is a p-channel transistor, boron or aluminum is added to the low-resistance region 368p. In addition, in order to control the threshold voltage of the transistor 300, the above-described impurity may be added to the semiconductor region 368i.

Note that the transistor 300LT may be either a p-channel transistor or an n-channel transistor. Alternatively, a plurality of the transistors 300LT may be provided in the circuit region SIC and both the p-channel transistor and the n-channel transistor may be used.

For each of the conductor 366 and the conductor 367, a metal such as aluminum, titanium, chromium, nickel, copper, yttrium, zirconium, molybdenum, silver, tantalum, or tungsten can be used, for example. Alternatively, for each of the conductor 366 and the conductor 367, an alloy containing two or more selected from the above metals as its main components can be used. Alternatively, for each of the conductor 366 and the conductor 367, a light-transmitting conductive material such as indium oxide, indium tin oxide (ITO), indium oxide containing tungsten, indium zinc oxide containing tungsten, indium oxide containing titanium, ITO containing titanium, indium zinc oxide, zinc oxide (ZnO), ZnO containing gallium, or indium tin oxide containing silicon can be used. Alternatively, for each of the conductor 366 and the conductor 367, silicide (e.g., nickel silicide) or a semiconductor (e.g., polycrystalline silicon or an oxide semiconductor) whose resistance is lowered by, for example, containing an impurity element may be used. Alternatively, for each of the conductor 366 and the conductor 367, a film containing graphene can be used. The film containing graphene can be formed, for example, by reducing a film containing graphene oxide. Alternatively, a conductive paste (e.g., a conductive paste containing silver, carbon, or copper) or a conductive polymer (e.g., polythiophene) may be used for forming the conductor 366 and the conductor 367. A conductive paste is preferable because it is inexpensive. A conductive polymer is preferable because it is easily applied. Alternatively, one or both of the conductor 366 and the conductor 367 can have a single-layer structure containing any of the above materials or a structure (a stacked-layer structure) in which two or more selected from the above materials overlap each other.

The conductor 369 functions as a wiring electrically connected to the low-resistance region 368p of the transistor 300LT. That is, the conductor 369 functions as the source or the drain of the transistor 300LT. Note that for the conductor 369, any of the materials usable for the conductor 366 and the conductor 367 can be used.

A conductor 329 functioning as a plug or a wiring is embedded in the insulator 320. Accordingly, the transistor 300LT can be electrically connected to the transistor MTCK. Note that for the conductor 329, a material that can be used for the conductor 330 can be used.

Note that the display apparatus of one embodiment of the present invention is not limited to having the structures of the display apparatus DSP2A in FIG. 80, the display apparatus DSP2B in FIG. 81, the display apparatus DSP2AA in FIG. 82, the display apparatus DSP2AB in FIG. 83, the display apparatus DSP2AC in FIG. 84, and the display apparatus DSP2AD in FIG. 85. The structure of the display apparatus of one embodiment of the present invention may be the structure of the display apparatus which is modified as appropriate.

For example, the display apparatus of one embodiment of the present invention may have a structure in which a plurality of substrates are bonded to each other. Specifically, for example, a structure may be employed in which a first substrate provided with the display region DIS is bonded over a second substrate provided with the circuit region SIC by Cu-to-Cu (copper-to-copper) direct bonding technique or the like (not illustrated).

### <Cross-Sectional Structure Example 4 of Display Apparatus>

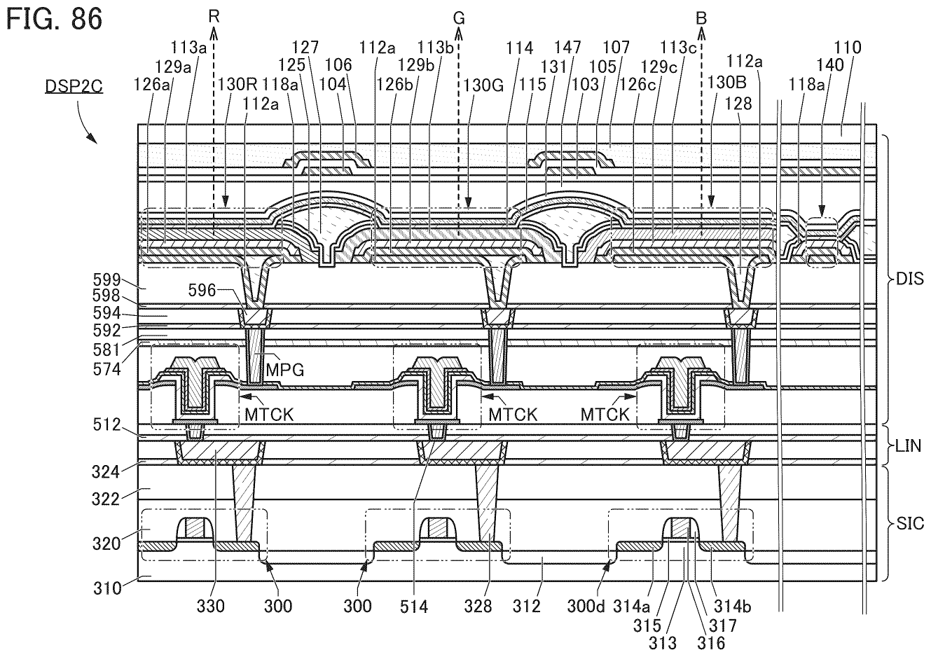

The display apparatus DSP2A illustrated in FIG. 80 may be provided with a panel having a touch sensor function (sometimes referred to as a touch panel), for example. In a display apparatus DSP2C illustrated in FIG. 86, a resin layer 147, an insulator 103, a conductor 104, an insulator 105, and a conductor 106 are formed in this order over the protective layer 131, for example.

The resin layer 147 preferably contains an organic insulating material. Examples of the organic insulating material include an acrylic resin, a polyimide resin, an epoxy resin, a polyamide resin, a polyimide-amide resin, a siloxane resin, a benzocyclobutene-based resin, a phenol resin, and a precursor of any of these resins.

The insulator 103 preferably contains an inorganic insulating material. Examples of the inorganic insulating material include oxide and nitride such as silicon oxide, silicon oxynitride, silicon nitride oxide, silicon nitride, aluminum oxide, aluminum oxynitride, and hafnium oxide.

The conductor 104 and the conductor 106 function as electrodes of a touch sensor. In the case of using a mutual capacitive touch sensor, a pulse potential may be supplied to one of the conductor 104 and the conductor 106, and an analog-digital (A-D) converter circuit or a sensing circuit such as a sense amplifier may be electrically connected to the other of the conductor 104 and the conductor 106, for example. In that case, a capacitor is formed between the conductor 104 and the conductor 106. When a finger or the like approaches the conductor 104 and the conductor 106, the electrostatic capacitance value changes. This change in the capacitance appears, when a pulse potential is supplied to one of the conductor 104 and the conductor 106, as a change in the amplitude of a signal that occurs in the other of the conductor 104 and the conductor 106. Accordingly, the touch and approach of the finger or the like can be sensed.

For the insulator 105, an inorganic insulating film or an organic insulating film can be used, for example. Specifically, for the insulator 105, a resin such as an acrylic resin or an epoxy resin can be used, for example. Alternatively, for the insulator 105, an inorganic insulating material such as silicon oxide, silicon oxynitride, silicon nitride oxide, silicon nitride, or aluminum oxide can be used, for example. Note that the insulator 105 may have either a single-layer structure or a stacked-layer structure.

Note that although FIG. 86 illustrates the structure in which the electrode of the touch sensor is provided above the light-emitting device 130, the touch sensor may be provided in the same layer as the light-emitting device 130 (not illustrated). For example, when formed concurrently with the light-emitting device 130, the touch sensor can be provided in the same layer as the light-emitting device 130.

### <Cross-Sectional Structure Example 5 of Display Apparatus>

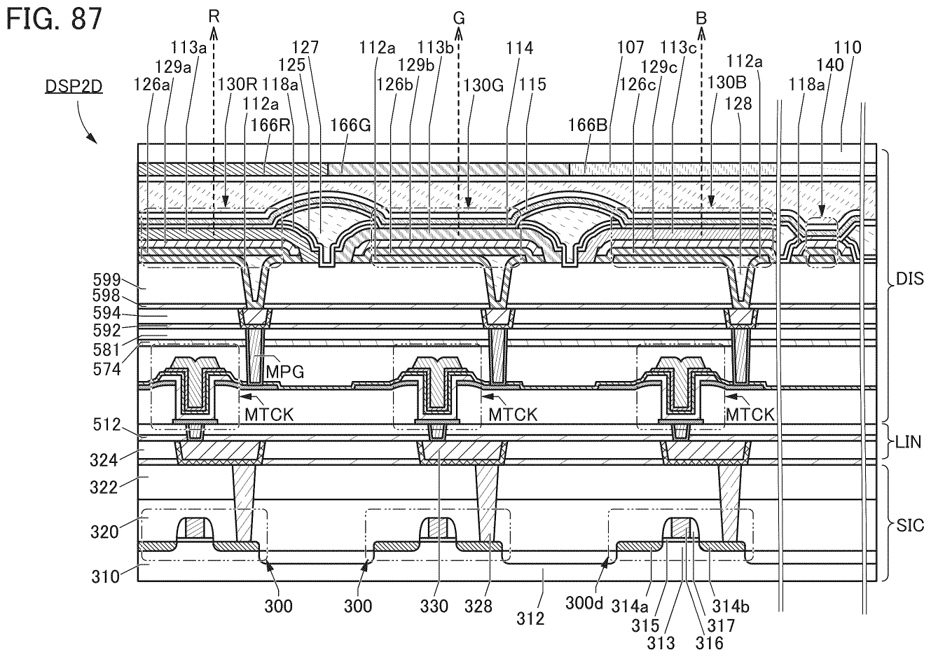

The display apparatus DSP2A illustrated in FIG. 80 may include, for example, a coloring layer (a color filter). A display apparatus DSP2D illustrated in FIG. 87 includes a coloring layer 166R, a coloring layer 166G, and a coloring layer 166B between the adhesive layer 107 and the substrate 110, for example. Note that the coloring layer 166R, the coloring layer 166G, and the coloring layer 166B can be formed on the substrate 110, for example. In the case where the light-emitting device 130R includes a light-emitting layer that emits red (R) light, the light-emitting device 130G includes a light-emitting layer that emits green (G) light, and the light-emitting device 130B includes a light-emitting layer that emits blue (B) light, the coloring layer 166R is a red coloring layer, the coloring layer 166G is a green coloring layer, and the coloring layer 166B is a blue coloring layer.

Note that a black matrix (not illustrated) may be provided between the coloring layer 166R and the coloring layer 166G, between the coloring layer 166G and the coloring layer 166B, and between the coloring layer 166G and the coloring layer 166B. Providing a black matrix in the display apparatus DSP2D can prevent light emitted from the light-emitting device from entering the color layer included in the adjacent pixel. This can enhance the display contrast, improving the display quality of the display apparatus DSP2D.

When one of the above structure examples is applied to a display apparatus, the display apparatus having high screen resolution and high definition can be achieved in some cases. Specifically, for example, a display apparatus with a screen resolution of HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320) can be achieved in some cases. Furthermore, specifically, for example, a display apparatus with a definition of higher than or equal to 100 ppi, higher than or equal to 300 ppi, higher than or equal to 500 ppi, higher than or equal to 1000 ppi, higher than or equal to 2000 ppi, higher than or equal to 3000 ppi, higher than or equal to 5000 ppi, or higher than or equal to 6000 ppi can be achieved in some cases.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 7

In this embodiment, a display module that can be used for the electronic device of one embodiment of the present invention will be described.

### <Structure Example of Display Module>

First, a display module including a display apparatus that can be used for the electronic device of one embodiment of the present invention will be described.

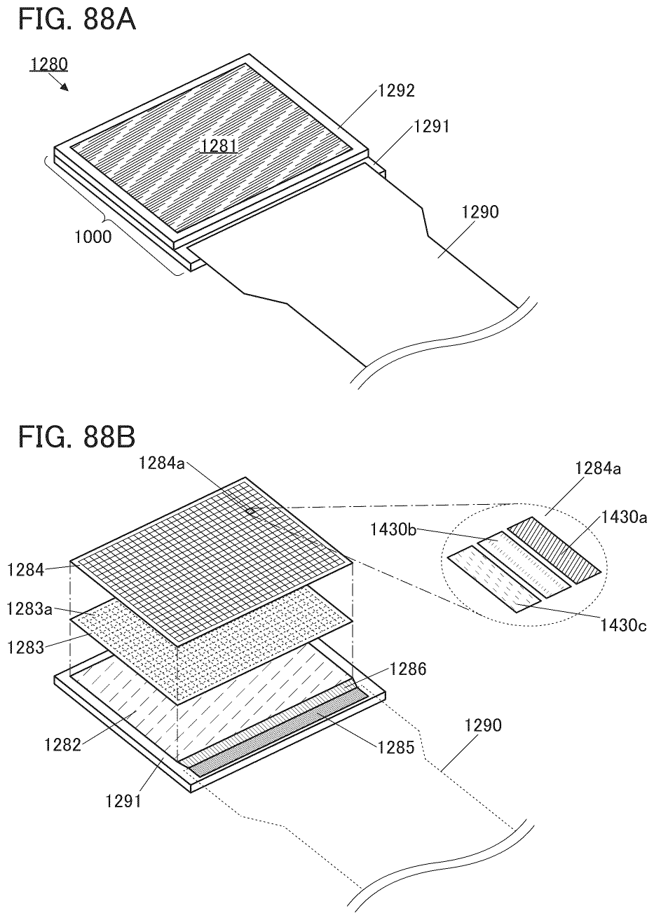

FIG. 88A is a perspective view of a display module 1280. The display module 1280 includes a display apparatus 1000 and an FPC 1290.

The display module 1280 includes a substrate 1291 and a substrate 1292. The display module 1280 includes a display portion 1281. The display portion 1281 is a region of the display module 1280 where an image is displayed, and is a region where light emitted from pixels provided in a pixel portion 1284 described later can be seen.

FIG. 88B is a perspective view schematically illustrating a structure on the substrate 1291 side. A circuit portion 1282, a pixel circuit portion 1283 over the circuit portion 1282, and the pixel portion 1284 over the pixel circuit portion 1283 are stacked over the substrate 1291. In addition, a terminal portion 1285 for connection to the FPC 1290 is provided in a portion not overlapping with the pixel portion 1284 over the substrate 1291. The terminal portion 1285 and the circuit portion 1282 are electrically connected to each other through a wiring portion 1286 formed of a plurality of wirings.

Note that the pixel portion 1284 and the pixel circuit portion 1283 correspond to the display region DIS described above, for example. The circuit portion 1282 corresponds to the circuit region SIC described above, for example.

The pixel portion 1284 includes a plurality of pixels 1284a arranged periodically. An enlarged view of one pixel 1284a is illustrated on the right side in FIG. 88B. The pixel 1284a includes a light-emitting device 1430a, a light-emitting device 1430b, and a light-emitting device 1430c that emit light of different colors. Note that the light-emitting device 1430a, the light-emitting device 1430b, and the light-emitting device 1430c correspond to the light-emitting device 130R, the light-emitting device 130G, and the light-emitting device 130B described above, for example. The above-described plurality of light-emitting devices may be arranged in a stripe pattern as illustrated in FIG. 88B. Alternatively, a variety of arrangement methods, such as S-stripe arrangement, matrix arrangement, delta arrangement, Bayer arrangement, and PenTile arrangement, can be employed.

The pixel circuit portion 1283 includes a plurality of pixel circuits 1283a arranged periodically.

One pixel circuit 1283a is a circuit that controls light emission from three light-emitting devices included in one pixel 1284a. One pixel circuit 1283a may be provided with three circuits each controlling light emission from one light-emitting device. For example, the pixel circuit 1283a can include at least one selection transistor, one current control transistor (driving transistor), and a capacitor for one light-emitting device. In that case, a gate signal is input to a gate of the selection transistor, and a source signal is input to one of a source and a drain of the selection transistor. Thus, an active-matrix display apparatus is achieved.

The circuit portion 1282 includes a circuit for driving the pixel circuits 1283a included in the pixel circuit portion 1283. For example, one or both of a gate line driver circuit and a source line driver circuit are preferably included. In addition, one or more selected from an arithmetic circuit, a memory circuit, and a power supply circuit may be included.

The FPC 1290 functions as a wiring for supplying a video signal or a power supply potential to the circuit portion 1282 from the outside. In addition, an IC may be mounted on the FPC 1290.

The display module 1280 can have a structure in which one or both of the pixel circuit portion 1283 and the circuit portion 1282 are stacked below the pixel portion 1284; thus, the aperture ratio (the effective display area ratio) of the display portion 1281 can be significantly high. For example, the aperture ratio of the display portion 1281 can be higher than or equal to 40% and lower than 100%, preferably higher than or equal to 50% and lower than or equal to 95%, further preferably higher than or equal to 60% and lower than or equal to 95%. Furthermore, the pixels 1284a can be arranged extremely densely and thus the display portion 1281 can have an extremely high definition. For example, the pixels 1284a are preferably arranged in the display portion 1281 with a definition higher than or equal to 100 ppi, preferably higher than or equal to 300 ppi, further preferably higher than or equal to 500 ppi, still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 6000 ppi, and lower than or equal to 20000 ppi or lower than or equal to 30000 ppi.

Such a display module 1280 has an extremely high definition and thus can be suitably used for a VR device such as a head-mounted display or a glasses-type AR device. For example, even with a structure in which the display portion of the display module 1280 is seen through a lens, pixels of the extremely-high-definition display portion 1281 included in the display module 1280 are prevented from being seen when the display portion is enlarged by the lens, so that display providing a strong sense of immersion can be performed. Without being limited thereto, the display module 1280 can be suitably used for electronic devices including relatively small display portions. For example, the display module 1280 can be suitably used for a display portion of a wearable electronic device such as a wristwatch.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 8

In this embodiment, electronic devices each including a display apparatus fabricated using one embodiment of the present invention will be described. Electronic devices described in this embodiment as examples are each provided with a display apparatus of one embodiment of the present invention in a display portion. Thus, the electronic devices achieve high definition.

One embodiment of the present invention includes the display apparatus and one or more selected from an antenna, a battery, a housing, a camera, a speaker, a microphone, a touch sensor, and an operation button.

The electronic device of one embodiment of the present invention may include a secondary battery, and it is preferable that the secondary battery be capable of being charged by contactless power transmission.

Examples of the secondary battery include a lithium ion secondary battery (such as a lithium polymer battery using a gel electrolyte (a lithium ion polymer battery)), a nickel-hydride battery, a nickel-cadmium battery, an organic radical battery, a lead-acid battery, an air secondary battery, a nickel-zinc battery, and a silver-zinc battery.

The electronic device of one embodiment of the present invention may include an antenna. With the antenna receiving a signal, the electronic device can display an image, information, or the like on a display portion. When the electronic device includes an antenna and a secondary battery, the antenna may be used for contactless power transmission.

The display portion of the electronic device of one embodiment of the present invention can display, for example, an image with full high definition, 4K2K, 8K4K, 16K8K, or higher screen resolution.

Examples of the electronic device include electronic devices having a relatively large screen, such as a television device, a laptop personal computer, a monitor device, digital signage, a pachinko machine, and a game machine. Other examples of the electronic device include a digital camera, a digital video camera, a digital photo frame, a mobile phone device, a portable game machine, a portable information terminal, and an audio reproducing device.

An electronic device to which one embodiment of the present invention is applied can be incorporated along an inner wall or an outer wall of a house or a building. The electronic device can be incorporated along a flat surface or a curved surface of an interior or an exterior of an automobile or the like.

### [Mobile Phone]

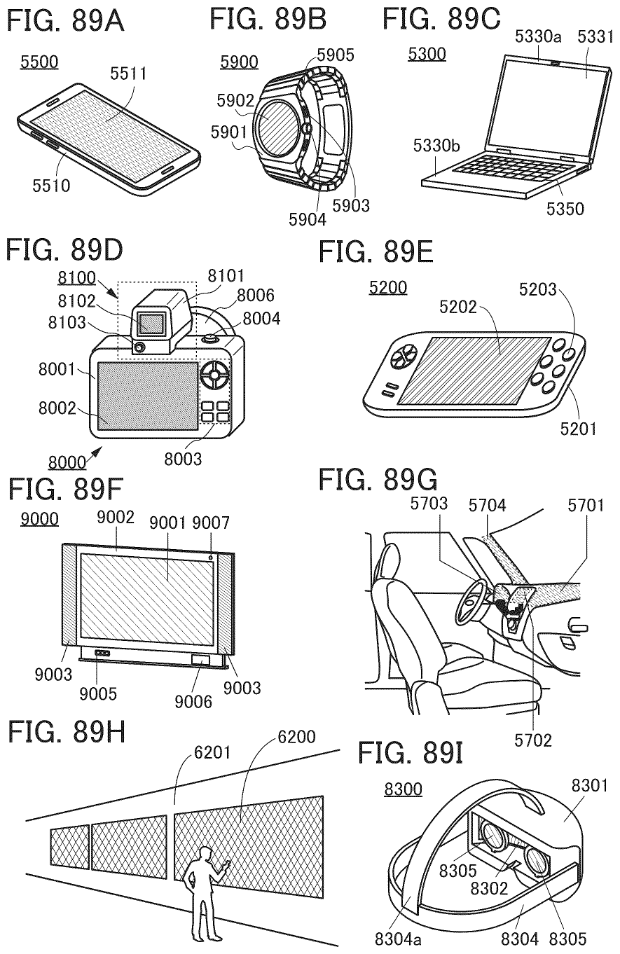

An information terminal 5500 illustrated in FIG. 89A is a mobile phone (smartphone), which is a type of information terminal. The information terminal 5500 includes a housing 5510 and a display portion 5511. As input interfaces, a touch panel and a button are provided in the display portion 5511 and the housing 5510, respectively.

### [Wearable Terminal]

FIG. 89B is an external view of an information terminal 5900, which is an example of a wearable terminal. The information terminal 5900 includes a housing 5901, a display portion 5902, an operation button 5903, a crown 5904, and a band 5905.

### [Information Terminal]

FIG. 89C illustrates a laptop information terminal 5300. The laptop information terminal 5300 illustrated in FIG. 89C includes, for example, a display portion 5331 in a housing 5330a and a keyboard portion 5350 in a housing 5330b.

Note that although FIG. 89A to FIG. 89C illustrate a smartphone, a wearable terminal, and a laptop information terminal as examples of electronic device in the above description, one embodiment of the present invention can also be applied to an information terminal other than a smartphone, a wearable terminal, and a laptop information terminal. Examples of the information terminals other than a smartphone, a wearable terminal, and a laptop information terminal include a PDA (Personal Digital Assistant), a desktop information terminal, and a workstation.

### [Camera]

FIG. 89D is an external view of a camera 8000 to which a finder 8100 is attached. The camera 8000 includes a housing 8001, a display portion 8002, operation buttons 8003, and a shutter button 8004. Furthermore, a detachable lens 8006 is attached to the camera 8000. The finder 8100 includes a housing 8101, a display portion 8102, and a button 8103.

Note that the lens 8006 may be included in the housing of the camera 8000.

Images can be taken with the camera 8000 at the press of the shutter button 8004 or the touch of the display portion 8002 serving as a touch panel.

The housing 8001 includes a mount including an electrode, so that a stroboscope, for example, as well as the finder 8100 can be connected to the housing 8001.

The housing 8101 is attached to the camera 8000 by a mount for engagement with the mount of the camera 8000. The finder 8100 can display an image received from the camera 8000 on the display portion 8102.

The button 8103 functions as a power supply button.

The display apparatus of one embodiment of the present invention can be used in the display portion 8002 of the camera 8000 and the display portion 8102 of the finder 8100. Note that a finder may be incorporated in the camera 8000.

### [Game Machine]

FIG. 89E is an external view of a portable game machine 5200, which is an example of a game machine. The portable game machine 5200 includes a housing 5201, a display portion 5202, and a button 5203.

An image displayed on the portable game machine 5200 can be output with a display apparatus included in a television device, a personal computer display, a game display, or a head-mounted display.

When the portable game machine 5200 includes the display apparatus described in the above embodiment, the portable game machine 5200 can have low power consumption. Furthermore, heat generation from a circuit can be reduced owing to low power consumption; thus, the influence of heat generation on the circuit, the peripheral circuit, and the module can be reduced.

Although FIG. 89E illustrates the portable game machine as an example of a game machine, the electronic device of one embodiment of the present invention is not limited thereto. Examples of the electronic device of one embodiment of the present invention include a stationary game machine, an arcade game machine installed in entertainment facilities (e.g., a game center and an amusement park), and a throwing machine for batting practice installed in sports facilities.

### [Television Device]

FIG. 89F is a perspective view illustrating a television device. A television device 9000 includes a housing 9002, a display portion 9001, a speaker 9003, an operation key 9005 (including a power switch or an operation switch), a connection terminal 9006, a sensor 9007 (for example, a sensor having a function of measuring force, displacement, position, speed, acceleration, angular velocity, rotational frequency, distance, light, liquid, magnetism, temperature, chemical substance, sound, time, hardness, electric field, current, voltage, power, radiation, flow rate, humidity, gradient, oscillation, odor, or infrared rays, and for another example, a sensor having a function of sensing or detecting odor or light (including infrared rays)). A memory device of one embodiment of the present invention can be provided in the television device. The television device can include the display portion 9001 having a screen size of, for example, 50 inches or more, or 100 inches or more.

When the television device 9000 includes the display apparatus described in the above embodiment, the television device 9000 can achieve low power consumption. Furthermore, heat generation from a circuit can be reduced owing to low power consumption; thus, the influence of heat generation on the circuit, the peripheral circuit, and the module can be reduced.

### [Moving Vehicle]

The display apparatus of one embodiment of the present invention can also be used around a driver's seat in a car, which is a moving vehicle.

FIG. 89G is a diagram illustrating a windshield and its vicinity inside a car. FIG. 89G illustrates a display panel 5701, a display panel 5702, and a display panel 5703 which are attached to a dashboard, and a display panel 5704 attached to a pillar.

The display panel 5701 to the display panel 5703 can display navigation data, a speedometer, a tachometer, a mileage, a fuel meter, a gearshift state, air-conditioning settings, and the like. Items displayed on the display panel and their layout can be changed as appropriate to suit the user's preferences, resulting in more sophisticated design. The display panel 5701 to the display panel 5703 can also be used as lighting devices.

The display panel 5704 can compensate for the view obstructed by the pillar (blind areas) by showing an image taken by an imaging unit provided for the car body. That is, displaying an image taken by the imaging unit provided on the outside of the car leads to elimination of blind areas and enhancement of safety. Moreover, showing an image to compensate for the area that cannot be seen makes it possible for a driver to confirm safety more easily and comfortably. The display panel 5704 can also be used as a lighting device.

The display apparatus of one embodiment of the present invention can be used for each of the display panel 5701 to the display panel 5704, for example.

Although a car is described above as an example of a moving vehicle, moving vehicles are not limited to a car. Examples of the moving vehicles include a train, a monorail train, a ship, and a flying object (for example, a helicopter, an unmanned aircraft (a drone), an airplane, and a rocket), and these moving vehicles can use the display apparatus of one embodiment of the present invention.

### [Digital Signage]

FIG. 89H shows an example of a digital signage that can be attached to a wall. FIG. 89H illustrates a state where a digital signage 6200 is attached to a wall 6201. The display apparatus of one embodiment of the present invention can be used in a display portion in the digital signage 6200, for example. An interface such as a touch panel may be provided in the digital signage 6200.

Note that an electronic device attachable to a wall is described above as an example of a digital signage, the kind of the digital signage is not limited thereto. Examples of the digital signage include a digital signage mounted on a pillar, a freestanding digital signage placed on the ground, and a digital signage mounted on a rooftop or a side wall of a building.

### [Head-Mounted Display]

FIG. 89I is an external view of an electronic device 8300 which is a head-mounted display for VR. The electronic device 8300 includes a housing 8301, a display portion 8302, a band-like fixing member 8304, a fixture member 8304a worn on a head, and a pair of lenses 8305.

Although not illustrated in FIG. 89I, the electronic device 8300 may include an interface such as an operation button or a power button.

A user can see display on the display portion 8302 through the lenses 8305. The display portion 8302 is preferably curved because the user can feel high realistic sensation. Another image displayed in another region of the display portion 8302 is seen through the lenses 8305, so that three-dimensional display using parallax can be performed. Note that the number of the display portions 8302 is not limited to one; two display portions 8302 may be provided for user's respective eyes.

As the display portion 8302, a display apparatus with extremely high definition is preferably used, for example. With use of a display apparatus with high definition for the display portion 8302, even when the display portion 8302 is enlarged by the lens 8305, the user does not see pixels and thus a more realistic image can be displayed.

The head-mounted display, which is an electronic device of one embodiment of the present invention, may have a structure of an electronic device which is a glasses-type head-mounted display, instead of the electronic device 8300 in FIG. 89I which is a goggles-type head-mounted display. In particular, a glasses-type head-mounted display is suitable for an electronic device for AR.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### Embodiment 9

In this embodiment, a structure example in which the semiconductor device described in the above embodiment is used for a memory device and an electronic device including the memory device will be described.

### <Structure Example of Memory Device>

The shift register SR provided in each of the driver circuit SD and the driver circuit GD described in Embodiment 1 and Embodiment 2 can be provided in a row decoder, a row driver, a column decoder, a column driver, or the like provided in a memory device. The transistor MTCK, the transistor MTHN, and the like described in the above embodiment can each be used as a transistor provided in a memory device 100.

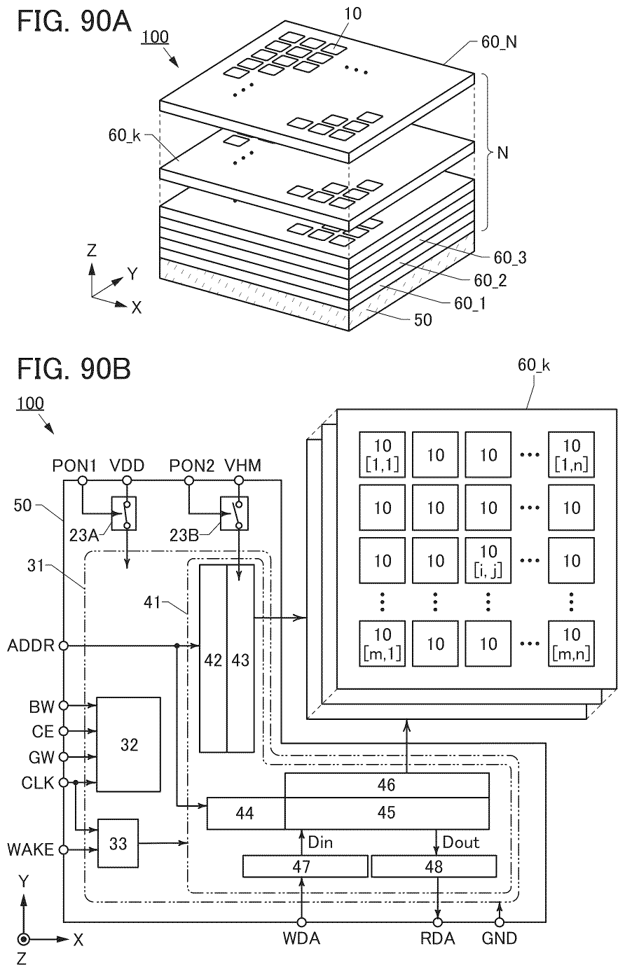

FIG. 90A is a schematic perspective view showing a structure example of the memory device 100. FIG. 90B is a block diagram showing the structure example of the memory device 100. The memory device 100 includes a driver circuit layer 50 and N (N is an integer greater than or equal to 1) memory layers 60. One memory layer 60 includes a plurality of memory cells 10 arranged in a matrix of m rows and n columns. Note that FIG. 90B shows an example in which a memory cell 10[1,1], a memory cell 10[m,1] (here, m is an integer greater than or equal to 1), a memory cell 10[1,n] (here, n is an integer greater than or equal to 1), a memory cell 10 [m,n], and a memory cell 10[i,j] (here, i is an integer greater than or equal to 1 and less than or equal to m, and j is an integer greater than or equal to 1 and less than or equal to n) are provided in a memory layer 60_k.

The N memory layers 60 are provided over the driver circuit layer 50. Provision of the N memory layers 60 over the driver circuit layer 50 can reduce the area occupied by the memory device 100. Furthermore, memory capacity per unit area can be increased.

In this embodiment, the first memory layer 60 is denoted by a memory layer 60_1, the second memory layer 60 is denoted by a memory layer 60_2, and the third memory layer 60 is denoted by a memory layer 60_3. Furthermore, the k-th memory layer 60 (k is an integer greater than or equal to 1 and less than or equal to N) is denoted by a memory layer 60_k, and the N-th memory layer 60 is denoted by a memory layer 60_N. Note that in this embodiment and the like, the simple term “memory layer 60” is sometimes used in the case of describing a matter related to all the N memory layers 60 or showing a matter common to the N memory layers 60.

### <<Structure Example of Driver Circuit Layer 50>>

The driver circuit layer 50 includes a PSW 23A (power switch), a PSW 23B, and a peripheral circuit 31. The peripheral circuit 31 includes a peripheral circuit 41, a control circuit 32, and a voltage generation circuit 33.

In the memory device 100, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 100. For example, the control circuit performs a logical operation on the signal CE, the signal GW, and the signal BW to determine an operation mode (e.g., a writing operation or a reading operation) of the memory device 100. The control circuit 32 generates a control signal for the peripheral circuit 41 so that the operation mode can be executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 10. The peripheral circuit 41 includes a row decoder 42, a column decoder 44, a row driver 43, a column driver 45, an input circuit 47, an output circuit 48, and a sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed.

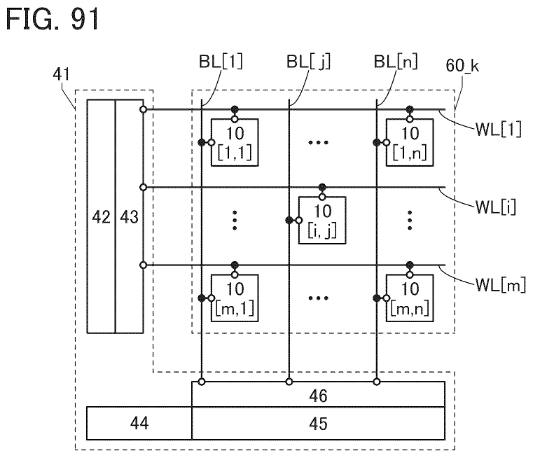

The row driver 43 has a function of selecting any one of word lines for writing and word lines for reading (e.g., any one of a wiring WL[1] to a wiring WL[m] illustrated in FIG. 91 described later) specified by the row decoder 42.

The column driver 45 has a function of writing data to the memory cells 10, a function of reading data from the memory cells 10, and a function of retaining the read data. The column driver 45 has a function of selecting write bit lines and read bit lines (e.g., any one of a wiring BL[1] to a wiring BL[n] illustrated in FIG. 91 described later) specified by the column decoder 44.

The input circuit 47 has a function of retaining the signal WDA. Data retained by the input circuit 47 is output to the column driver 45. Data output from the input circuit 47 is data (Din) to be written to the memory cells 10. Data (Dout) read from the memory cells 10 by the column driver 45 is output to the output circuit 48. The output circuit 48 has a function of retaining Dout. In addition, the output circuit 48 has a function of outputting Dout to the outside of the memory device 100. Data output from the output circuit 48 is the signal RDA.

The PSW 23A has a function of controlling supply of VDD to the peripheral circuit 31. The PSW 23B has a function of controlling supply of VHM to the row driver 43. Here, in the memory device 100, a high power supply voltage is VDD and a low power supply voltage is GND (a ground potential). In addition, VHM is a high power supply voltage used to set a word line at a high level and is higher than VDD. The on state and the off state of the PSW 23A are switched by the signal PON1, and the on state and the off state of the PSW 23B is switched by the signal PON2. The number of power domains to which VDD is supplied is one in the peripheral circuit 31 in FIG. 90B but can be more than one. In that case, a power switch is provided for each power domain.

Next, electrical connection between the peripheral circuit 41 and the memory layer 60 is described.

FIG. 91 is a block diagram showing a structure example of the peripheral circuit 41 and the memory layer 60_k. In FIG. 91, the row decoder 42 and the row driver 43 are electrically connected to each of the wiring WL[1] to the wiring WL[m], and the column decoder 44, the column driver 45, and the sense amplifier 46 are electrically connected to each of the wiring BL[1] to the wiring BL[n].

Note that the wiring WL[1] to the wiring WL[m] function as word lines. The wiring WL[1] to the wiring WL[m] may each be a wiring group in which a plurality of wirings are combined.

The wiring BL[1] to the wiring BL[n] function as word lines. The wiring BL[1] to the wiring BL[n] may each be a wiring group in which a plurality of wirings are combined.

The memory cell 10 [i,j] located at the i-th row and the j-th column is electrically connected to the wiring WL[i] and the wiring BL[f].

As illustrated in FIG. 91, the memory layer 60_k is electrically connected to the peripheral circuit 41, whereby data writing to the memory layer 60_k and data reading from the memory layer 60_k can be performed.

### <Examples of Electronic Products>

Electronic components, electronic devices, a large computer, space equipment, and a data center (also referred to as DC) in which the memory device described above can be used will be described. Electronic components, electronic devices, a large computer, space equipment, and a data center in which the memory device is used are effective in improving performance, e.g., reducing power consumption. Note that electronic components, electronic devices, a large computer, space equipment, and a data center are collectively referred to as electronic products in some cases.

### [Electronic Component]

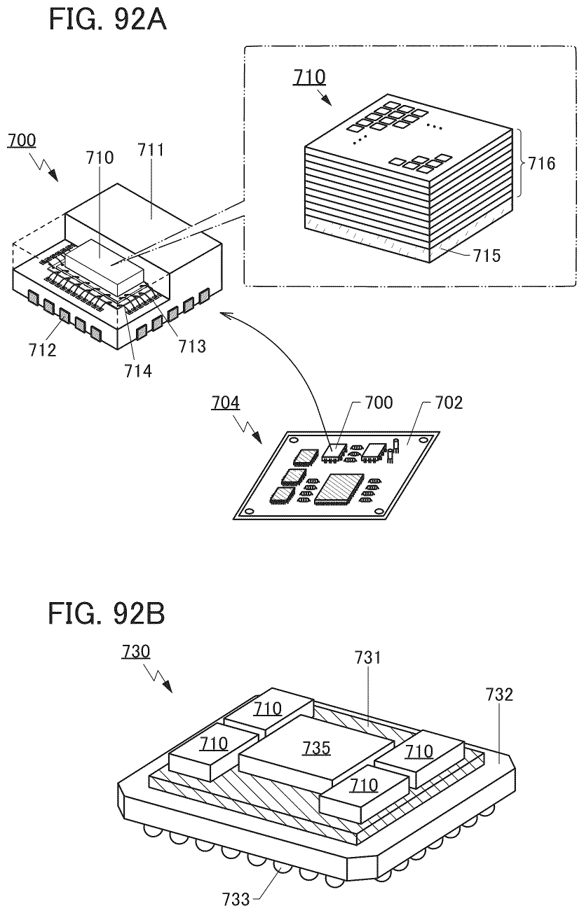

FIG. 92A shows a perspective view of a substrate (a circuit board 704) on which an electronic component 700 is mounted. The electronic component 700 illustrated in FIG. 92A includes a semiconductor device 710 in a mold 711. Some components are omitted in FIG. 92A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as TSV (Through Silicon Via) or a bonding technique such as Cu-to-Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and the plurality of memory cell arrays be monolithically stacked. Monolithically stacking the plurality of memory cell arrays can improve one or both of a memory bandwidth and a memory access latency. Note that a bandwidth refers to a data transfer volume per unit time, and an access latency refers to time from access to start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Examples of a semiconductor material that can be used for a die include silicon (Si), silicon carbide (SiC), and gallium nitride (GaN). A die obtained from a silicon substrate (also referred to as a silicon wafer) may be referred to as a silicon die, for example.

FIG. 92B shows a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP or an MCM that includes a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected to each other using a silicon interposer and TSV, a space for the width of the terminal pitches and the like is needed. Thus, in the case where the size of the electronic component 730 is to be reduced, the width of the terminal pitches causes a problem, which sometimes makes it difficult to provide a large number of wirings for a wide memory bandwidth. For this reason, the above-described monolithic stacked-layer structure using OS transistors is suitable. A composite structure combining memory cell arrays stacked using TSV and monolithically stacked memory cell arrays may be employed.

In addition, a heat sink (a radiator plate) may be provided to overlap with the electronic component 730. In the case of providing a heat sink, the levels of integrated circuits provided on the interposer 731 are preferably equal to each other. For example, in the electronic component 730 described in this embodiment, the levels of the semiconductor devices 710 and the semiconductor device 735 are preferably equal to each other.

To mount the electronic component 730 on another substrate, an electrode 733 may be provided on a bottom portion of the package substrate 732. FIG. 92B shows an example in which the electrode 733 is formed of a solder ball. Solder balls are provided in a matrix on the bottom portion of the package substrate 732, so that BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by any of various mounting methods not limited to BGA and PGA. Examples of a mounting method include an SPGA (Staggered Pin Grid Array), an LGA (Land Grid Array), a QFP (Quad Flat Package), a QFJ (Quad Flat J-leaded package), and a QFN (Quad Flat Non-leaded package).

### [Electronic Device]

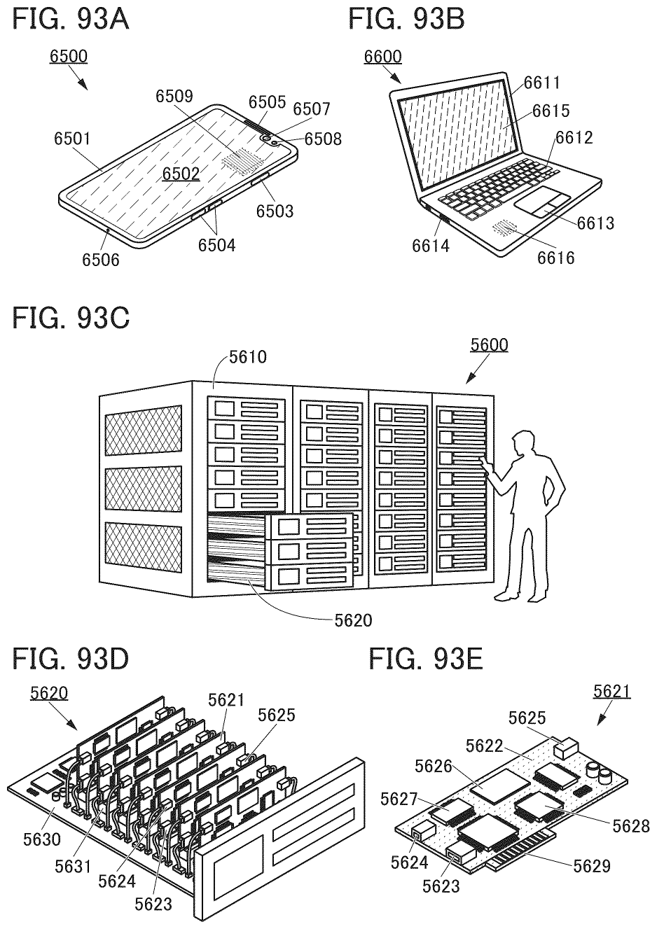

FIG. 93A shows a perspective view of an electronic device 6500. The electronic device 6500 illustrated in FIG. 93A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, and a control device 6509. One or more selected from a CPU, a GPU, and a memory device are provided as the control device 6509, for example. The semiconductor device of one embodiment of the present invention can be used for the display portion 6502, the control device 6509, and the like.

An electronic device 6600 illustrated in FIG. 93B is an information terminal that can be used as a laptop personal computer. The electronic device 6600 includes a housing 6611, a keyboard 6612, a pointing device 6613, an external connection port 6614, a display portion 6615, and a control device 6616. One or more selected from a CPU, a GPU, and a memory device are provided as the control device 6616, for example. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

FIG. 93C shows a perspective view of a large computer 5600. In the large computer 5600 illustrated in FIG. 93C, a plurality of rack mount computers 5620 are stored in a rack 5610. Note that the large computer 5600 may be referred to as a supercomputer.

The computer 5620 can have a structure in a perspective view shown in FIG. 93D, for example. In FIG. 93D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 93E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Although FIG. 93E illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used for space equipment such as equipment that processes and stores information.

The semiconductor device of one embodiment of the present invention can include an OS transistor. A change in electrical characteristics of the OS transistor due to radiation irradiation is small. That is, the OS transistor is highly resistant to radiation and thus can be suitably used in an environment where radiation can enter. For example, the OS transistor can be suitably used in outer space.

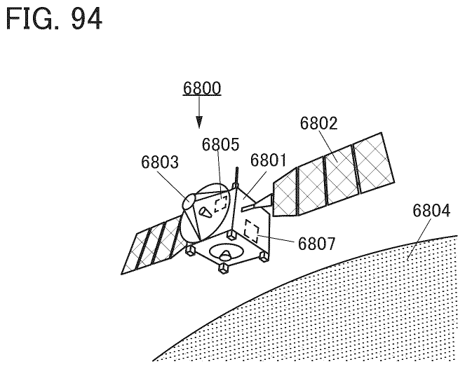

FIG. 94 illustrates an artificial satellite 6800 as an example of space equipment. The artificial satellite 6800 includes a body 6801, a solar panel 6802, an antenna 6803, a secondary battery 6805, and a control device 6807. FIG. 94 illustrates a planet 6804 in outer space, for example. Note that outer space refers to, for example, space at an altitude greater than or equal to 100 km, and outer space in this specification may also include thermosphere, mesosphere, and stratosphere.

Although not illustrated in FIG. 94, a battery management system (also referred to as BMS) or a battery control circuit may be provided in the secondary battery 6805. The battery management system or the battery control circuit preferably includes an OS transistor, in which case power consumption is low and high reliability is achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, power required for an operation of the artificial satellite 6800 is generated. However, for example, in the situation where the solar panel is not irradiated with sunlight or in the situation where the amount of sunlight with which the solar panel is irradiated is small, the amount of generated power is small. Accordingly, power required for an operation of the artificial satellite 6800 might not be generated. In order to operate the artificial satellite 6800 even with a small amount of generated power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. The control device 6807 is formed using one or more selected from a CPU, a GPU, and a memory device, for example. Note that the semiconductor device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of space equipment in this embodiment, one embodiment of the present invention is not limited thereto. The semiconductor device of one embodiment of the present invention can be suitably used for space equipment such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for a storage system used in a data center, for example. Long-term management of data, such as guarantee of data immutability, is required for the data center. The long-term management of data needs an increase in building size owing to installation of storages and servers for storing an enormous amount of data, a stable power source for data retention, cooling equipment necessary for data retention, and the like.

With use of the semiconductor device of one embodiment of the present invention for the storage system used in the data center, power required for data retention can be reduced and a semiconductor device retaining data can be downsized. Thus, downsizing of the storage system, downsizing of the power source for data retention, downscaling of the cooling equipment, and the like can be achieved, for example. This can reduce the space of the data center.

Since the semiconductor device of one embodiment of the present invention has low power consumption, heat generation from a circuit can be reduced. Accordingly, adverse effects of the heat generation on each of the circuit itself, the peripheral circuit, and the module can be reduced. Furthermore, the use of the semiconductor device of one embodiment of the present invention enables a data center that operates stably even in a high-temperature environment. Thus, the reliability of the data center can be increased.

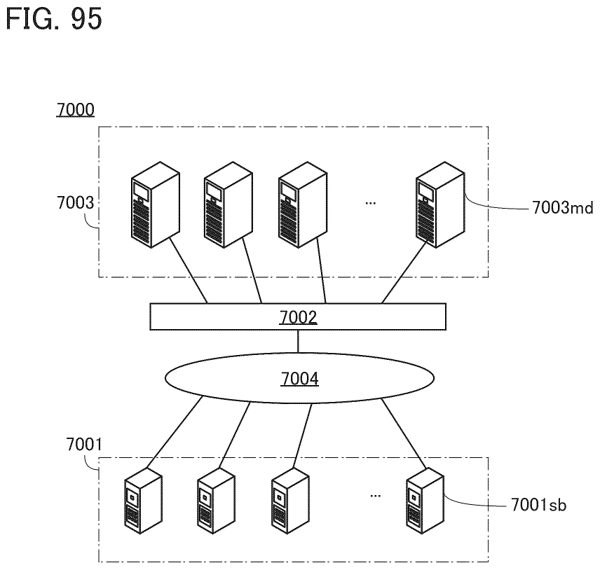

FIG. 95 illustrates a storage system that can be used in a data center. A storage system 7000 illustrated in FIG. 95 includes a plurality of servers 7001sb as a host 7001. The storage system 7000 includes a plurality of memory devices 7003md as a storage 7003. In the illustrated mode, the host 7001 and the storage 7003 are connected to each other through a storage area network 7004 and a storage control circuit 7002.

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but the time is still considerably longer than the time required for a DRAM that can be used as a cache memory in the storage. In the storage system, in order to solve the problem of low access speed of the storage 7003, a cache memory is usually provided in the storage to shorten the time taken for storing and outputting data.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing is possible by stacking memory cell arrays.

The use of the semiconductor device of one embodiment of the present invention for one or more selected from an electronic component, an electronic device, a large computer, space equipment, and a data center will produce an effect of reducing power consumption. While the demand for energy will increase with increasing performance and integration degree of semiconductor devices, the use of the semiconductor device of one embodiment of the present invention can thus reduce the emission amount of greenhouse gas typified by carbon dioxide (CO₂). The semiconductor device of one embodiment of the present invention can be effectively used as one of the global warming countermeasures because of its low power consumption.

Note that this embodiment can be combined with the same embodiment or any of the other embodiments in this specification as appropriate. For example, the configurations, structures, methods, and the like described in this embodiment can be used in an appropriate combination with any of the configurations, structures, methods, and the like described in the same embodiment. For another example, the configurations, structures, methods, and the like described in this embodiment can be used in an appropriate combination with any of the configurations, structures, methods, and the like described in the other embodiments and the like.

### REFERENCE NUMERALS

BF[1]: circuit, BF[m]: circuit, BS: substrate, BSL: bus wiring, C21: capacitor, C22: capacitor, CCL: capacitor, CPW: capacitor, CLK1: terminal, CLK2: terminal, CLK3: terminal, CLK4: terminal, CLK5: terminal, CLS: wiring, COM: wiring, CSL: wiring, CVT: converter circuit, DAC[1]: digital-to-analog converter circuit, DAC[5]: digital-to-analog converter circuit, DAC: digital-to-analog converter circuit, DAD: digital-to-analog converter circuit, DAT: wiring, DI: diode, DIS: display region, DRV: driver circuit region, DSP: display apparatus, ECR: EL correction circuit, ED: light-emitting device, EPS: power supply circuit, GD: driver circuit, GDR: driver circuit, GEM: conductor, GL: wiring, GLS[i]: wiring, GLS: wiring, GT: terminal, IL: wiring, IN1L: wiring, INIT: wiring, INV: inverter, INV1: inverter, INV2: inverter, INV3: inverter, INV4: inverter, INV5: inverter, INV10: inverter, IP: terminal, IT: terminal, ITA: terminal, ITB: terminal, KK: opening, LA[1]: first latch circuit, LA[5]: first latch circuit, LA: first latch circuit, LB[1]: second latch circuit, LB[5]: second latch circuit, LB: second latch circuit, LGC: circuit, LIN: wiring region, LI: terminal, LO1: terminal, LO2: terminal, LS[1]: level shifter circuit, LS[5]: level shifter circuit, LS: level shifter circuit, LSa: level shifter circuit, LTCSF: circuit, LV: level shifter circuit, LVS: amplifier circuit, MEM: memory device, MFNC: functional circuit region, MN: transistor, MN10: transistor, MN11: transistor, MN12: transistor, MN13: transistor, MN21: transistor, MN22: transistor, MN23: transistor, MN24: transistor, MN26: transistor, MN27: transistor, MN31: transistor, MN32: transistor, MN33: transistor, MN34: transistor, MN35: transistor, MN36: transistor, MN37: transistor, MN38: transistor, MN51: transistor, MN52: transistor, MN53: transistor, MN54: transistor, MN55: transistor, MN56: transistor, MN57: transistor, MN58: transistor, MN59: transistor, MP1: transistor, MP2: transistor, MP3: transistor, MP4: transistor, MP5: transistor, MP6: transistor, MP7: transistor, MP8: transistor, MP9: transistor, MP10: transistor, MPG: conductor, MPGa: conductor, MPGb: conductor, MPGc: conductor, MTCK: transistor, MTCK1: transistor, MTCK2: transistor, MTHN: transistor, MTHN1: transistor, MTHN2: transistor, OP: terminal, OPC: circuit, OT: terminal, OTA: terminal, OTB: terminal, OUTL: terminal, PDA: sensor, PLG: conductor, PRT: protection circuit, PWC: terminal, PX[i,j]: pixel circuit, PX: pixel circuit, PXA: pixel array, RES[1]: memory circuit, RES[2]: memory circuit, RES[5]: memory circuit, RES: memory circuit, RESA: memory circuit, RESB: memory circuit, RESC: memory circuit, RESCMS: memory circuit, RESD1: memory circuit, RESD2: memory circuit, RESD3: memory circuit, RESD4: memory circuit, RESD5: memory circuit, RESD6: memory circuit, RESD6A: memory circuit, RESD7: memory circuit, RESD7A: memory circuit, RESD8A: memory circuit, RESD9: memory circuit, RESD9A: memory circuit, RESD10: memory circuit, RESD10A: memory circuit, RESD11: memory circuit, RESD11A: memory circuit, RESD12: memory circuit, RESD12A: memory circuit, RESD12B: memory circuit, RESD13: memory circuit, RESD14: memory circuit, RESD14A: memory circuit, RESD15: memory circuit, RESD15A: memory circuit, RESPMS: memory circuit, SAM[1]: source follower circuit, SAM[5]: source follower circuit, SAM: source follower circuit, SAMa: source follower circuit, SAMb: source follower circuit, SCC: sensor controller, SD: driver circuit, SDD: conductor, SDR: driver circuit, SDU: conductor, SF: amplifier circuit, SG: wiring, SIC: circuit region, SIG[1]: image signal, SIG[2]: image signal, SL[1]: wiring, SL[5]: wiring, SL: wiring, SLS[j]: wiring, SLS: wiring, SMC: semiconductor, SNCL: wiring, SP: wiring, SR: shift register, SW: switch, SWP: switch, SWPL: wiring, T11: time, T12: time, T13: time, T14: time, TMC: timing controller, TMR: terminal region, TSD: driver circuit, VBIS: wiring, VBL: wiring, VCAT: wiring, VCOM: wiring, VDL: wiring, VDE11: wiring, VDE12: wiring, VDE13: wiring, VDE14: wiring, VDE15: wiring, VDE16: wiring, VDE17: wiring, VDE18: wiring, VDE19: wiring, VDE20: wiring, VE11: wiring, VE12: wiring, VE13: wiring, VE14: wiring, VE15: wiring, VE22: wiring, VE23: wiring, VE24: wiring, VE25: wiring, VEL: wiring, VIS: wiring, VSE10: wiring, VSE11: wiring, VSE16: wiring, VSE17: wiring, VSE18: wiring, VSE19: wiring, VSE21: wiring, VSE22: wiring, VSE23: wiring, VSE24: wiring, 21: CPU, 22a: circuit, 22b: circuit, 22: GPU, 23A: PSW, 23B: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 50: driver circuit layer, 60_1: memory layer, 60_2: memory layer, 60_3: memory layer, 60_N: memory layer, 100: memory device, 103: insulator, 104: conductor, 105: insulator, 106: conductor, 107: adhesive layer, 110: substrate, 112a: conductor, 112b: conductor, 112c: conductor, 113a: first layer, 113b: second layer, 113c: third layer, 114: common layer, 115: common electrode, 118a: mask layer, 125: insulator, 126a: conductor, 126b: conductor, 126c: conductor, 127: insulator, 128: layer, 129a: conductor, 129b: conductor, 129c: conductor, 130B: light-emitting device, 130G: light-emitting device, 130R: light-emitting device, 130: light-emitting device, 131: protective layer, 140: connection portion, 147: resin layer, 166B: coloring layer, 166G: coloring layer, 166R: coloring layer, 300d: transistor, 300LT: transistor, 300: transistor, 310: substrate, 312: element isolation layer, 313: semiconductor region, 314a: low-resistance region, 314b: low-resistance region, 315: insulator, 316: conductor, 317: insulator, 320: insulator, 322: insulator, 324: insulator, 326: insulator, 328: conductor, 329: conductor, 330: conductor, 350: insulator, 352: insulator, 354: insulator, 356: conductor, 361: insulator, 362: insulator, 363: insulator, 364: insulator, 366: conductor, 367: conductor, 368i: semiconductor region, 368p: low-resistance region, 368: semiconductor layer, 369: conductor, 512: insulator, 514: conductor, 574: insulator, 581: insulator, 592: insulator, 594: insulator, 596: conductor, 597: conductor, 598: insulator, 599: insulator, 700: electronic component, 702: printed circuit board, 704: circuit board, 710: semiconductor device, 711: mold, 712: land, 713: electrode pad, 714: wire, 715: driver circuit layer, 716: memory layer, 730: electronic component, 731: interposer, 732: package substrate, 733: electrode, 735: semiconductor device, 1000: display apparatus, 1280: display module, 1281: display portion, 1282: circuit portion, 1283a: pixel circuit, 1283: pixel circuit portion, 1284a: pixel, 1284: pixel portion, 1285: terminal portion, 1286: wiring portion, 1290: FPC, 1291: substrate, 1292: substrate, 1430a: light-emitting device, 1430b: light-emitting device, 1430c: light-emitting device, 5200: portable game machine, 5201: housing, 5202: display portion, 5203: button, 5300: laptop information terminal, 5330a: housing, 5330b: housing, 5331: display portion, 5350: keyboard portion, 5500: information terminal, 5510: housing, 5511: display portion, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5701: display panel, 5702: display panel, 5703: display panel, 5704: display panel, 5900: information terminal, 5901: housing, 5902: display portion, 5903: operation button, 5904: crown, 5905: band, 6200: digital signage, 6201: wall, 6500: electronic device, 6501: housing, 6502: display portion, 6504: button, 6505: speaker, 6507: camera, 6509: control device, 6600: electronic device, 6611: housing, 6612: keyboard, 6613: pointing device, 6614: external connection port, 6615: display portion, 6616: control device, 6800: artificial satellite, 6801: body, 6803: antenna, 6804: planet, 6805: secondary battery, 6807: control device, 7000: storage system, 7001: host, 7001sb: server, 7002: storage control circuit, 7003: storage, 7003md: memory device, 8000: camera, 8001: housing, 8002: display portion, 8003: operation button, 8004: shutter button, 8006: lens, 8100: finder, 8101: housing, 8102: display portion, 8103: button, 8300: electronic device, 8301: housing, 8302: display portion, 8304a: fixture member, 8304: fixture member, 8305: lens, 9000: television device, 9001: display portion, 9002: housing, 9003: speaker, 9005: operation key, 9006: connection terminal, 9007: sensor

1. A semiconductor device comprising:
a shift register and a source follower circuit,
wherein the shift register comprises a first transistor,
wherein the source follower circuit comprises a second transistor,
wherein the first transistor and the second transistor each comprise a first insulator,
wherein the first transistor comprises a first gate insulating film,
wherein the second transistor comprises a second gate insulating film,
wherein the first transistor comprises a first channel formation region along a side surface of a first opening formed in the first insulator,
wherein the second transistor comprises a second channel formation region along a side surface of a second opening formed in the first insulator,
wherein the first gate insulating film is positioned above the first channel formation region in a plan view,
wherein the second gate insulating film is positioned above the second channel formation region in the plan view, and
wherein a thickness of the second gate insulating film is larger than a thickness of the first gate insulating film.

2. The semiconductor device according to claim 1,
wherein the first gate insulating film comprises a second insulator,
wherein the second gate insulating film comprises the second insulator and a third insulator, and
wherein the third insulator is positioned over the second insulator.

3. The semiconductor device according to claim 2, comprising:
a latch circuit,
wherein the latch circuit comprises a third transistor,
wherein the third transistor comprises a third gate insulating film,
wherein the third transistor comprises a third channel formation region along a side surface of a third opening formed in the first insulator,
wherein the third gate insulating film is positioned above the third channel formation region in the plan view, and
wherein the third gate insulating film comprises the second insulator.

4. The semiconductor device according to claim 3, comprising:
a level shifter circuit,
wherein the level shifter circuit comprises a fourth transistor,
wherein the fourth transistor comprises a fourth gate insulating film,
wherein the fourth transistor comprises a fourth channel formation region along a side surface of a fourth opening formed in the first insulator,
wherein the fourth gate insulating film is positioned above the fourth channel formation region in the plan view, and
wherein the fourth gate insulating film comprises the second insulator and the third insulator.

5. The semiconductor device according to claim 4,
wherein the first channel formation region, the second channel formation region, the third channel formation region, and the fourth channel formation region each comprise one or more selected from indium, zinc, and an element M, and
wherein the element Mis one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, cobalt, magnesium, and antimony.

6. The semiconductor device according to claim 5,
wherein the side surfaces of the first opening, the second opening, the third opening, and the fourth opening each have a taper angle greater than or equal to 70° and less than or equal to 110°.

7. A display apparatus comprising the semiconductor device according to claim 6 and a pixel circuit,
wherein the pixel circuit comprises a driving transistor,
wherein the driving transistor comprises a fifth gate insulating film,
wherein the driving transistor comprises a fifth channel formation region above the first insulator,
wherein the fifth gate insulating film is positioned above the fifth channel formation region in the plan view, and
wherein the fifth gate insulating film comprises the second insulator and the third insulator.

8. The display apparatus according to claim 7,
wherein the fifth channel formation region comprises one or more selected from indium, zinc, and the element M.

9. The display apparatus according to claim 8,
wherein the pixel circuit comprises a light-emitting device, and
wherein the light-emitting device comprises an organic EL material.

10. An electronic device comprising the display apparatus according to claim 9 and a housing.

11. A semiconductor device comprising:
a first transistor, a second transistor, a third transistor, and a fourth transistor,
wherein the first transistor, the second transistor, the third transistor, and the fourth transistor each comprise a first conductor positioned below a first insulator and configured to be one of a source and a drain, a second conductor positioned above the first insulator and configured to be the other of the source and the drain, a semiconductor in contact with a side surface of an opening formed in the first insulator and in contact with the first conductor and the second conductor, a gate insulating film positioned over the semiconductor, and a gate electrode positioned over the gate insulating film,
wherein the gate insulating film of each of the first transistor and the second transistor is thicker than the gate insulating film of each of the third transistor and the fourth transistor,
wherein one of the first conductor and the second conductor of the first transistor is electrically connected to one of the first conductor and the second conductor of the second transistor, and
wherein one of the first conductor and the second conductor of the third transistor is electrically connected to one of the first conductor and the second conductor of the fourth transistor.

12. The semiconductor device according to claim 11,
wherein the gate insulating film of each of the first transistor and the second transistor comprises a second insulator,
wherein the gate insulating film of each of the third transistor and the fourth transistor comprises the second insulator and a third insulator, and
wherein the third insulator is positioned over the second insulator.

13. The semiconductor device according to claim 12, comprising:
a first circuit,
wherein the first circuit comprises a first terminal, a second terminal, a third terminal, and a fourth terminal,
wherein the first terminal is electrically connected to the gate electrode of the first transistor,
wherein the second terminal is electrically connected to the gate electrode of the second transistor,
wherein the third terminal is electrically connected to the gate electrode of the third transistor,
wherein the fourth terminal is electrically connected to the gate electrode of the fourth transistor, and
wherein the first circuit is configured to output one of a high-level potential and a low-level potential to each of the first terminal and the third terminal and configured to output the other of the high-level potential and the low-level potential to each of the second terminal and the fourth terminal.

14. A semiconductor device comprising:
a first transistor, a second transistor, a third transistor, a fourth transistor, a fifth transistor, a sixth transistor, a first capacitor, and a second capacitor,
wherein the first transistor, the second transistor, the third transistor, the fourth transistor, the fifth transistor, and the sixth transistor each comprise a first conductor positioned below a first insulator and configured to be one of a source and a drain, a second conductor positioned above the first insulator and configured to be the other of the source and the drain, a semiconductor in contact with a side surface of an opening formed in the first insulator and in contact with the first conductor and the second conductor, a gate insulating film positioned over the semiconductor, and a gate electrode positioned over the gate insulating film,
wherein the gate insulating film of each of the first transistor, the second transistor, and the fifth transistor is thicker than the gate insulating film of each of the third transistor, the fourth transistor, and the sixth transistor,
wherein one of the first conductor and the second conductor of the first transistor is electrically connected to one of the first conductor and the second conductor of the second transistor and one of a pair of terminals of the first capacitor,
wherein the gate electrode of the first transistor is electrically connected to one of the first conductor and the second conductor of the fifth transistor and the other of the pair of terminals of the first capacitor,
wherein one of the first conductor and the second conductor of the third transistor is electrically connected to one of the first conductor and the second conductor of the fourth transistor and one of a pair of terminals of the second capacitor,
wherein the gate electrode of the third transistor is electrically connected to one of the first conductor and the second conductor of the sixth transistor and the other of the pair of terminals of the second capacitor,
wherein the other of the first conductor and the second conductor of the fifth transistor is electrically connected to the other of the first conductor and the second conductor of the sixth transistor, and
wherein the gate electrode of the second transistor is electrically connected to the gate electrode of the fourth transistor.

15. The semiconductor device according to claim 14,
wherein the gate insulating film of each of the first transistor, the second transistor, and the fifth transistor comprises a second insulator,
wherein the gate insulating film of each of the third transistor, the fourth transistor, and the sixth transistor comprises the second insulator and a third insulator, and
wherein the third insulator is positioned over the second insulator.

16. The semiconductor device according to claim 15, comprising:
a first circuit,
wherein the first circuit comprises a first terminal and a second terminal,
wherein the first terminal is electrically connected to the other of the first conductor and the second conductor of the fifth transistor and the other of the first conductor and the second conductor of the sixth transistor,
wherein the second terminal is electrically connected to the gate electrode of the second transistor and the gate electrode of the fourth transistor, and
wherein the first circuit is configured to output one of a high-level potential and a low-level potential to the first terminal and configured to output the other of the high-level potential and the low-level potential to the second terminal.

17-30. (canceled)
